(19) United States
(12) Patent Application Publication
(10) Pub. No.: US 2023/0165141 A1
(43) Pub. Date: May 25, 2023

(54) ORGANIC LIGHT EMITTING ELEMENT

(71) Applicant: LG DISPLAY CO., LTD., Seoul (KR)

(72) Inventors: Seonkeun YOO, Paju-si (KR); Youngjun YU, Paju-si (KR); SangBeom KIM, Paju-si (KR)

(73) Assignee: LG DISPLAY CO., LTD., Seoul (KR)

(21) Appl. No.: 17/978,088

(22) Filed: Oct. 31, 2022

(30) Foreign Application Priority Data
Nov. 10, 2021 (KR) 10-2021-0154311

(51) Int. Cl. H01L 51/00

(52) U.S. Cl. CPC H01L 51/0067; H01L 51/0072; H01L 51/0071; H01L 51/0073; H01L 51/0074; H01L 51/5044

(57) ABSTRACT

Embodiments of the disclosure relate to an organic light emitting element. Specifically, there may be provided an organic light emitting element having high efficiency or long lifespan by including a first electrode, a second electrode, and an organic material layer positioned therebetween wherein the organic material layer includes a specific compound.

### CROSS-REFERENCE TO RELATED APPLICATION

This application claims priority from Korean Patent Application No. 10-2021-0154311, filed on Nov. 10, 2021, which is hereby incorporated by reference for all purposes as if fully set forth herein.

### BACKGROUND

### Technical Field

Embodiments of the disclosure relate to an organic light emitting element.

### Discussion of the Related Art

In general, organic light emission refers to a phenomenon in which electric energy is converted into light energy by an organic material. The organic light emitting element refers to a light emitting element using the organic light emission phenomenon. The organic light emitting element has a structure including an anode, a cathode, and an organic material layer disposed therebetween.

The organic material layer may have a multilayer structure composed of different materials to increase the efficiency and stability of the organic light emitting element and may include a light emitting layer (also referred to as an emission material layer (EML)).

The lifespan and efficiency are the most important issues with organic light emitting elements. The efficiency, lifespan, and driving voltage are related to each other. If the efficiency is increased, the driving voltage is relatively decreased, so that the crystallization of the organic material by the Joule heating during driving is reduced, leading to an increase in lifespan.

The role of the light emitting layer EML is important to enhance the light emitting properties of the organic light emitting element and increase the lifespan. In particular, to have high-efficiency characteristics, the host material of the light emitting layer is required to have a high triplet level, and the stability of the material is needed.

### SUMMARY

Accordingly, embodiments of the present disclosure are directed to an organic light emitting element that substantially obviates one or more of the problems due to limitations and disadvantages of the related art.

In order for the organic light emitting element to sufficiently exhibit its excellent characteristics, the materials constituting the organic material layer should be stable and have excellent efficiency. Since the phosphorescent organic light emitting element has a greater hole mobility than electron mobility in the light emitting layer and a long triplet state lifespan, excitons formed in the light emitting layer are distributed over a wide area, so that the light emission may be reduced. Accordingly, the inventors of the disclosure have invented an organic light emitting element that may have excellent efficiency or long lifespan.

An aspect of the present disclosure is to provide an organic light emitting element having high efficiency or long lifespan.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein an organic light emitting element comprises a first electrode, a second electrode, and an organic material layer positioned between the first electrode and the second electrode.

The organic material layer includes a compound represented by chemical formula 1 below:

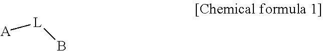

in chemical formula 1, A is chemical formula a, B is chemical formula b, and L is one of a direct bond, chemical formula L-1, chemical formula L-2, and chemical formula L-3.

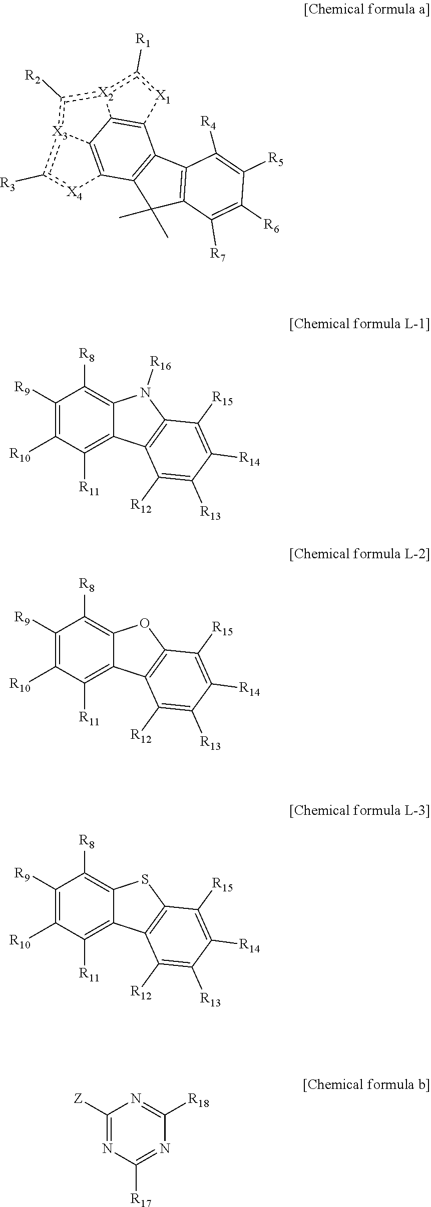

According to embodiments of the disclosure, there may be provided an organic light emitting element having high efficiency or long lifespan.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIGS. 1 and 2 are views schematically illustrating an organic light emitting element according to embodiments of the disclosure;

FIG. 3 is a view schematically illustrating an organic light emitting element according to embodiments of the disclosure; and

FIG. 4 is a view schematically illustrating an organic light emitting element according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

As used herein, the term “halo” or “halogen” includes fluorine (F), chlorine (Cl), bromine (Br), and iodine (I), and the like, unless otherwise specified.

As used herein, the term “alkyl” or “alkyl group” may mean a radical of a saturated aliphatic functional group having 1 to 60 carbon atoms linked by a single bond and including a straight chain alkyl group, branched chain alkyl group, cycloalkyl (alicyclic) group, alkyl-substituted cycloalkyl group, or cycloalkyl-substituted alkyl group, unless otherwise specified.

As used herein, the term “haloalkyl group” or “halogenalkyl group” may mean a halogen-substituted alkyl group unless otherwise specified.

As used herein, the term “alkenyl” or “alkynyl” may have a double bond or a triple bond, respectively, and may include a straight or branched chain group and may have 2 to 60 carbon atoms unless otherwise specified.

As used herein, the term “cycloalkyl” may refer to an alkyl forming a ring having 3 to 60 carbon atoms, unless otherwise specified.

As used herein, the term “alkoxy group” or “alkyloxy group” refers to an alkyl group to which an oxygen radical is bonded, and may have 1 to 60 carbon atoms unless otherwise specified.

As used herein, the term “alkenoxyl group”, “alkenoxy group”, “alkenyloxyl group”, or “alkenyloxy group” refers to an alkenyl group to which an oxygen radical is attached, and may have 2 to 60 carbon atoms unless otherwise specified.

As used herein, the terms “aryl group” and “arylene group” each may have 6 to 60 carbon atoms unless otherwise specified, but are not limited thereto. In the disclosure, the aryl group or the arylene group may include a monocyclic type, a ring assembly, a fused polycyclic system, a spiro compound, and the like. For example, the aryl group includes, but is not limited to, phenyl, biphenyl, naphthyl, anthryl, indenyl, phenanthryl, triphenylenyl, pyrenyl, peryleneyl, chrysenyl, naphthacenyl, or fluoranthenyl. The naphthyl may include 1-naphthyl and 2-naphthyl, and the anthryl may include 1-anthryl, 2-anthryl and 9-anthryl.

In the disclosure, the term “fluorenyl group” or “fluorenylene group” may refer to a monovalent or divalent functional group, respectively, of fluorene, unless otherwise specified. The “fluorenyl group” or “fluorenylene group” may mean a substituted fluorenyl group or a substituted fluorenylene group. “Substituted fluorenyl group” or “substituted fluorenylene group” may refer to a monovalent or divalent functional group of substituted fluorene. “Substituted fluorene” may mean that at least one of the following substituents R, R′, R″ and R′″ is a functional group other than hydrogen. It may include a case where R and R′ are bonded to each other to form a spiro compound together with the carbon to which they are bonded.

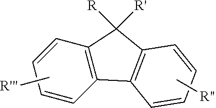

As used herein, the term “spiro compound” has a ‘spiro union’, and the spiro union means a union formed as two rings share only one atom. In this case, the atom shared by the two rings may be referred to as a ‘spiro atom’.

As used herein, the term “heterocyclic group” may include not only an aromatic ring, such as a “heteroaryl group” or “heteroarylene group” but also a non-aromatic ring and, unless otherwise specified, means a ring with 2 to 50 carbon atoms and one or more heteroatoms, but is not limited thereto. As used herein, the term “heteroatom” refers to N, O, S, P or Si unless otherwise specified, and the heterocyclic group may mean a monocyclic group containing a heteroatom, a ring assembly, a fused polycyclic system, or a spyro compound.

The “heterocyclic group” may include a ring containing SO2 instead of carbon forming the ring. For example, the “heterocyclic group” may include the following compounds.

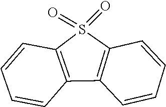 [SMILES: O=S1(=O)c2ccccc2-c2ccccc21]

As used herein, the term “ring” may include monocycles and polycycles, may include hydrocarbon rings as well as heterocycles containing at least one heteroatom, or may include aromatic and non-aromatic rings.

As used herein, the term “polycycle” may include ring assemblies, fused polycyclic systems, and spiro compounds, may include aromatic as well as non-aromatic compounds, or may include heterocycles containing at least one heteroatom as well as hydrocarbon rings.

As used herein, the term “aliphatic ring group” refers to a cyclic hydrocarbon other than the aromatic hydrocarbon, may include a monocyclic type, a ring assembly, a fused polycyclic system, and a spiro compound and, unless otherwise specified, may mean a ring having 3 to 60 carbon atoms. For example, a fusion of benzene, which is an aromatic ring, and cyclohexane, which is a non-aromatic ring, also corresponds to an aliphatic ring.

As used herein, the term “alkylsilyl group” may refer to a monovalent substituent in which three alkyl groups are bonded to a Si atom.

As used herein, the term “arylsilyl group” may refer to a monovalent substituent in which three aryl groups are bonded to a Si atom.

As used herein, the term “alkylarylsilyl group” may refer to a monovalent substituent in which one alkyl group and two aryl groups are bonded to a Si atom or two alkyl groups and one aryl group are bonded to the Si atom.

As used herein, the term “ring assembly” means that two or more ring systems (single or fused ring systems) are directly connected to each other through single or double bonds. For example, in the case of an aryl group, a biphenyl group or a terphenyl group may be a ring assembly but is not limited thereto.

As used herein, the term “fused polycyclic system” refers to a type of fused rings sharing at least two atoms. For example, in the case of an aryl group, a naphthalenyl group, a phenanthrenyl group, or a fluorenyl group may be a fused polycyclic system, but is not limited thereto.

When prefixes are named successively, it may mean that the substituents are listed in the order specified first. For example, an arylalkoxy group may mean an alkoxy group substituted with an aryl group, an alkoxycarbonyl group may mean a carbonyl group substituted with an alkoxy group, and an arylcarbonylalkenyl group may mean an alkenyl group substituted with an arylcarbonyl group. The arylcarbonyl group may be a carbonyl group substituted with an aryl group.

Unless otherwise explicitly stated, in the term “substituted” or “unsubstituted” as used herein, “substituted” may mean being substituted with one or more substituents selected from the group consisting of halogen, amino group, nitrile group, nitro group, C₁-C₂₀ alkyl group, C₁-C₂₀ alkoxy group, C₁-C₂₀ alkylamine group, C₁-C₂₀ alkylthiophene group, C₆-C₂₀ arylthiophene group, C₂-C₂₀ alkenyl group, C₂-C₂₀ alkynyl group, C₃-C₂₀ cycloalkyl group, C₆-C₂₀ aryl group, C₈-C₂₀ arylalkenyl group, silane group, boron group, germanium group, and C₂-C₂₀ heterocyclic group including at least one heteroatom selected from the group consisting of O, N, S, Si and P, but is not limited to the substituents.

In the disclosure, the ‘functional group names’ corresponding to the aryl group, arylene group, and heterocyclic group provided as examples of the symbols and their substituents may be described with ‘the names of the functional groups reflecting the valence’, but may also be described with ‘the names of the parent compounds.’ For example, in the case of ‘phenanthrene’, which is a type of aryl group, its name may be specified with its group identified, such as ‘phenanthryl (group)’ for the monovalent group, and ‘phenanthrylene (group)’ as the divalent group, but may also be specified as ‘phenanthrene’, which is the name of the parent compound, regardless of the valence. Similarly, pyrimidine may be specified as ‘pyrimidine’ regardless of the valence or may also be specified as pyrimidinyl (group) for the monovalence and as pyrimidylene (group) for the divalence. Therefore, in the disclosure, when the type of the substituent is specified with the name of the parent compound, it may mean an n-valent ‘group’ formed by detachment of the hydrogen atom bonded to a carbon atom and/or a heteroatom of the parent compound.

Further, unless explicitly stated, the formulas used in the disclosure may be applied in the same manner as the definition of the substituent by the the following formulas.

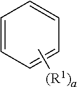

When a is 0, it means that the substituent R₁ does not exist, meaning that hydrogen is bonded to each of the carbon atoms forming the benzene ring. In this case, the chemical formula or chemical compound may be specified without expressing the hydrogen bonded to the carbon. Further, when a is 1, one substituent R₁ is bonded to any one of the carbon atoms forming the benzene ring, and when a is 2 or 3, it may be bonded as follows. When a is an integer of 4 to 6, it is bonded to the carbon of the benzene ring in a similar manner, and when a is an integer of 2 or more, R₁ may be identical or different.

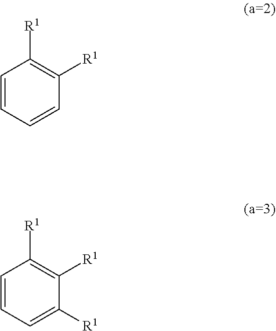

In the disclosure, when substituents are bonded to each other to form a ring, it may mean that adjacent groups are bonded to each other to form a monocycle or fused polycycle, and the monocycle or fused polycycle may include heterocycles containing at least one heteroatom as well as hydrocarbon rings and may include aromatic and non-aromatic rings.

In the disclosure, organic light emitting element may mean a component(s) between the anode and the cathode or an organic light emitting diode including an anode, a cathode, and component(s) positioned therebetween.

In some cases, in the disclosure, organic light emitting element may mean an organic light emitting diode and a panel including the same, or an electronic device including the panel and circuitry. The electronic device may include, e.g., a display device, a lighting device, a solar cell, a portable or mobile terminal (e.g., a smart phone, a tablet, a PDA, an electronic dictionary, or PMP), a navigation terminal, a game device, various TVs, and various computer monitors but, without limited thereto, may include any type of device including the component(s).

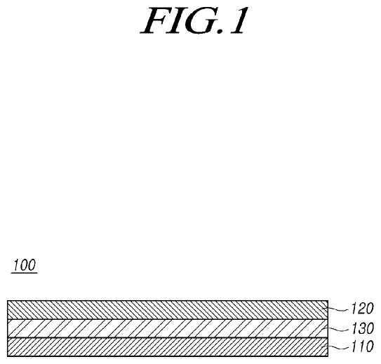

FIG. 1 is a view schematically illustrating an organic light emitting element according to embodiments of the disclosure.

The organic light emitting element 100 according to embodiments of the disclosure includes a first electrode 110, a second electrode 120, and an organic material layer 130 positioned between the first electrode 110 and the second electrode 120.

For example, the first electrode 110 may be the anode electrode, and the second electrode 120 may be the cathode electrode.

For example, the first electrode 110 may be a transparent electrode, and the second electrode 130 may be a reflective electrode. In another example, the first electrode 110 may be a reflective electrode, and the second electrode 130 may be a transparent electrode.

The organic material layer 130 is a layer positioned between the first electrode 110 and the second electrode 120 and including an organic material and may be composed of a plurality of layers.

The organic material layer 130 includes a compound represented by chemical formula 1. The compound represented by chemical formula 1 is described below in detail.

The organic material layer 130 may include a light emitting layer. The organic layer 130 may further include at least one of a hole injection layer, a hole transport layer, an electron transport layer, and an electron injection layer.

For example, the organic material layer 130 may include a hole injection layer positioned on the first electrode 110, a hole transport layer positioned on the hole injection layer, a light emitting layer positioned on the hole transport layer, an electron transport layer positioned on the light emitting layer, and an electron injection layer positioned on the electron transport layer. In such an example, the first electrode 110 may be the anode electrode, and the second electrode 120 may be the cathode electrode.

The light emitting layer is a layer in which as holes and electrons transferred from the first electrode 110 and the second electrode 130 meet to emit light and may include, e.g., a host material and a dopant.

The light emitting layer may include the compound represented by chemical formula 1 described above. The compound represented by chemical formula 1 may be the host compound of the light emitting layer. For example, the compound represented by chemical formula 1 may be a phosphorescent host compound of the light emitting layer.

The light emitting layer may further include a host compound different from the compound represented by chemical formula 1 described above. The type of the host compound that may be additionally included is not particularly limited, and a known host compound may be used.

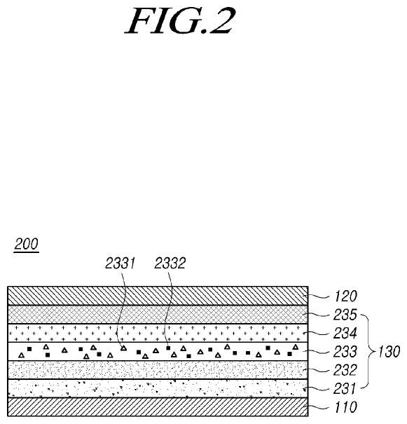

FIG. 2 is a view schematically illustrating an organic light emitting element according to embodiments of the disclosure.

The organic light emitting element 200 according to embodiments of the disclosure includes a first electrode 110, a second electrode 120, and an organic material layer 130 positioned between the first electrode 110 and the second electrode 120.

For example, the first electrode 110 may be the anode electrode, and the second electrode 120 may be the cathode electrode.

For example, the first electrode 110 may be a transparent electrode, and the second electrode 120 may be a reflective electrode. In another example, the first electrode 110 may be a reflective electrode, and the second electrode 120 may be a transparent electrode.

The organic material layer 130 is a layer positioned between the first electrode 110 and the second electrode 120 and including an organic material and may be composed of a plurality of layers.

The organic material layer 130 includes a compound represented by chemical formula 1. The compound represented by chemical formula 1 is described below in detail.

The organic material layer 130 may include a hole injection layer 231 positioned on the first electrode 110, a hole transport layer 232 positioned on the hole injection layer 231, a light emitting layer 233 positioned on the hole transport layer 232, an electron transport layer 234 positioned on the light emitting layer 233, and an electron injection layer 235 positioned on the electron transport layer 234. In such an example, the first electrode 110 may be the anode electrode, and the second electrode 120 may be the cathode electrode. The organic material layer 130 may not include some of the layers shown in FIG. 2 or may include an additional functional layer, such as a light emitting assist layer.

The light emitting layer 233 may include the compound represented by chemical formula 1 described above.

The light emitting layer 233 may include a host compound 2331 and a dopant 2332. The host compound 2331 may be a compound represented by chemical formula 1 described above. The host compound 2331 may further include another compound different from the compound represented by chemical formula 1 described above. For example, the host compound 2331 may include a compound represented by chemical formula 1 and a biscarbazole-based compound.

The type of the dopant 2332 is not particularly limited. For example, the dopant 2332 may be a green phosphorescent dopant. For example, the dopant 2332 may be a metal complex, such as of iridium.

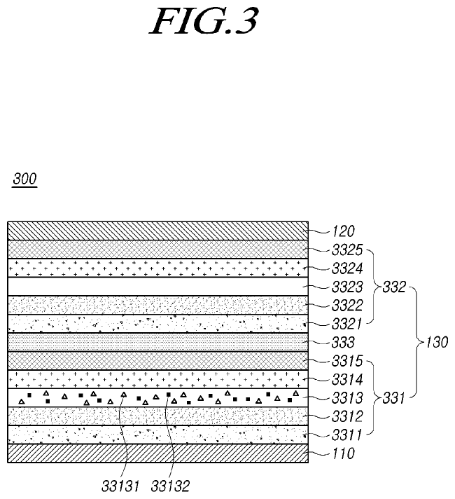

FIG. 3 is a view schematically illustrating an organic light emitting element according to embodiments of the disclosure.

Referring to FIG. 3, the organic material layer 130 includes a first stack 331, a second stack 332, and a charge generation layer 333 positioned between the first stack 331 and the second stack 332.

The organic light emitting element 300 may be a tandem-type organic light emitting element including a plurality of stacks each including a light emitting layer. The plurality of light emitting layers may be formed of the same material or different materials. The first stack 331 may include a first light emitting layer 3313. The second stack 332 may include a second light emitting layer 3323. The first light emitting layer 3313 and the second light emitting layer 3323 may be formed of the same material or different materials.

The first stack 331 may include a first light emitting layer 3313. The first light emitting layer 3313 may include, e.g., a first host compound 33131 and a first dopant 33132.

The first stack 231 may further include at least one of a hole injection layer, a hole transport layer, an electron transport layer, and an electron injection layer.

For example, the first stack 331 may include a first hole injection layer 3311 positioned on the first electrode 110, a first hole transport layer 3312 positioned on the first hole injection layer 3311, a first light emitting layer 3313 positioned on the first hole transport layer 3312, a first electron transport layer 3314 positioned on the first light emitting layer 3313, and a first electron injection layer 3315 positioned on the first electron transport layer 3314. In such an example, the first electrode 110 may be the anode electrode, and the second electrode 120 may be the cathode electrode. The first stack 331 may not include some of the layers shown in FIG. 3 or may include an additional functional layer, such as a light emitting assist layer.

The first light emitting layer 3313 may include the compound represented by chemical formula 1 described above.

The first light emitting layer 3313 may include a first host compound 33131 and a first dopant 33132. The first host compound 33131 may be a compound represented by chemical formula 1 described above. The first host compound 33131 may further include another compound different from the compound represented by chemical formula 1 described above. For example, the first host compound 33131 may include a compound represented by chemical formula 1 and a biscarbazole-based compound.

The type of the first dopant 33132 is not particularly limited. For example, the first dopant 33132 may be a green phosphorescent dopant. For example, the first dopant 33132 may be a metal complex, such as of iridium.

The second stack 332 may include a second light emitting layer 3323. The second light emitting layer 3323 may include, e.g., a second host compound and a second dopant.

The second stack 332 may further include at least one of a hole injection layer, a hole transport layer, an electron transport layer, and an electron injection layer.

For example, the second stack 332 may include a second hole injection layer 3321 positioned on the second electrode 110, a second hole transport layer 3322 positioned on the second hole injection layer 3321, a second light emitting layer 3323 positioned on the second hole transport layer 3322, a second electron transport layer 3324 positioned on the second light emitting layer 3323, and a second electron injection layer 3325 positioned on the second electron transport layer 3324. In such an example, the first electrode 110 may be the anode electrode, and the second electrode 120 may be the cathode electrode. The second stack 332 may not include some of the layers shown in FIG. 3 or may include an additional functional layer, such as a light emitting assist layer.

The second light emitting layer 3323 may emit light of the same color as, or a different color from, the light emitted by the first light emitting layer 3313. In the disclosure, that the light emitting layers emit light of the same color means that the light emitting layers emit not only light of colors with the same color coordinates but also light of colors similar to each other to be classified as pixels representing the same color in the technical field of the disclosure.

The second light emitting layer 3323 may include a second host compound and a second dopant.

The type of the second host compound is not particularly limited. The second host compound may be the same as, or different from, the first host compound 33131.

The type of the second dopant is not particularly limited. The second dopant may be the same as, or different from, the first dopant 33132.

In embodiments of the disclosure, the second light emitting layer 3323 may emit light of the same color as the light emitted by the first light emitting layer 3313. In the above-described embodiments, the first light emitting layer 3323 may include the compound represented by chemical formula 2 described above.

In embodiments in which the first light emitting layer 3313 and the second light emitting layer 3323 emit light of the same color, the second host compound may be a compound represented by chemical formula 1 described above. The second host compound may further include another compound different from the compound represented by chemical formula 1 described above. For example, the second host compound may include a compound represented by chemical formula 1 and a biscarbazole-based compound.

In embodiments in which the first light emitting layer 3313 and the second light emitting layer 3323 emit light of the same color, the type of the second dopant is not particularly limited and may be the same as the first dopant 33132. For example, the second dopant may be a green phosphorescent dopant. For example, the second dopant may be a metal complex, such as of iridium.

The charge generation layer 333 may be formed between the plurality of light emitting layers to smoothly distribute charges, thereby increasing the current efficiency of the light emitting layer. Accordingly, the charge generation layer 333 is positioned between the first stack 331 including the first light emitting layer 3313 and the second stack 332 including the second light emitting layer 3323.

The charge generation layer 333 may include a p-type charge generation layer and an n-type charge generation layer to smoothly distribute charges. When the first electrode 110 is the anode electrode, and the second electrode 120 is the cathode electrode, the p-type charge generation layer may be positioned on the side of the cathode electrode, and the n-type charge generation layer may be positioned on the side of the anode electrode.

Although FIG. 3 illustrates a tandem-type organic light emitting element including two stacks, embodiments of the disclosure are not limited thereto but may include tandem-type organic light emitting elements including two or more stacks. When the organic light emitting element 300 includes an additional stack, an additional charge generation layer may be positioned between the additional stack and the first stack 331 or second stack 332 adjacent thereto.

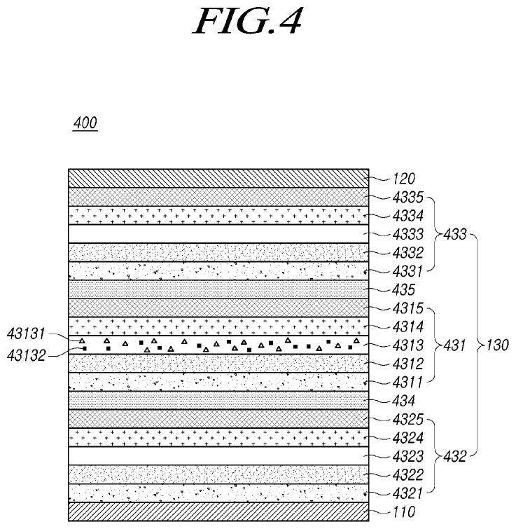

FIG. 4 is a view schematically illustrating an organic light emitting element according to embodiments of the disclosure.

Referring to FIG. 4, the organic material layer 130 includes a first stack 431, a second stack 432, a third stack 433, a first charge generation layer 434 positioned between the first stack 431 and the second stack 432, and a second charge generation layer 435 positioned between the first stack 431 and the third stack 433. In the embodiments illustrated in FIG. 4, the first stack 431 is positioned between the second stack 432 and the third stack 433, but embodiments of the disclosure including three stacks are limited to this structure, and the positions of the first stack 431, the second stack 432, and the third stack 433 may be exchanged with each other.

The organic light emitting element 400 may be a tandem-type organic light emitting element including a plurality of stacks each including a light emitting layer. The plurality of light emitting layers may be formed of the same material or different materials.

The first stack 431 may include a first light emitting layer 4313. The first light emitting layer 4313 may include, e.g., a first host compound 43131 and a first dopant 43132.

The first stack 431 may further include at least one of a hole injection layer, a hole transport layer, an electron transport layer, and an electron injection layer.

For example, the first stack 431 may include a first hole injection layer 4311 positioned on the first electrode 110, a first hole transport layer 4312 positioned on the first hole injection layer 4311, a first light emitting layer 4313 positioned on the first hole transport layer 4312, a first electron transport layer 4314 positioned on the first light emitting layer 4313, and a first electron injection layer 4315 positioned on the first electron transport layer 4314. In such an example, the first electrode 110 may be the anode electrode, and the second electrode 120 may be the cathode electrode. The first stack 431 may not include some of the layers shown in FIG. 4 or may include an additional functional layer, such as a light emitting assist layer.

The first light emitting layer 4313 may include the compound represented by chemical formula 1 described above.

The first light emitting layer 4313 may include a first host compound 43131 and a first dopant 43132. The first host compound 43131 may be a compound represented by chemical formula 1 described above. The first host compound 43131 may further include another compound different from the compound represented by chemical formula 1 described above. For example, the first host compound 43131 may include a compound represented by chemical formula 1 and a biscarbazole-based compound.

The type of the first dopant 43132 is not particularly limited. For example, the first dopant 43132 may be a green phosphorescent dopant. For example, the first dopant 43132 may be a metal complex, such as of iridium.

The second stack 432 may include a second light emitting layer 4323. The second light emitting layer 4323 may include, e.g., a second host compound 43231 and a second dopant 43232.

The second stack 432 may further include at least one of a hole injection layer, a hole transport layer, an electron transport layer, and an electron injection layer.

For example, the second stack 432 may include a second hole injection layer 4321 positioned on the second electrode 110, a second hole transport layer 4322 positioned on the second hole injection layer 4321, a second light emitting layer 4323 positioned on the second hole transport layer 4322, a second electron transport layer 4324 positioned on the second light emitting layer 4323, and a second electron injection layer 4325 positioned on the second electron transport layer 4324. In such an example, the first electrode 110 may be the anode electrode, and the second electrode 120 may be the cathode electrode. The second stack 432 may not include some of the layers shown in FIG. 4 or may include an additional functional layer, such as a light emitting assist layer.

The second light emitting layer 4323 may emit light of the same color as or a different color from, the light emitted by the first light emitting layer 4313.

The second light emitting layer 4323 may include a second host compound and a second dopant.

The type of the second host compound is not particularly limited. The second host compound may be the same as, or different from, the first host compound 43131.

The type of the second dopant is not particularly limited. The second dopant may be the same as, or different from, the first dopant 43132.

In embodiments of the disclosure, the second light emitting layer 4323 may emit light of the same color as the light emitted by the first light emitting layer 4313. In the above-described embodiments, the first light emitting layer 4323 may include the compound represented by chemical formula 2 described above.

In embodiments in which the first light emitting layer 4313 and the second light emitting layer 4323 emit light of the same color, the second host compound may be a compound represented by chemical formula 1 described above. The second host compound may further include another compound different from the compound represented by chemical formula 1 described above. For example, the second host compound may include a compound represented by chemical formula 1 and a biscarbazole-based compound.

In embodiments in which the first light emitting layer 4313 and the second light emitting layer 4323 emit light of the same color, the type of the second dopant is not particularly limited and may be the same as the first dopant 43132. For example, the second dopant may be a green phosphorescent dopant. For example, the second dopant may be a metal complex, such as of iridium.

The third stack 433 may include a third light emitting layer 4333. The third light emitting layer 4333 may include, e.g., a third host compound and a third dopant.

The third stack 432 may further include at least one of a hole injection layer, a hole transport layer, an electron transport layer, and an electron injection layer.

For example, the third stack 432 may include a third hole injection layer 4331 positioned on the third electrode 110, a third hole transport layer 4332 positioned on the third hole injection layer 4331, a third light emitting layer 4333 positioned on the third hole transport layer 4332, a third electron transport layer 4334 positioned on the third light emitting layer 4333, and a third electron injection layer 4335 positioned on the third electron transport layer 4334. In such an example, the first electrode 110 may be the anode electrode, and the second electrode 120 may be the cathode electrode. The third stack 433 may not include some of the layers shown in FIG. 4 or may include an additional functional layer, such as a light emitting assist layer.

The third light emitting layer 4333 may emit light of the same color as or a different color from, the light emitted by the first light emitting layer 4313.

The third light emitting layer 4333 may include a third host compound and a third dopant.

The type of the third host compound is not particularly limited. The third host compound may be the same as, or different from, the first host compound 43131.

The type of the third dopant is not particularly limited. The third dopant may be the same as, or different from, the first dopant 43132.

In embodiments of the disclosure, the third light emitting layer 4333 may emit light of the same color as the light emitted by the first light emitting layer 4313. In the above-described embodiments, the first light emitting layer 4333 may include the compound represented by chemical formula 3 described above.

In embodiments in which the first light emitting layer 4313 and the third light emitting layer 4333 emit light of the same color, the third host compound may be a compound represented by chemical formula 1 described above. The third host compound may further include another compound different from the compound represented by chemical formula 1 described above. For example, the third host compound may include a compound represented by chemical formula 1 and a biscarbazole-based compound.

In embodiments in which the first light emitting layer 4313 and the third light emitting layer 4333 emit light of the same color, the type of the second dopant is not particularly limited and may be the same as the first dopant 43132. For example, the second dopant may be a green phosphorescent dopant. For example, the second dopant may be a metal complex, such as of iridium.

The first host compound 43131, the second host compound, and the third host compound may be the same as or different from each other. One or more of the first host compound 43131, the second host compound, and the third host compound may be a compound represented by chemical formula 1 described above. Accordingly, one of the first host compound 43131, the second host compound, and the third host compound may include a compound represented by chemical formula 1 described above. Two of the first host compound 43131, the second host compound, and the third host compound may include a compound represented by chemical formula 1 described above. All of the first host compound 43131, the second host compound, and the third host compound may include a compound represented by chemical formula 1 described above. When there are two or more light emitting layers containing a host compound including the compound represented by chemical formula 1, the two or more light emitting layers may emit light of the same color.

The first dopant 33132, the second dopant, and the third dopant may be the same as or different from each other.

As the first stack 431, the second stack 432, and the third stack 433 are configured as described above, the holes and electrons transferred from the first electrode 110 and the second electrode 120 meet at the first light emitting layer 4313, the second light emitting layer 4323, and the third light emitting layer 4333, emitting light.

The first charge generation layer 434 and second charge generation layer 435 may be formed between the plurality of light emitting layers to smoothly distribute charges, thereby increasing the current efficiency of the light emitting layer. Accordingly, the first charge generation layer 434 may be positioned between the first stack 431 including the first light emitting layer 4313 and the second stack 432 including the second light emitting layer 4323, and the second charge generation layer 435 may be positioned between the second stack 432 including the second light emitting layer 433 and the third stack 433 including the third light emitting layer 4333.

The first charge generation layer 434 and second charge generation layer 435 may include a p-type charge generation layer and an n-type charge generation layer to smoothly distribute charges. When the first electrode 110 is the anode electrode, and the second electrode 120 is the cathode electrode, the p-type charge generation layer may be positioned on the side of the cathode electrode, and the n-type charge generation layer may be positioned on the side of the anode electrode.

The first charge generation layer 434 and the second charge generation layer 435 may be the same as or different from each other. The first charge generation layer 434 and the second charge generation layer 435 may be formed of the same material or different materials.

The compound represented by chemical formula 1 described above is described below.

The compound represented by chemical formula 1 described above is described below.

The compound represented by chemical formula 1 described above may be represented by chemical formula 1 as follows.

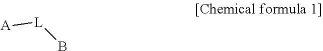

In chemical formula 1, A is chemical formula a below, B is chemical formula b below, and L is one of a direct bond, chemical formula L-1 below, chemical formula L-2 below, and chemical formula L-3 below.

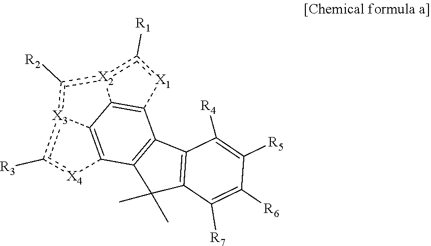

In chemical formula a, X₁, X₂, X₃ and X₄ are selected from among N, S, O, and R₁₆, i) if X₁ is N, X₂ is selected from O and S and, along with X₁, forms a pentagonal ring, X₃ and X₄ are R₁₆ and ii) if X₂ is N, X₁ or X₃ is selected from O and S and, along with X₂, forms a pentagonal ring, X₁, X₃ and X₄ which do not form a pentagonal ring are R₁₆, iii) if X₃ is N, X₂ or X₄ is selected from O and S and, along with X₃, forms a pentagonal ring, X₁, X₂ and X₄ which do not form a pentagonal ring are R₁₆ and iv) if X₄ is N, X₃ is selected from O and S, and X₄ and, along with X₄, form a pentagonal ring, and X₁ and X₂ are R₁₆.

R₁, R₂ and R₃ are each independently selected from the group consisting of hydrogen; a C₁-C₂₀ alkyl group; a C₃-C₃₀ cycloalkyl group; an alkoxy group; an aryloxy group; an alkyl thioxy group; an arylthioxy group; an alkyl sulfoxy group; an arylsulfoxy group; a C₆-C₆₀ aryl group; a fluorenyl group; and a C₂-C₆₀ heterocyclic group containing at least one heteroatom of O, N, S, Si and P.

When one or more of R₁, R₂, and R₃ are aryl groups, the aryl groups may each independently be a C₆-C₃₀ aryl group, a C₆-C₂₀ aryl group, or a C₆-C₁₂ aryl group.

When one or more of R₁, R₂, and R₃ are heterocyclic groups, the heterocyclic groups may each independently be a C₂-C₃₀ heterocyclic group, a C₂-C₂₀ heterocyclic group, or a C₂-C₁₂ heterocyclic group.

R₄, R₅, R₆, R₇ and R₁₆ are each independently hydrogen or C₆-C₆₀ aryl groups, and one of R₄, R₅, R₆ and R₇ is a direct bond with L.

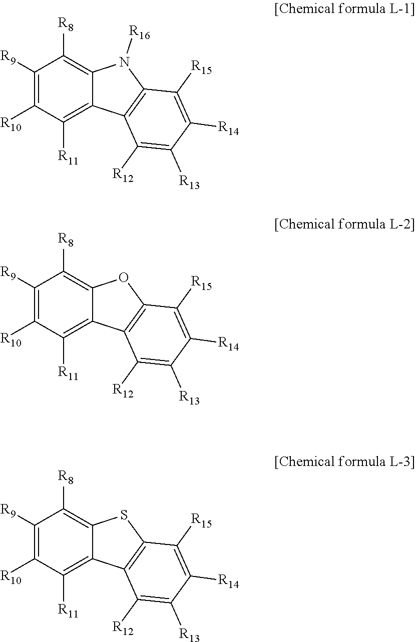

One of R₈ to R₁₆ in chemical formula L-1, R₈ to R₁₅ in chemical formula L-2 and R₈ to R₁₅ in chemical formula L-3 is a direct bond with A of chemical formula 1, and another one is a direct bond with B of chemical formula 1, and the rest which are not direct bonds with A or B are each independently selected from the group consisting of hydrogen; a cyano group; halogen; a C₁-C₂₀ alkyl group; a C₃-C₃₀ cycloalkyl group; an alkoxy group; an aryloxy group; an alkyl thioxy group; an arylthioxy group; an alkyl sulfoxy group; an arylsulfoxy group; a silyl group; an aryl phosphine group; a phosphine oxide group; a C₆-C₆₀ aryl group; and a C₂-C₆₀ heterocyclic group containing at least one heteroatom of O, N, S, Si and P.

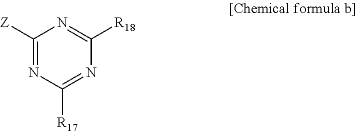

In chemical formula b, Z is a direct bond with L of chemical formula 1.

R₁₇ and R₁₈ are each independently selected from the group consisting of a C₆-C₆₀ aryl group; and a C₂-C₆₀ heterocyclic group containing at least one heteroatom of O, N, S, Si, and P.

The alkyl group, cycloalkyl group, alkoxy group, aryloxy group, alkylthioxy group, arylthioxy group, alkylsulfoxy group, arylsulfoxy group, fluorenyl group, aryl group, heterocyclic group, silyl group and arylphosphine group each are further substituted with one or more substituents selected from the group consisting of a halogen group; a C₁-C₂₀ alkyl group; a C₂-C₂₀ alkenyl group; a C₂-C₂₀ alkynyl group; a fluorenyl group; a C₆-C₂₀ aryl group; and a C₂-C₂₀ heterocyclic group.

Chemical formula a may be represented by one of chemical formula a1, chemical formula a2, and chemical formula a3.

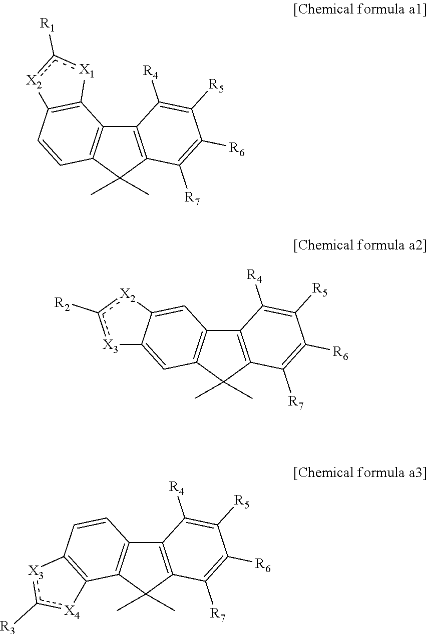

In chemical formula a1, X₁ and X₂ are N, S or O, if either one is N, the other is S or O, and R₁, R₄, R₅, R₆ and R₇ are the same as those defined in chemical formula 1.

In chemical formula a1, X₂ and X₃ are N, S or O, if either one is N, the other is S or O, and R₂, R₄, R₅, R₆ and R₇ are the same as those defined in chemical formula 2.

In chemical formula a1, X₃ and X₄ are N, S or O, if either one is N, the other is S or O, and R₃, R₄, R₅, R₆ and R₇ are the same as those defined in chemical formula 3.

One or more of the hydrogen atoms contained in the compound represented by chemical formula 1 may be substituted with deuterium or tritium.

The compound represented by chemical formula 1 described above may be one or more of the above-described compounds.

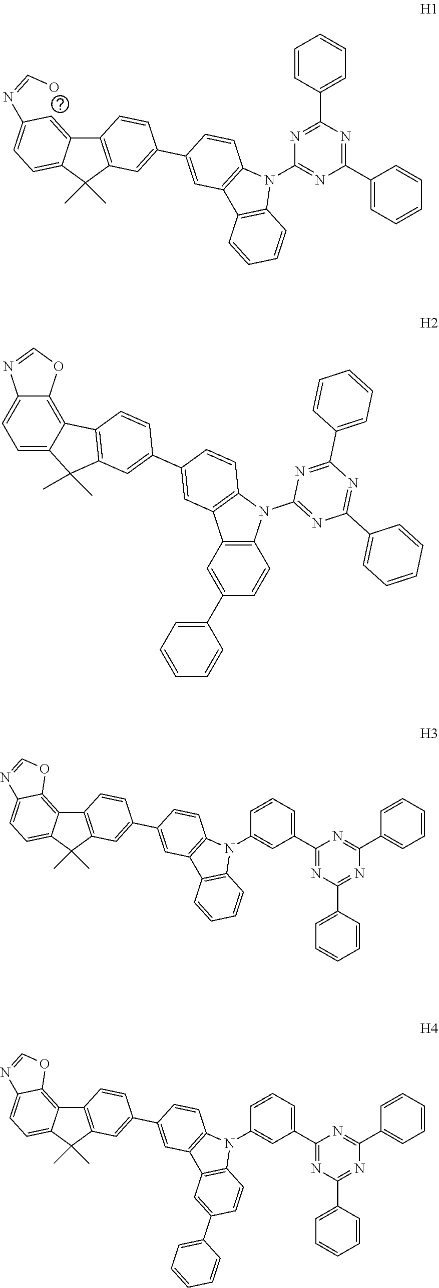 [SMILES: CC1(C)c2ccc(/N=C\O)cc2-c2ccc(-c3ccc4c(c3)c3ccccc3n4-c3nc(-c4ccccc4)nc(-c4ccccc4)n3)cc21 ; CC1(C)c2cc(-c3ccc4c(c3)c3cc(-c5ccccc5)ccc3n4-c3nc(-c4ccccc4)nc(-c4ccccc4)n3)ccc2-c2c1ccc1ncoc21 ; CC1(C)c2cc(-c3ccc4c(c3)c3ccccc3n4-c3cccc(-c4nc(-c5ccccc5)nc(-c5ccccc5)n4)c3)ccc2-c2c1ccc1ncoc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2c1ccc1ncoc21]

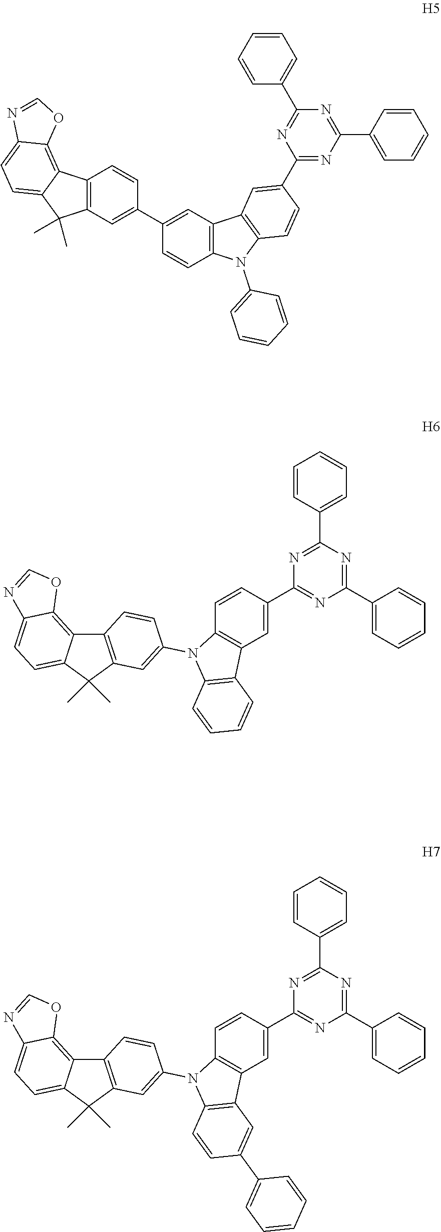 [SMILES: CC1(C)c2cc(-c3ccc4c(c3)c3cc(-c5nc(-c6ccccc6)nc(-c6ccccc6)n5)ccc3n4-c3ccccc3)ccc2-c2c1ccc1ncoc21 ; CC1(C)c2cc(-n3c4ccccc4c4cc(-c5nc(-c6ccccc6)nc(-c6ccccc6)n5)ccc43)ccc2-c2c1ccc1ncoc21 ; CC1(C)c2cc(-n3c4ccc(-c5ccccc5)cc4c4cc(-c5nc(-c6ccccc6)nc(-c6ccccc6)n5)ccc43)ccc2-c2c1ccc1ncoc21]

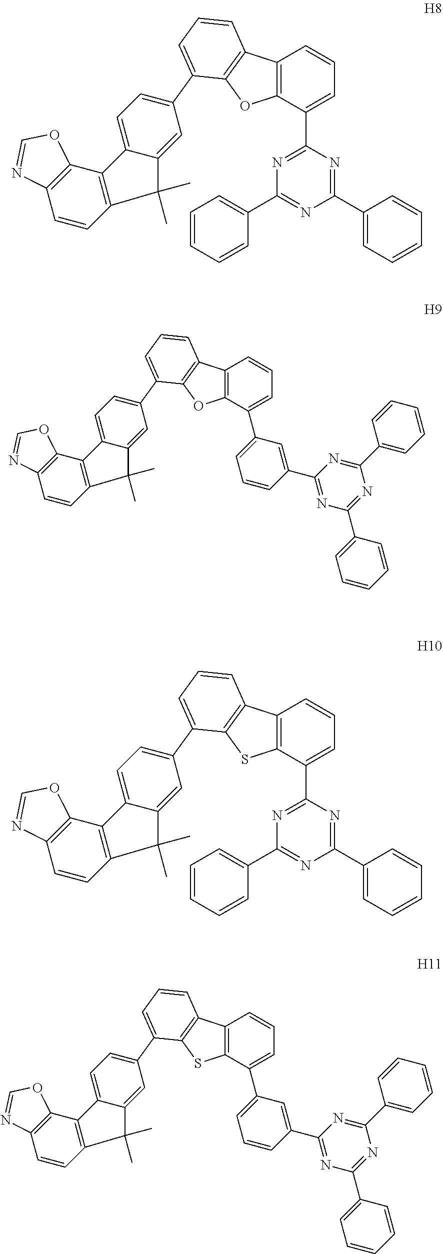 [SMILES: CC1(C)c2cc(-c3cccc4c3oc3c(-c5nc(-c6ccccc6)nc(-c6ccccc6)n5)cccc34)ccc2-c2c1ccc1ncoc21 ; CC1(C)c2cc(-c3cccc4c3oc3c(-c5cccc(-c6nc(-c7ccccc7)nc(-c7ccccc7)n6)c5)cccc34)ccc2-c2c1ccc1ncoc21 ; CC1(C)c2cc(-c3cccc4c3sc3c(-c5nc(-c6ccccc6)nc(-c6ccccc6)n5)cccc34)ccc2-c2c1ccc1ncoc21 ; CC1(C)c2cc(-c3cccc4c3sc3c(-c5cccc(-c6nc(-c7ccccc7)nc(-c7ccccc7)n6)c5)cccc34)ccc2-c2c1ccc1ncoc21]

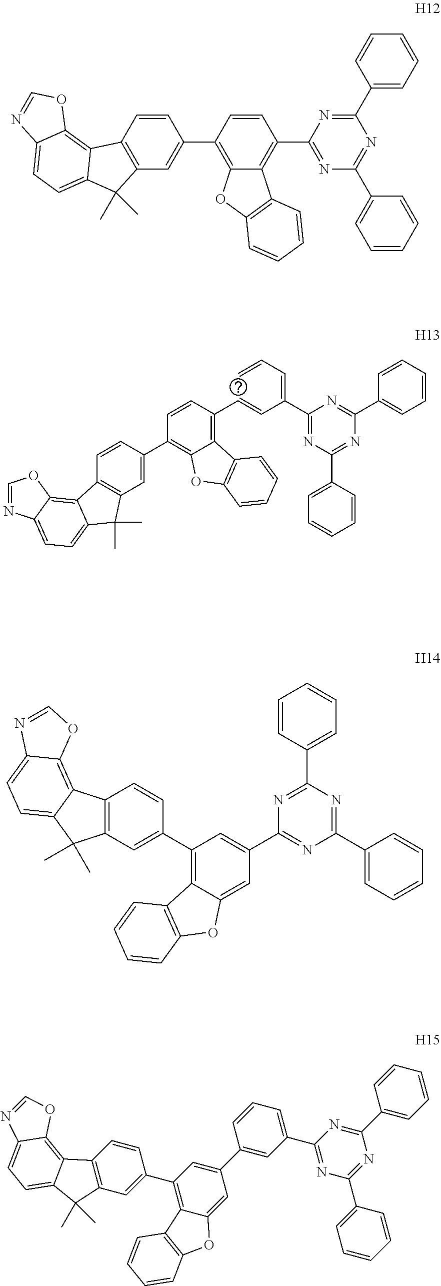 [SMILES: CC1(C)c2cc(-c3ccc(-c4nc(-c5ccccc5)nc(-c5ccccc5)n4)c4c3oc3ccccc34)ccc2-c2c1ccc1ncoc21 ; C=C/C=C(\C=C\c1ccc(-c2ccc3c(c2)C(C)(C)c2ccc4ncoc4c2-3)c2oc3ccccc3c12)c1nc(-c2ccccc2)nc(-c2ccccc2)n1 ; CC1(C)c2cc(-c3cc(-c4nc(-c5ccccc5)nc(-c5ccccc5)n4)cc4oc5ccccc5c34)ccc2-c2c1ccc1ncoc21 ; CC1(C)c2cc(-c3cc(-c4cccc(-c5nc(-c6ccccc6)nc(-c6ccccc6)n5)c4)cc4oc5ccccc5c34)ccc2-c2c1ccc1ncoc21]

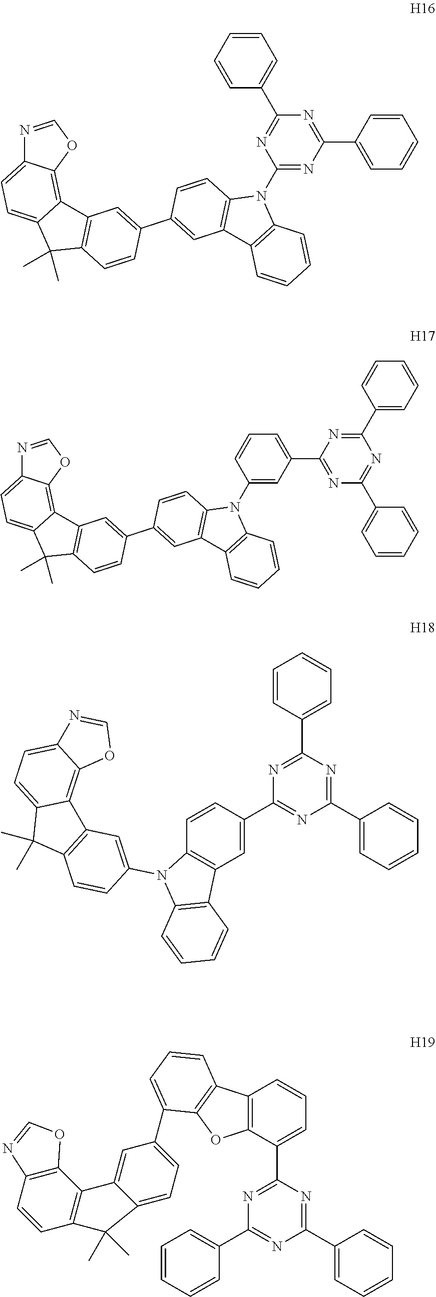 [SMILES: CC1(C)c2ccc(-c3ccc4c(c3)c3ccccc3n4-c3nc(-c4ccccc4)nc(-c4ccccc4)n3)cc2-c2c1ccc1ncoc21 ; CC1(C)c2ccc(-c3ccc4c(c3)c3ccccc3n4-c3cccc(-c4nc(-c5ccccc5)nc(-c5ccccc5)n4)c3)cc2-c2c1ccc1ncoc21 ; CC1(C)c2ccc(-n3c4ccccc4c4cc(-c5nc(-c6ccccc6)nc(-c6ccccc6)n5)ccc43)cc2-c2c1ccc1ncoc21 ; CC1(C)c2ccc(-c3cccc4c3oc3c(-c5nc(-c6ccccc6)nc(-c6ccccc6)n5)cccc34)cc2-c2c1ccc1ncoc21]

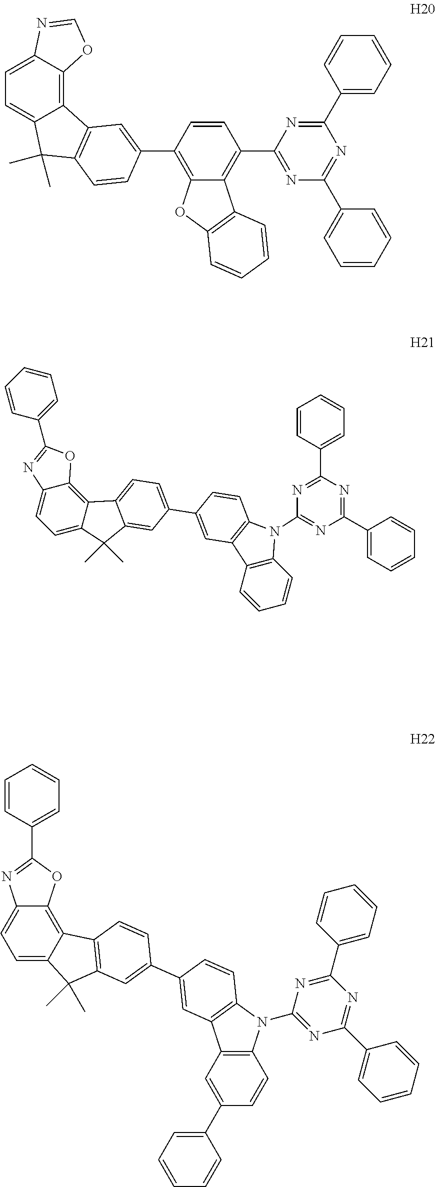 [SMILES: CC1(C)c2ccc(-c3ccc(-c4nc(-c5ccccc5)nc(-c5ccccc5)n4)c4c3oc3ccccc34)cc2-c2c1ccc1ncoc21 ; CC1(C)c2cc(-c3ccc4c(c3)c3ccccc3n4-c3nc(-c4ccccc4)nc(-c4ccccc4)n3)ccc2-c2c1ccc1nc(-c3ccccc3)oc21 ; CC1(C)c2cc(-c3ccc4c(c3)c3cc(-c5ccccc5)ccc3n4-c3nc(-c4ccccc4)nc(-c4ccccc4)n3)ccc2-c2c1ccc1nc(-c3ccccc3)oc21]

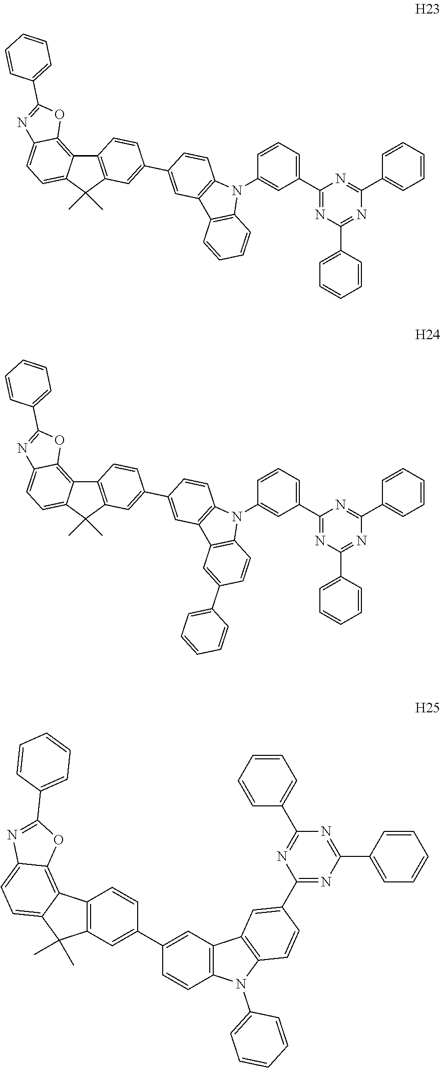 [SMILES: CC1(C)c2cc(-c3ccc4c(c3)c3ccccc3n4-c3cccc(-c4nc(-c5ccccc5)nc(-c5ccccc5)n4)c3)ccc2-c2c1ccc1nc(-c3ccccc3)oc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2c1ccc1nc(-c3ccccc3)oc21 ; CC1(C)c2cc(-c3ccc4c(c3)c3cc(-c5nc(-c6ccccc6)nc(-c6ccccc6)n5)ccc3n4-c3ccccc3)ccc2-c2c1ccc1nc(-c3ccccc3)oc21]

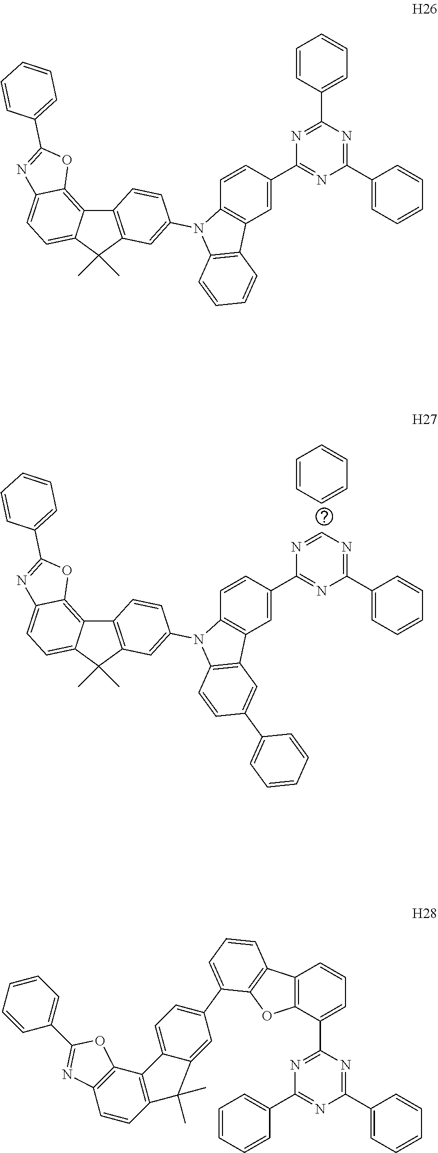

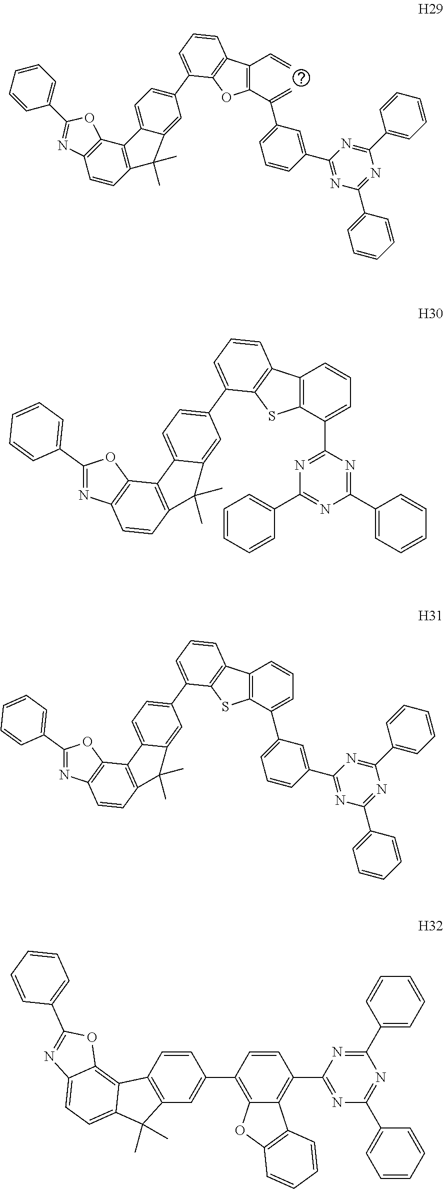 [SMILES: C=Cc1c(C(=C)c2cccc(-c3nc(-c4ccccc4)nc(-c4ccccc4)n3)c2)oc2c(-c3ccc4c(c3)C(C)(C)c3ccc5nc(-c6ccccc6)oc5c3-4)cccc12 ; CC1(C)c2cc(-c3cccc4c3sc3c(-c5nc(-c6ccccc6)nc(-c6ccccc6)n5)cccc34)ccc2-c2c1ccc1nc(-c3ccccc3)oc21 ; CC1(C)c2cc(-c3cccc4c3sc3c(-c5cccc(-c6nc(-c7ccccc7)nc(-c7ccccc7)n6)c5)cccc34)ccc2-c2c1ccc1nc(-c3ccccc3)oc21 ; CC1(C)c2cc(-c3ccc(-c4nc(-c5ccccc5)nc(-c5ccccc5)n4)c4c3oc3ccccc34)ccc2-c2c1ccc1nc(-c3ccccc3)oc21]

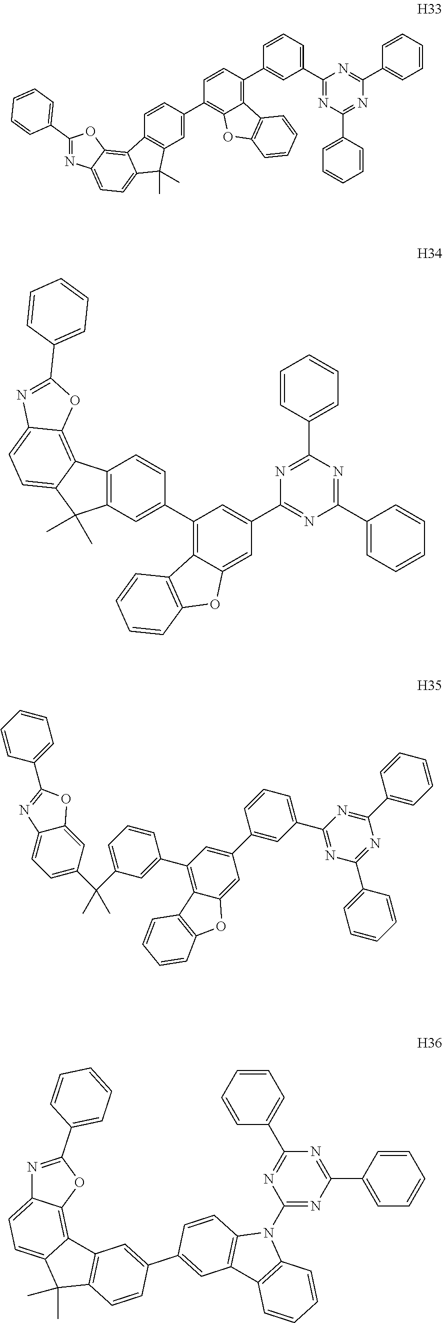 [SMILES: CC1(C)c2cc(-c3ccc(-c4cccc(-c5nc(-c6ccccc6)nc(-c6ccccc6)n5)c4)c4c3oc3ccccc34)ccc2-c2c1ccc1nc(-c3ccccc3)oc21 ; CC1(C)c2cc(-c3cc(-c4nc(-c5ccccc5)nc(-c5ccccc5)n4)cc4oc5ccccc5c34)ccc2-c2c1ccc1nc(-c3ccccc3)oc21 ; CC(C)(c1cccc(-c2cc(-c3cccc(-c4nc(-c5ccccc5)nc(-c5ccccc5)n4)c3)cc3oc4ccccc4c23)c1)c1ccc2nc(-c3ccccc3)oc2c1 ; CC1(C)c2ccc(-c3ccc4c(c3)c3ccccc3n4-c3nc(-c4ccccc4)nc(-c4ccccc4)n3)cc2-c2c1ccc1nc(-c3ccccc3)oc21]

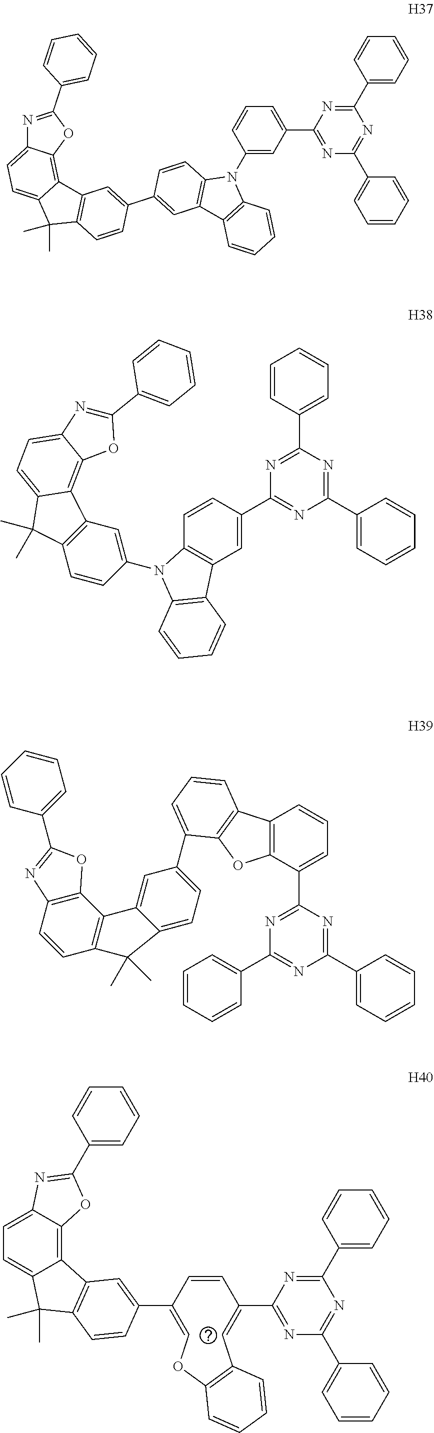 [SMILES: CC1(C)c2ccc(-c3ccc4c(c3)c3ccccc3n4-c3cccc(-c4nc(-c5ccccc5)nc(-c5ccccc5)n4)c3)cc2-c2c1ccc1nc(-c3ccccc3)oc21 ; CC1(C)c2ccc(-n3c4ccccc4c4cc(-c5nc(-c6ccccc6)nc(-c6ccccc6)n5)ccc43)cc2-c2c1ccc1nc(-c3ccccc3)oc21 ; CC1(C)c2ccc(-c3cccc4c3oc3c(-c5nc(-c6ccccc6)nc(-c6ccccc6)n5)cccc34)cc2-c2c1ccc1nc(-c3ccccc3)oc21 ; CC1(C)c2ccc(C3=C\Oc4ccccc4/C=C(c4nc(-c5ccccc5)nc(-c5ccccc5)n4)/C=C\3)cc2-c2c1ccc1nc(-c3ccccc3)oc21]

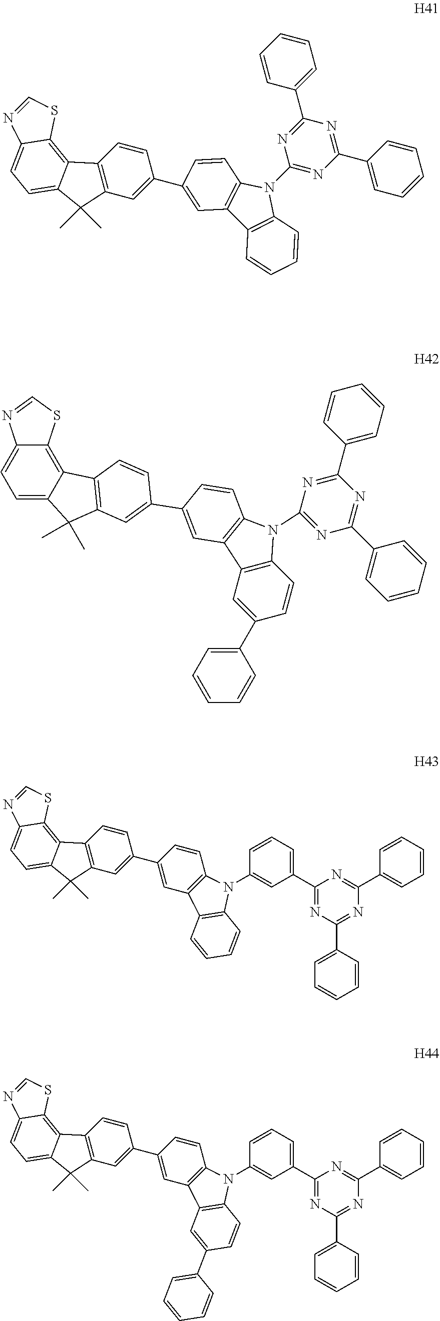 [SMILES: CC1(C)c2cc(-c3ccc4c(c3)c3ccccc3n4-c3nc(-c4ccccc4)nc(-c4ccccc4)n3)ccc2-c2c1ccc1ncsc21 ; CC1(C)c2cc(-c3ccc4c(c3)c3cc(-c5ccccc5)ccc3n4-c3nc(-c4ccccc4)nc(-c4ccccc4)n3)ccc2-c2c1ccc1ncsc21 ; CC1(C)c2cc(-c3ccc4c(c3)c3ccccc3n4-c3cccc(-c4nc(-c5ccccc5)nc(-c5ccccc5)n4)c3)ccc2-c2c1ccc1ncsc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2c1ccc1ncsc21]

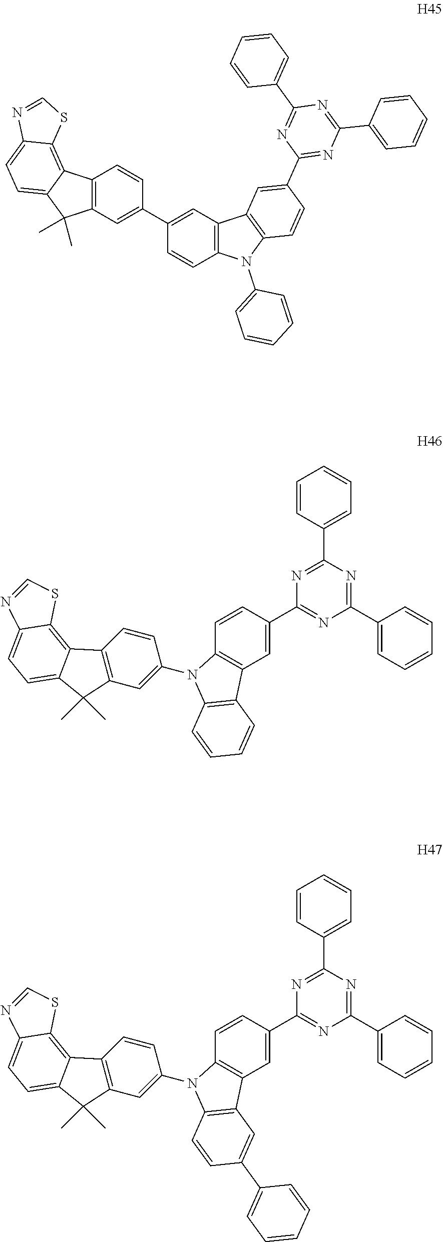 [SMILES: CC1(C)c2cc(-c3ccc4c(c3)c3cc(-c5nc(-c6ccccc6)nc(-c6ccccc6)n5)ccc3n4-c3ccccc3)ccc2-c2c1ccc1ncsc21 ; CC1(C)c2cc(-n3c4ccccc4c4cc(-c5nc(-c6ccccc6)nc(-c6ccccc6)n5)ccc43)ccc2-c2c1ccc1ncsc21 ; CC1(C)c2cc(-n3c4ccc(-c5ccccc5)cc4c4cc(-c5nc(-c6ccccc6)nc(-c6ccccc6)n5)ccc43)ccc2-c2c1ccc1ncsc21]

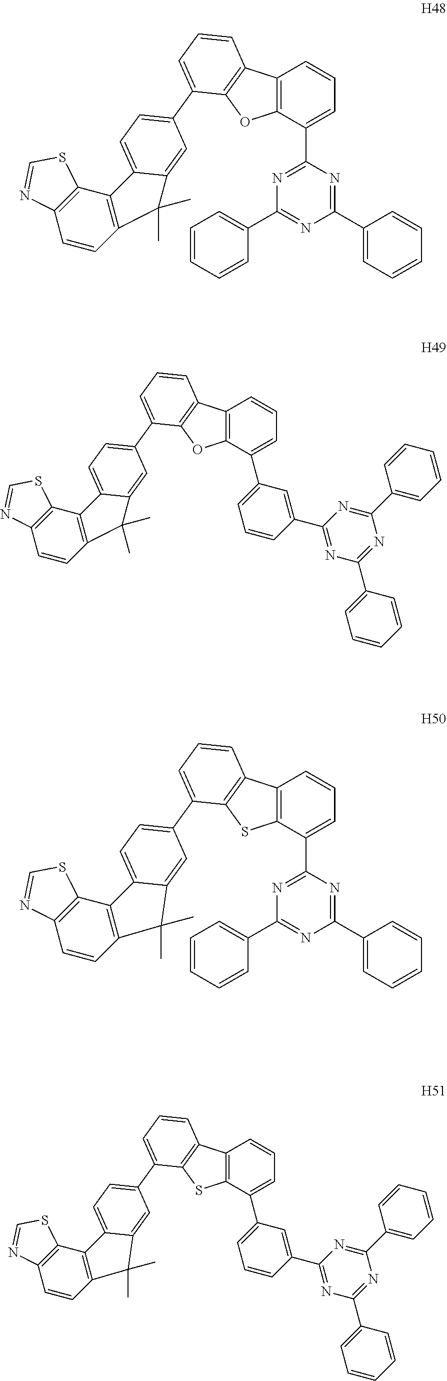 [SMILES: CC1(C)c2cc(-c3cccc4c3oc3c(-c5nc(-c6ccccc6)nc(-c6ccccc6)n5)cccc34)ccc2-c2c1ccc1ncsc21 ; CC1(C)c2cc(-c3cccc4c3oc3c(-c5cccc(-c6nc(-c7ccccc7)nc(-c7ccccc7)n6)c5)cccc34)ccc2-c2c1ccc1ncsc21 ; CC1(C)c2cc(-c3cccc4c3sc3c(-c5nc(-c6ccccc6)nc(-c6ccccc6)n5)cccc34)ccc2-c2c1ccc1ncsc21 ; CC1(C)c2cc(-c3cccc4c3sc3c(-c5cccc(-c6nc(-c7ccccc7)nc(-c7ccccc7)n6)c5)cccc34)ccc2-c2c1ccc1ncsc21]

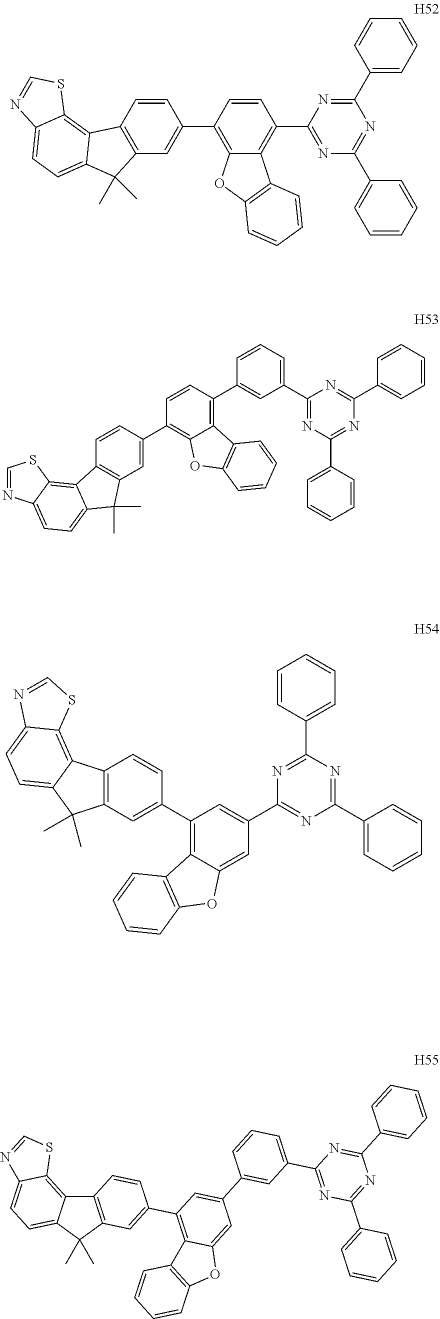 [SMILES: CC1(C)c2cc(-c3ccc(-c4nc(-c5ccccc5)nc(-c5ccccc5)n4)c4c3oc3ccccc34)ccc2-c2c1ccc1ncsc21 ; CC1(C)c2cc(-c3ccc(-c4cccc(-c5nc(-c6ccccc6)nc(-c6ccccc6)n5)c4)c4c3oc3ccccc34)ccc2-c2c1ccc1ncsc21 ; CC1(C)c2cc(-c3cc(-c4nc(-c5ccccc5)nc(-c5ccccc5)n4)cc4oc5ccccc5c34)ccc2-c2c1ccc1ncsc21 ; CC1(C)c2cc(-c3cc(-c4cccc(-c5nc(-c6ccccc6)nc(-c6ccccc6)n5)c4)cc4oc5ccccc5c34)ccc2-c2c1ccc1ncsc21]

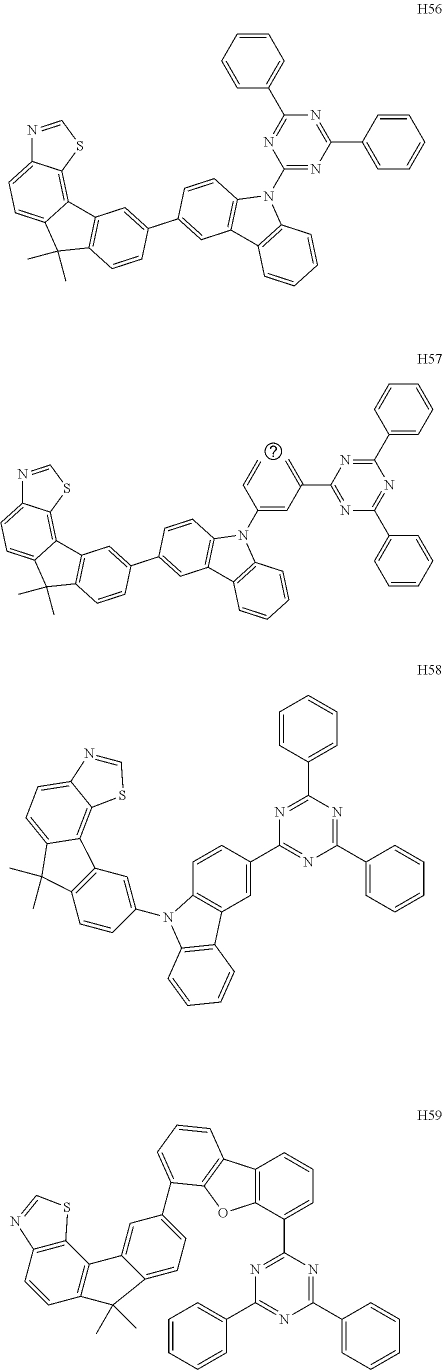 [SMILES: CC1(C)c2ccc(-c3ccc4c(c3)c3ccccc3n4-c3nc(-c4ccccc4)nc(-c4ccccc4)n3)cc2-c2c1ccc1ncsc21 ; C=C/C(=C\C(=C)c1nc(-c2ccccc2)nc(-c2ccccc2)n1)n1c2ccccc2c2cc(-c3ccc4c(c3)-c3c(ccc5ncsc35)C4(C)C)ccc21 ; CC1(C)c2ccc(-n3c4ccccc4c4cc(-c5nc(-c6ccccc6)nc(-c6ccccc6)n5)ccc43)cc2-c2c1ccc1ncsc21 ; CC1(C)c2ccc(-c3cccc4c3oc3c(-c5nc(-c6ccccc6)nc(-c6ccccc6)n5)cccc34)cc2-c2c1ccc1ncsc21]

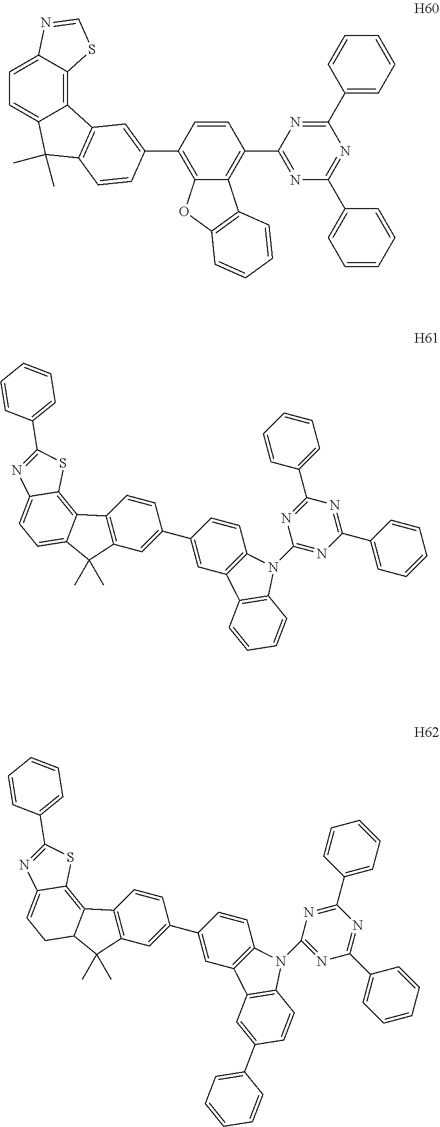 [SMILES: CC1(C)c2ccc(-c3ccc(-c4nc(-c5ccccc5)nc(-c5ccccc5)n4)c4c3oc3ccccc34)cc2-c2c1ccc1ncsc21 ; CC1(C)c2cc(-c3ccc4c(c3)c3ccccc3n4-c3nc(-c4ccccc4)nc(-c4ccccc4)n3)ccc2-c2c1ccc1nc(-c3ccccc3)sc21 ; CC1(C)c2cc(-c3ccc4c(c3)c3cc(-c5ccccc5)ccc3n4-c3nc(-c4ccccc4)nc(-c4ccccc4)n3)ccc2C2=c3sc(-c4ccccc4)nc3=CCC21]

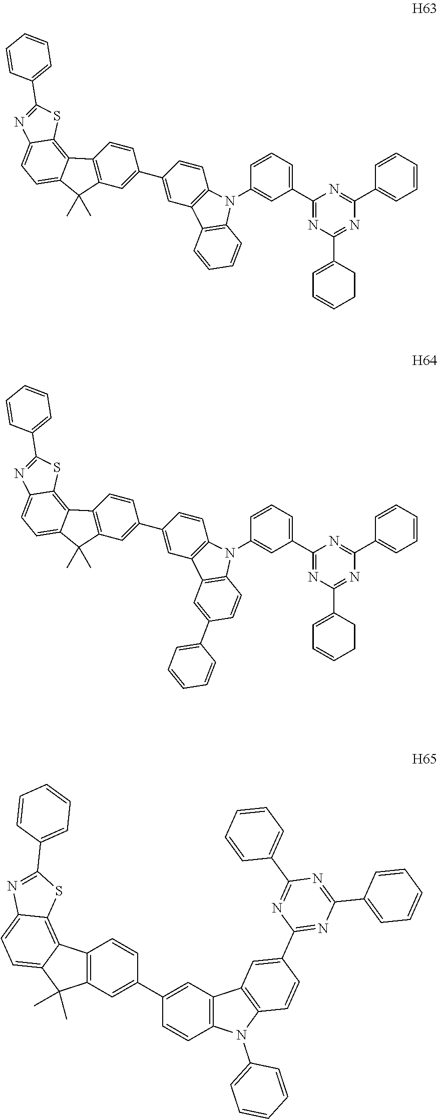 [SMILES: CC1(C)c2cc(-c3ccc4c(c3)c3ccccc3n4-c3cccc(-c4nc(C5=CC=CCC5)nc(-c5ccccc5)n4)c3)ccc2-c2c1ccc1nc(-c3ccccc3)sc21 ; CC1(C)c2cc(-c3ccc4c(c3)c3cc(-c5ccccc5)ccc3n4-c3cccc(-c4nc(C5=CC=CCC5)nc(-c5ccccc5)n4)c3)ccc2-c2c1ccc1nc(-c3ccccc3)sc21 ; CC1(C)c2cc(-c3ccc4c(c3)c3cc(-c5nc(-c6ccccc6)nc(-c6ccccc6)n5)ccc3n4-c3ccccc3)ccc2-c2c1ccc1nc(-c3ccccc3)sc21]

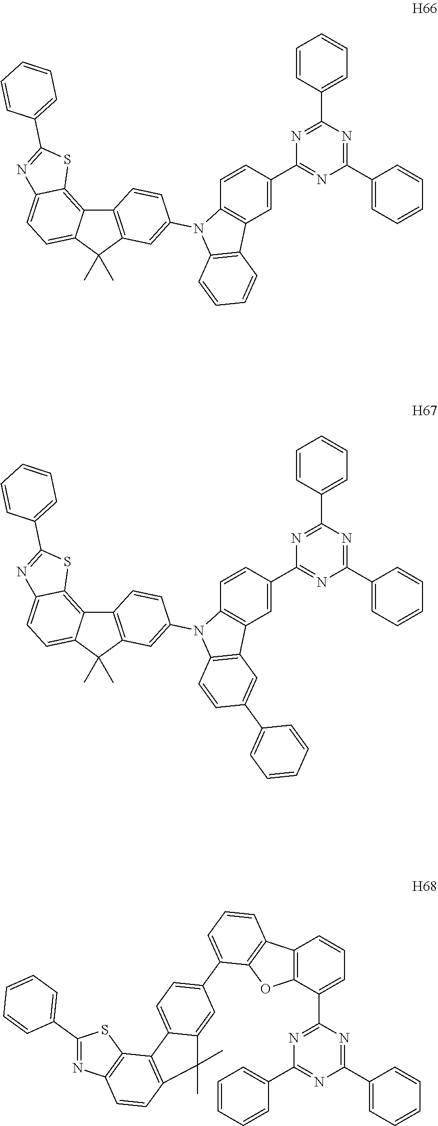 [SMILES: CC1(C)c2cc(-n3c4ccccc4c4cc(-c5nc(-c6ccccc6)nc(-c6ccccc6)n5)ccc43)ccc2-c2c1ccc1nc(-c3ccccc3)sc21 ; CC1(C)c2cc(-n3c4ccc(-c5ccccc5)cc4c4cc(-c5nc(-c6ccccc6)nc(-c6ccccc6)n5)ccc43)ccc2-c2c1ccc1nc(-c3ccccc3)sc21 ; CC1(C)c2cc(-c3cccc4c3oc3c(-c5nc(-c6ccccc6)nc(-c6ccccc6)n5)cccc34)ccc2-c2c1ccc1nc(-c3ccccc3)sc21]

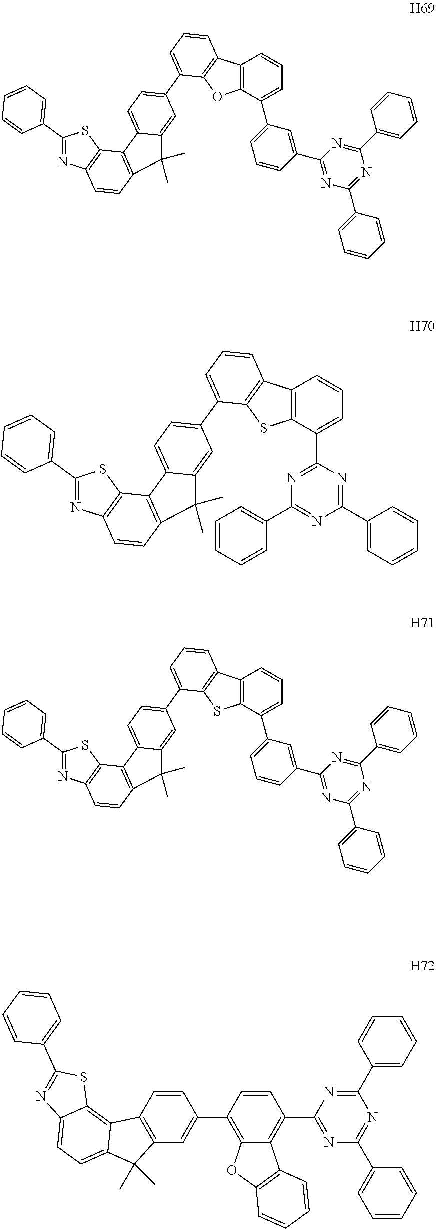 [SMILES: CC1(C)c2cc(-c3cccc4c3oc3c(-c5cccc(-c6nc(-c7ccccc7)nc(-c7ccccc7)n6)c5)cccc34)ccc2-c2c1ccc1nc(-c3ccccc3)sc21 ; CC1(C)c2cc(-c3cccc4c3sc3c(-c5nc(-c6ccccc6)nc(-c6ccccc6)n5)cccc34)ccc2-c2c1ccc1nc(-c3ccccc3)sc21 ; CC1(C)c2cc(-c3cccc4c3sc3c(-c5cccc(-c6nc(-c7ccccc7)nc(-c7ccccc7)n6)c5)cccc34)ccc2-c2c1ccc1nc(-c3ccccc3)sc21 ; CC1(C)c2cc(-c3ccc(-c4nc(-c5ccccc5)nc(-c5ccccc5)n4)c4c3oc3ccccc34)ccc2-c2c1ccc1nc(-c3ccccc3)sc21]

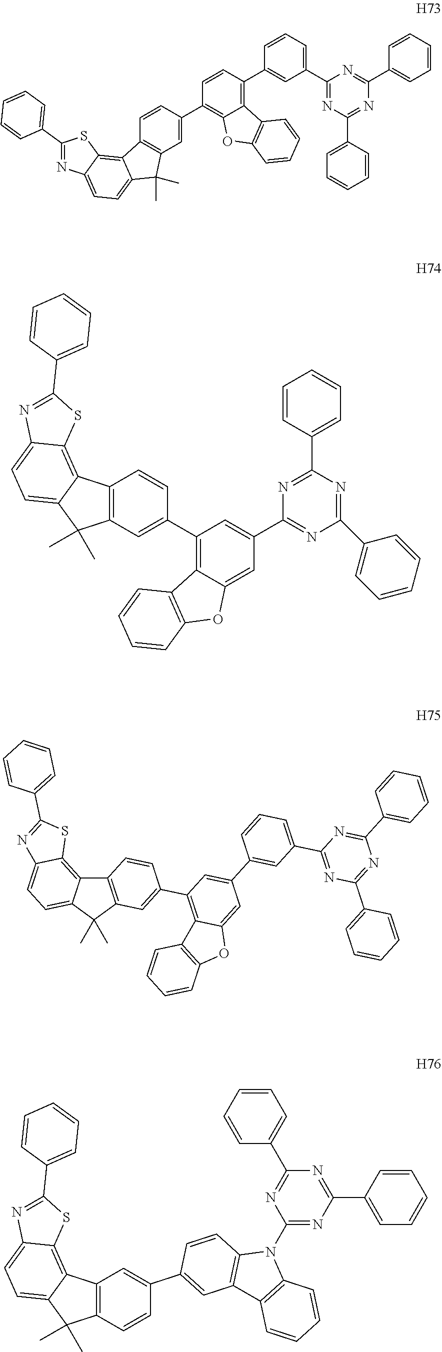 [SMILES: CC1(C)c2cc(-c3ccc(-c4cccc(-c5nc(-c6ccccc6)nc(-c6ccccc6)n5)c4)c4c3oc3ccccc34)ccc2-c2c1ccc1nc(-c3ccccc3)sc21 ; CC1(C)c2cc(-c3cc(-c4nc(-c5ccccc5)nc(-c5ccccc5)n4)cc4oc5ccccc5c34)ccc2-c2c1ccc1nc(-c3ccccc3)sc21 ; CC1(C)c2cc(-c3cc(-c4cccc(-c5nc(-c6ccccc6)nc(-c6ccccc6)n5)c4)cc4oc5ccccc5c34)ccc2-c2c1ccc1nc(-c3ccccc3)sc21 ; CC1(C)c2ccc(-c3ccc4c(c3)c3ccccc3n4-c3nc(-c4ccccc4)nc(-c4ccccc4)n3)cc2-c2c1ccc1nc(-c3ccccc3)sc21]

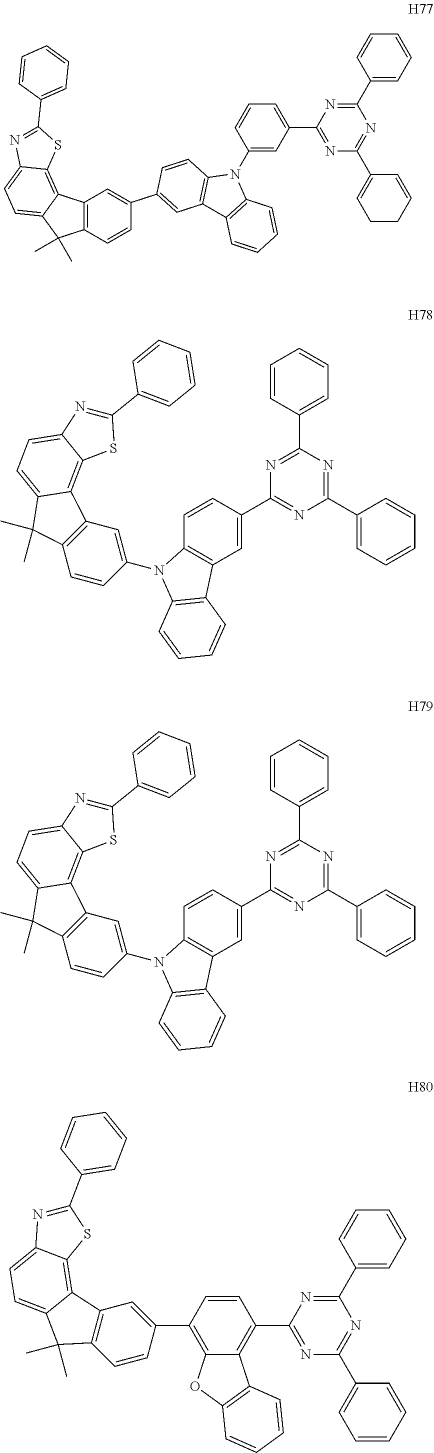 [SMILES: CC1(C)c2ccc(-c3ccc4c(c3)c3ccccc3n4-c3cccc(-c4nc(C5=CCCC=C5)nc(-c5ccccc5)n4)c3)cc2-c2c1ccc1nc(-c3ccccc3)sc21 ; CC1(C)c2ccc(-n3c4ccccc4c4cc(-c5nc(-c6ccccc6)nc(-c6ccccc6)n5)ccc43)cc2-c2c1ccc1nc(-c3ccccc3)sc21 ; CC1(C)c2ccc(-n3c4ccccc4c4cc(-c5nc(-c6ccccc6)nc(-c6ccccc6)n5)ccc43)cc2-c2c1ccc1nc(-c3ccccc3)sc21 ; CC1(C)c2ccc(-c3ccc(-c4nc(-c5ccccc5)nc(-c5ccccc5)n4)c4c3oc3ccccc34)cc2-c2c1ccc1nc(-c3ccccc3)sc21]

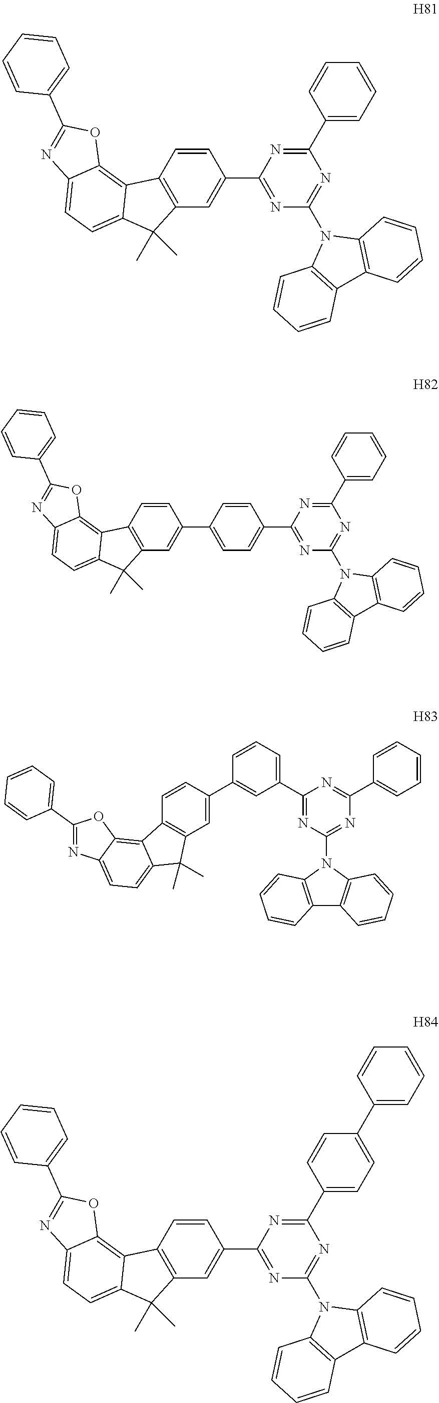 [SMILES: CC1(C)c2cc(-c3nc(-c4ccccc4)nc(-n4c5ccccc5c5ccccc54)n3)ccc2-c2c1ccc1nc(-c3ccccc3)oc21 ; CC1(C)c2cc(-c3ccc(-c4nc(-c5ccccc5)nc(-n5c6ccccc6c6ccccc65)n4)cc3)ccc2-c2c1ccc1nc(-c3ccccc3)oc21 ; CC1(C)c2cc(-c3cccc(-c4nc(-c5ccccc5)nc(-n5c6ccccc6c6ccccc65)n4)c3)ccc2-c2c1ccc1nc(-c3ccccc3)oc21 ; CC1(C)c2cc(-c3nc(-c4ccc(-c5ccccc5)cc4)nc(-n4c5ccccc5c5ccccc54)n3)ccc2-c2c1ccc1nc(-c3ccccc3)oc21]

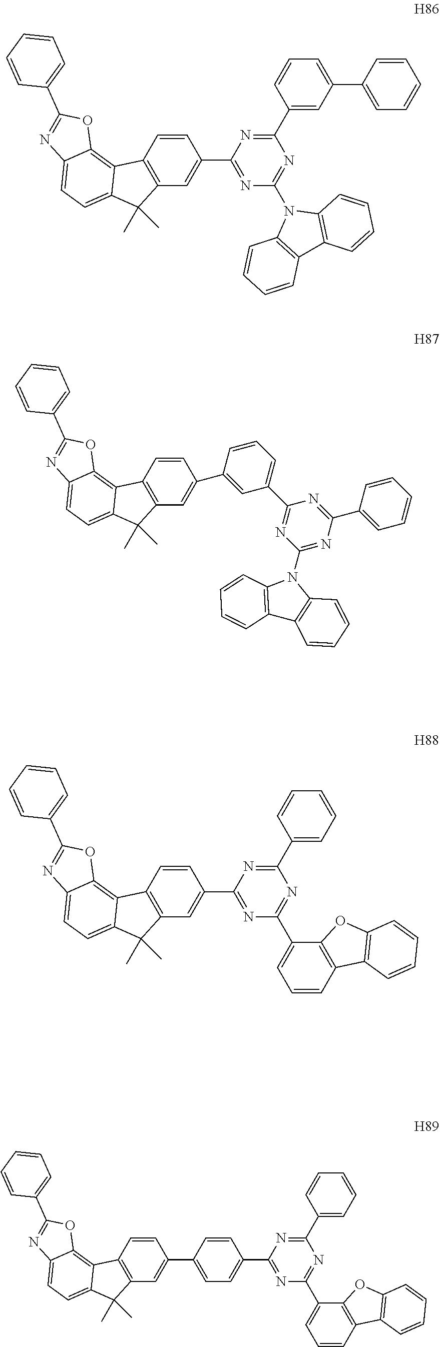 [SMILES: CC1(C)c2cc(-c3nc(-c4cccc(-c5ccccc5)c4)nc(-n4c5ccccc5c5ccccc54)n3)ccc2-c2c1ccc1nc(-c3ccccc3)oc21 ; CC1(C)c2cc(-c3cccc(-c4nc(-c5ccccc5)nc(-n5c6ccccc6c6ccccc65)n4)c3)ccc2-c2c1ccc1nc(-c3ccccc3)oc21 ; CC1(C)c2cc(-c3nc(-c4ccccc4)nc(-c4cccc5c4oc4ccccc45)n3)ccc2-c2c1ccc1nc(-c3ccccc3)oc21 ; CC1(C)c2cc(-c3ccc(-c4nc(-c5ccccc5)nc(-c5cccc6c5oc5ccccc56)n4)cc3)ccc2-c2c1ccc1nc(-c3ccccc3)oc21]

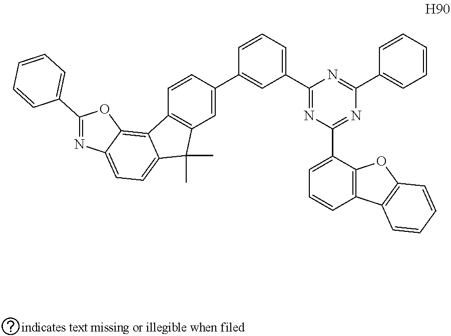 [SMILES: CC1(C)c2cc(-c3cccc(-c4nc(-c5ccccc5)nc(-c5cccc6c5oc5ccccc56)n4)c3)ccc2-c2c1ccc1nc(-c3ccccc3)oc21]

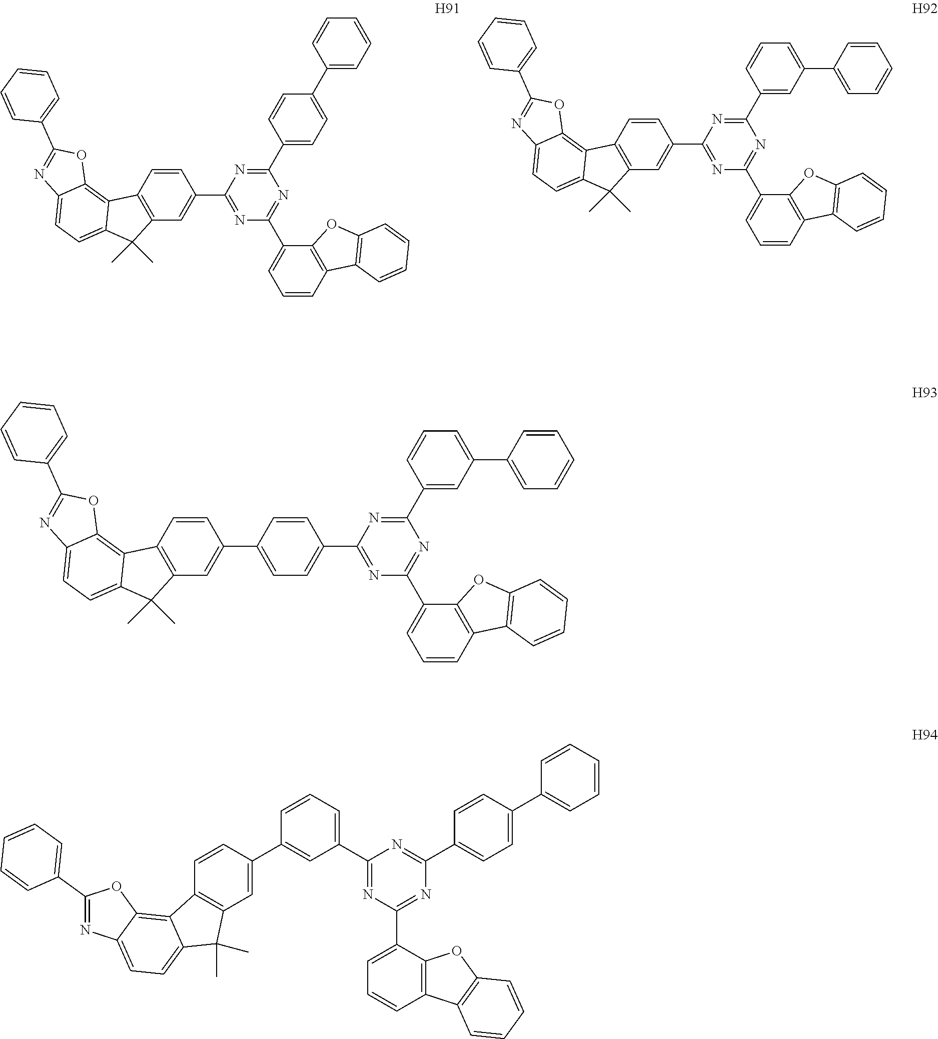 [SMILES: CC1(C)c2cc(-c3nc(-c4ccc(-c5ccccc5)cc4)nc(-c4cccc5c4oc4ccccc45)n3)ccc2-c2c1ccc1nc(-c3ccccc3)oc21 ; CC1(C)c2cc(-c3nc(-c4cccc(-c5ccccc5)c4)nc(-c4cccc5c4oc4ccccc45)n3)ccc2-c2c1ccc1nc(-c3ccccc3)oc21 ; CC1(C)c2cc(-c3ccc(-c4nc(-c5cccc(-c6ccccc6)c5)nc(-c5cccc6c5oc5ccccc56)n4)cc3)ccc2-c2c1ccc1nc(-c3ccccc3)oc21 ; CC1(C)c2cc(-c3cccc(-c4nc(-c5ccc(-c6ccccc6)cc5)nc(-c5cccc6c5oc5ccccc56)n4)c3)ccc2-c2c1ccc1nc(-c3ccccc3)oc21]

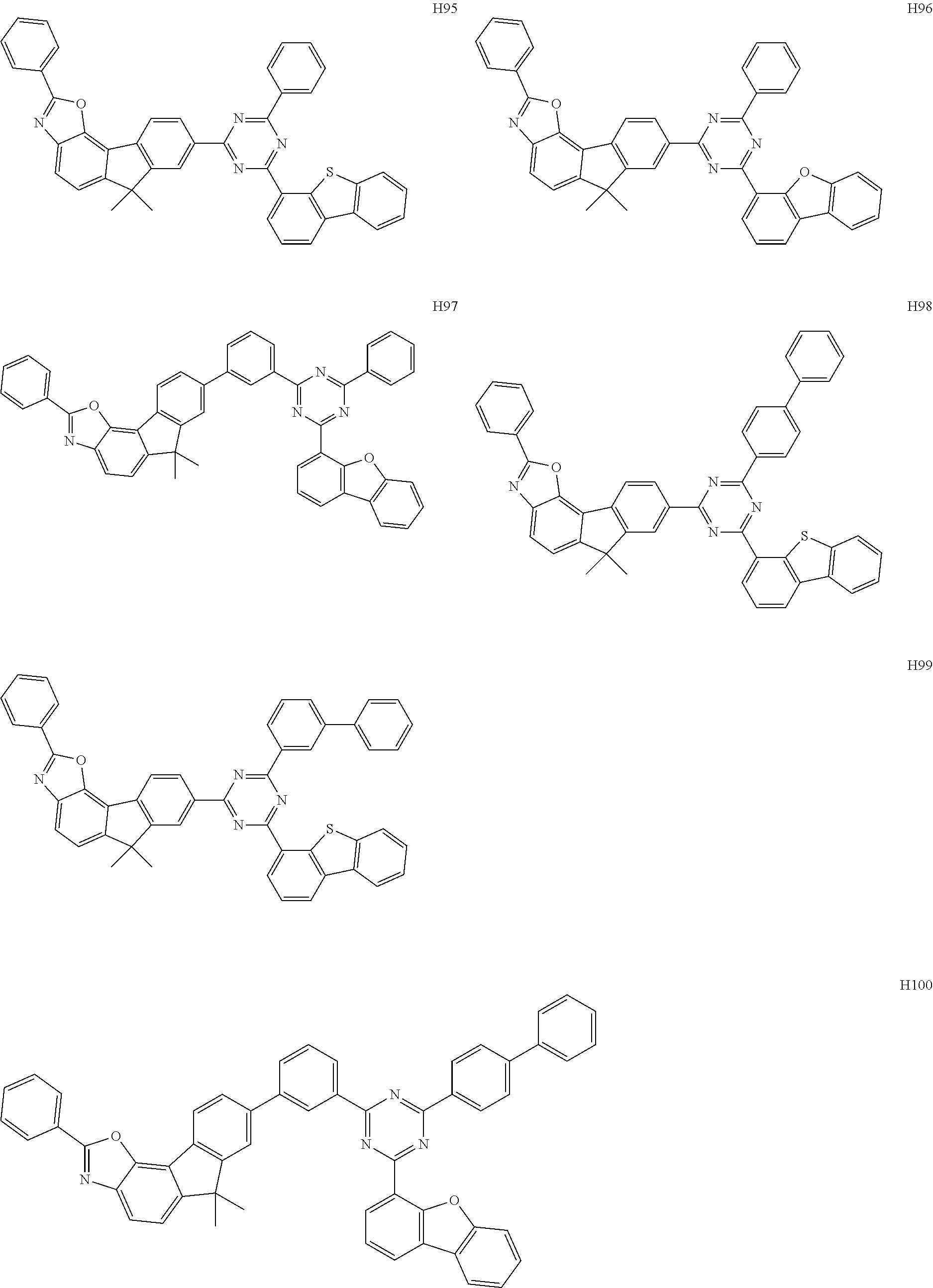

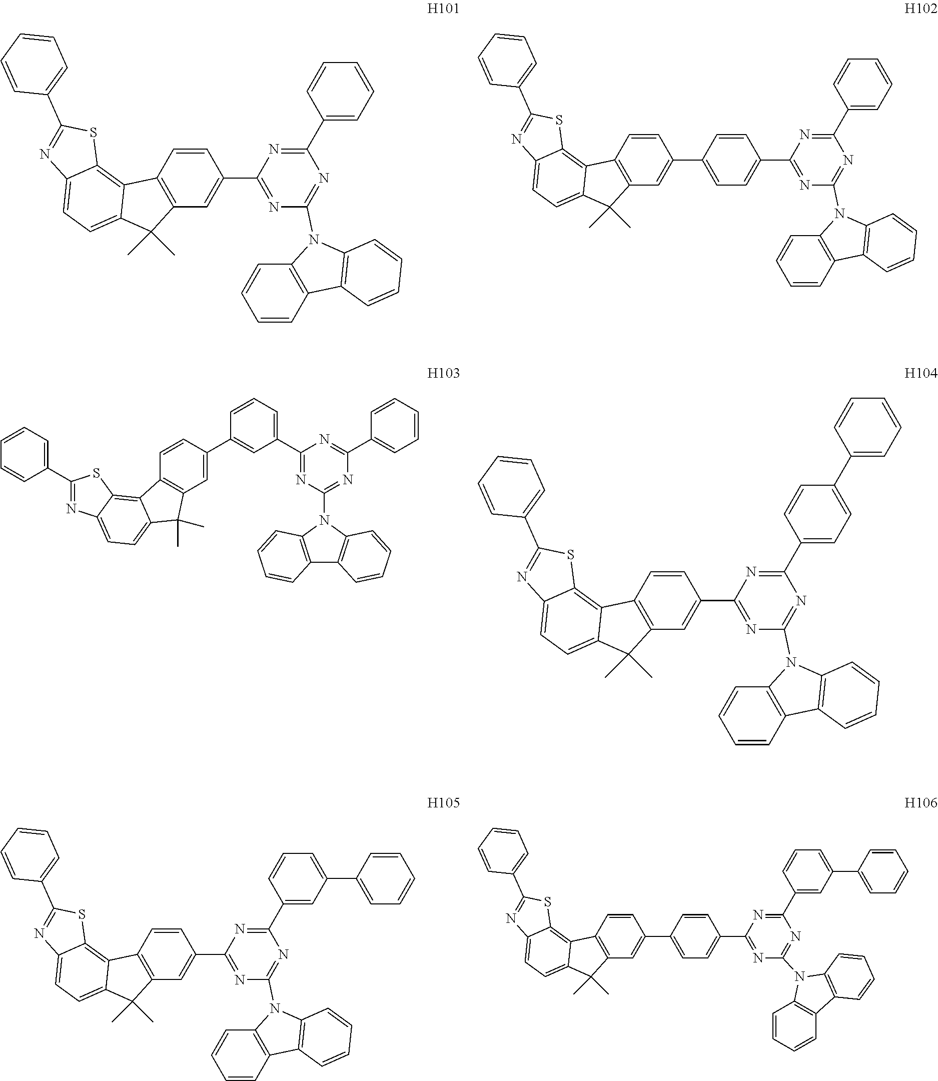

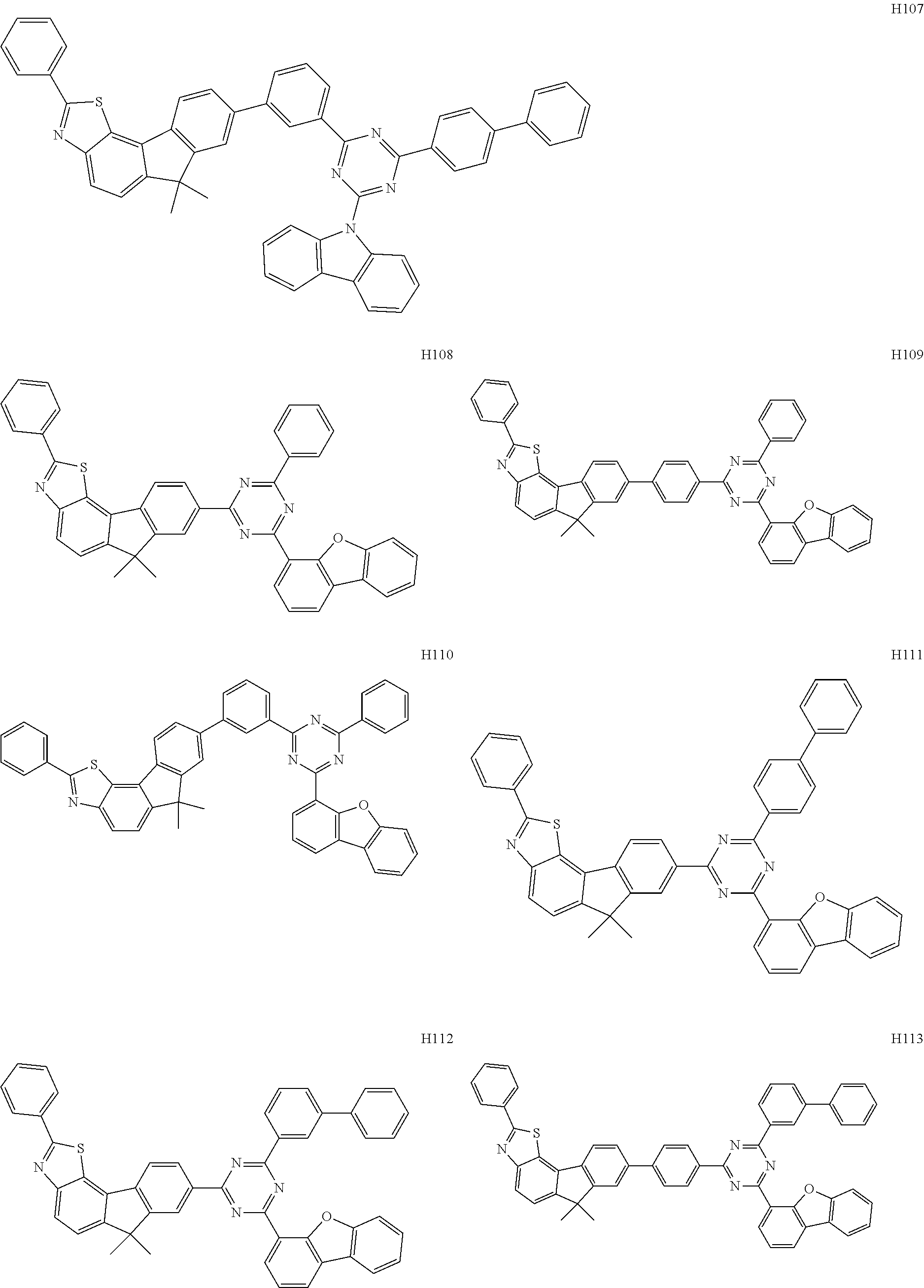

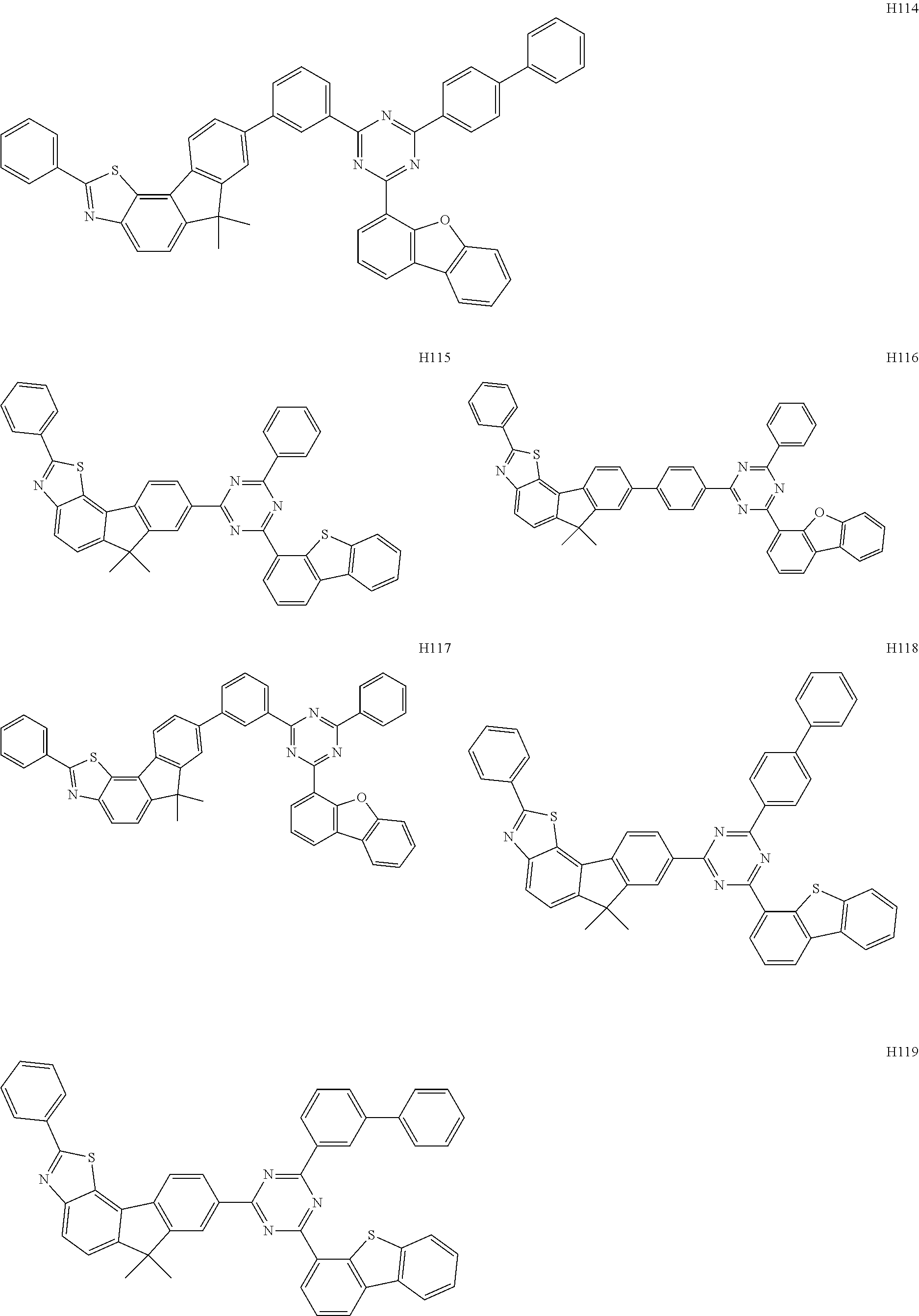

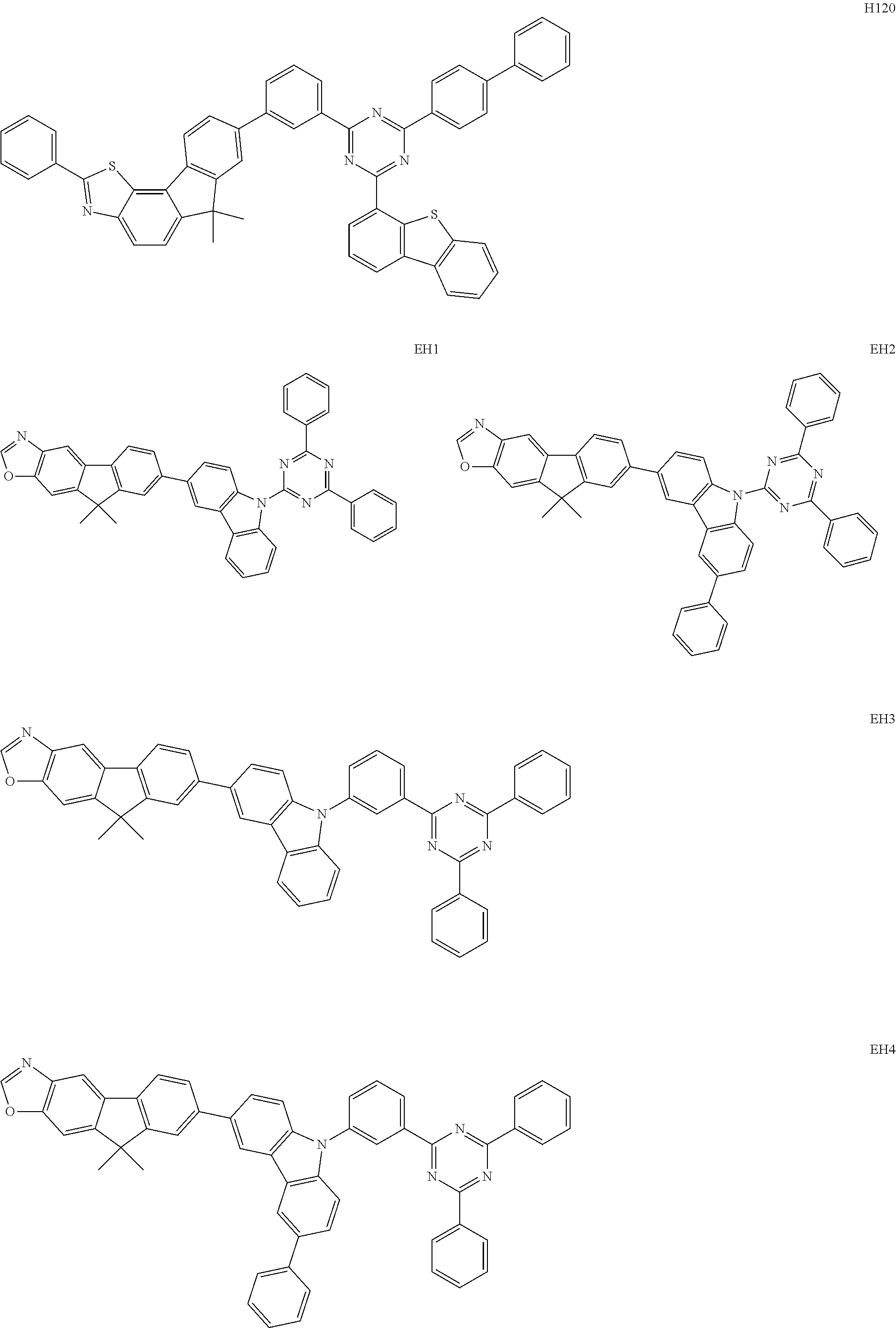 [SMILES: CC1(C)c2cc(-c3cccc(-c4nc(-c5ccc(-c6ccccc6)cc5)nc(-c5cccc6c5sc5ccccc56)n4)c3)ccc2-c2c1ccc1nc(-c3ccccc3)sc21 ; CC1(C)c2cc(-c3ccc4c(c3)c3ccccc3n4-c3nc(-c4ccccc4)nc(-c4ccccc4)n3)ccc2-c2cc3ncoc3cc21 ; CC1(C)c2cc(-c3ccc4c(c3)c3cc(-c5ccccc5)ccc3n4-c3nc(-c4ccccc4)nc(-c4ccccc4)n3)ccc2-c2cc3ncoc3cc21 ; CC1(C)c2cc(-c3ccc4c(c3)c3ccccc3n4-c3cccc(-c4nc(-c5ccccc5)nc(-c5ccccc5)n4)c3)ccc2-c2cc3ncoc3cc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2cc3ncoc3cc21]

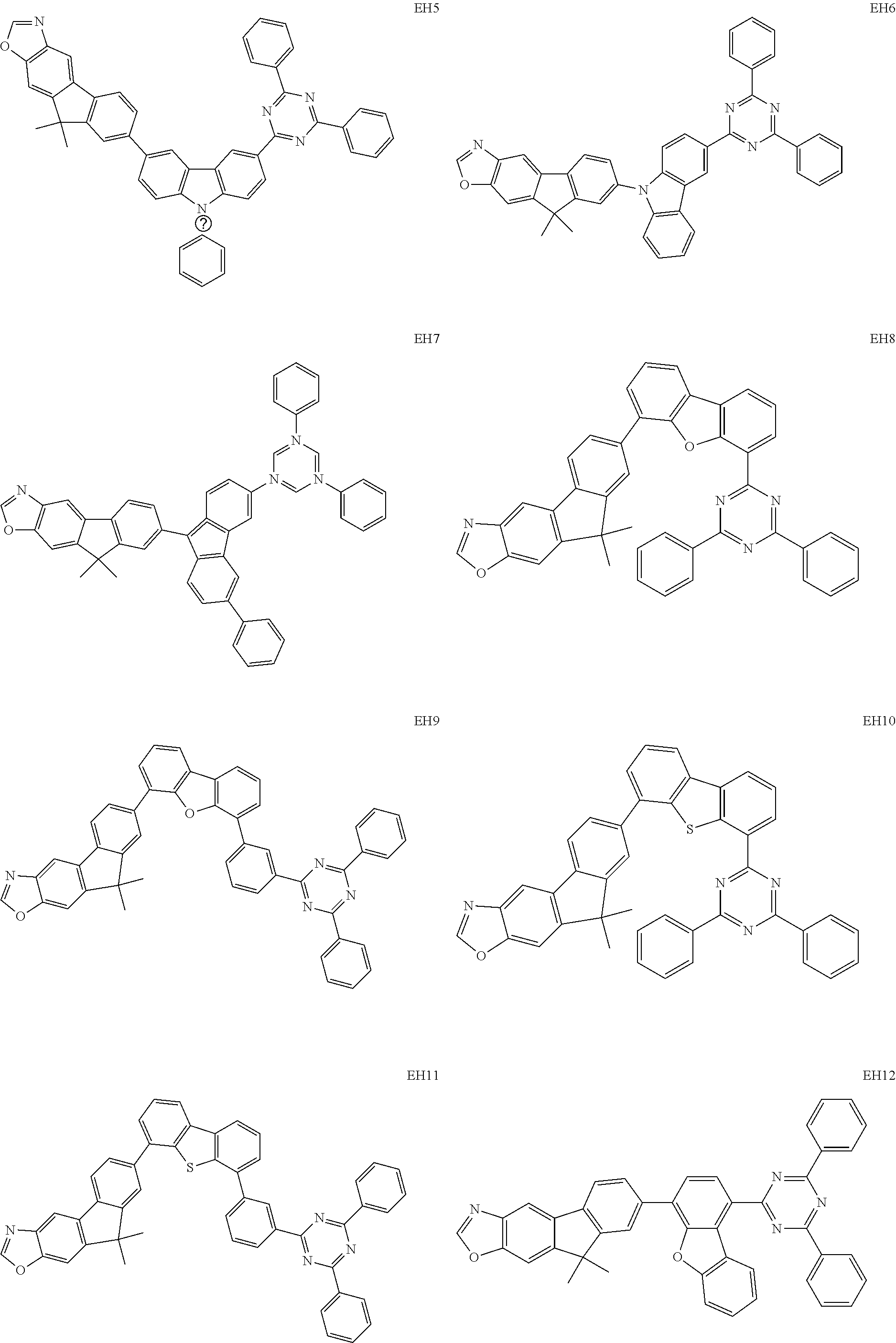

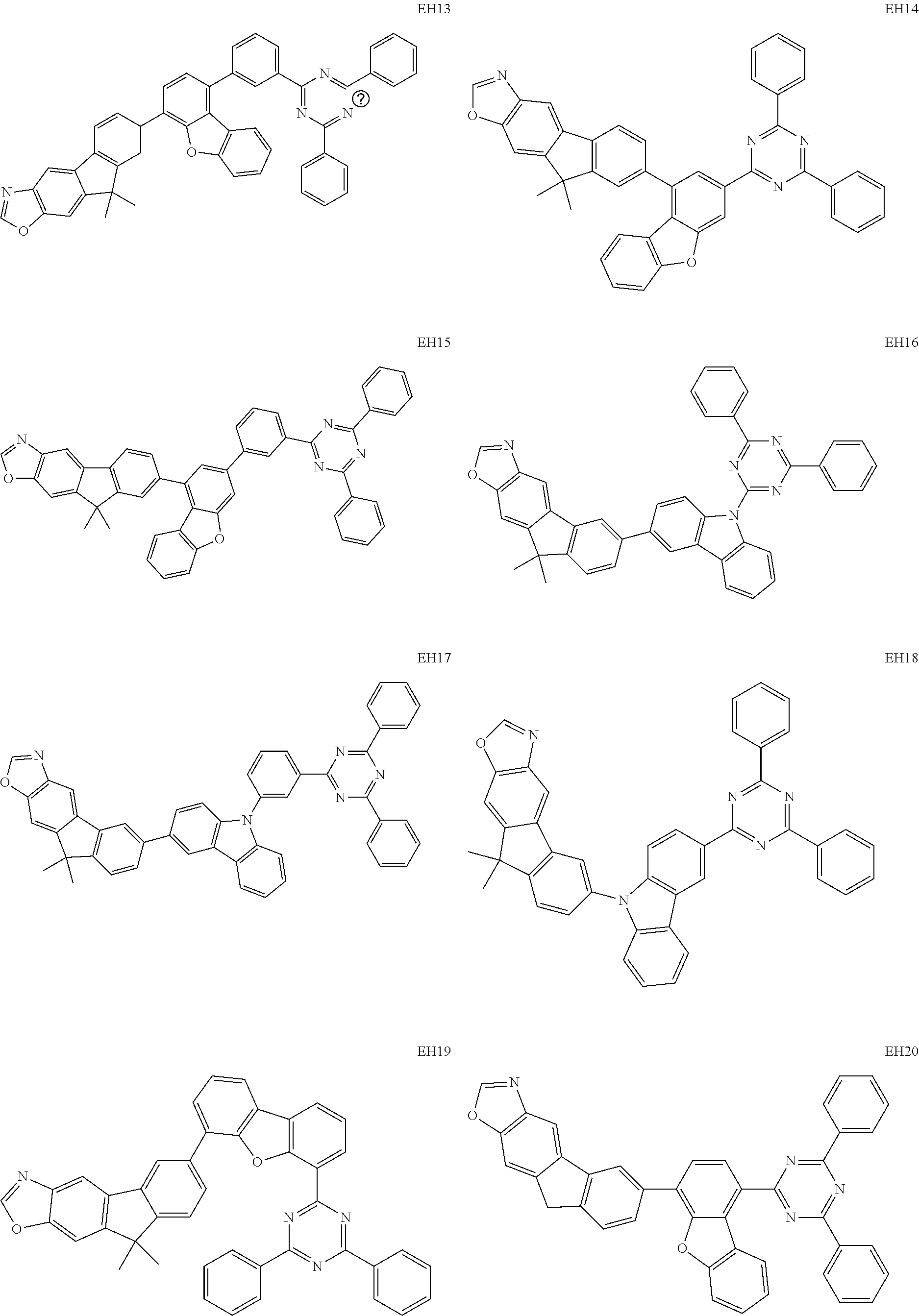

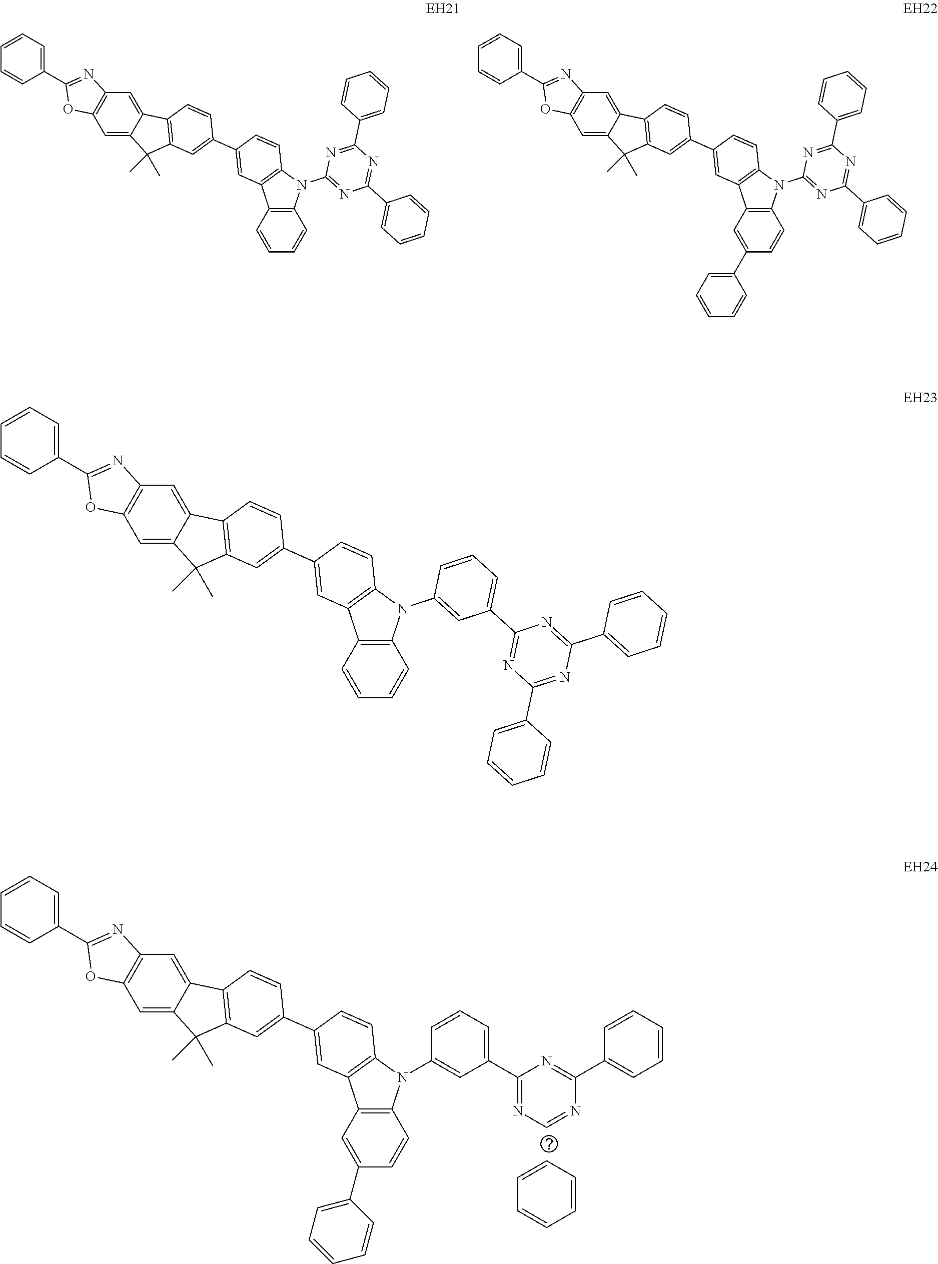

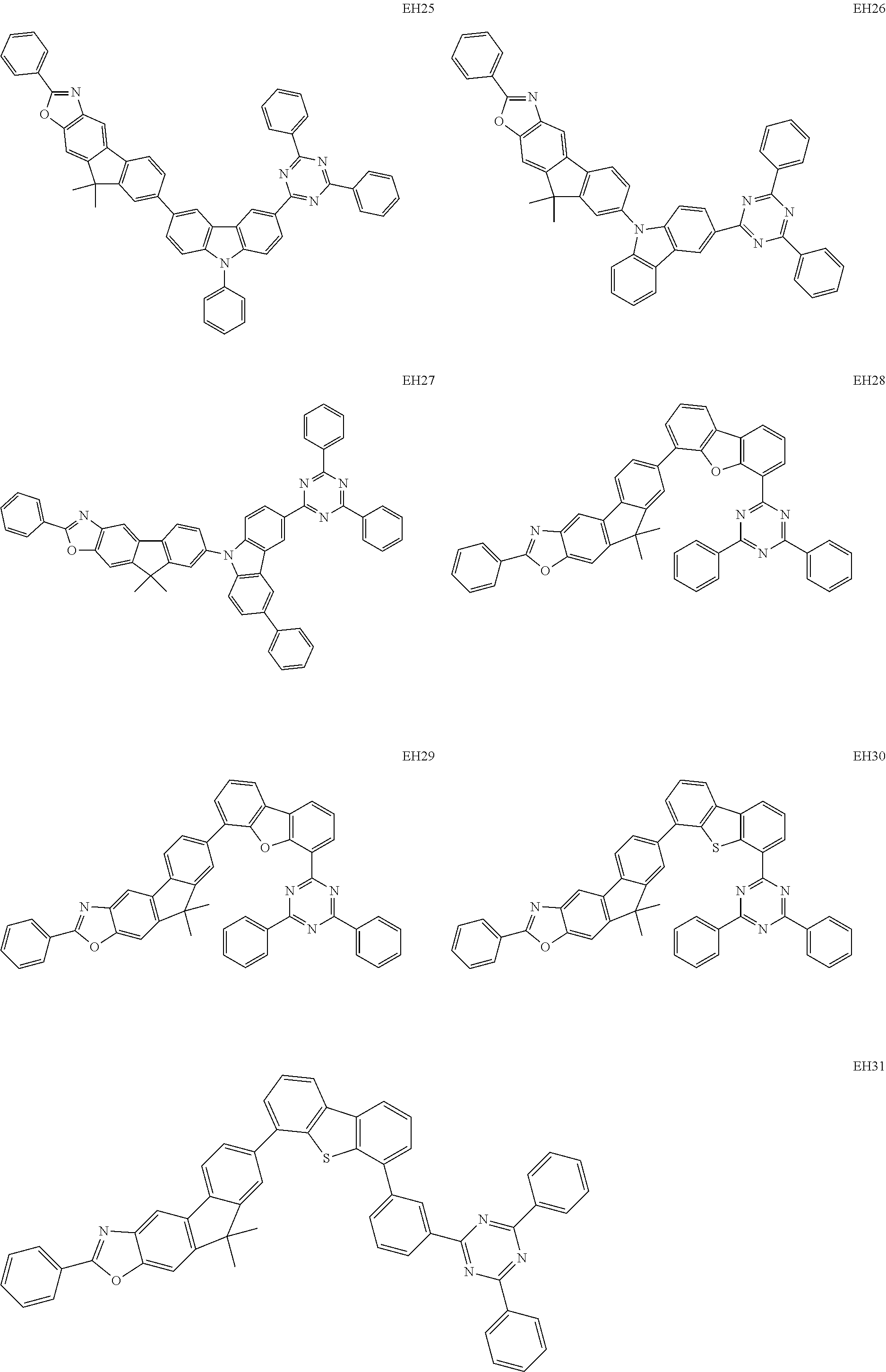

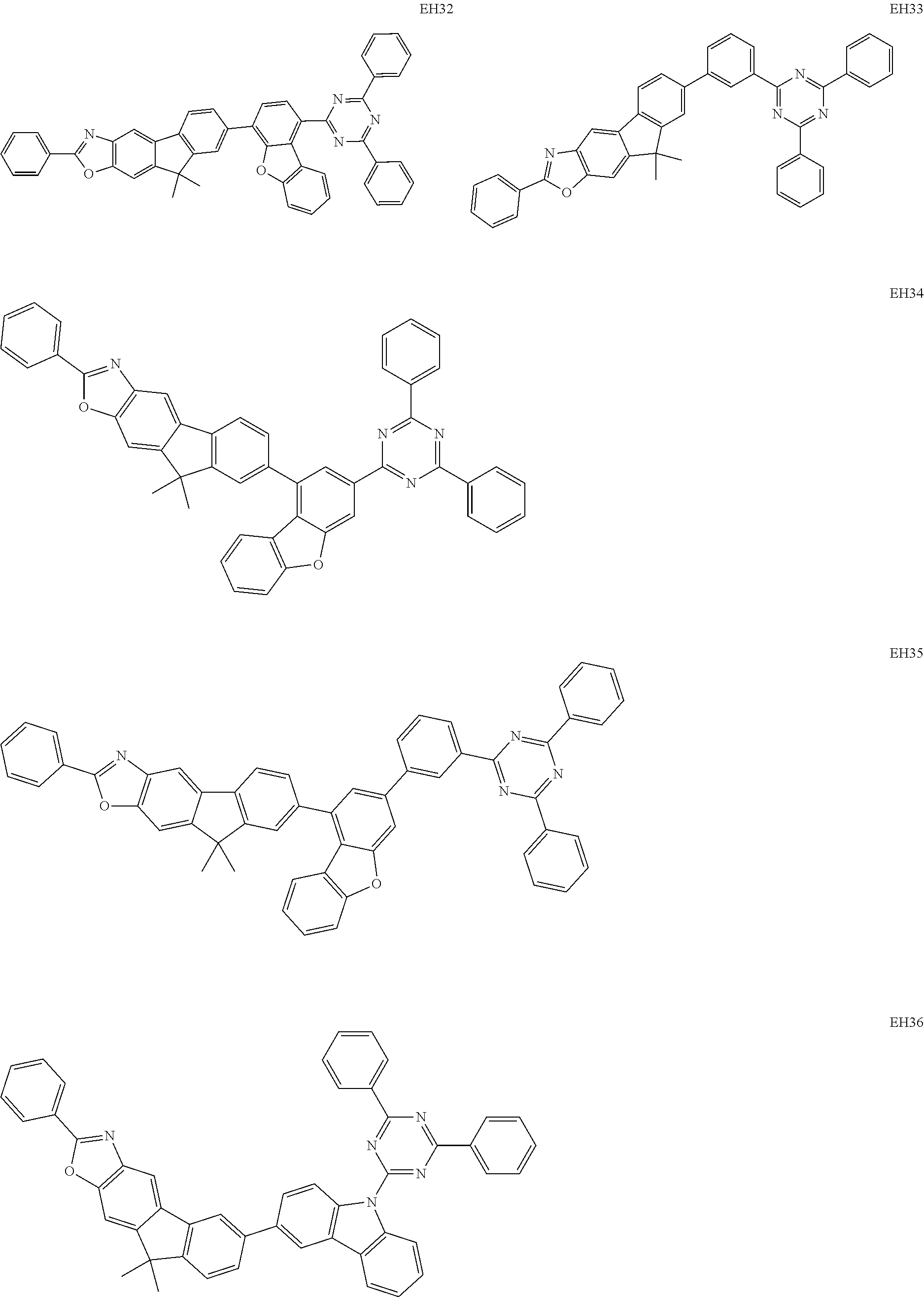 [SMILES: CC1(C)c2cc(-c3ccc(-c4nc(-c5ccccc5)nc(-c5ccccc5)n4)c4c3oc3ccccc34)ccc2-c2cc3nc(-c4ccccc4)oc3cc21 ; CC1(C)c2cc(-c3cccc(-c4nc(-c5ccccc5)nc(-c5ccccc5)n4)c3)ccc2-c2cc3nc(-c4ccccc4)oc3cc21 ; CC1(C)c2cc(-c3cc(-c4nc(-c5ccccc5)nc(-c5ccccc5)n4)cc4oc5ccccc5c34)ccc2-c2cc3nc(-c4ccccc4)oc3cc21 ; CC1(C)c2cc(-c3cc(-c4cccc(-c5nc(-c6ccccc6)nc(-c6ccccc6)n5)c4)cc4oc5ccccc5c34)ccc2-c2cc3nc(-c4ccccc4)oc3cc21 ; CC1(C)c2ccc(-c3ccc4c(c3)c3ccccc3n4-c3nc(-c4ccccc4)nc(-c4ccccc4)n3)cc2-c2cc3nc(-c4ccccc4)oc3cc21]

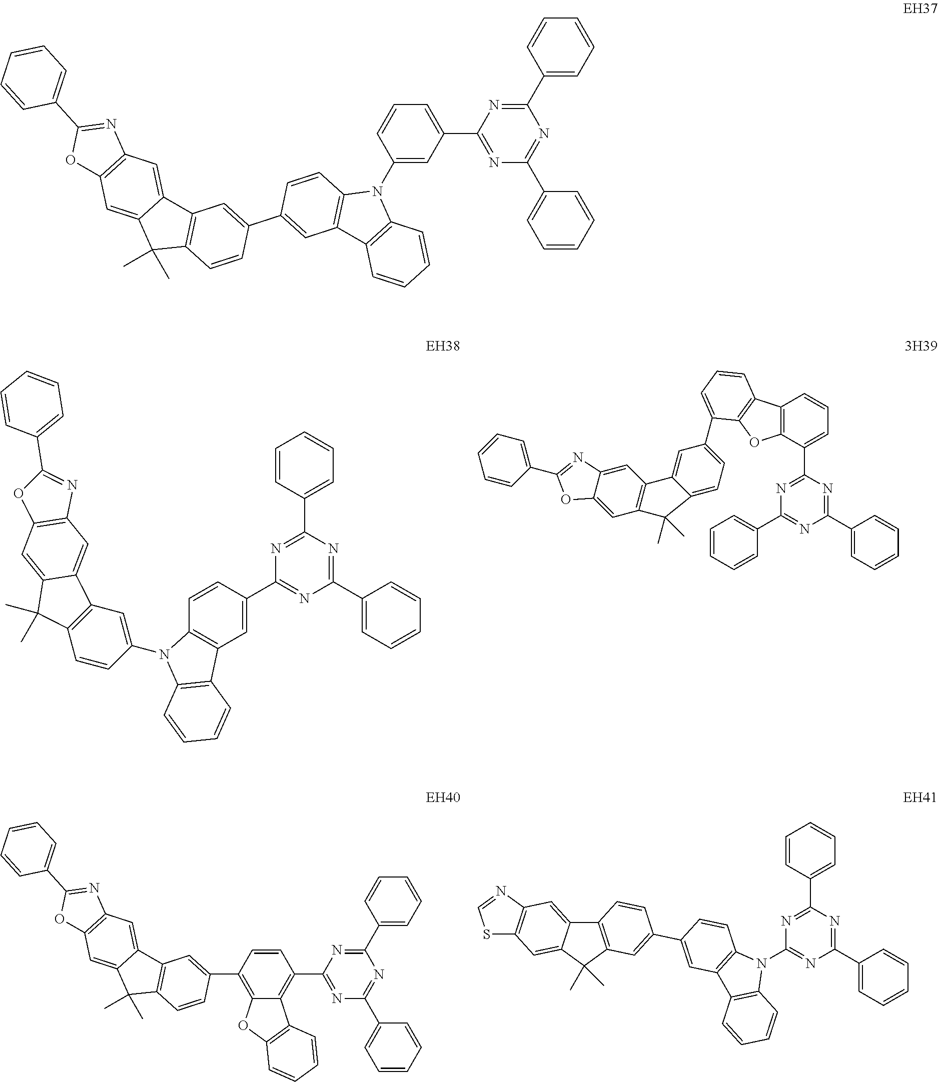 [SMILES: CC1(C)c2ccc(-c3ccc4c(c3)c3ccccc3n4-c3cccc(-c4nc(-c5ccccc5)nc(-c5ccccc5)n4)c3)cc2-c2cc3nc(-c4ccccc4)oc3cc21 ; CC1(C)c2ccc(-n3c4ccccc4c4cc(-c5nc(-c6ccccc6)nc(-c6ccccc6)n5)ccc43)cc2-c2cc3nc(-c4ccccc4)oc3cc21 ; CC1(C)c2ccc(-c3cccc4c3oc3c(-c5nc(-c6ccccc6)nc(-c6ccccc6)n5)cccc34)cc2-c2cc3nc(-c4ccccc4)oc3cc21 ; CC1(C)c2ccc(-c3ccc(-c4nc(-c5ccccc5)nc(-c5ccccc5)n4)c4c3oc3ccccc34)cc2-c2cc3nc(-c4ccccc4)oc3cc21 ; CC1(C)c2cc(-c3ccc4c(c3)c3ccccc3n4-c3nc(-c4ccccc4)nc(-c4ccccc4)n3)ccc2-c2cc3ncsc3cc21]

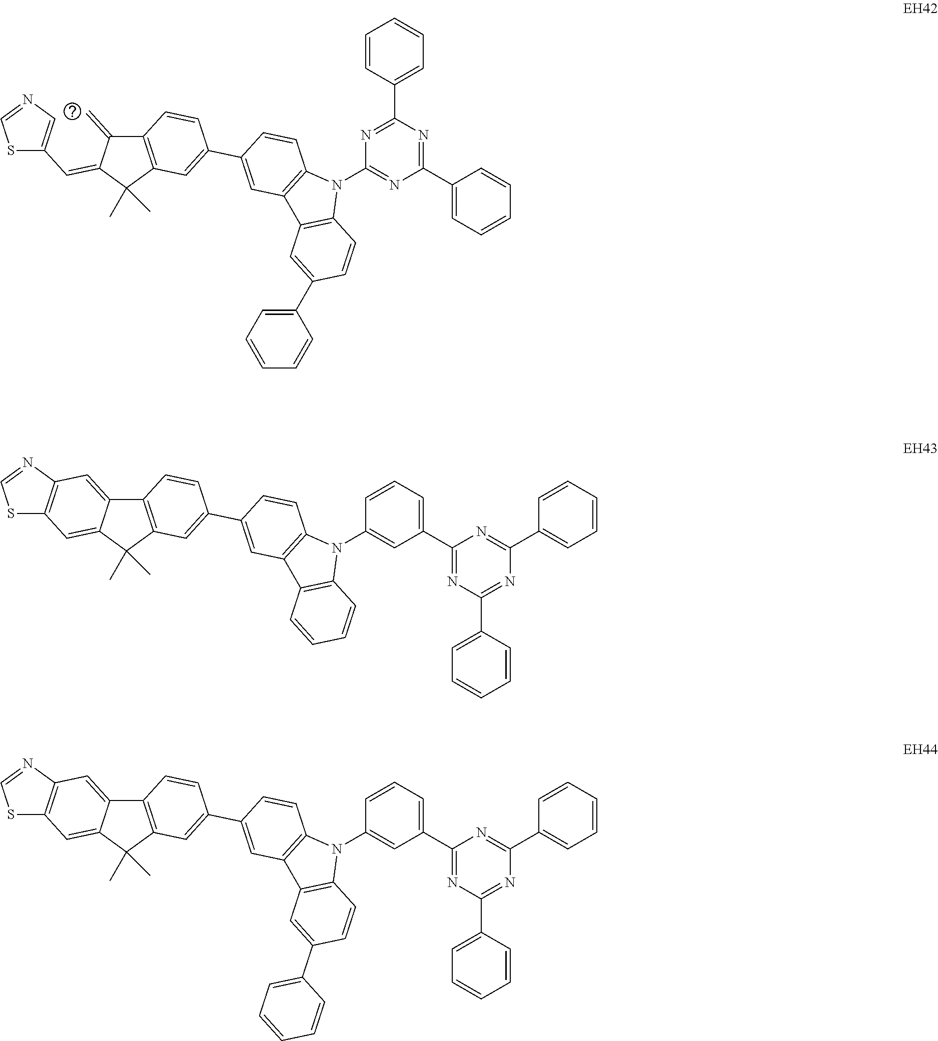 [SMILES: C=C1/C(=C\c2cncs2)C(C)(C)c2cc(-c3ccc4c(c3)c3cc(-c5ccccc5)ccc3n4-c3nc(-c4ccccc4)nc(-c4ccccc4)n3)ccc21 ; CC1(C)c2cc(-c3ccc4c(c3)c3ccccc3n4-c3cccc(-c4nc(-c5ccccc5)nc(-c5ccccc5)n4)c3)ccc2-c2cc3ncsc3cc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2cc3ncsc3cc21]

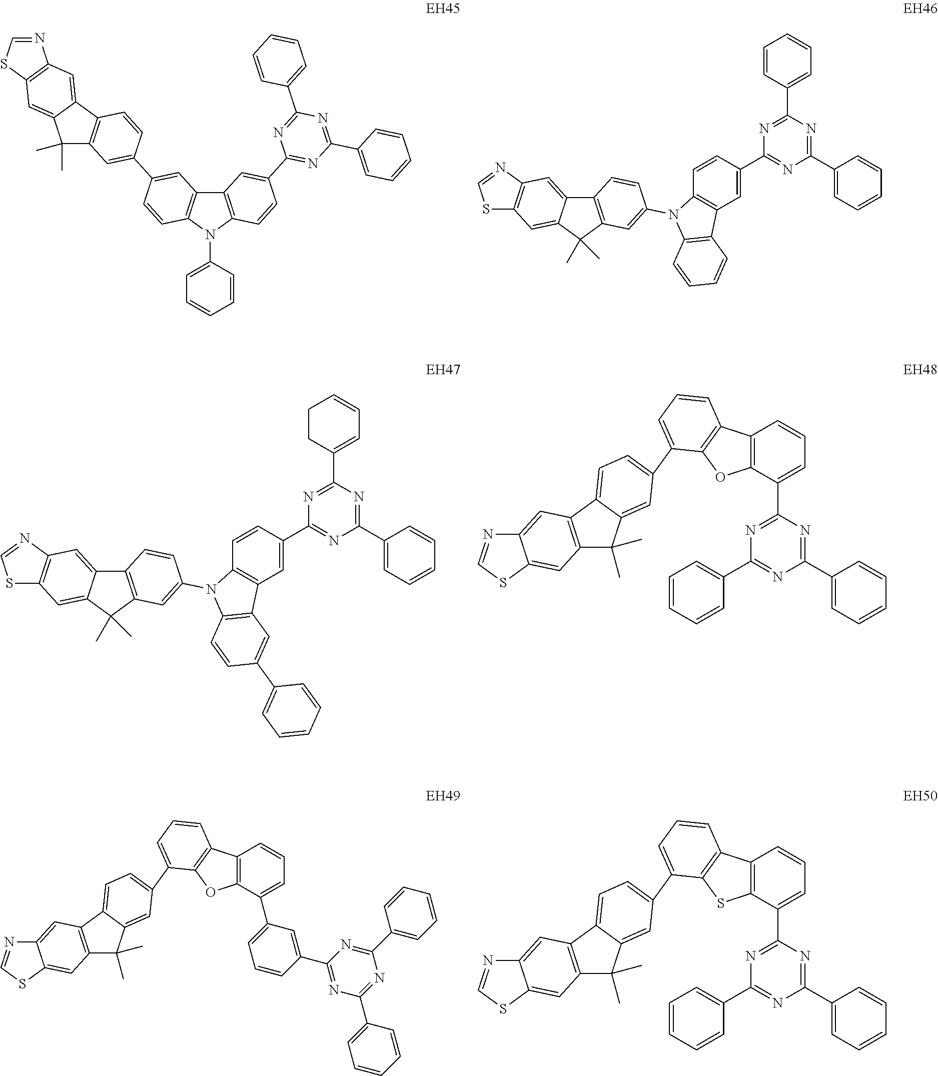

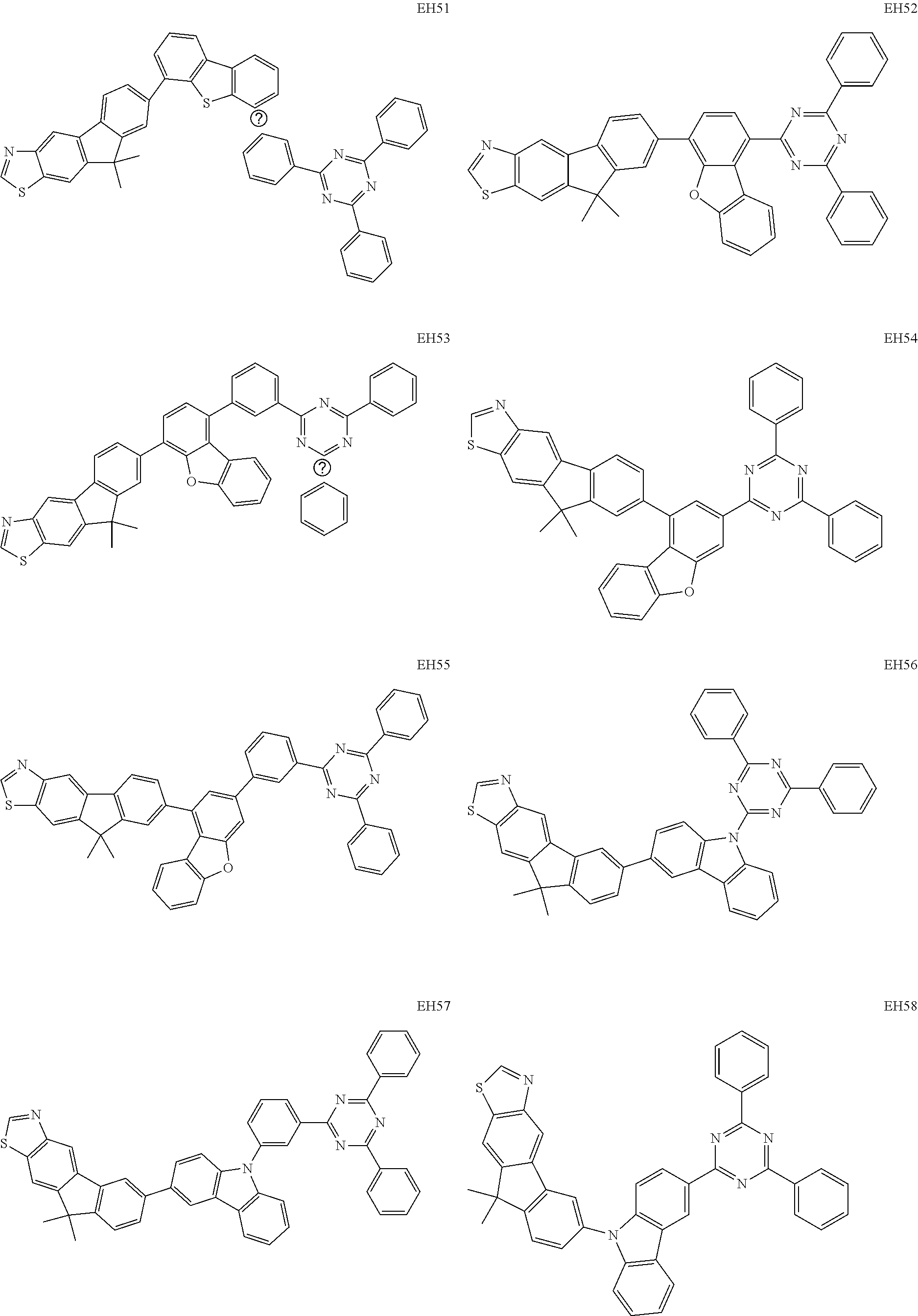

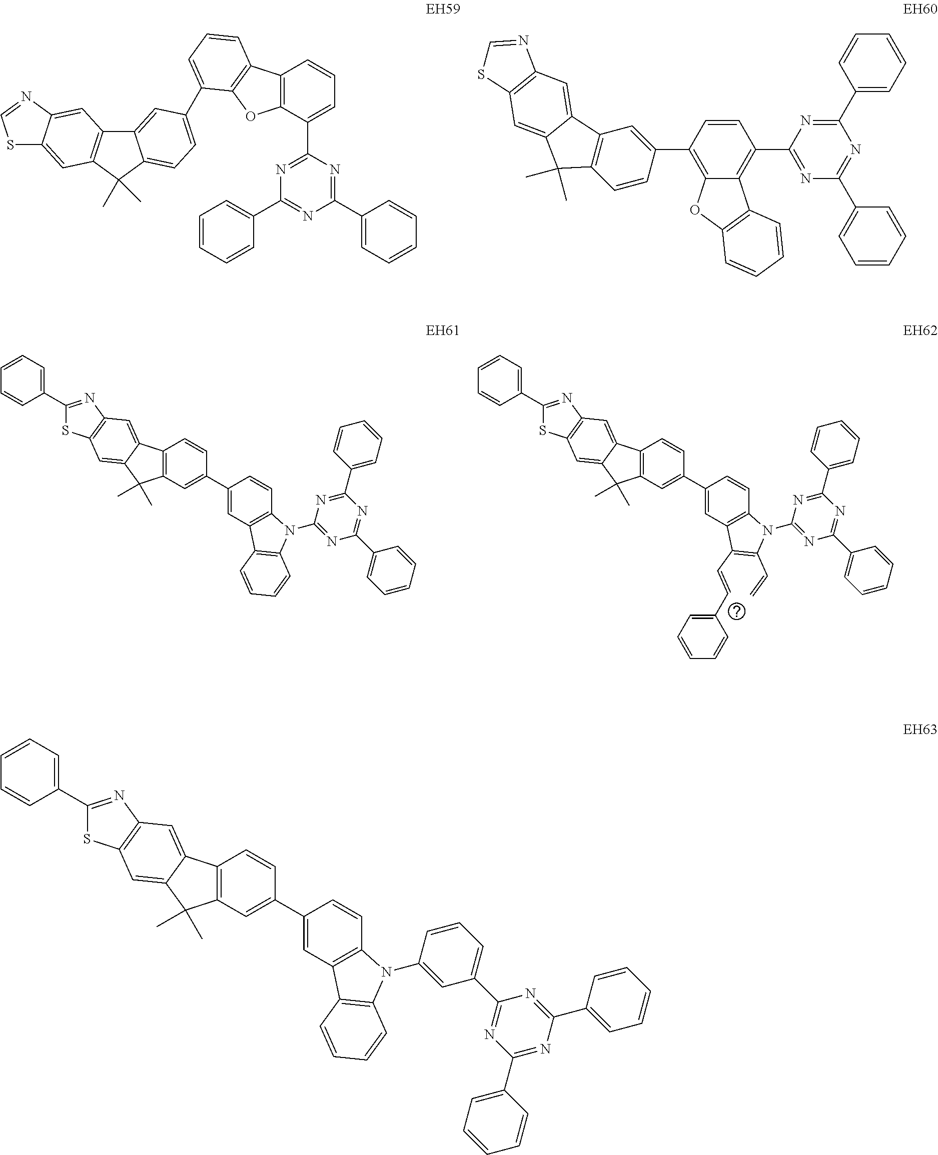 [SMILES: CC1(C)c2ccc(-c3cccc4c3oc3c(-c5nc(-c6ccccc6)nc(-c6ccccc6)n5)cccc34)cc2-c2cc3ncsc3cc21 ; CC1(C)c2ccc(-c3ccc(-c4nc(-c5ccccc5)nc(-c5ccccc5)n4)c4c3oc3ccccc34)cc2-c2cc3ncsc3cc21 ; CC1(C)c2cc(-c3ccc4c(c3)c3ccccc3n4-c3nc(-c4ccccc4)nc(-c4ccccc4)n3)ccc2-c2cc3nc(-c4ccccc4)sc3cc21 ; C=Cc1c(/C=C/c2ccccc2)c2cc(-c3ccc4c(c3)C(C)(C)c3cc5sc(-c6ccccc6)nc5cc3-4)ccc2n1-c1nc(-c2ccccc2)nc(-c2ccccc2)n1 ; CC1(C)c2cc(-c3ccc4c(c3)c3ccccc3n4-c3cccc(-c4nc(-c5ccccc5)nc(-c5ccccc5)n4)c3)ccc2-c2cc3nc(-c4ccccc4)sc3cc21]

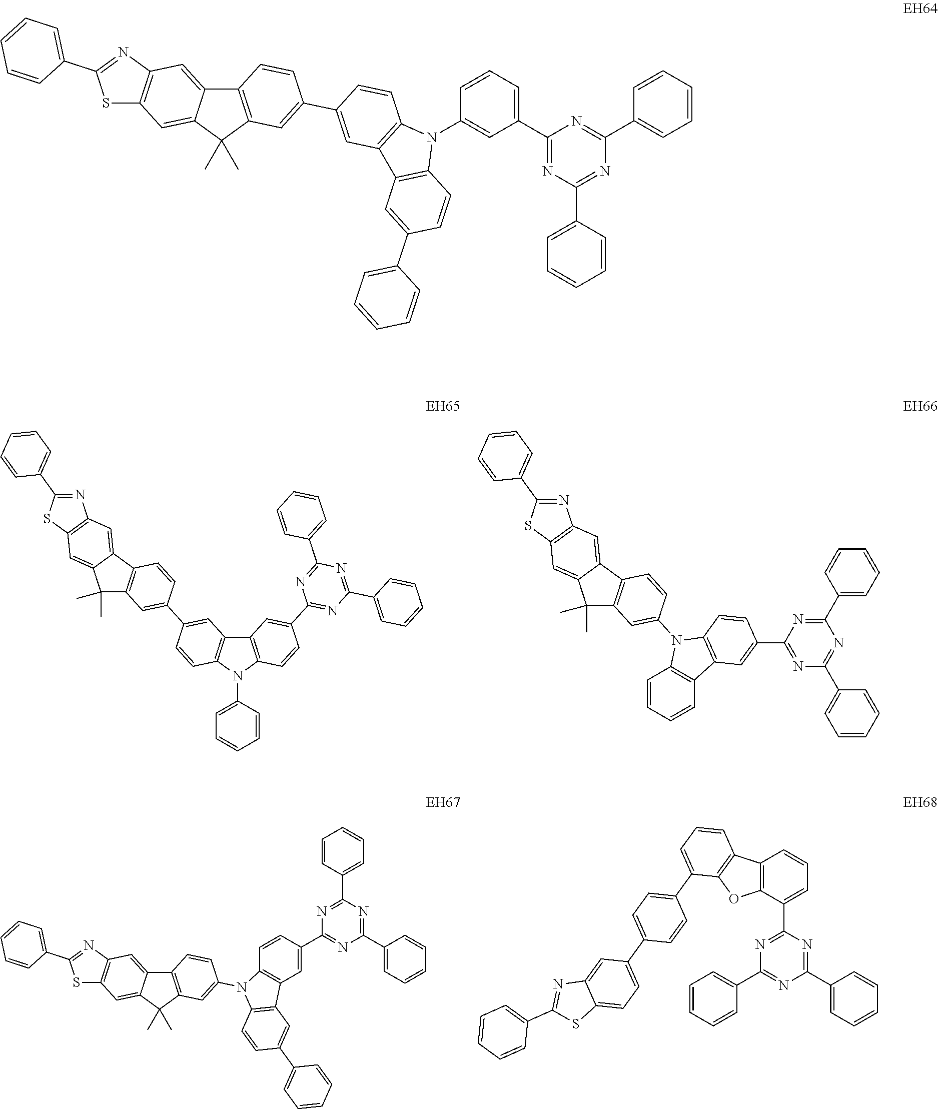

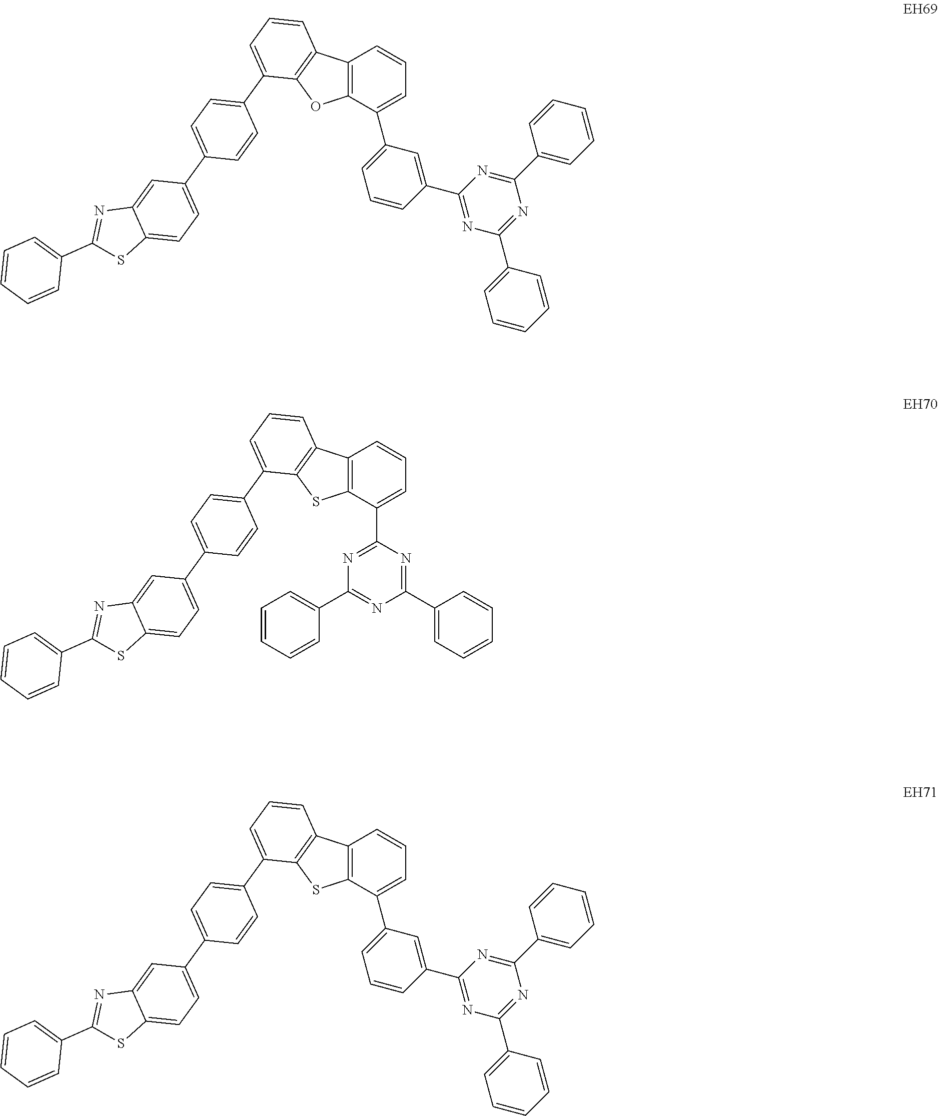 [SMILES: c1ccc(-c2nc(-c3ccccc3)nc(-c3cccc(-c4cccc5c4oc4c(-c6ccc(-c7ccc8sc(-c9ccccc9)nc8c7)cc6)cccc45)c3)n2)cc1 ; c1ccc(-c2nc(-c3ccccc3)nc(-c3cccc4c3sc3c(-c5ccc(-c6ccc7sc(-c8ccccc8)nc7c6)cc5)cccc34)n2)cc1 ; c1ccc(-c2nc(-c3ccccc3)nc(-c3cccc(-c4cccc5c4sc4c(-c6ccc(-c7ccc8sc(-c9ccccc9)nc8c7)cc6)cccc45)c3)n2)cc1]

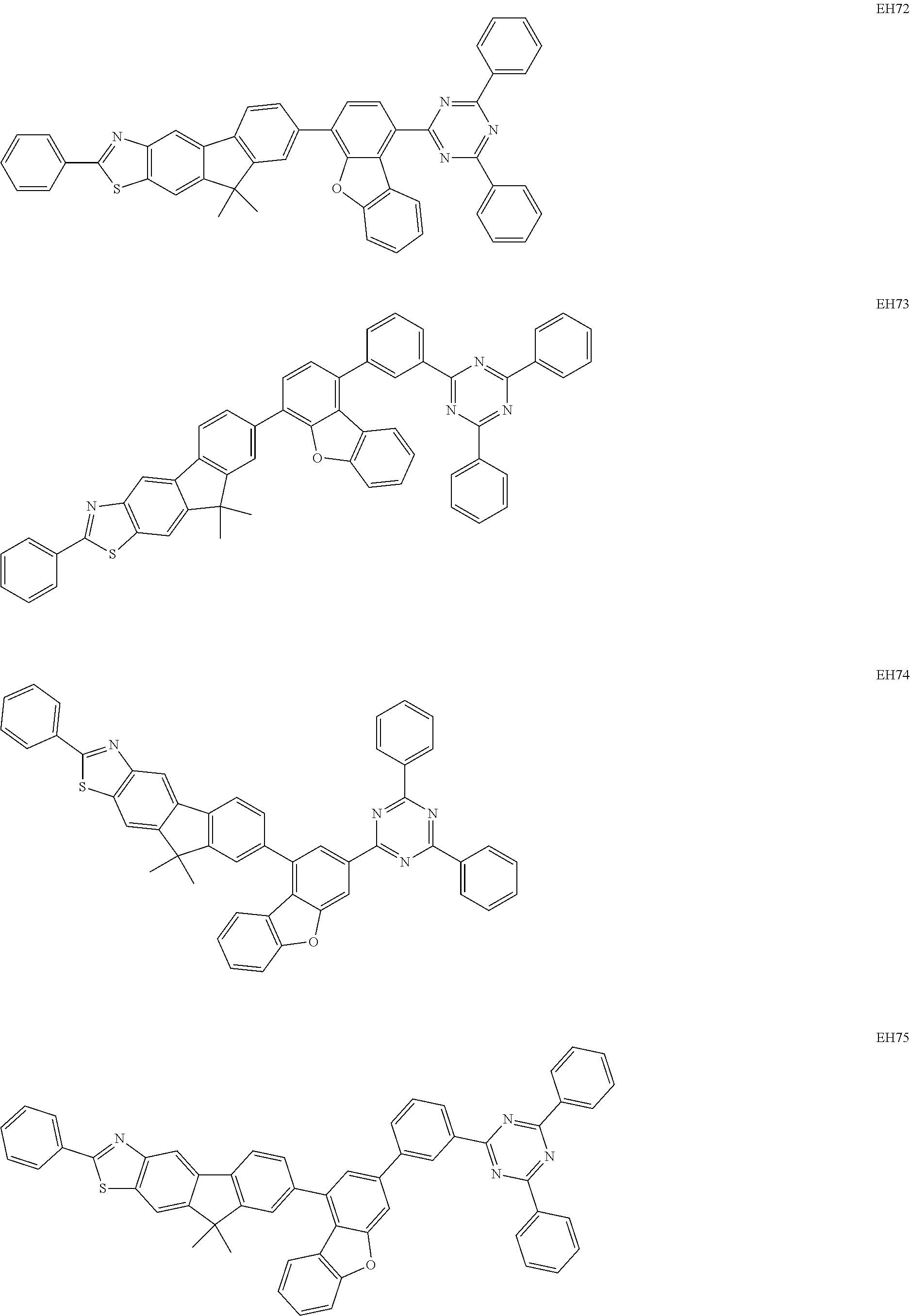 [SMILES: CC1(C)c2cc(-c3ccc(-c4nc(-c5ccccc5)nc(-c5ccccc5)n4)c4c3oc3ccccc34)ccc2-c2cc3nc(-c4ccccc4)sc3cc21 ; CC1(C)c2cc(-c3ccc(-c4cccc(-c5nc(-c6ccccc6)nc(-c6ccccc6)n5)c4)c4c3oc3ccccc34)ccc2-c2cc3nc(-c4ccccc4)sc3cc21 ; CC1(C)c2cc(-c3cc(-c4nc(-c5ccccc5)nc(-c5ccccc5)n4)cc4oc5ccccc5c34)ccc2-c2cc3nc(-c4ccccc4)sc3cc21 ; CC1(C)c2cc(-c3cc(-c4cccc(-c5nc(-c6ccccc6)nc(-c6ccccc6)n5)c4)cc4oc5ccccc5c34)ccc2-c2cc3nc(-c4ccccc4)sc3cc21]

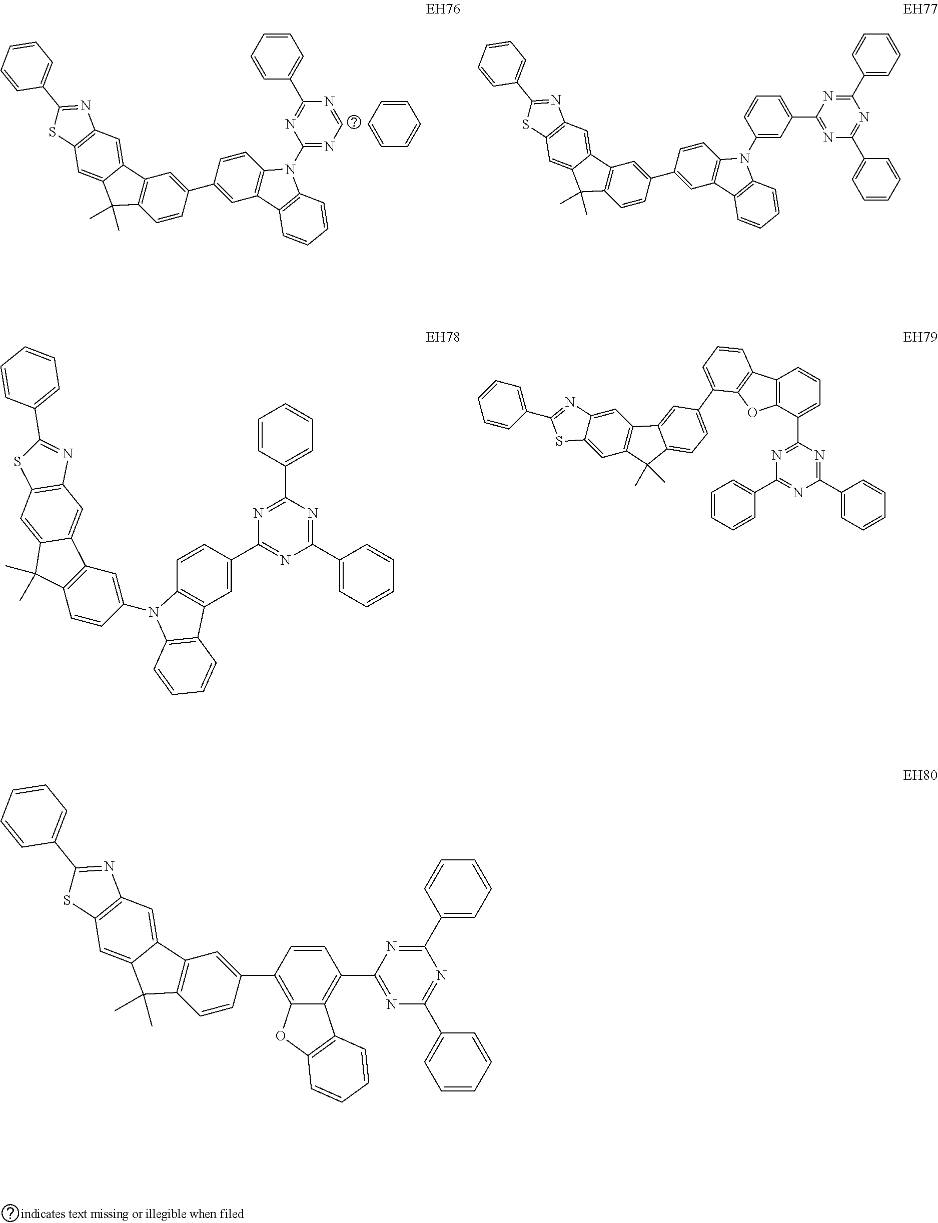

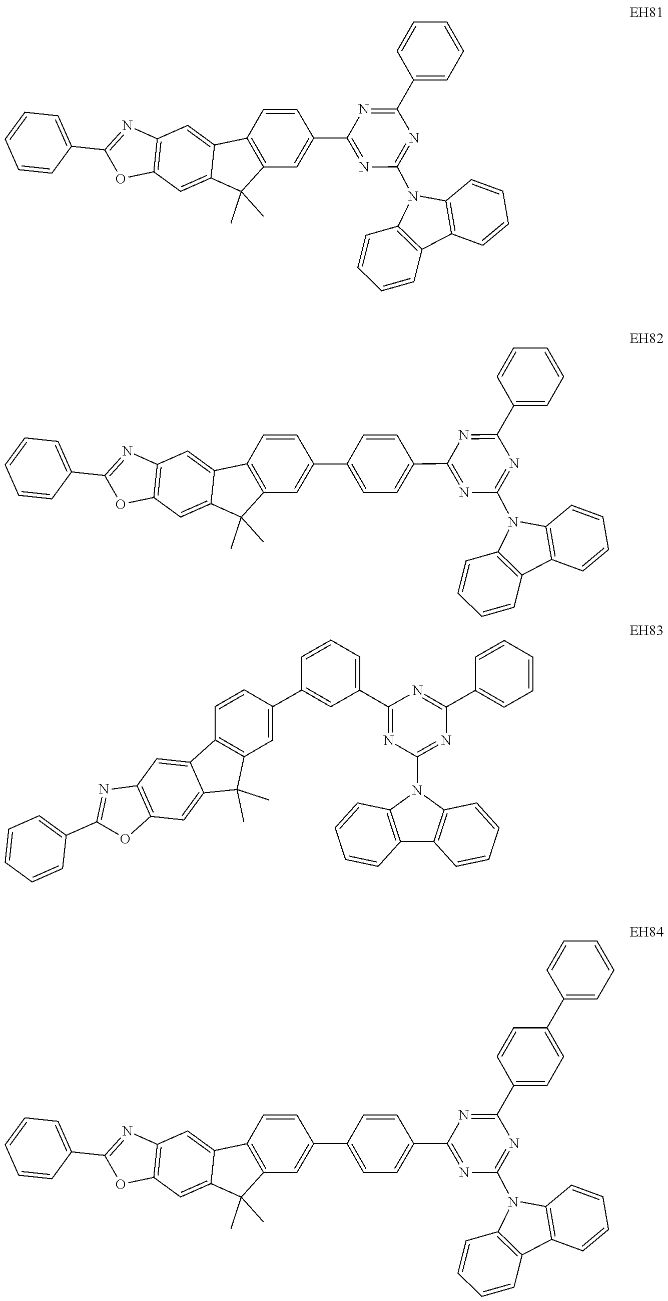

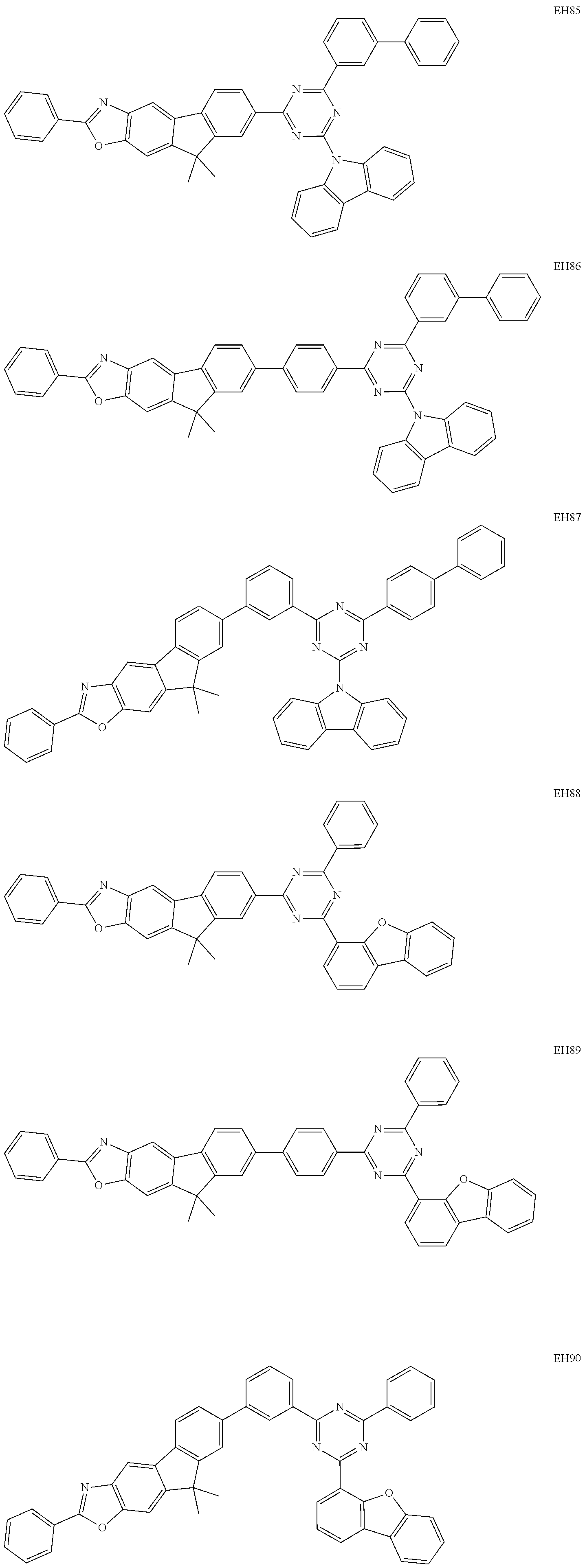

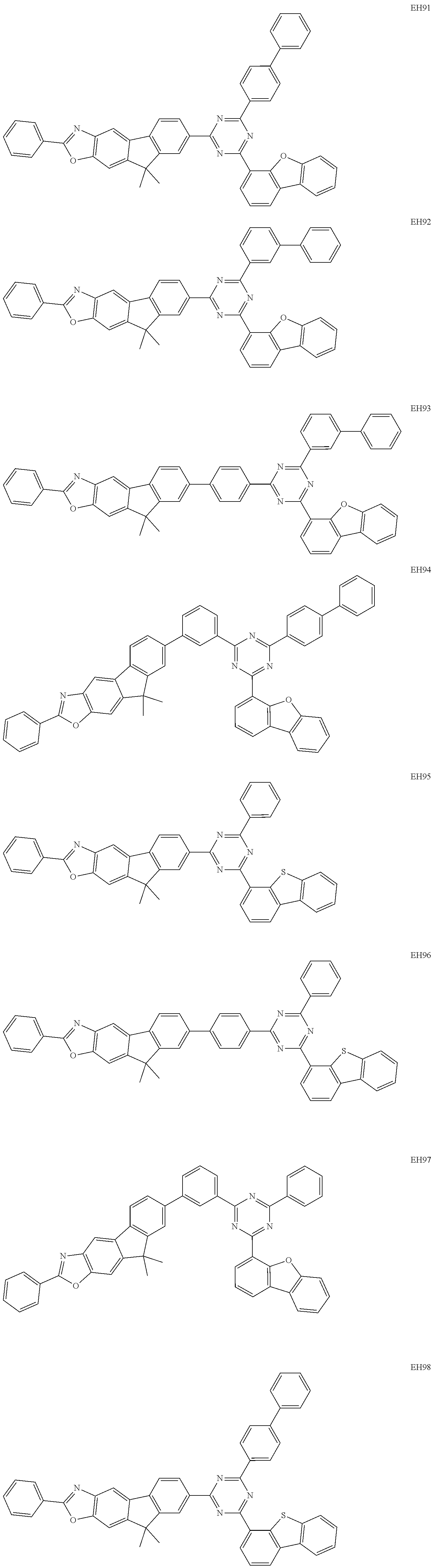

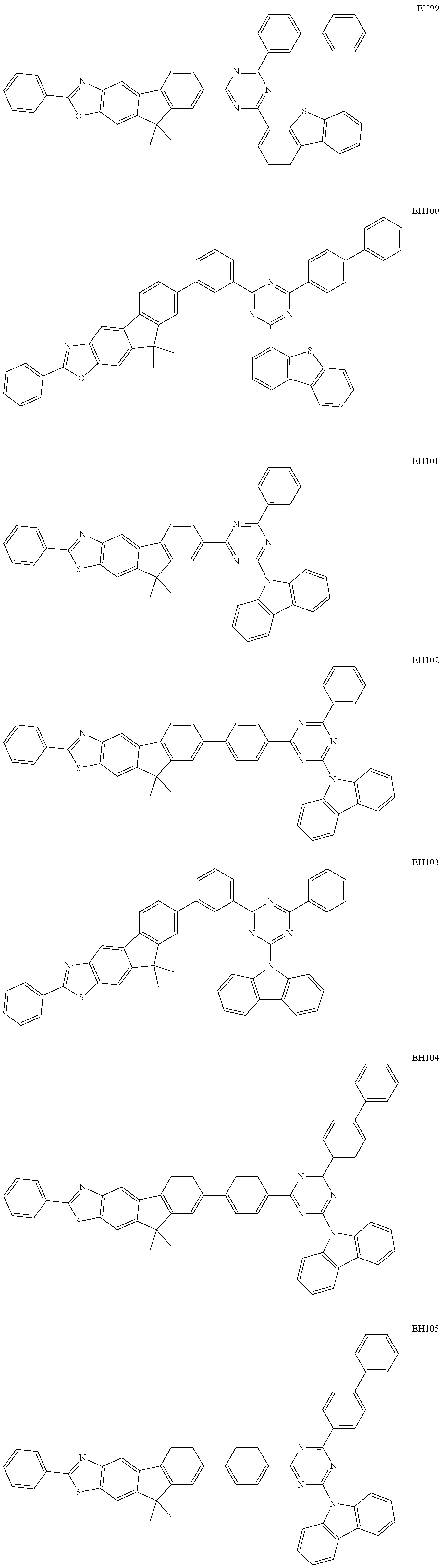

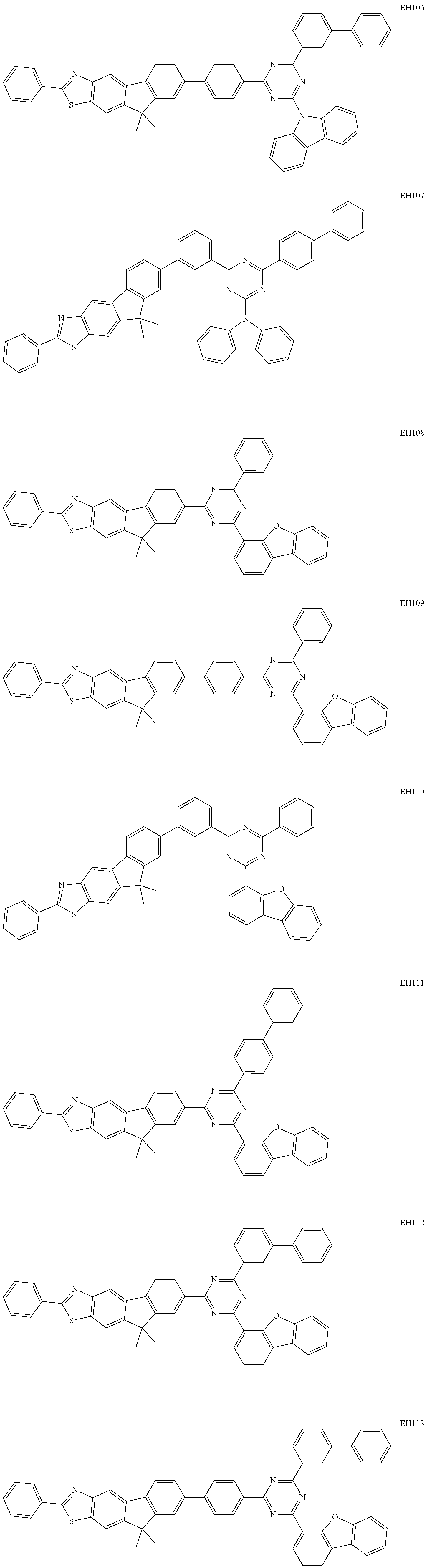

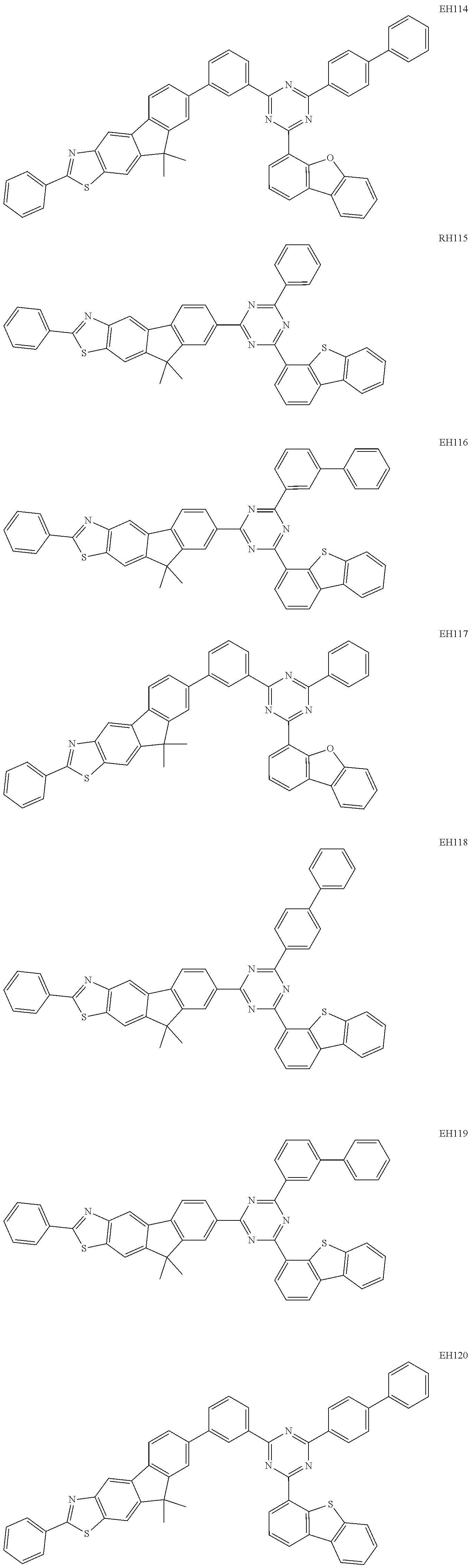

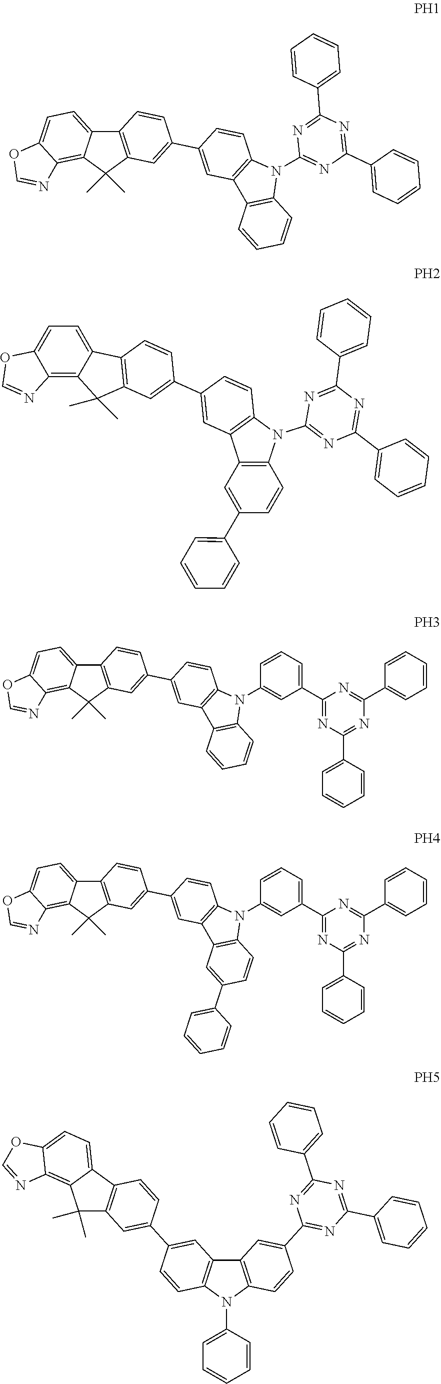 [SMILES: CC1(C)c2cc(-c3ccc4c(c3)c3ccccc3n4-c3nc(-c4ccccc4)nc(-c4ccccc4)n3)ccc2-c2ccc3ocnc3c21 ; CC1(C)c2cc(-c3ccc4c(c3)c3cc(-c5ccccc5)ccc3n4-c3nc(-c4ccccc4)nc(-c4ccccc4)n3)ccc2-c2ccc3ocnc3c21 ; CC1(C)c2cc(-c3ccc4c(c3)c3ccccc3n4-c3cccc(-c4nc(-c5ccccc5)nc(-c5ccccc5)n4)c3)ccc2-c2ccc3ocnc3c21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2ccc3ocnc3c21 ; CC1(C)c2cc(-c3ccc4c(c3)c3cc(-c5nc(-c6ccccc6)nc(-c6ccccc6)n5)ccc3n4-c3ccccc3)ccc2-c2ccc3ocnc3c21]

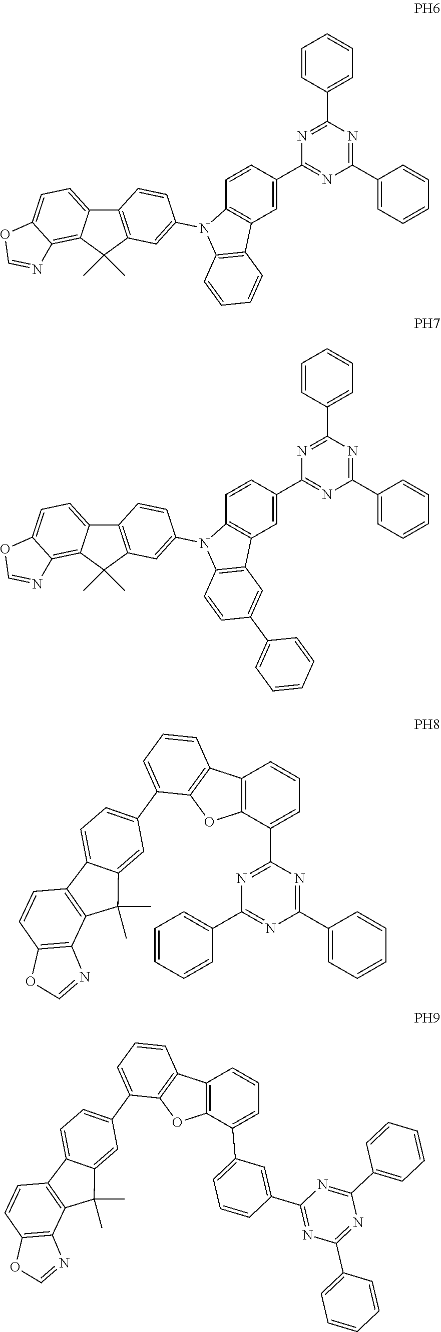 [SMILES: CC1(C)c2cc(-n3c4ccccc4c4cc(-c5nc(-c6ccccc6)nc(-c6ccccc6)n5)ccc43)ccc2-c2ccc3ocnc3c21 ; CC1(C)c2cc(-n3c4ccc(-c5ccccc5)cc4c4cc(-c5nc(-c6ccccc6)nc(-c6ccccc6)n5)ccc43)ccc2-c2ccc3ocnc3c21 ; CC1(C)c2cc(-c3cccc4c3oc3c(-c5nc(-c6ccccc6)nc(-c6ccccc6)n5)cccc34)ccc2-c2ccc3ocnc3c21 ; CC1(C)c2cc(-c3cccc4c3oc3c(-c5cccc(-c6nc(-c7ccccc7)nc(-c7ccccc7)n6)c5)cccc34)ccc2-c2ccc3ocnc3c21]

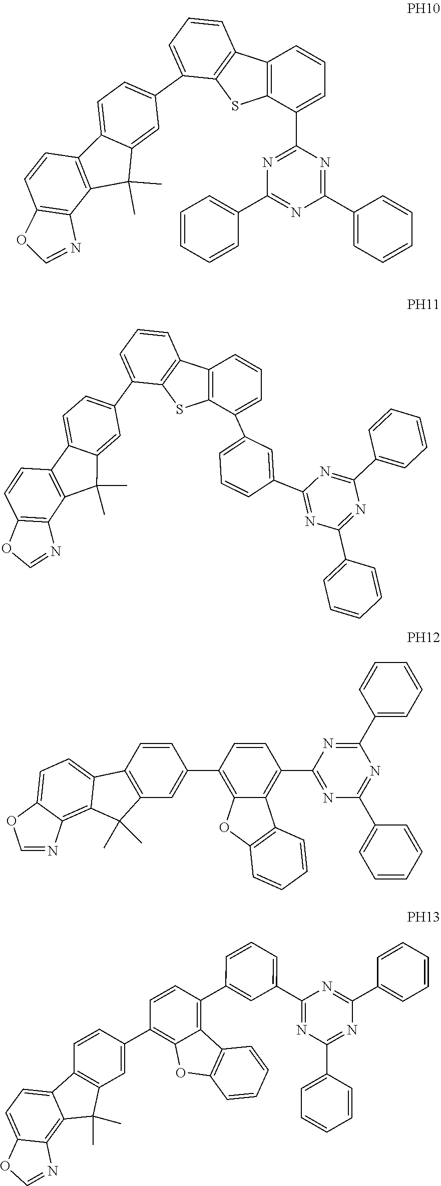 [SMILES: CC1(C)c2cc(-c3cccc4c3sc3c(-c5nc(-c6ccccc6)nc(-c6ccccc6)n5)cccc34)ccc2-c2ccc3ocnc3c21 ; CC1(C)c2cc(-c3cccc4c3sc3c(-c5cccc(-c6nc(-c7ccccc7)nc(-c7ccccc7)n6)c5)cccc34)ccc2-c2ccc3ocnc3c21 ; CC1(C)c2cc(-c3ccc(-c4nc(-c5ccccc5)nc(-c5ccccc5)n4)c4c3oc3ccccc34)ccc2-c2ccc3ocnc3c21 ; CC1(C)c2cc(-c3ccc(-c4cccc(-c5nc(-c6ccccc6)nc(-c6ccccc6)n5)c4)c4c3oc3ccccc34)ccc2-c2ccc3ocnc3c21]

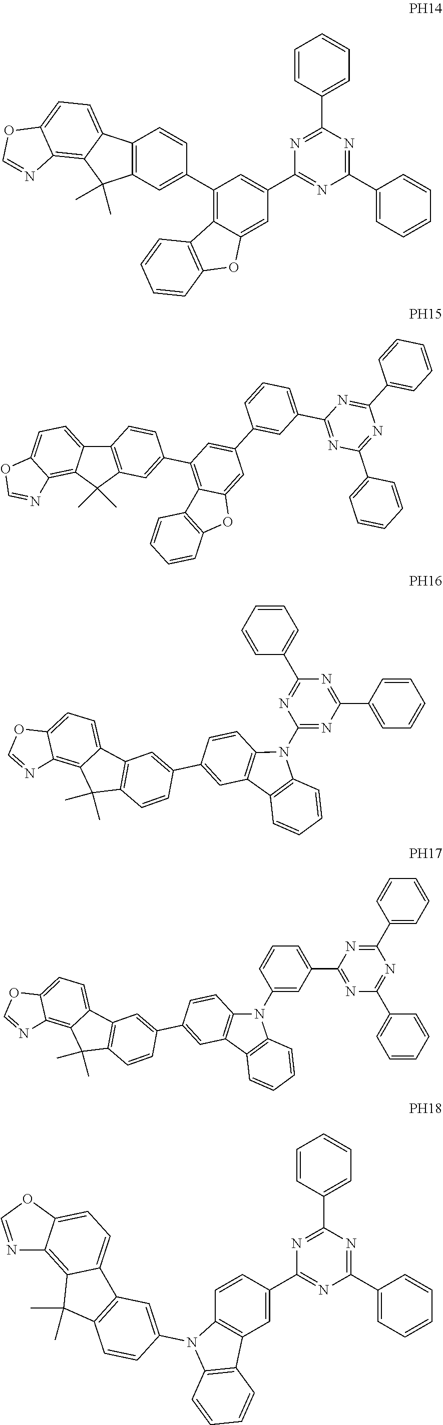 [SMILES: CC1(C)c2cc(-c3cc(-c4nc(-c5ccccc5)nc(-c5ccccc5)n4)cc4oc5ccccc5c34)ccc2-c2ccc3ocnc3c21 ; CC1(C)c2cc(-c3cc(-c4cccc(-c5nc(-c6ccccc6)nc(-c6ccccc6)n5)c4)cc4oc5ccccc5c34)ccc2-c2ccc3ocnc3c21 ; CC1(C)c2ccc(-c3ccc4c(c3)c3ccccc3n4-c3nc(-c4ccccc4)nc(-c4ccccc4)n3)cc2-c2ccc3ocnc3c21 ; CC1(C)c2ccc(-c3ccc4c(c3)c3ccccc3n4-c3cccc(-c4nc(-c5ccccc5)nc(-c5ccccc5)n4)c3)cc2-c2ccc3ocnc3c21 ; CC1(C)c2ccc(-n3c4ccccc4c4cc(-c5nc(-c6ccccc6)nc(-c6ccccc6)n5)ccc43)cc2-c2ccc3ocnc3c21]

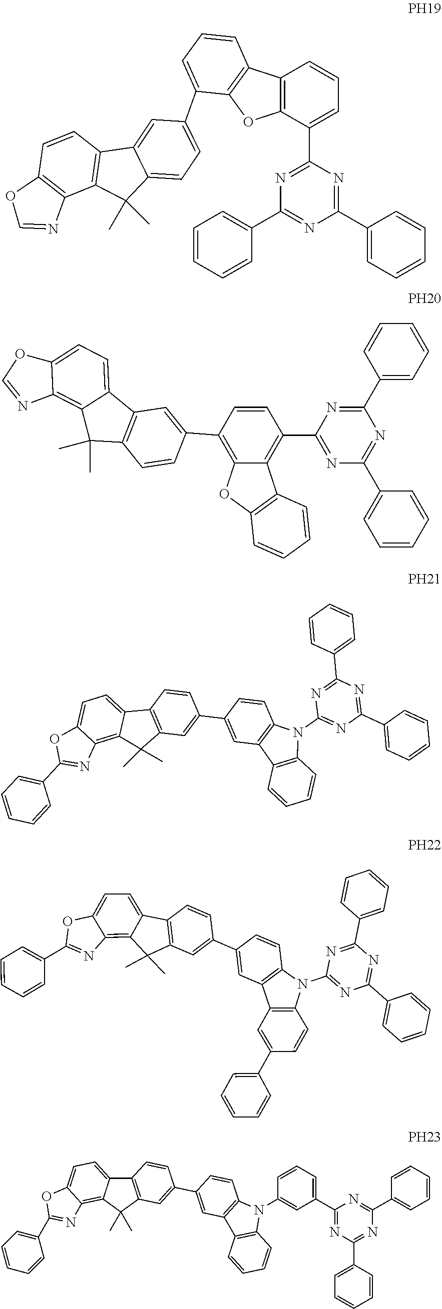 [SMILES: CC1(C)c2ccc(-c3cccc4c3oc3c(-c5nc(-c6ccccc6)nc(-c6ccccc6)n5)cccc34)cc2-c2ccc3ocnc3c21 ; CC1(C)c2ccc(-c3ccc(-c4nc(-c5ccccc5)nc(-c5ccccc5)n4)c4c3oc3ccccc34)cc2-c2ccc3ocnc3c21 ; CC1(C)c2cc(-c3ccc4c(c3)c3ccccc3n4-c3nc(-c4ccccc4)nc(-c4ccccc4)n3)ccc2-c2ccc3oc(-c4ccccc4)nc3c21 ; CC1(C)c2cc(-c3ccc4c(c3)c3cc(-c5ccccc5)ccc3n4-c3nc(-c4ccccc4)nc(-c4ccccc4)n3)ccc2-c2ccc3oc(-c4ccccc4)nc3c21 ; CC1(C)c2cc(-c3ccc4c(c3)c3ccccc3n4-c3cccc(-c4nc(-c5ccccc5)nc(-c5ccccc5)n4)c3)ccc2-c2ccc3oc(-c4ccccc4)nc3c21]

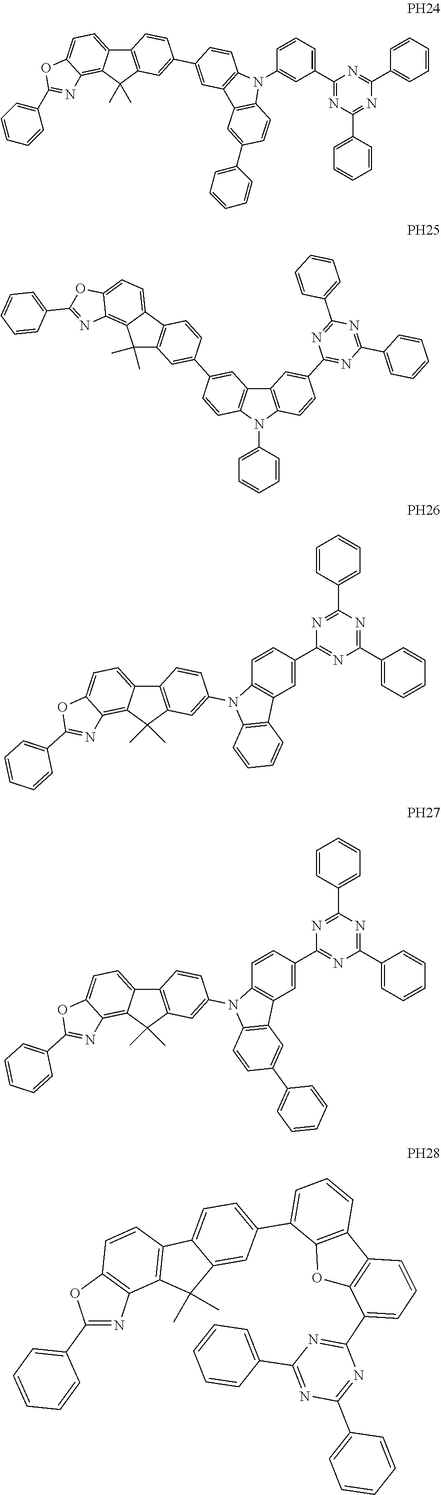

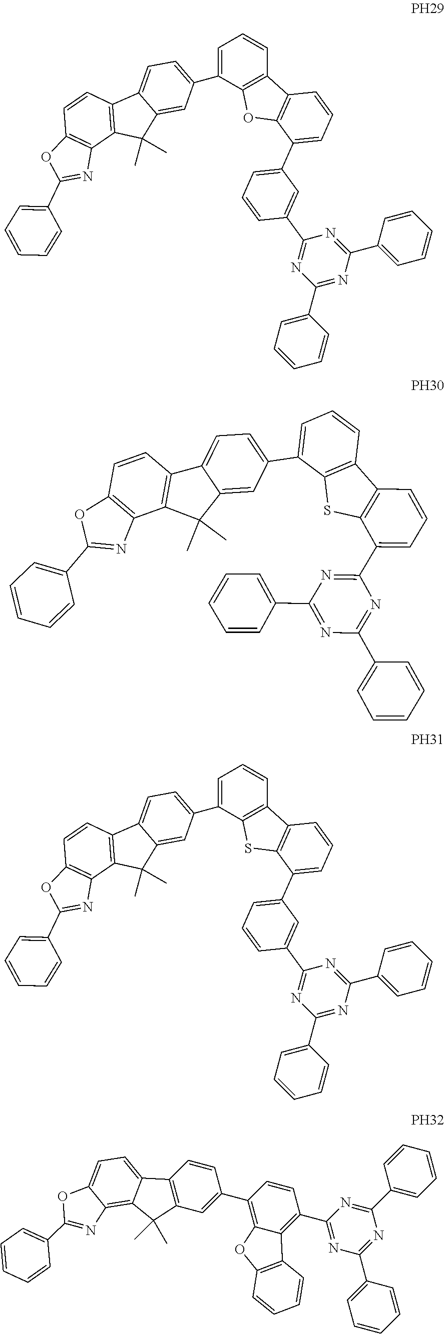 [SMILES: CC1(C)c2cc(-c3cccc4c3oc3c(-c5cccc(-c6nc(-c7ccccc7)nc(-c7ccccc7)n6)c5)cccc34)ccc2-c2ccc3oc(-c4ccccc4)nc3c21 ; CC1(C)c2cc(-c3cccc4c3sc3c(-c5nc(-c6ccccc6)nc(-c6ccccc6)n5)cccc34)ccc2-c2ccc3oc(-c4ccccc4)nc3c21 ; CC1(C)c2cc(-c3cccc4c3sc3c(-c5cccc(-c6nc(-c7ccccc7)nc(-c7ccccc7)n6)c5)cccc34)ccc2-c2ccc3oc(-c4ccccc4)nc3c21 ; CC1(C)c2cc(-c3ccc(-c4nc(-c5ccccc5)nc(-c5ccccc5)n4)c4c3oc3ccccc34)ccc2-c2ccc3oc(-c4ccccc4)nc3c21]

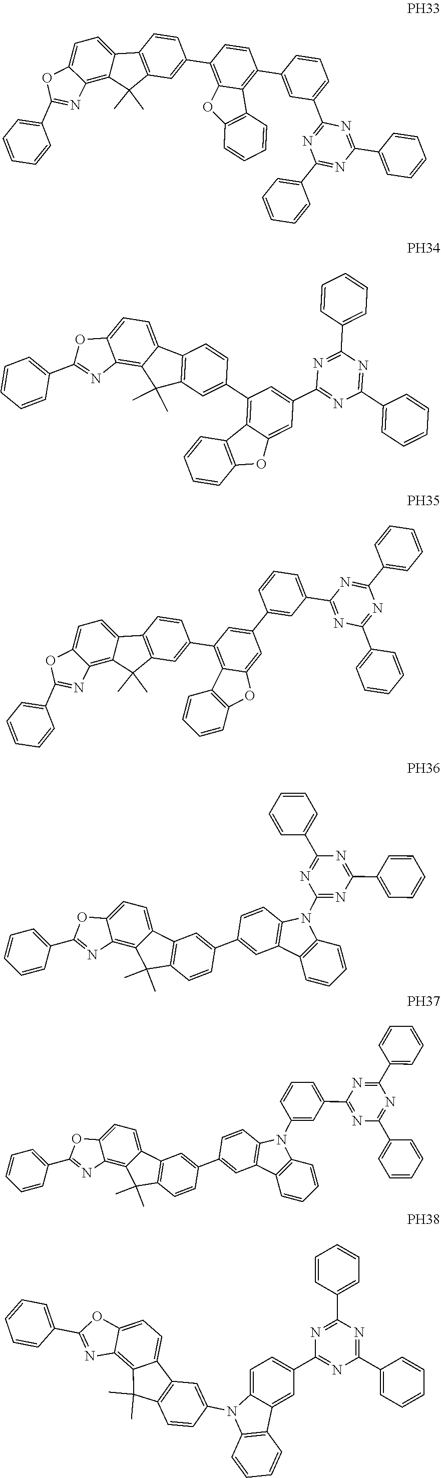

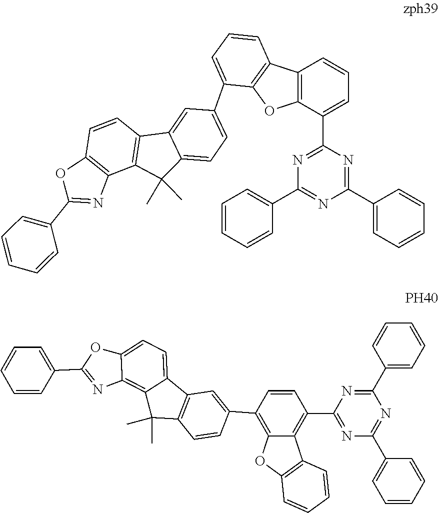 [SMILES: CC1(C)c2ccc(-c3cccc4c3oc3c(-c5nc(-c6ccccc6)nc(-c6ccccc6)n5)cccc34)cc2-c2ccc3oc(-c4ccccc4)nc3c21 ; CC1(C)c2ccc(-c3ccc(-c4nc(-c5ccccc5)nc(-c5ccccc5)n4)c4c3oc3ccccc34)cc2-c2ccc3oc(-c4ccccc4)nc3c21]

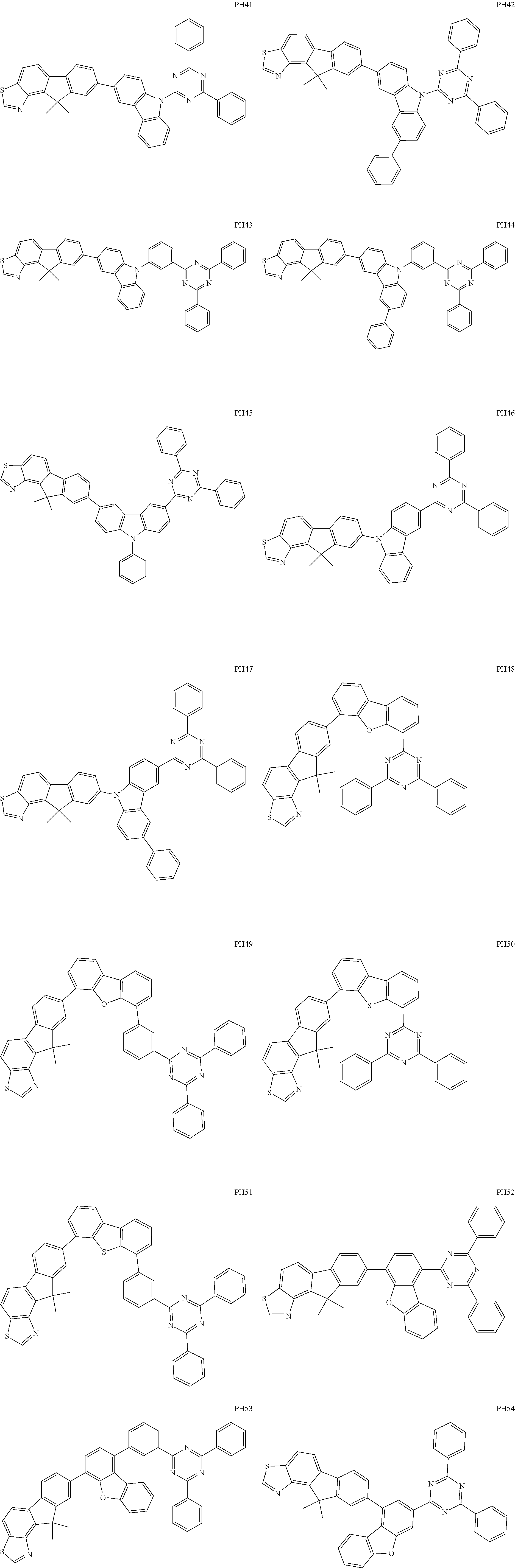

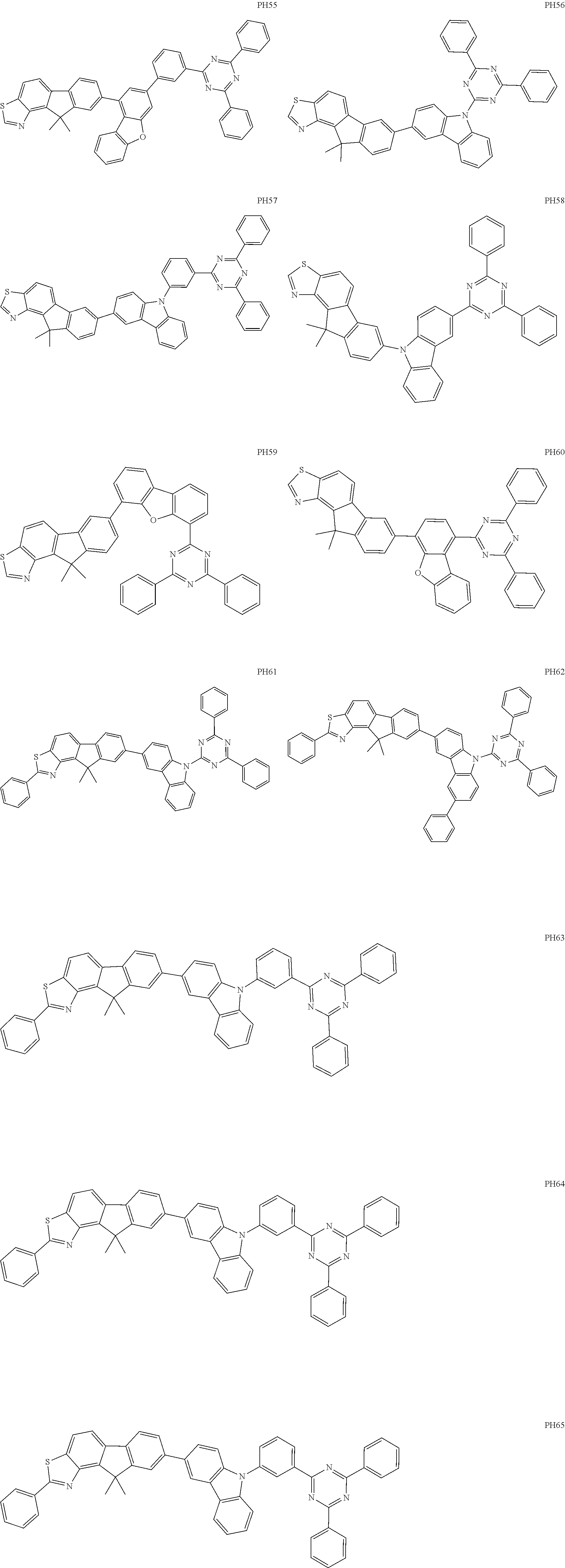

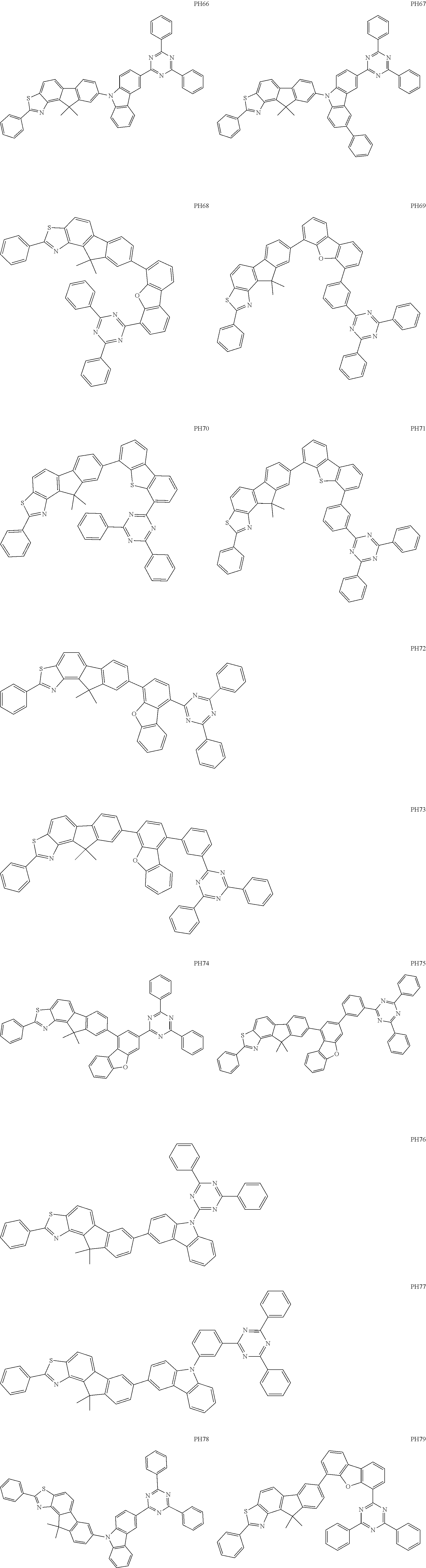

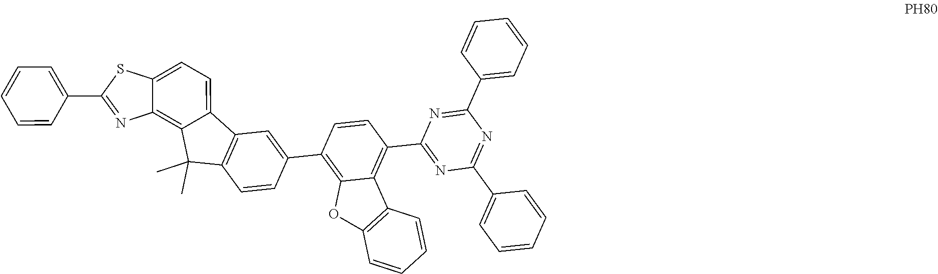 [SMILES: CC1(C)c2ccc(-c3ccc(-c4nc(-c5ccccc5)nc(-c5ccccc5)n4)c4c3oc3ccccc34)cc2-c2ccc3sc(-c4ccccc4)nc3c21]

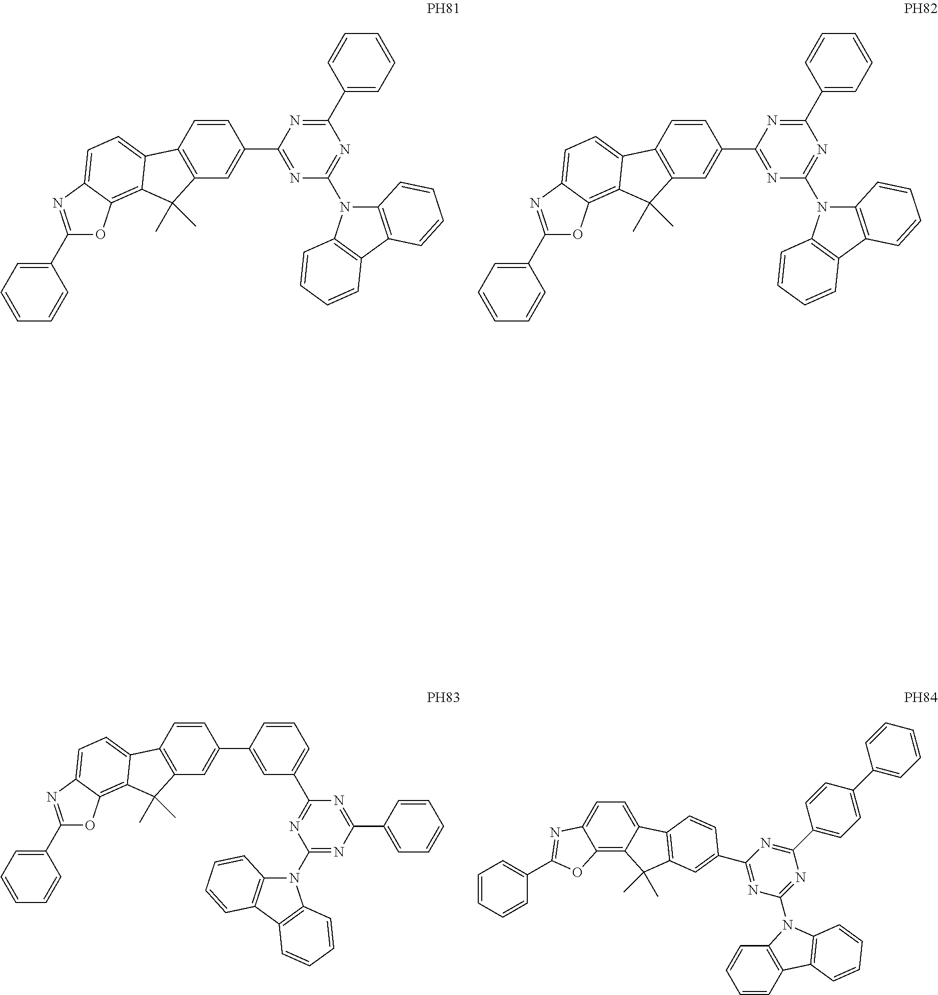 [SMILES: CC1(C)c2cc(-c3nc(-c4ccccc4)nc(-n4c5ccccc5c5ccccc54)n3)ccc2-c2ccc3nc(-c4ccccc4)oc3c21 ; CC1(C)c2cc(-c3nc(-c4ccccc4)nc(-n4c5ccccc5c5ccccc54)n3)ccc2-c2ccc3nc(-c4ccccc4)oc3c21 ; CC1(C)c2cc(-c3cccc(-c4nc(-c5ccccc5)nc(-n5c6ccccc6c6ccccc65)n4)c3)ccc2-c2ccc3nc(-c4ccccc4)oc3c21 ; CC1(C)c2cc(-c3nc(-c4ccc(-c5ccccc5)cc4)nc(-n4c5ccccc5c5ccccc54)n3)ccc2-c2ccc3nc(-c4ccccc4)oc3c21]

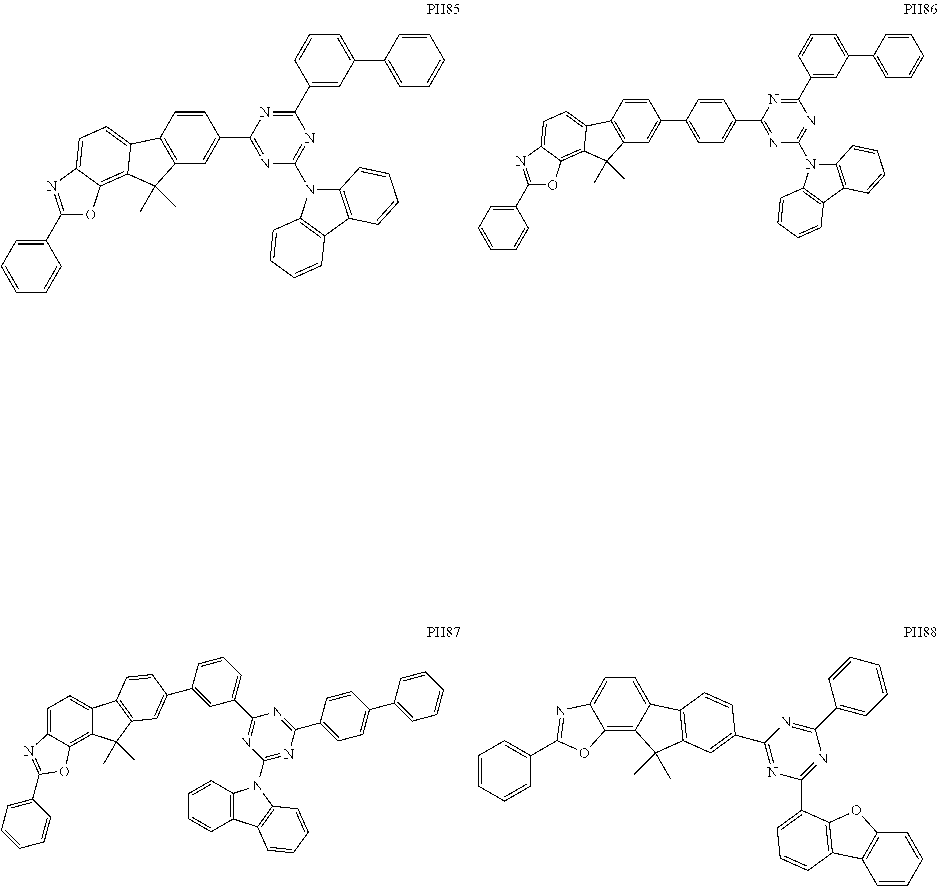 [SMILES: CC1(C)c2cc(-c3nc(-c4cccc(-c5ccccc5)c4)nc(-n4c5ccccc5c5ccccc54)n3)ccc2-c2ccc3nc(-c4ccccc4)oc3c21 ; CC1(C)c2cc(-c3ccc(-c4nc(-c5cccc(-c6ccccc6)c5)nc(-n5c6ccccc6c6ccccc65)n4)cc3)ccc2-c2ccc3nc(-c4ccccc4)oc3c21 ; CC1(C)c2cc(-c3cccc(-c4nc(-c5ccc(-c6ccccc6)cc5)nc(-n5c6ccccc6c6ccccc65)n4)c3)ccc2-c2ccc3nc(-c4ccccc4)oc3c21 ; CC1(C)c2cc(-c3nc(-c4ccccc4)nc(-c4cccc5c4oc4ccccc45)n3)ccc2-c2ccc3nc(-c4ccccc4)oc3c21]

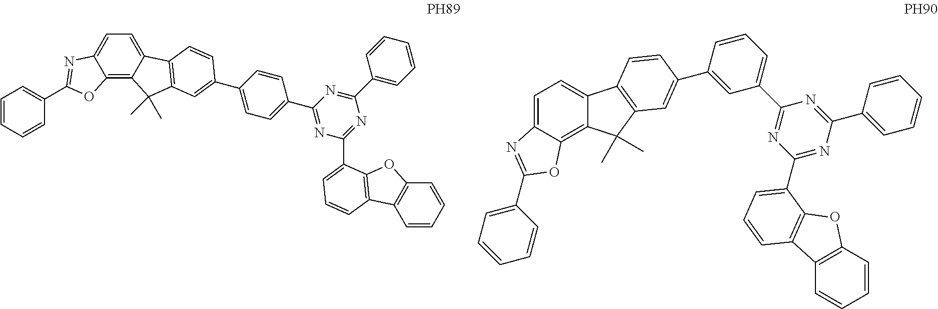 [SMILES: CC1(C)c2cc(-c3ccc(-c4nc(-c5ccccc5)nc(-c5cccc6c5oc5ccccc56)n4)cc3)ccc2-c2ccc3nc(-c4ccccc4)oc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)oc3c21]

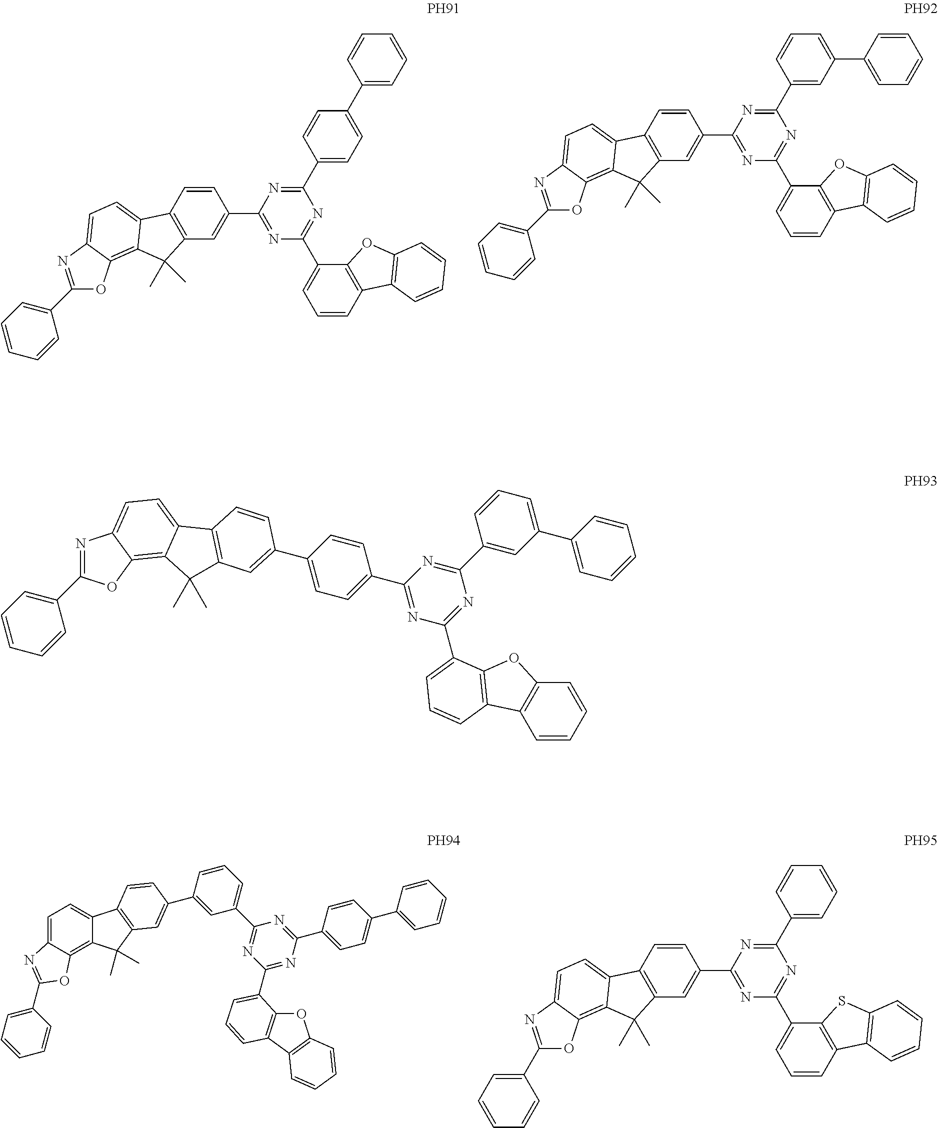

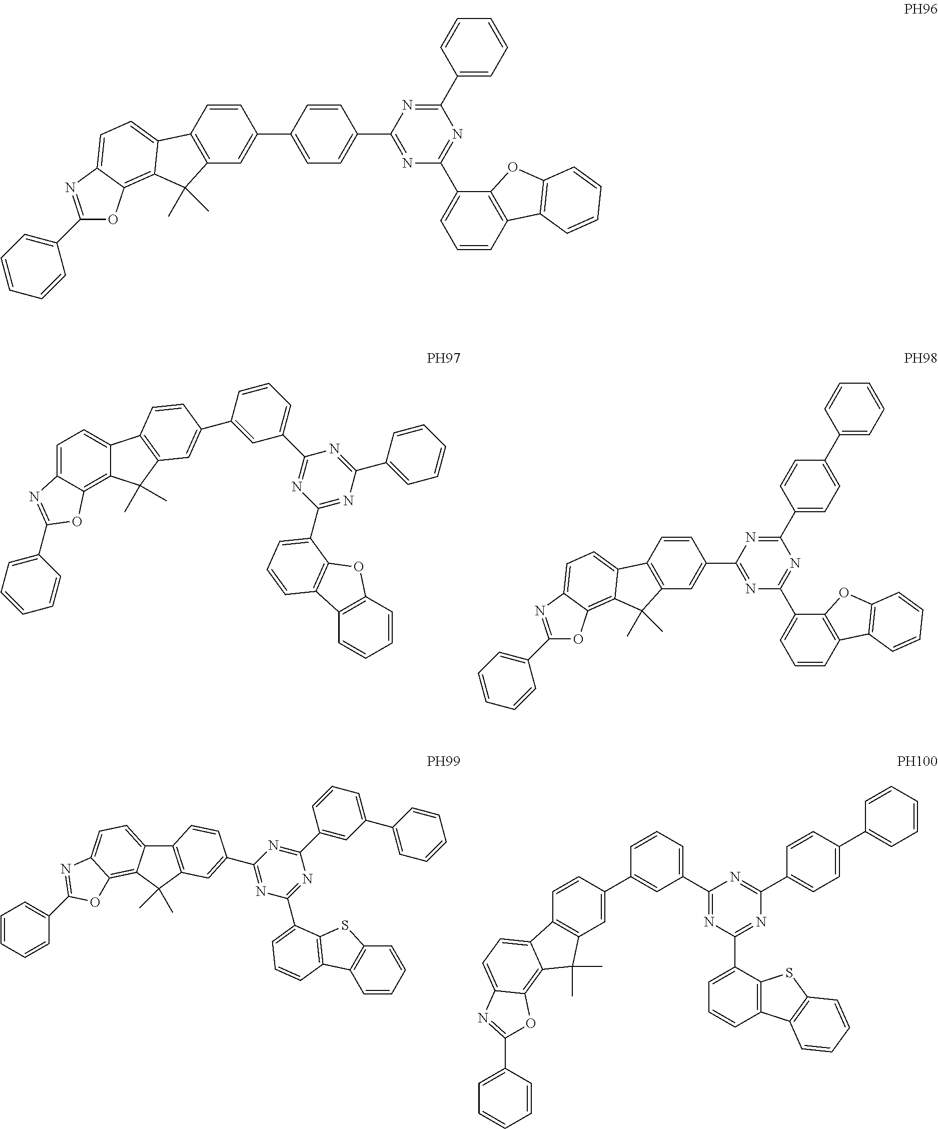 [SMILES: CC1(C)c2cc(-c3ccc(-c4nc(-c5ccccc5)nc(-c5cccc6c5oc5ccccc56)n4)cc3)ccc2-c2ccc3nc(-c4ccccc4)oc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)oc3c21 ; CC1(C)c2cc(-c3nc(-c4ccc(-c5ccccc5)cc4)nc(-c4cccc5c4oc4ccccc45)n3)ccc2-c2ccc3nc(-c4ccccc4)oc3c21 ; CC1(C)c2cc(-c3nc(-c4cccc(-c5ccccc5)c4)nc(-c4cccc5c4sc4ccccc45)n3)ccc2-c2ccc3nc(-c4ccccc4)oc3c21 ; CC1(C)c2cc(-c3cccc(-c4nc(-c5ccc(-c6ccccc6)cc5)nc(-c5cccc6c5sc5ccccc56)n4)c3)ccc2-c2ccc3nc(-c4ccccc4)oc3c21]

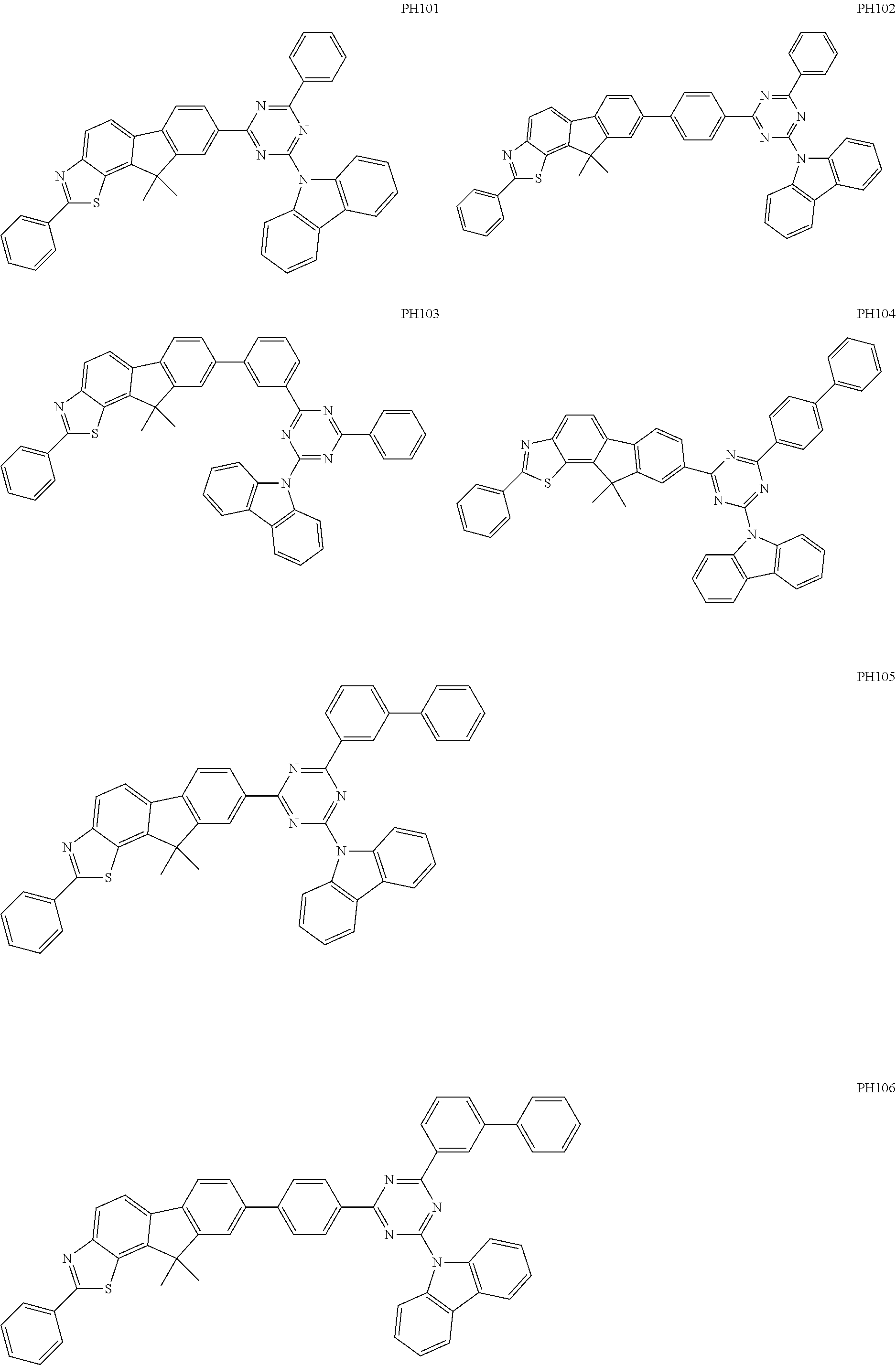

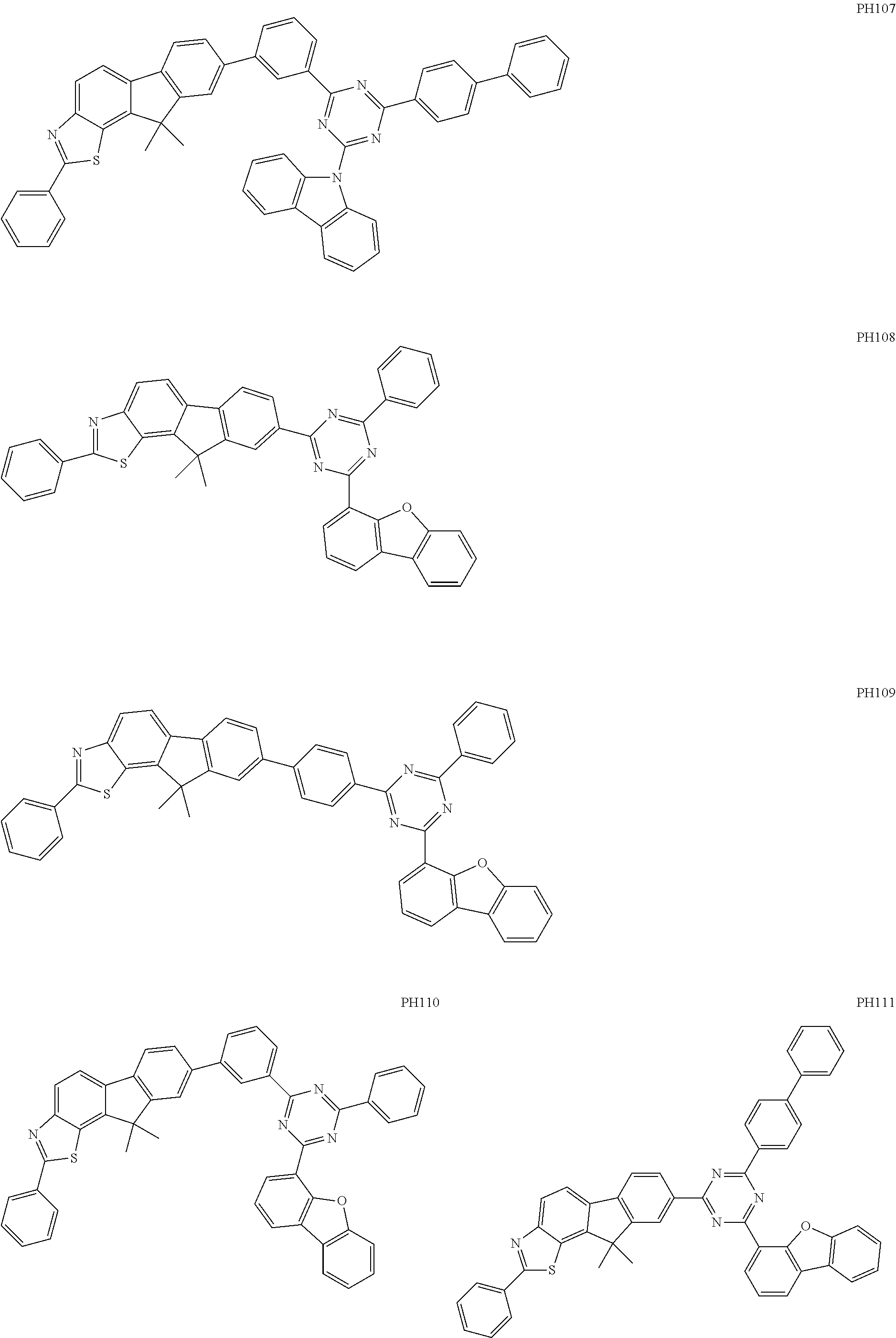 [SMILES: CC1(C)c2cc(-c3cccc(-c4nc(-c5ccc(-c6ccccc6)cc5)nc(-n5c6ccccc6c6ccccc65)n4)c3)ccc2-c2ccc3nc(-c4ccccc4)sc3c21 ; CC1(C)c2cc(-c3nc(-c4ccccc4)nc(-c4cccc5c4oc4ccccc45)n3)ccc2-c2ccc3nc(-c4ccccc4)sc3c21 ; CC1(C)c2cc(-c3ccc(-c4nc(-c5ccccc5)nc(-c5cccc6c5oc5ccccc56)n4)cc3)ccc2-c2ccc3nc(-c4ccccc4)sc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)sc3c21 ; CC1(C)c2cc(-c3nc(-c4ccc(-c5ccccc5)cc4)nc(-c4cccc5c4oc4ccccc45)n3)ccc2-c2ccc3nc(-c4ccccc4)sc3c21]

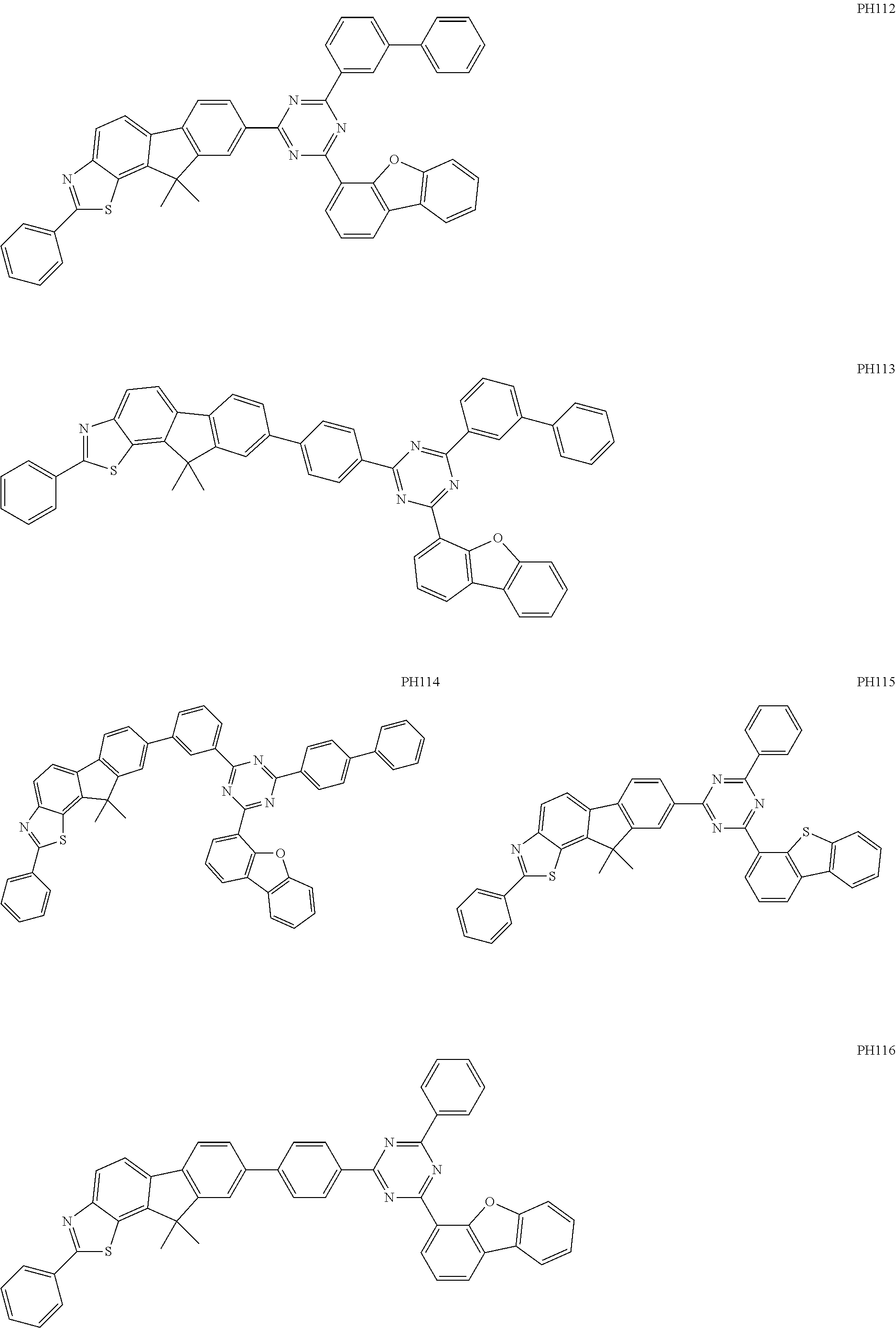 [SMILES: CC1(C)c2cc(-c3nc(-c4cccc(-c5ccccc5)c4)nc(-c4cccc5c4oc4ccccc45)n3)ccc2-c2ccc3nc(-c4ccccc4)sc3c21 ; CC1(C)c2cc(-c3ccc(-c4nc(-c5cccc(-c6ccccc6)c5)nc(-c5cccc6c5oc5ccccc56)n4)cc3)ccc2-c2ccc3nc(-c4ccccc4)sc3c21 ; CC1(C)c2cc(-c3cccc(-c4nc(-c5ccc(-c6ccccc6)cc5)nc(-c5cccc6c5oc5ccccc56)n4)c3)ccc2-c2ccc3nc(-c4ccccc4)sc3c21 ; CC1(C)c2cc(-c3nc(-c4ccccc4)nc(-c4cccc5c4sc4ccccc45)n3)ccc2-c2ccc3nc(-c4ccccc4)sc3c21 ; CC1(C)c2cc(-c3ccc(-c4nc(-c5ccccc5)nc(-c5cccc6c5oc5ccccc56)n4)cc3)ccc2-c2ccc3nc(-c4ccccc4)sc3c21]

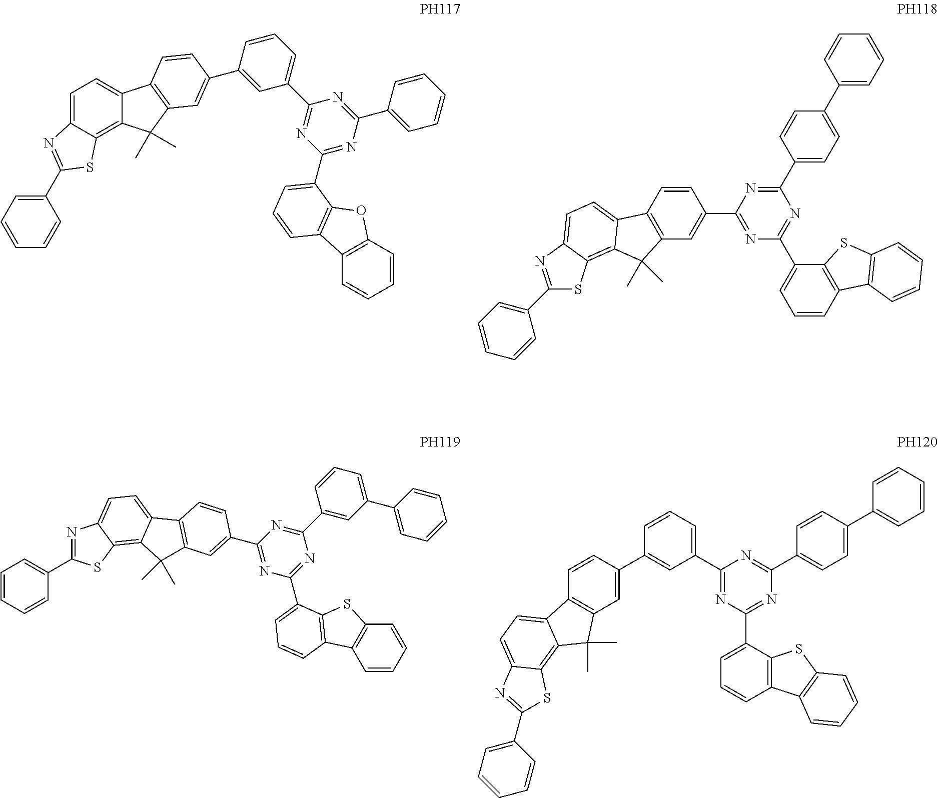 [SMILES: CC1(C)c2cc(-c3cccc(-c4nc(-c5ccccc5)nc(-c5cccc6c5oc5ccccc56)n4)c3)ccc2-c2ccc3nc(-c4ccccc4)sc3c21 ; CC1(C)c2cc(-c3nc(-c4ccc(-c5ccccc5)cc4)nc(-c4cccc5c4sc4ccccc45)n3)ccc2-c2ccc3nc(-c4ccccc4)sc3c21 ; CC1(C)c2cc(-c3nc(-c4cccc(-c5ccccc5)c4)nc(-c4cccc5c4sc4ccccc45)n3)ccc2-c2ccc3nc(-c4ccccc4)sc3c21 ; CC1(C)c2cc(-c3cccc(-c4nc(-c5ccc(-c6ccccc6)cc5)nc(-c5cccc6c5sc5ccccc56)n4)c3)ccc2-c2ccc3nc(-c4ccccc4)sc3c21]

One or more of the hydrogen atoms contained in the H1 to PH120 may be substituted with deuterium or tritium.

The above-described embodiments are merely examples, and it will be appreciated by one of ordinary skill in the art various changes may be made thereto without departing from the scope of the disclosure. Accordingly, the embodiments set forth herein are provided for illustrative purposes, but not to limit the scope of the disclosure, and should be appreciated that the scope of the disclosure is not limited by the embodiments. The scope of the disclosure should be construed by the following claims, and all technical spirits within equivalents thereof should be interpreted to belong to the scope of the disclosure.

An example of manufacturing an organic light emitting element according to embodiments of the disclosure are described below in detail with reference to embodiments thereof, but embodiments of the disclosure are not limited to the following embodiments.

### Example of Preparing the Compound

The compound represented by chemical formula 1 may be prepared by preparing the final compound according to the synthesis method described below.

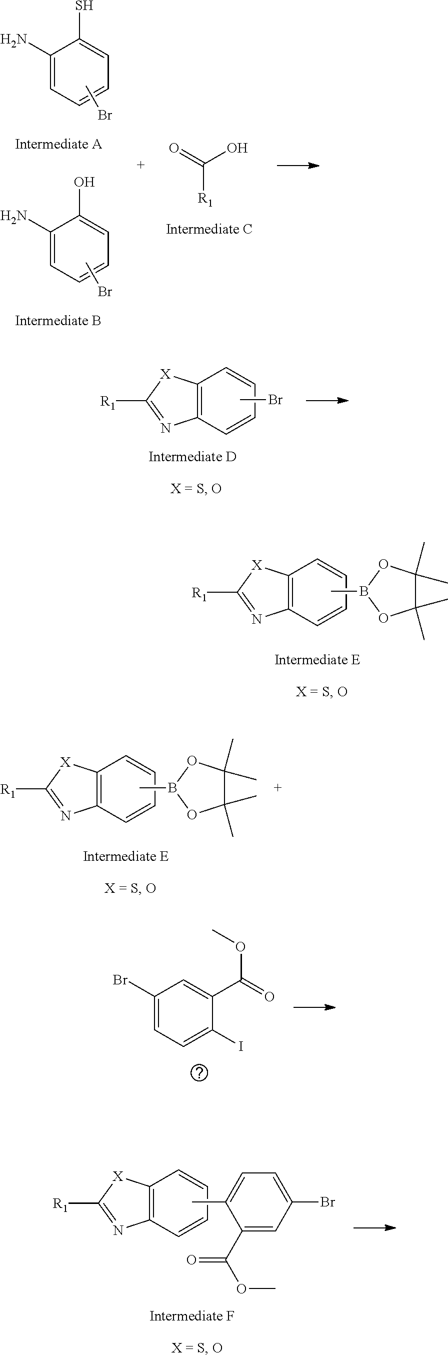

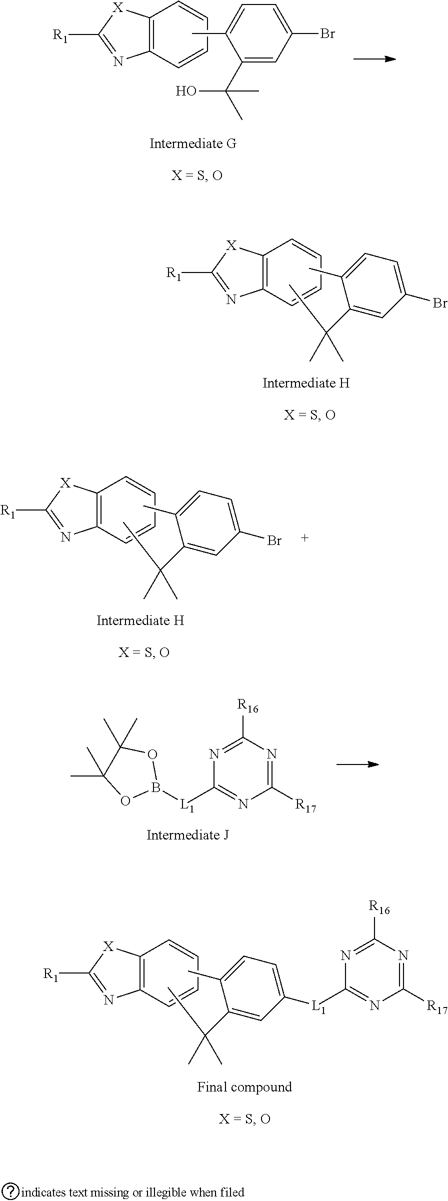

In the synthesis method, R₁, R₁₆ and R₁₇ are the same as those defined in the description in connection with chemical formula 1. L₁ is one of a direct bond, chemical formula L-1, chemical formula L-2, and chemical formula L-3.

### Synthesis of Intermediate D

An intermediate C (0.1 eq), an intermediate A (or an intermediate B, 2 eq), disopropylethylamine (2.5 eq), 4M K K₂CO₃ aqueous solution, and methylene chloride are put in a round-bottom flask and stirred while reducing the temperature to 0° C. Dioxo-fluor reagent, 50% in THF (2 eq) diluted with a small amount of MC is slowly added dropwise to the solution. After the dropwise addition is finished, the solution is stirred at 0° C. for 2 hours. After the reaction is finished by adding 100 ml of saturated aqueous sodium bicarbonate solution to the reaction solution, the solution is heated to room temperature. After the reaction solution is separated into layers to recover the organic layer, the organic layer was dried with MgSO₄ and concentrated under reduced pressure. The concentrated crude material was column-separated to obtain a compound in a yield of 68%.

### Synthesis of Intermediate E

An intermediate D (1eq), bis(pinacolato)diboron(1.5 eq), [1,1′-bis(diphenylphosphino)ferrocene]dichloropalladium(II) (0.02 eq), KOAc(potassium acetate, 2 eq), and 1,4-dioxane as a solvent, are put in a round-bottom flask, heated, and stirred under reflux for 12 hours. After completion of the reaction, the reaction solution was cooled to room temperature and then filtered using celite. The filtrate was concentrated under reduced pressure and then recrystallized using dichloromethane to obtain a compound in a yield of 80%.

### Synthesis of Intermediate F

Methyl-5-bromo-iodobenzoate (1eql), an intermediate E (1.1 eq), tetrakis(triphenylphosphine)palladium(0) (0.02 eq), and 4M K₂CO₃(potassium carbonate) were put in a round-bottom flask and added with toluene and EtOH as a solvent and were stirred under reflux for 12 hours. After completion of the reaction, the reaction solution is filtered to obtain crude. The filtered crude material was column-separated with methylene chloride/hexane to obtain a compound in a yield of 71%.

### Synthesis of Intermediate G

An intermediate F (1eq) and 150 ml of anhydrous THF are put in a round-bottom flask and stirred in a nitrogen atmosphere. Methylmagnesium bromide (2.4 eq) diluted with a small amount of anhydrous THF was slowly added dropwise to the solution that was then stirred for 6 hours. After completion of the reaction, 10% NH₄Cl aqueous solution was added to the reaction solution and stirred for 1 hour, was separated into layers by EA to recover an organic layer, followed by concentration under reduced pressure, obtaining a compound in a yield of 70%.

### Synthesis of Intermediate H

An intermediate G (1eql) and hydrochloric acid (1.5 eq) were put in a round-bottom flask, and acetic acid as a solvent was added, followed by heating under reflux and stirring for 2 hours. After completion of the reaction, if the reaction solution is poured into distilled water, crystals are precipitated, and the precipitate is filtered. The filtrate was dissolved in MC and dried through MgSO₄, and was then reprecipitated with MC and ethanol, obtaining a compound in a yield of 83%.

### Synthesis of Final Compound

An intermediate H(1eq), an intermediate J (1.2 eq), tetrakis(triphenylphosphine)palladium(0) (0.02 eq), and 4M K₂CO₃(potassium carbonate, 2 eq) were put in a round-bottom flask, and toluene and EtOH(ethanol) were added, and then stirred under reflux for 12 hours. After completion of the reaction, the reaction solution was filtered to obtain crude. The filtered crude material was column-separated to obtain a compound in a yield of 69%.

Manufacturing Evaluation of Organic Light Emitting Element

### Comparison Example 1

An anode, a hole injection layer, a hole transport layer, a light emitting layer, an electron transport layer, an electron injection layer, and a cathode were formed on a substrate to manufacture an organic light emitting element having a mono structure as shown in Table 1 below. All the properties of the organic light emitting element manufactured in the disclosure were evaluated at room temperature using a constant current source and a photometer.

TABLE 1

| Components | Materials |
|---|---|
| anode | ITO (Indium tin oxide) |
| hole injection layer | HI1 |
| hole transport layer | HT1 |
| light emitting layer | EM1, EM2, EM3 |
| electron transport layer | ET1 |
| electron injection layer | LiF |
| cathode | Al |

The compounds used in the comparative examples are as follows.

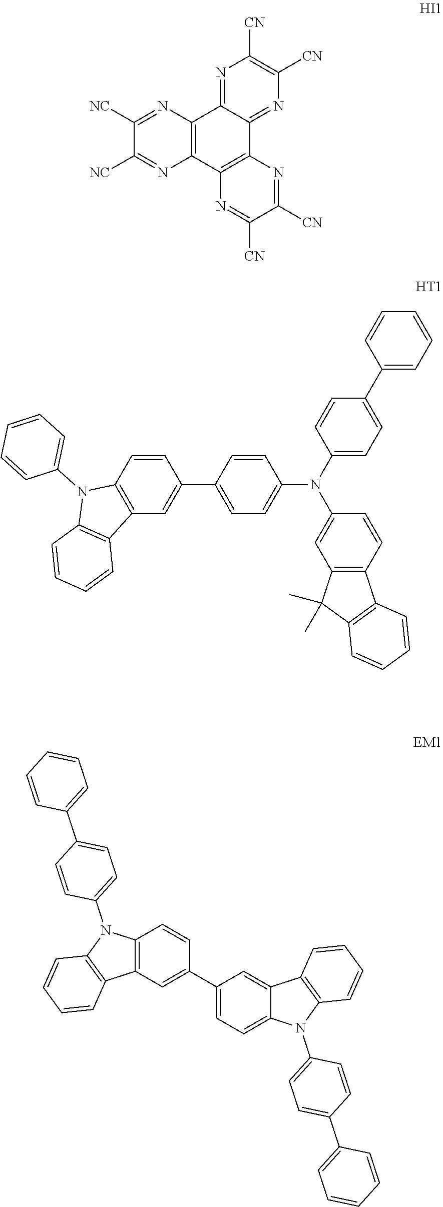 [SMILES: N#Cc1nc2c3nc(C#N)c(C#N)nc3c3nc(C#N)c(C#N)nc3c2nc1C#N ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-n3c4ccccc4c4cc(-c5ccc6c(c5)c5ccccc5n6-c5ccc(-c6ccccc6)cc5)ccc43)cc2)cc1]

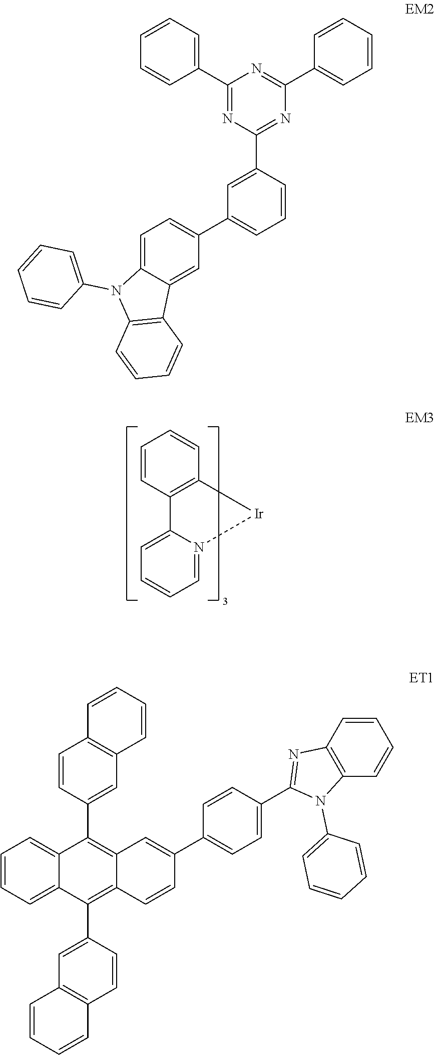

### Embodiments 1 to 54

The organic light emitting element was manufactured in the same manner as in comparative example 1 except that the materials shown in Table 2 below were used instead of EM2 of the light emitting layer.

TABLE 2

| | | | efficiency | lifespan |
|---|---|---|---|---|
| | light | | (embodiment/ | (embodiment/ |
| | emitting | | comparative | comparative |
| | layer | voltage | example | example |
| | material | difference | 1, %) | 1, %) |
| comparison | EM2 | — | — | — |
| example | | | | |
| 1 | | | | |
| embodiment | H1 | −0.15 | 108% | 108% |
| 1 | | | | |
| embodiment | H6 | −0.04 | 105% | 108% |
| 2 | | | | |
| embodiment | H9 | −0.20 | 107% | 105% |
| 3 | | | | |
| embodiment | H10 | −0.20 | 108% | 108% |
| 4 | | | | |
| embodiment | H11 | −0.23 | 111% | 103% |
| 5 | | | | |
| embodiment | H16 | −0.18 | 113% | 103% |
| 6 | | | | |
| embodiment | H18 | −0.10 | 107% | 104% |
| 7 | | | | |
| embodiment | H19 | −0.20 | 110% | 105% |
| 8 | | | | |
| embodiment | H21 | −0.18 | 103% | 106% |
| 9 | | | | |
| embodiment | H25 | −0.10 | 102% | 105% |
| 10 | | | | |
| embodiment | H27 | −0.02 | 102% | 108% |
| 11 | | | | |
| embodiment | H30 | −0.15 | 104% | 104% |
| 12 | | | | |
| embodiment | H36 | −0.20 | 108% | 102% |
| 13 | | | | |
| embodiment | H39 | −0.21 | 112% | 103% |
| 14 | | | | |
| embodiment | H41 | −0.18 | 108% | 102% |
| 15 | | | | |
| embodiment | H81 | −0.03 | 105% | 105% |
| 16 | | | | |
| embodiment | H86 | −0.08 | 109% | 106% |
| 17 | | | | |
| embodiment | H108 | −0.12 | 108% | 104% |
| 18 | | | | |
| embodiment | EH1 | −0.12 | 111% | 107% |
| 19 | | | | |
| embodiment | EH6 | 0.06 | 105% | 110% |
| 20 | | | | |
| embodiment | EH9 | −0.22 | 108% | 108% |
| 21 | | | | |
| embodiment | EH10 | −0.17 | 111% | 107% |
| 22 | | | | |
| embodiment | EH11 | −0.23 | 113% | 105% |
| 23 | | | | |
| embodiment | EH16 | −0.16 | 115% | 100% |
| 24 | | | | |
| embodiment | EH18 | −0.07 | 110% | 107% |
| 25 | | | | |
| embodiment | EH19 | −0.17 | 115% | 105% |
| 26 | | | | |
| embodiment | EH21 | −0.18 | 111% | 107% |
| 27 | | | | |
| embodiment | EH25 | −0.07 | 104% | 107% |
| 28 | | | | |
| embodiment | EH27 | 0.01 | 109% | 105% |
| 29 | | | | |
| embodiment | EH30 | −0.12 | 107% | 107% |
| 30 | | | | |
| embodiment | EH36 | −0.17 | 104% | 107% |
| 31 | | | | |
| embodiment | EH39 | −0.18 | 113% | 105% |
| 32 | | | | |
| embodiment | EH41 | −0.17 | 108% | 102% |
| 33 | | | | |
| embodiment | EH81 | −0.01 | 108% | 105% |
| 34 | | | | |
| embodiment | EH86 | −0.06 | 111% | 106% |
| 35 | | | | |
| embodiment | EH108 | −0.10 | 111% | 104% |
| 36 | | | | |
| embodiment | PH1 | −0.13 | 102% | 103% |
| 37 | | | | |
| embodiment | PH6 | 0.05 | 100% | 110% |
| 38 | | | | |
| embodiment | PH9 | −0.23 | 106% | 111% |
| 39 | | | | |
| embodiment | PH10 | −0.18 | 110% | 111% |
| 40 | | | | |
| embodiment | PH11 | −0.26 | 111% | 108% |
| 41 | | | | |
| embodiment | PH16 | −0.17 | 108% | 99% |
| 42 | | | | |
| embodiment | PH18 | −0.1 | 105% | 107% |
| 43 | | | | |
| embodiment | PH19 | −0.18 | 112% | 107% |
| 44 | | | | |
| embodiment | PH21 | −0.19 | 108% | 109% |
| 45 | | | | |
| embodiment | PH25 | −0.08 | 101% | 109% |
| 46 | | | | |
| embodiment | PH27 | −0.01 | 107% | 108% |
| 47 | | | | |
| embodiment | PH30 | −0.13 | 105% | 110% |
| 48 | | | | |
| embodiment | PH36 | −0.18 | 103% | 111% |
| 49 | | | | |
| embodiment | PH39 | −0.19 | 124% | 121% |
| 50 | | | | |
| embodiment | PH41 | −0.18 | 106% | 105% |
| 51 | | | | |
| embodiment | PH81 | −0.04 | 106% | 108% |
| 52 | | | | |
| embodiment | PH86 | −0.09 | 107% | 107% |
| 53 | | | | |
| embodiment | PH108 | −0.13 | 108% | 106% |
| 54 | | | | |

Referring to Table 2, it may be seen that the organic light emitting element according to embodiments of the disclosure has better efficiency or lifespan than the organic light emitting elements of the comparative examples.

In comparative example 1, EM2 was used as the light emitting layer host compound. It may be seen that the embodiments using compounds including a core represented by chemical formula 1 have better efficiency and lifespan than comparative example 1.

It will be apparent to those skilled in the art that various modifications and variations can be made in the organic light emitting element of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light emitting element, comprising:
a first electrode;
a second electrode; and
an organic material layer positioned between the first electrode and the second electrode, wherein the organic material layer includes a compound represented by chemical formula 1 below: 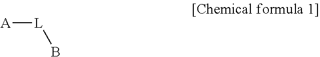
in chemical formula 1,
A is chemical formula a, B is chemical formula b,
L is one of a direct bond, chemical formula L-1, chemical formula L-2, and chemical formula L-3, 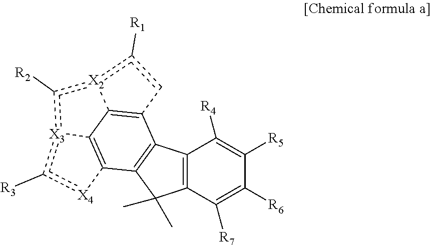
in chemical formula a,
X₁, X₂, X₃ and X₄ are selected from among N, S, O, and R₁₆, i) if X₁ is N, X₂ is selected from O and S and, along with X₁, forms a pentagonal ring, X₃ and X₄ are R₁₆ and ii) if X₂ is N, X₁ or X₃ is selected from O and S and, along with X₂, forms a pentagonal ring, X₁, X₃ and X₄ which do not form a pentagonal ring are R₁₆, iii) if X₃ is N, X₂ or X₄ is selected from O and S and, along with X₃, forms a pentagonal ring, X₁, X₂ and X₄ which do not form a pentagonal ring are R₁₆ and iv) if X₄ is N, X₃ is selected from O and S, and X₄ and, along with X₄, form a pentagonal ring, and X₁ and X₂ are R₁₆,
R₁, R₂ and R₃ are each independently selected from the group consisting of hydrogen; a C₁-C₂₀ alkyl group; a C₃-C₃₀ cycloalkyl group; an alkoxy group; an aryloxy group; an alkyl thioxy group; an arylthioxy group; an alkyl sulfoxy group; an arylsulfoxy group; a C₆-C₆₀ aryl group; a fluorenyl group; and a C₂-C₆₀ heterocyclic group containing at least one heteroatom of O, N, S, Si and P,
R₄, R₅, R₆, R₇ and R₁₆ are each independently hydrogen or C₆-C₆₀ aryl groups, and one of R₄, R₅, R₆ and R₇ is a direct bond with L, 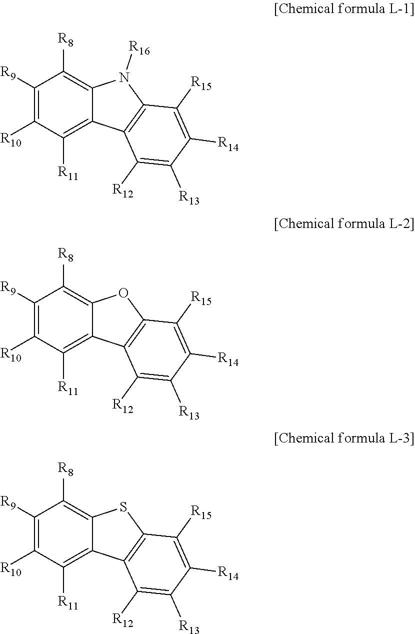
one of R₈ to R₁₆ in chemical formula L-1, R₈ to R₁₅ in chemical formula L-2 and R₈ to R₁₅ in chemical formula L-3 is a direct bond with A of chemical formula 1, and another one is a direct bond with B of chemical formula 1, and the rest which are not direct bonds with A or B are each independently selected from the group consisting of hydrogen; a cyano group; halogen; a C₁-C₂₀ alkyl group; a C₃-C₃₀ cycloalkyl group; an alkoxy group; an aryloxy group; an alkyl thioxy group; an arylthioxy group; an alkyl sulfoxy group; an arylsulfoxy group; a silyl group; an aryl phosphine group; a phosphine oxide group; a C₆-C₆₀ aryl group; and a C₂-C₆₀ heterocyclic group containing at least one heteroatom of O, N, S, Si and P, 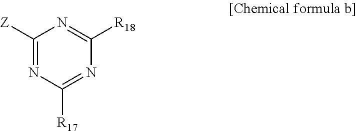
in chemical formula b,
Z is a direct bond with L of chemical formula 1, R₁₇ and R₁₈ are each independently selected from the group consisting of a C₆-C₆₀ aryl group; and a C₂-C₆₀ heterocyclic group containing at least one heteroatom of O, N, S, Si, and P, and the alkyl group, cycloalkyl group, alkoxy group, aryloxy group, alkylthioxy group, arylthioxy group, alkylsulfoxy group, arylsulfoxy group, fluorenyl group, aryl group, heterocyclic group, silyl group and arylphosphine group each are further substituted with one or more substituents selected from the group consisting of a halogen group; a C₁-C₂₀ alkyl group; a C₂-C₂₀ alkenyl group; a C₂-C₂₀ alkynyl group; a fluorenyl group; a C₆-C₂₀ aryl group; and a C₂-C₂₀ heterocyclic group.

2. The organic light emitting element of claim 1, wherein chemical formula a is represented by one of chemical formula a1, chemical formula a2, and chemical formula a3: 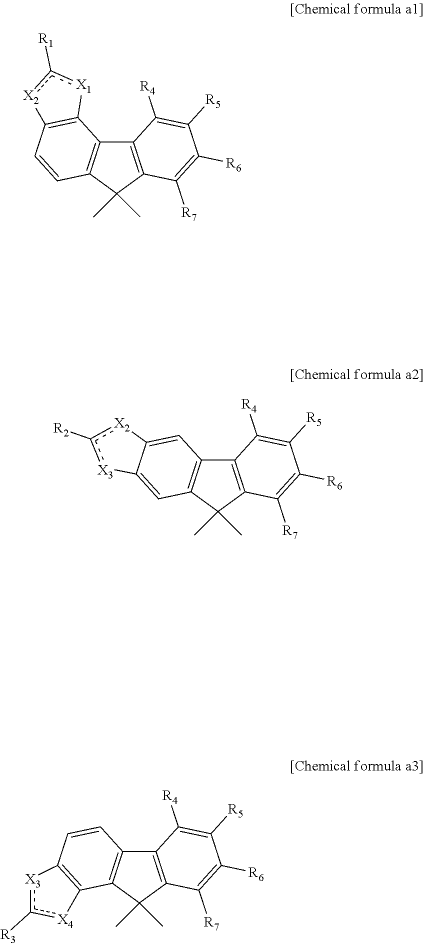
in chemical formula a1, X₁ and X₂ are N, S or O, if either one is N, the other is S or O, and R₁, R₄, R₅, R₆ and R₇ are the same as those defined in chemical formula 1,
in chemical formula 2, X₂ and X₃ are N, S or O, if either one is N, the other is S or O, and R₂, R₄, R₅, R₆ and R₇ are the same as those defined in chemical formula 1, and
in chemical formula 3, X₃ and X₄ are N, S or O, if either one is N, the other is S or O, and R₃, R₄, R₅, R₆ and R₇ are the same as those defined in chemical formula 1.

3. The organic light emitting element of claim 1, wherein the compound represented by chemical formula 1 is one or more of compounds below:

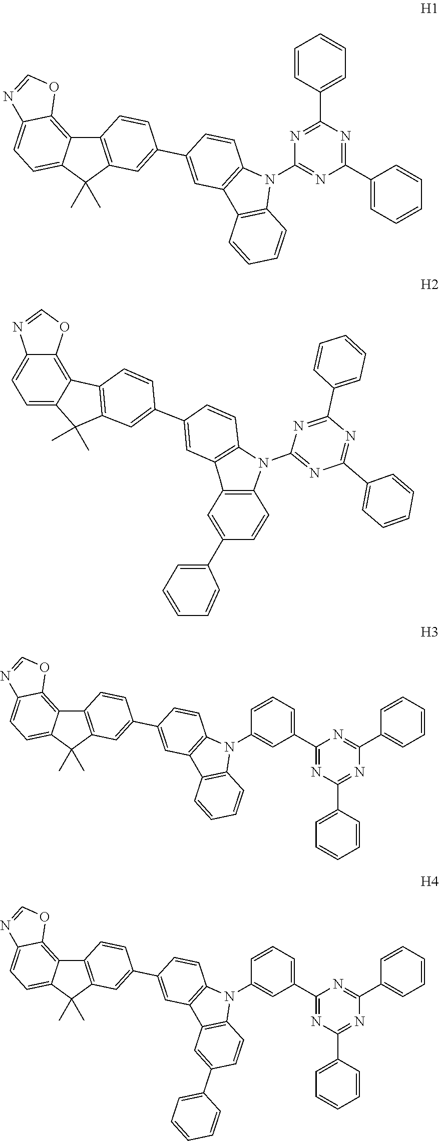

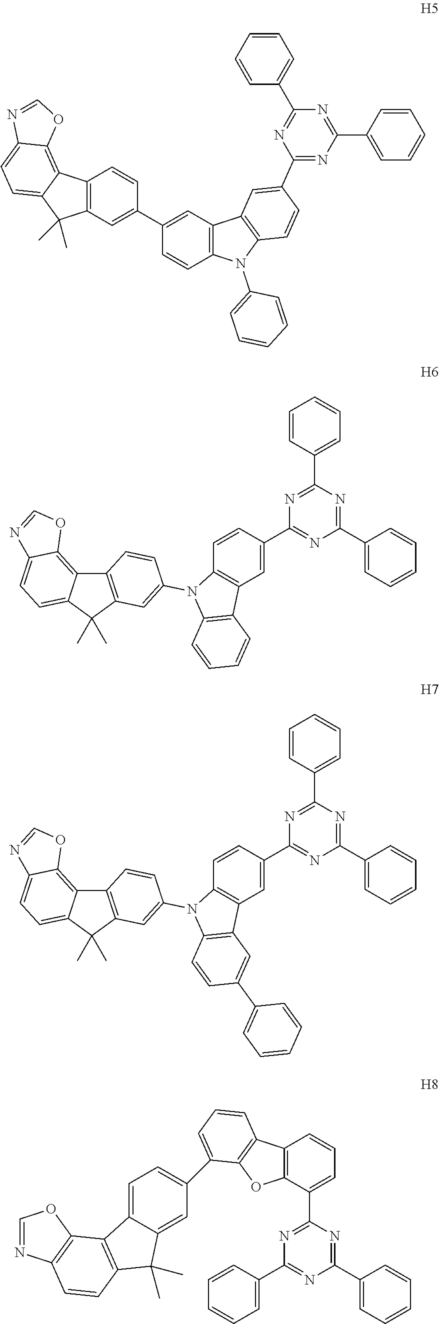 [SMILES: CC1(C)c2cc(-c3ccc4c(c3)c3cc(-c5nc(-c6ccccc6)nc(-c6ccccc6)n5)ccc3n4-c3ccccc3)ccc2-c2c1ccc1ncoc21 ; CC1(C)c2cc(-n3c4ccccc4c4cc(-c5nc(-c6ccccc6)nc(-c6ccccc6)n5)ccc43)ccc2-c2c1ccc1ncoc21 ; CC1(C)c2cc(-n3c4ccc(-c5ccccc5)cc4c4cc(-c5nc(-c6ccccc6)nc(-c6ccccc6)n5)ccc43)ccc2-c2c1ccc1ncoc21 ; CC1(C)c2cc(-c3cccc4c3oc3c(-c5nc(-c6ccccc6)nc(-c6ccccc6)n5)cccc34)ccc2-c2c1ccc1ncoc21]

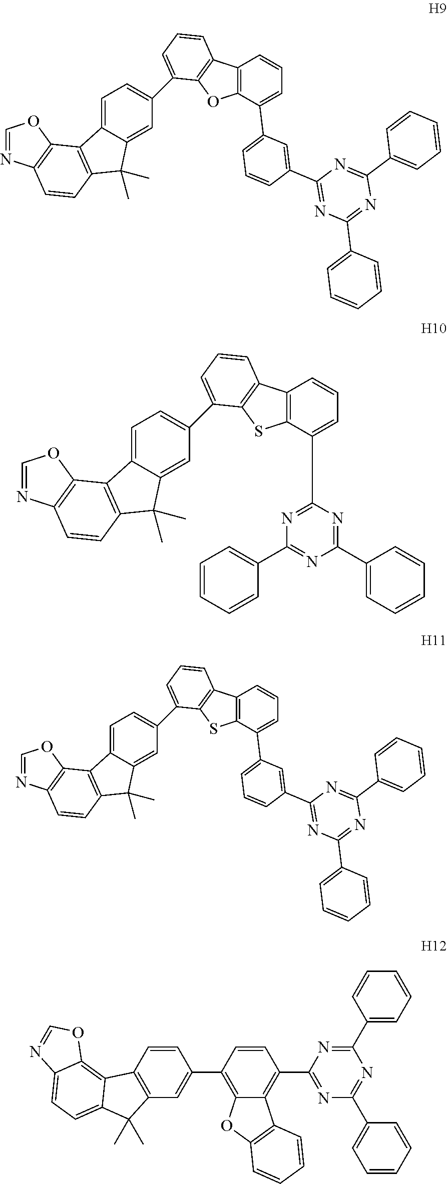 [SMILES: CC1(C)c2cc(-c3cccc4c3oc3c(-c5cccc(-c6nc(-c7ccccc7)nc(-c7ccccc7)n6)c5)cccc34)ccc2-c2c1ccc1ncoc21 ; CC1(C)c2cc(-c3cccc4c3sc3c(Cc5nc(-c6ccccc6)nc(-c6ccccc6)n5)cccc34)ccc2-c2c1ccc1ncoc21 ; CC1(C)c2cc(-c3cccc4c3sc3c(-c5cccc(-c6nc(-c7ccccc7)nc(-c7ccccc7)n6)c5)cccc34)ccc2-c2c1ccc1ncoc21 ; CC1(C)c2cc(-c3ccc(-c4nc(-c5ccccc5)nc(-c5ccccc5)n4)c4c3oc3ccccc34)ccc2-c2c1ccc1ncoc21]

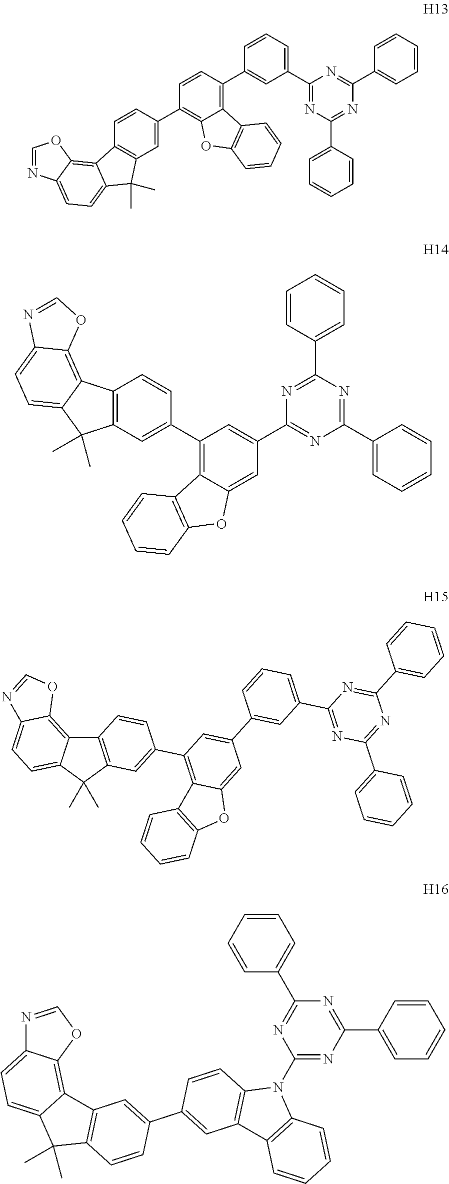 [SMILES: CC1(C)c2cc(-c3ccc(-c4cccc(-c5nc(-c6ccccc6)nc(-c6ccccc6)n5)c4)c4c3oc3ccccc34)ccc2-c2c1ccc1ncoc21 ; CC1(C)c2cc(-c3cc(-c4nc(-c5ccccc5)nc(-c5ccccc5)n4)cc4oc5ccccc5c34)ccc2-c2c1ccc1ncoc21 ; CC1(C)c2cc(-c3cc(-c4cccc(-c5nc(-c6ccccc6)nc(-c6ccccc6)n5)c4)cc4oc5ccccc5c34)ccc2-c2c1ccc1ncoc21 ; CC1(C)c2ccc(-c3ccc4c(c3)c3ccccc3n4-c3nc(-c4ccccc4)nc(-c4ccccc4)n3)cc2-c2c1ccc1ncoc21]

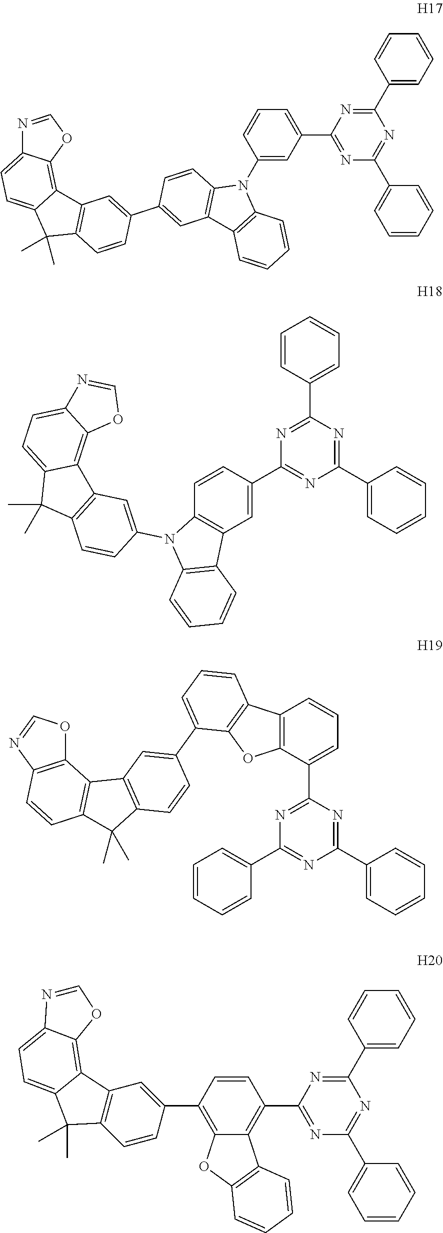

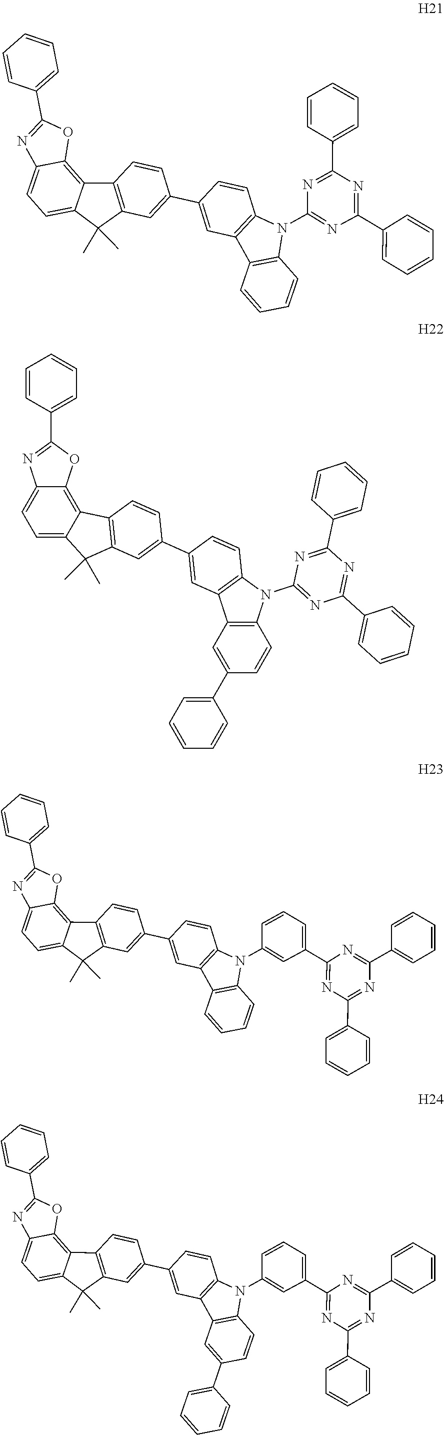 [SMILES: CC1(C)c2cc(-c3ccc4c(c3)c3ccccc3n4-c3nc(-c4ccccc4)nc(-c4ccccc4)n3)ccc2-c2c1ccc1nc(-c3ccccc3)oc21 ; CC1(C)c2cc(-c3ccc4c(c3)c3cc(-c5ccccc5)ccc3n4-c3nc(-c4ccccc4)nc(-c4ccccc4)n3)ccc2-c2c1ccc1nc(-c3ccccc3)oc21 ; CC1(C)c2cc(-c3ccc4c(c3)c3ccccc3n4-c3cccc(-c4nc(-c5ccccc5)nc(-c5ccccc5)n4)c3)ccc2-c2c1ccc1nc(-c3ccccc3)oc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2c1ccc1nc(-c3ccccc3)oc21]

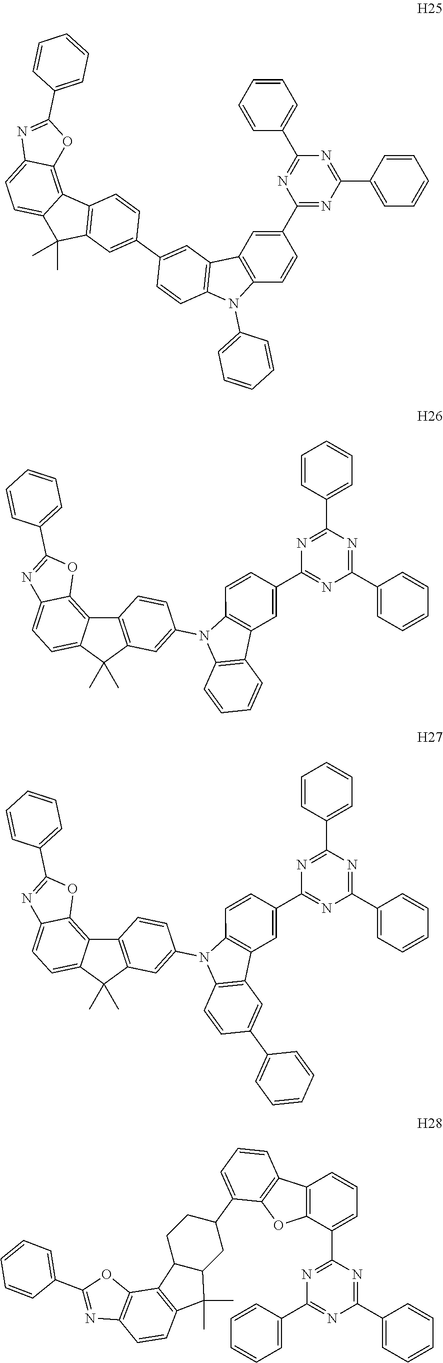 [SMILES: CC1(C)c2cc(-c3ccc4c(c3)c3cc(-c5nc(-c6ccccc6)nc(-c6ccccc6)n5)ccc3n4-c3ccccc3)ccc2-c2c1ccc1nc(-c3ccccc3)oc21 ; CC1(C)c2cc(-n3c4ccccc4c4cc(-c5nc(-c6ccccc6)nc(-c6ccccc6)n5)ccc43)ccc2-c2c1ccc1nc(-c3ccccc3)oc21 ; CC1(C)c2cc(-n3c4ccc(-c5ccccc5)cc4c4cc(-c5nc(-c6ccccc6)nc(-c6ccccc6)n5)ccc43)ccc2-c2c1ccc1nc(-c3ccccc3)oc21 ; CC1(C)c2ccc3nc(-c4ccccc4)oc3c2C2CCC(c3cccc4c3oc3c(-c5nc(-c6ccccc6)nc(-c6ccccc6)n5)cccc34)CC21]

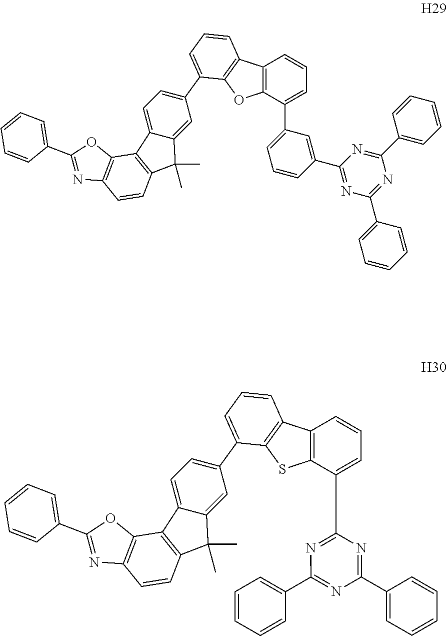 [SMILES: CC1(C)c2cc(-c3cccc4c3oc3c(-c5cccc(-c6nc(-c7ccccc7)nc(-c7ccccc7)n6)c5)cccc34)ccc2-c2c1ccc1nc(-c3ccccc3)oc21 ; CC1(C)c2cc(-c3cccc4c3sc3c(Cc5nc(-c6ccccc6)nc(-c6ccccc6)n5)cccc34)ccc2-c2c1ccc1nc(-c3ccccc3)oc21]

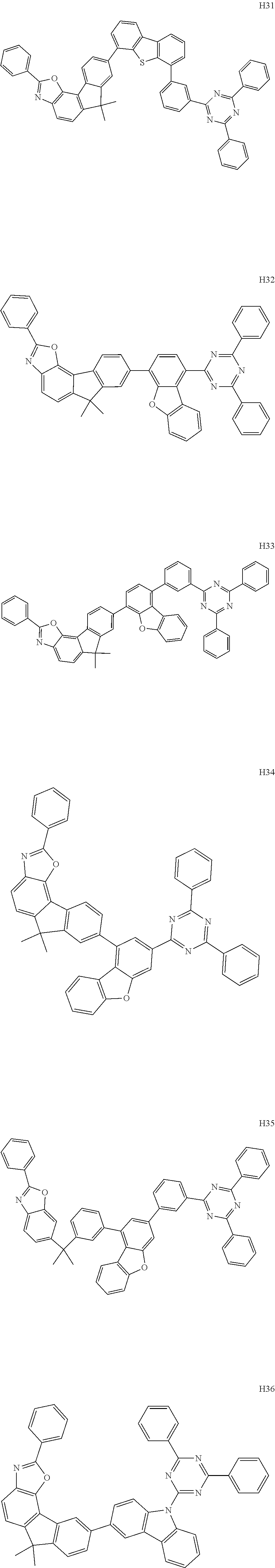

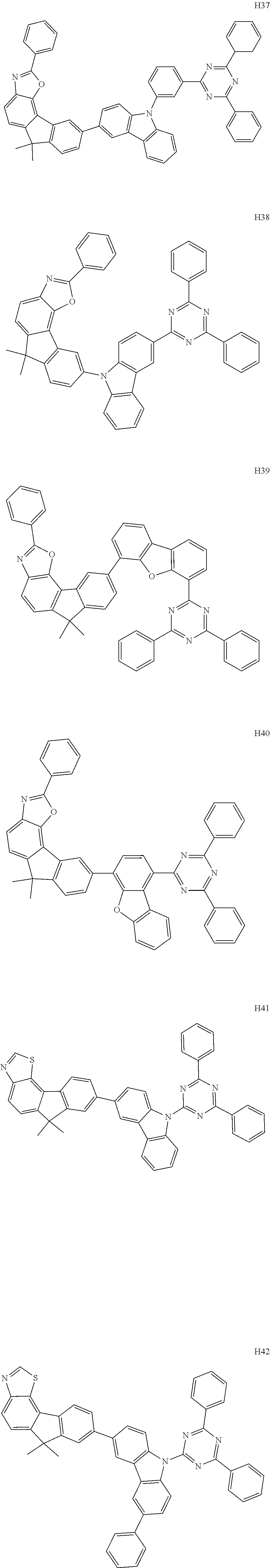

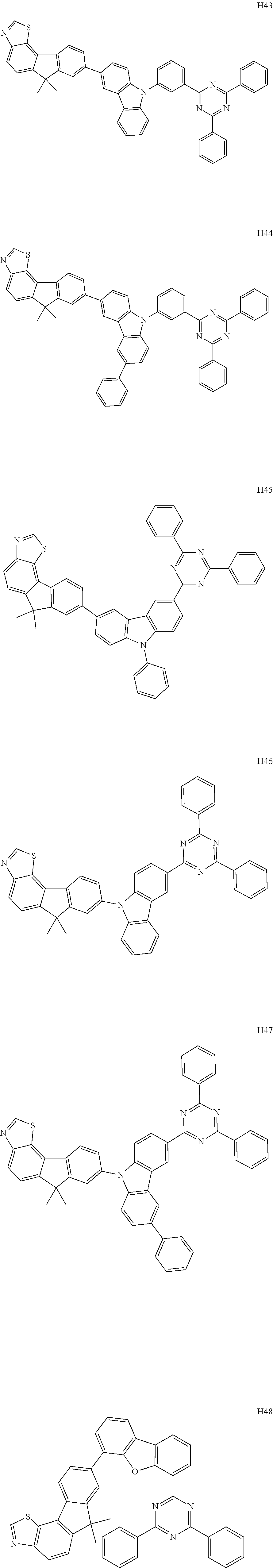

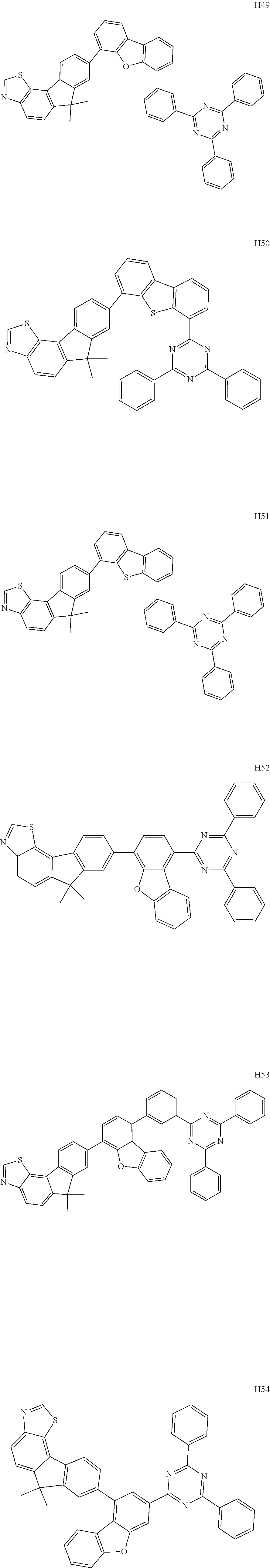

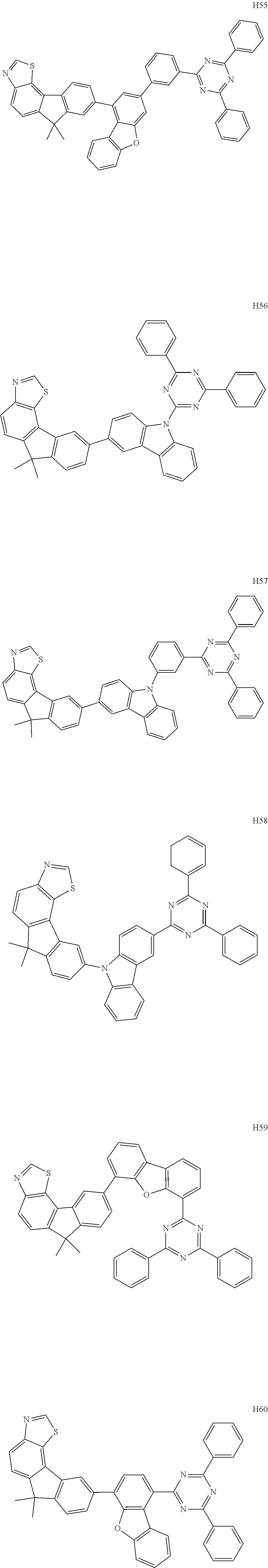

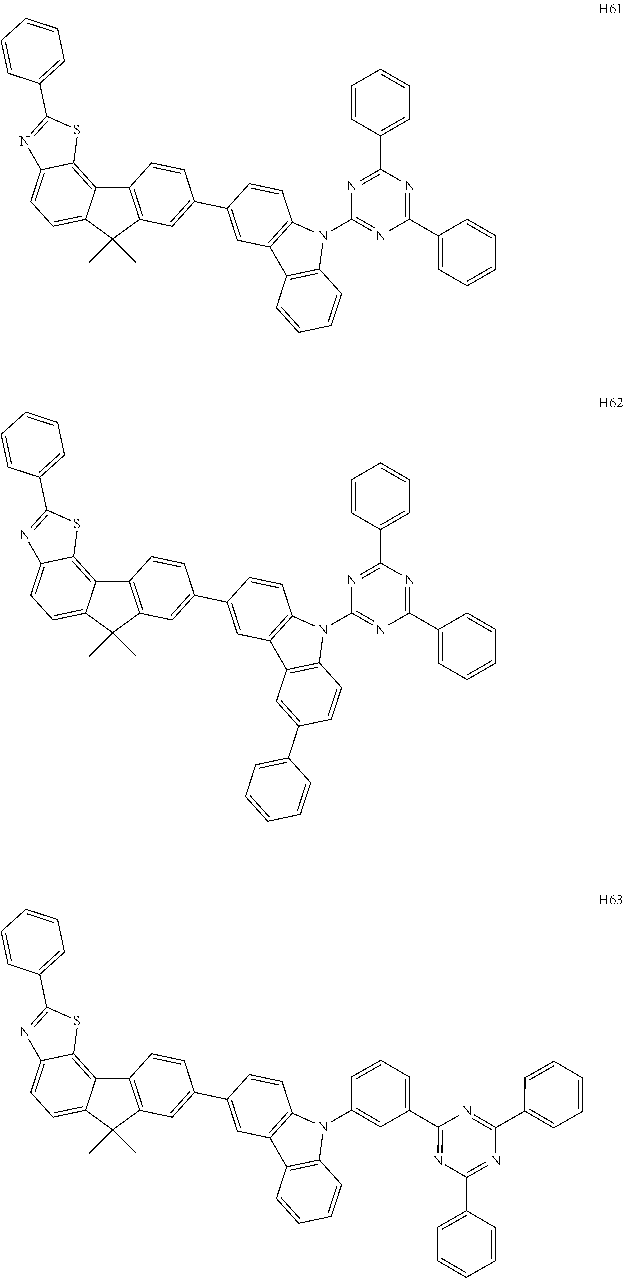 [SMILES: CC1(C)c2cc(-c3ccc4c(c3)c3ccccc3n4-c3nc(-c4ccccc4)nc(-c4ccccc4)n3)ccc2-c2c1ccc1nc(-c3ccccc3)sc21 ; CC1(C)c2cc(-c3ccc4c(c3)c3cc(-c5ccccc5)ccc3n4-c3nc(-c4ccccc4)nc(-c4ccccc4)n3)ccc2-c2c1ccc1nc(-c3ccccc3)sc21 ; CC1(C)c2cc(-c3ccc4c(c3)c3ccccc3n4-c3cccc(-c4nc(-c5ccccc5)nc(-c5ccccc5)n4)c3)ccc2-c2c1ccc1nc(-c3ccccc3)sc21]

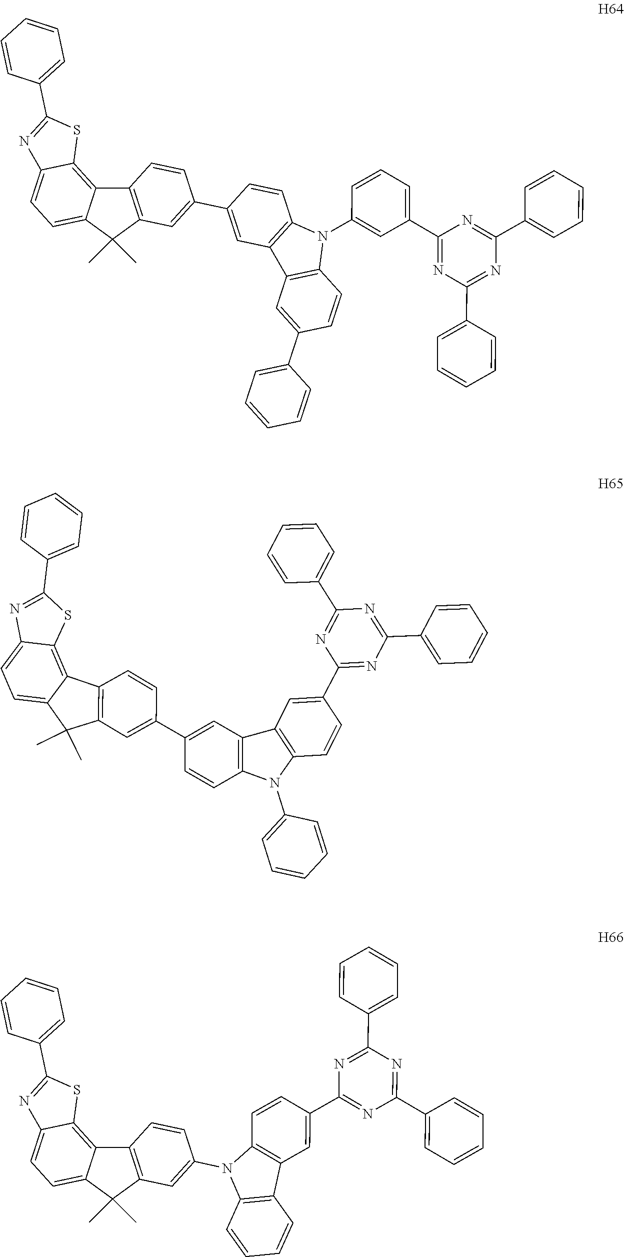 [SMILES: CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2c1ccc1nc(-c3ccccc3)sc21 ; CC1(C)c2cc(-c3ccc4c(c3)c3cc(-c5nc(-c6ccccc6)nc(-c6ccccc6)n5)ccc3n4-c3ccccc3)ccc2-c2c1ccc1nc(-c3ccccc3)sc21 ; CC1(C)c2cc(-n3c4ccccc4c4cc(-c5nc(-c6ccccc6)nc(-c6ccccc6)n5)ccc43)ccc2-c2c1ccc1nc(-c3ccccc3)sc21]

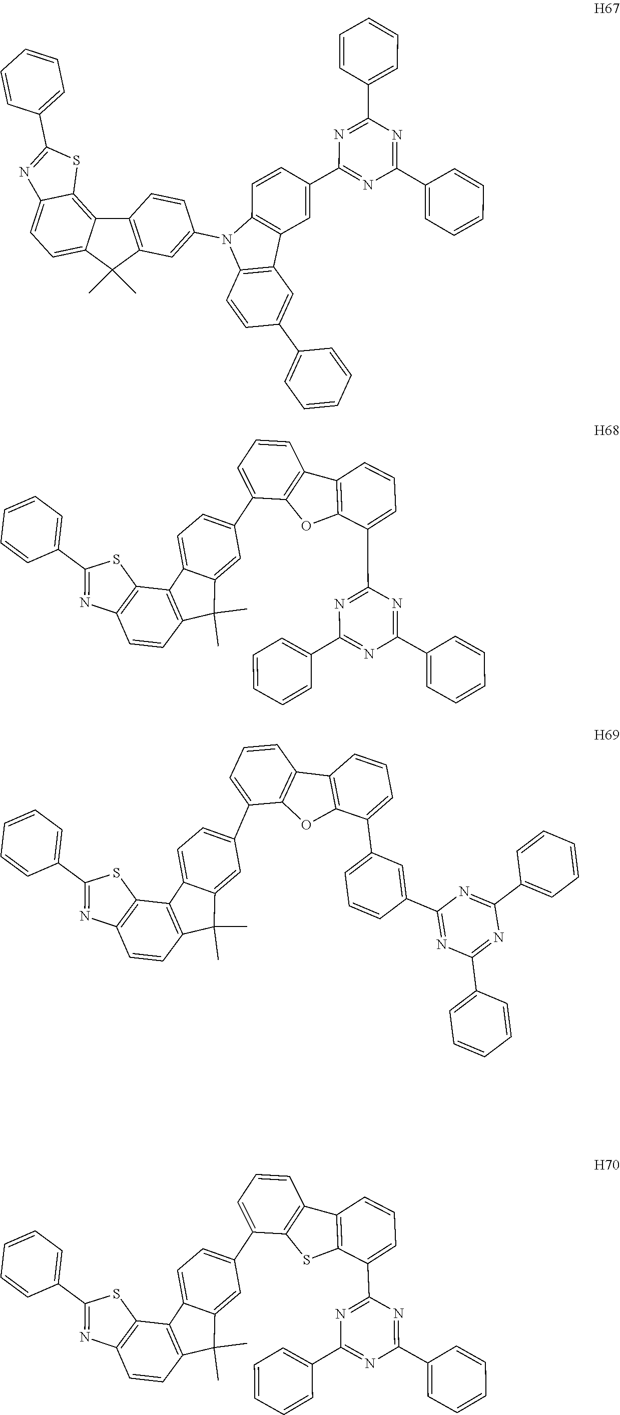

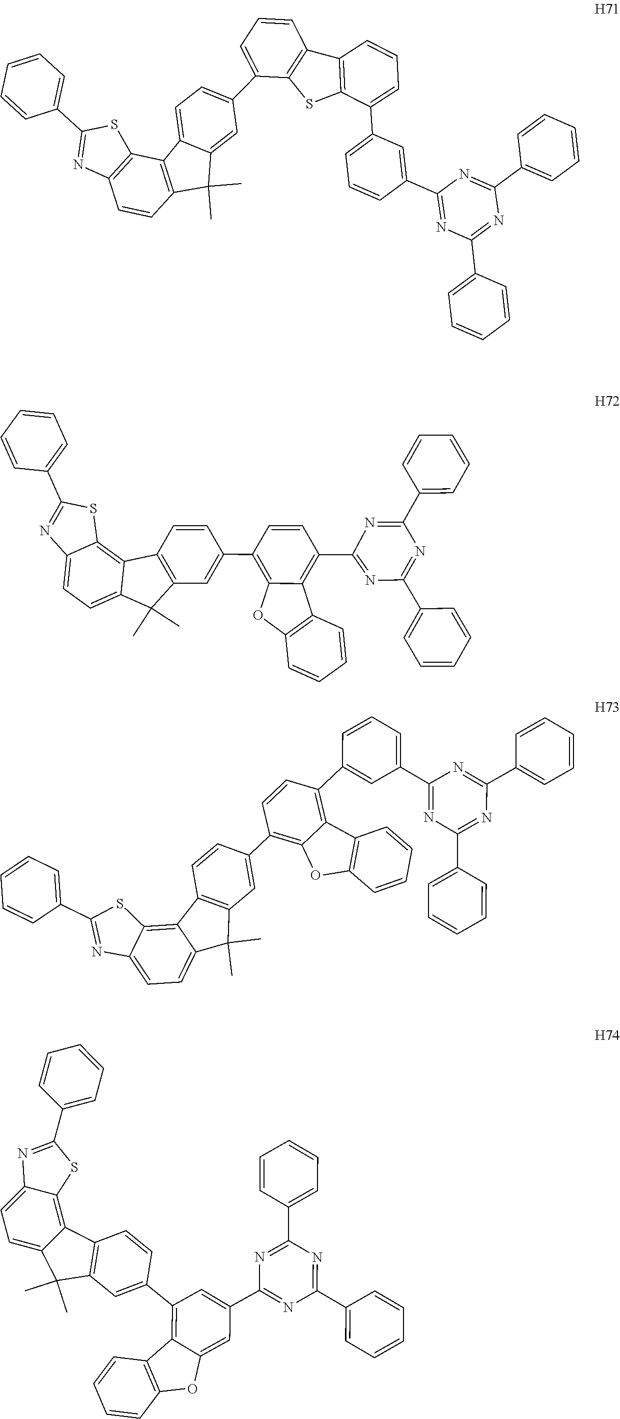 [SMILES: CC1(C)c2cc(-c3cccc4c3sc3c(-c5cccc(-c6nc(-c7ccccc7)nc(-c7ccccc7)n6)c5)cccc34)ccc2-c2c1ccc1nc(-c3ccccc3)sc21 ; CC1(C)c2cc(-c3ccc(-c4nc(-c5ccccc5)nc(-c5ccccc5)n4)c4c3oc3ccccc34)ccc2-c2c1ccc1nc(-c3ccccc3)sc21 ; CC1(C)c2cc(-c3ccc(-c4cccc(-c5nc(-c6ccccc6)nc(-c6ccccc6)n5)c4)c4c3oc3ccccc34)ccc2-c2c1ccc1nc(-c3ccccc3)sc21 ; CC1(C)c2cc(-c3cc(-c4nc(-c5ccccc5)nc(-c5ccccc5)n4)cc4oc5ccccc5c34)ccc2-c2c1ccc1nc(-c3ccccc3)sc21]

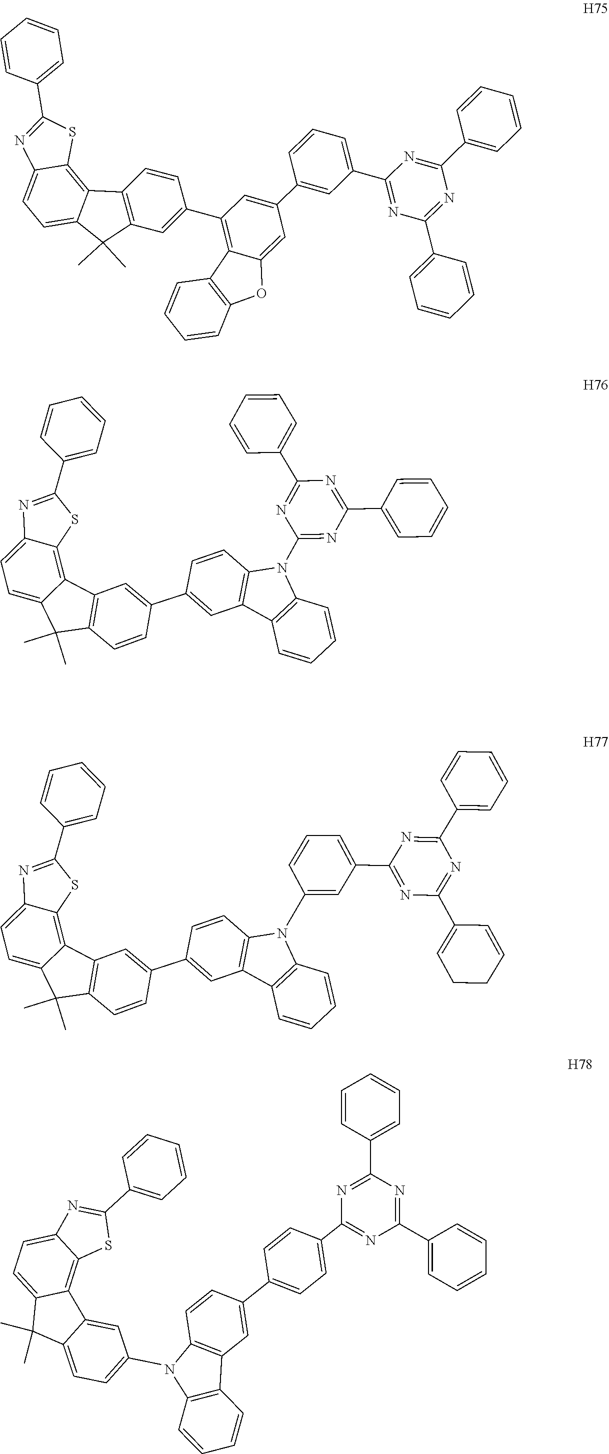

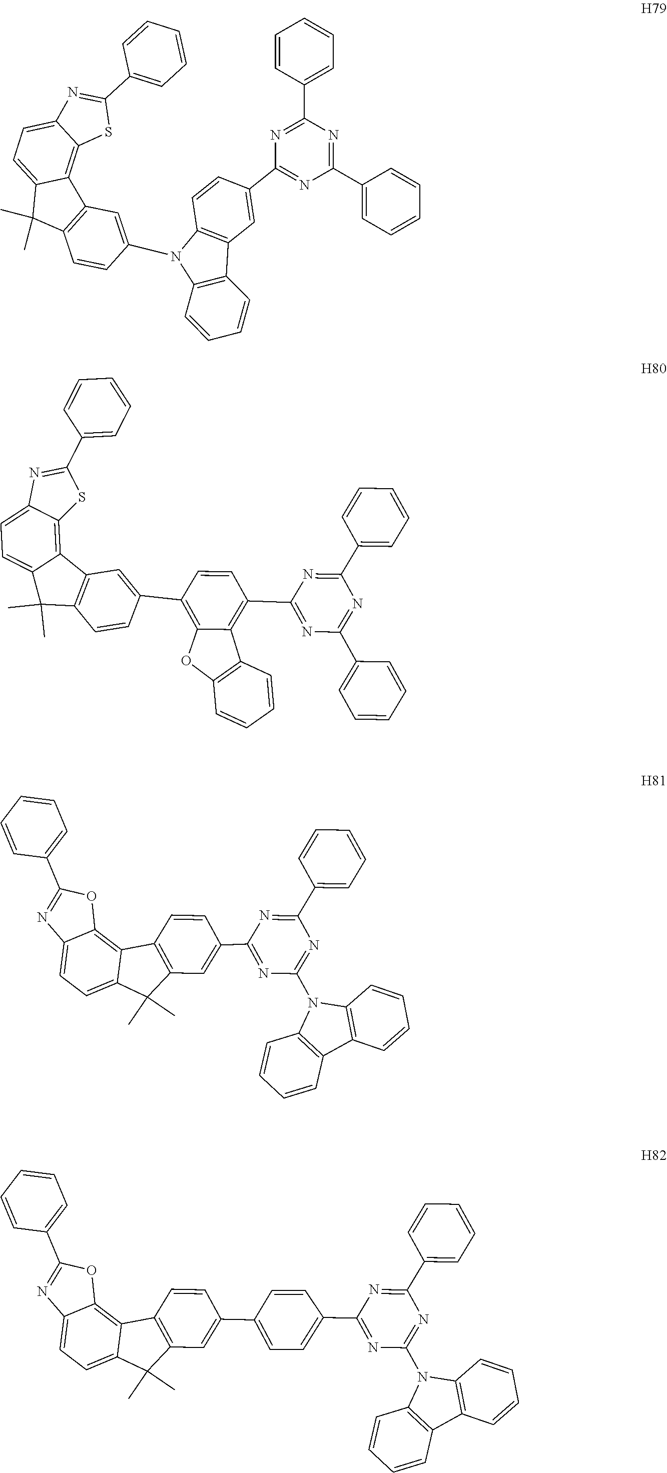 [SMILES: CC1(C)c2ccc(-n3c4ccccc4c4cc(-c5nc(-c6ccccc6)nc(-c6ccccc6)n5)ccc43)cc2-c2c1ccc1nc(-c3ccccc3)sc21 ; CC1(C)c2ccc(-c3ccc(-c4nc(-c5ccccc5)nc(-c5ccccc5)n4)c4c3oc3ccccc34)cc2-c2c1ccc1nc(-c3ccccc3)sc21 ; CC1(C)c2cc(-c3nc(-c4ccccc4)nc(-n4c5ccccc5c5ccccc54)n3)ccc2-c2c1ccc1nc(-c3ccccc3)oc21 ; CC1(C)c2cc(-c3ccc(-c4nc(-c5ccccc5)nc(-n5c6ccccc6c6ccccc65)n4)cc3)ccc2-c2c1ccc1nc(-c3ccccc3)oc21]

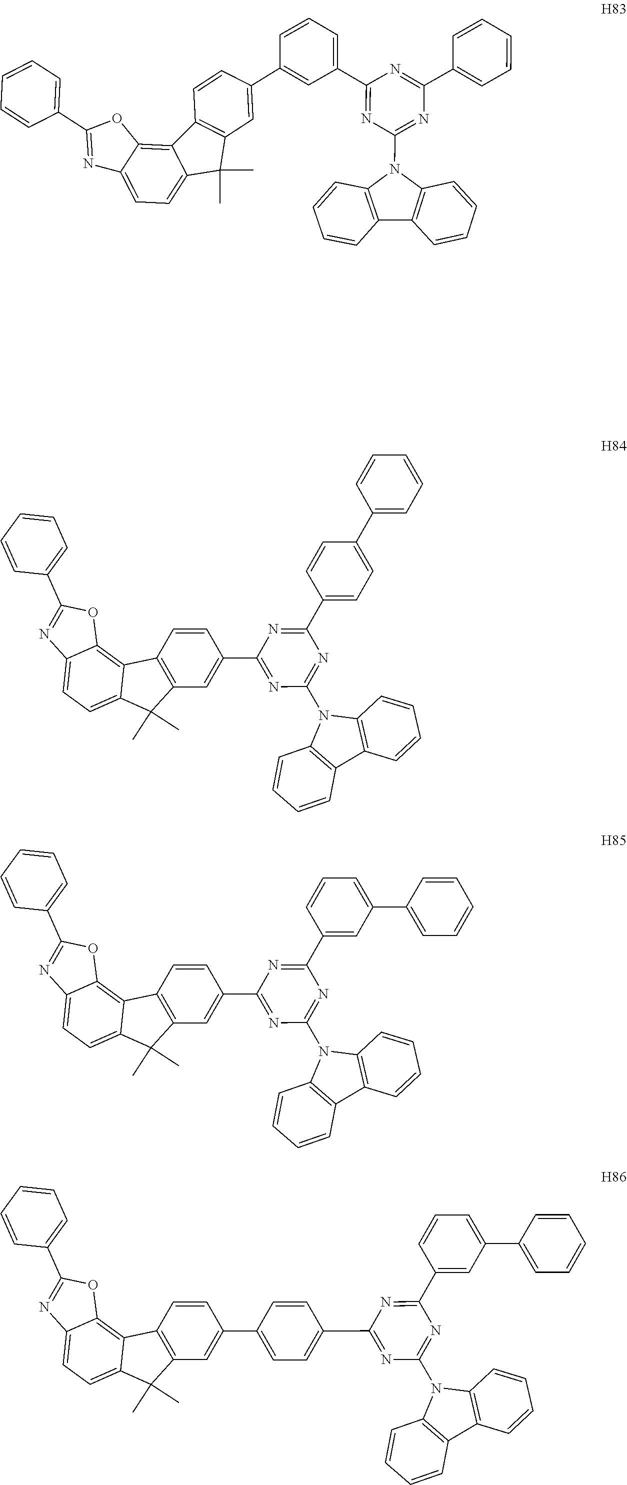 [SMILES: CC1(C)c2cc(-c3cccc(-c4nc(-c5ccccc5)nc(-n5c6ccccc6c6ccccc65)n4)c3)ccc2-c2c1ccc1nc(-c3ccccc3)oc21 ; CC1(C)c2cc(-c3nc(-c4ccc(-c5ccccc5)cc4)nc(-n4c5ccccc5c5ccccc54)n3)ccc2-c2c1ccc1nc(-c3ccccc3)oc21 ; CC1(C)c2cc(-c3nc(-c4cccc(-c5ccccc5)c4)nc(-n4c5ccccc5c5ccccc54)n3)ccc2-c2c1ccc1nc(-c3ccccc3)oc21 ; CC1(C)c2cc(-c3ccc(-c4nc(-c5cccc(-c6ccccc6)c5)nc(-n5c6ccccc6c6ccccc65)n4)cc3)ccc2-c2c1ccc1nc(-c3ccccc3)oc21]

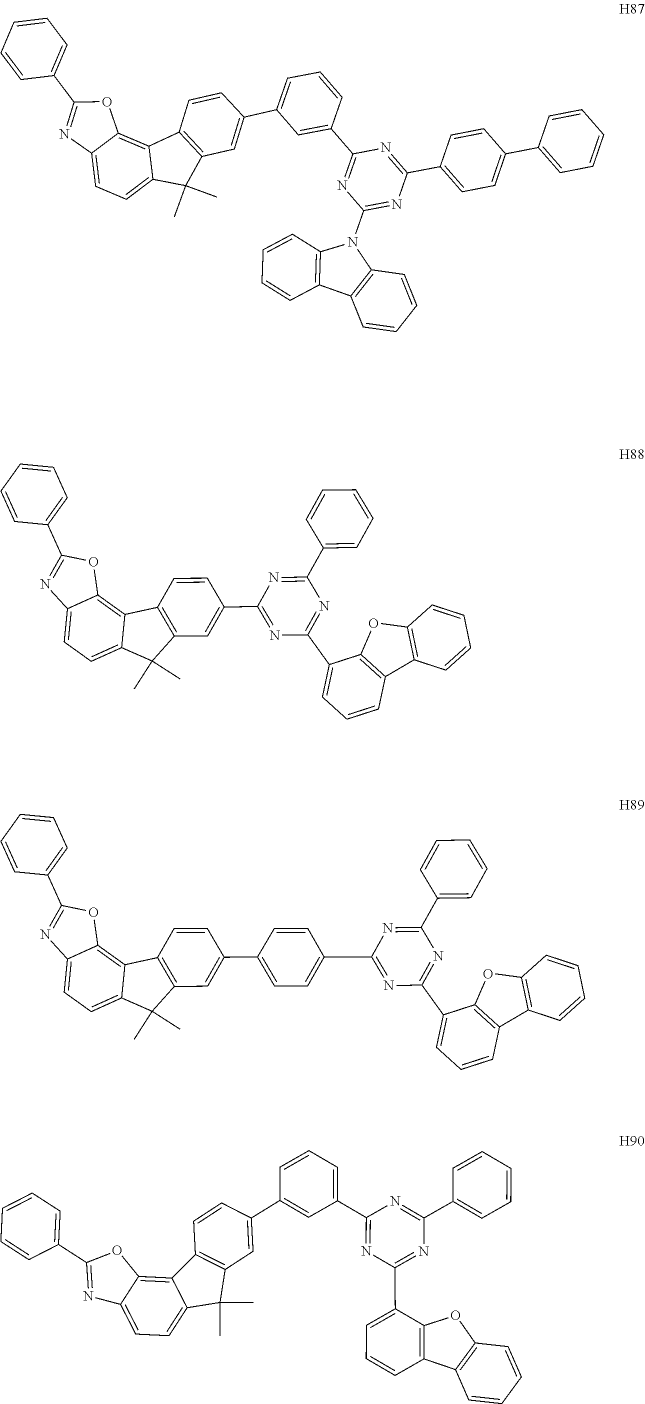 [SMILES: CC1(C)c2cc(-c3cccc(-c4nc(-c5ccc(-c6ccccc6)cc5)nc(-n5c6ccccc6c6ccccc65)n4)c3)ccc2-c2c1ccc1nc(-c3ccccc3)oc21 ; CC1(C)c2cc(-c3nc(-c4ccccc4)nc(-c4cccc5c4oc4ccccc45)n3)ccc2-c2c1ccc1nc(-c3ccccc3)oc21 ; CC1(C)c2cc(-c3ccc(-c4nc(-c5ccccc5)nc(-c5cccc6c5oc5ccccc56)n4)cc3)ccc2-c2c1ccc1nc(-c3ccccc3)oc21 ; CC1(C)c2cc(-c3cccc(-c4nc(-c5ccccc5)nc(-c5cccc6c5oc5ccccc56)n4)c3)ccc2-c2c1ccc1nc(-c3ccccc3)oc21]

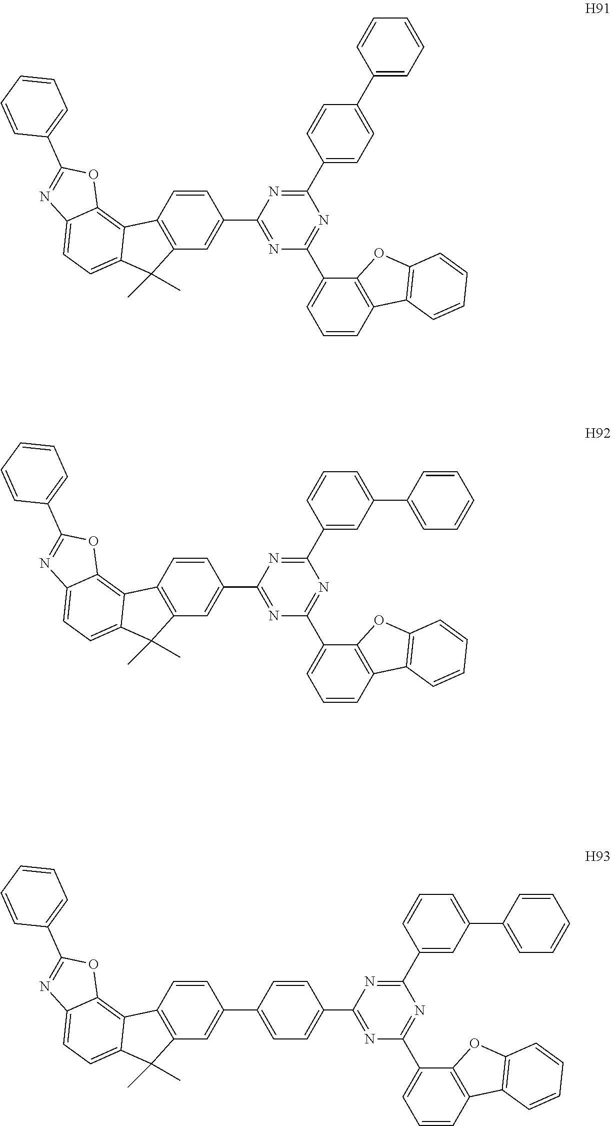 [SMILES: CC1(C)c2cc(-c3nc(-c4ccc(-c5ccccc5)cc4)nc(-c4cccc5c4oc4ccccc45)n3)ccc2-c2c1ccc1nc(-c3ccccc3)oc21 ; CC1(C)c2cc(-c3nc(-c4cccc(-c5ccccc5)c4)nc(-c4cccc5c4oc4ccccc45)n3)ccc2-c2c1ccc1nc(-c3ccccc3)oc21 ; CC1(C)c2cc(-c3ccc(-c4nc(-c5cccc(-c6ccccc6)c5)nc(-c5cccc6c5oc5ccccc56)n4)cc3)ccc2-c2c1ccc1nc(-c3ccccc3)oc21]

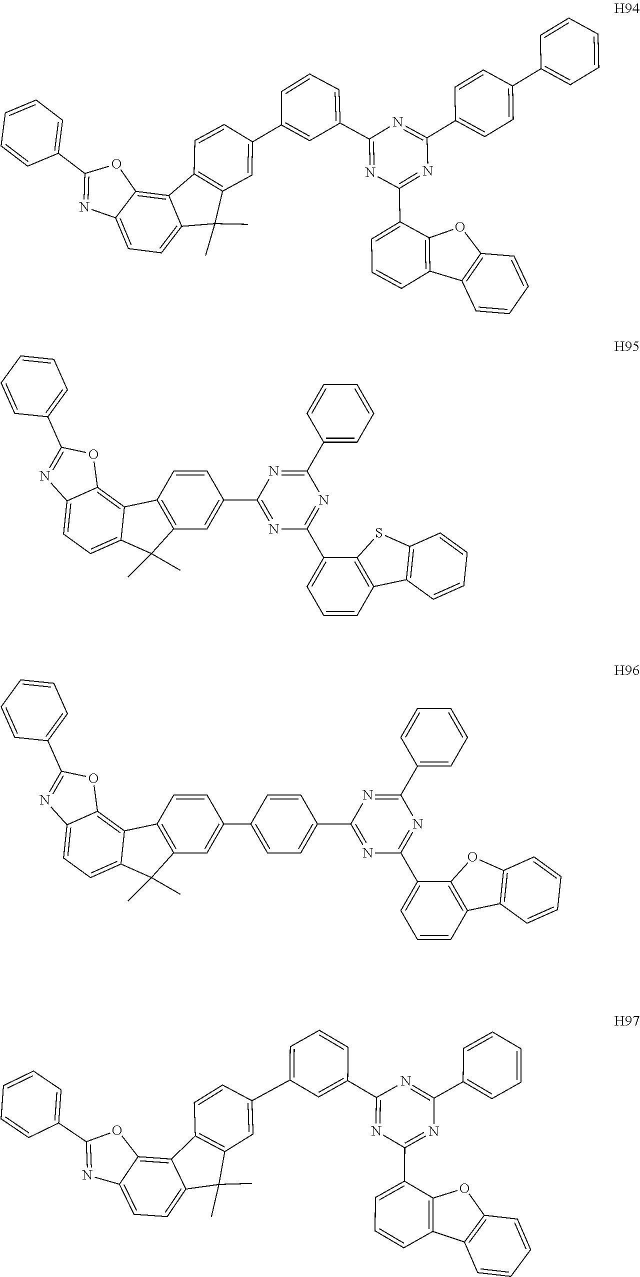 [SMILES: CC1(C)c2cc(-c3cccc(-c4nc(-c5ccc(-c6ccccc6)cc5)nc(-c5cccc6c5oc5ccccc56)n4)c3)ccc2-c2c1ccc1nc(-c3ccccc3)oc21 ; CC1(C)c2cc(-c3nc(-c4ccccc4)nc(-c4cccc5c4sc4ccccc45)n3)ccc2-c2c1ccc1nc(-c3ccccc3)oc21 ; CC1(C)c2cc(-c3ccc(-c4nc(-c5ccccc5)nc(-c5cccc6c5oc5ccccc56)n4)cc3)ccc2-c2c1ccc1nc(-c3ccccc3)oc21 ; CC1(C)c2cc(-c3cccc(-c4nc(-c5ccccc5)nc(-c5cccc6c5oc5ccccc56)n4)c3)ccc2-c2c1ccc1nc(-c3ccccc3)oc21]

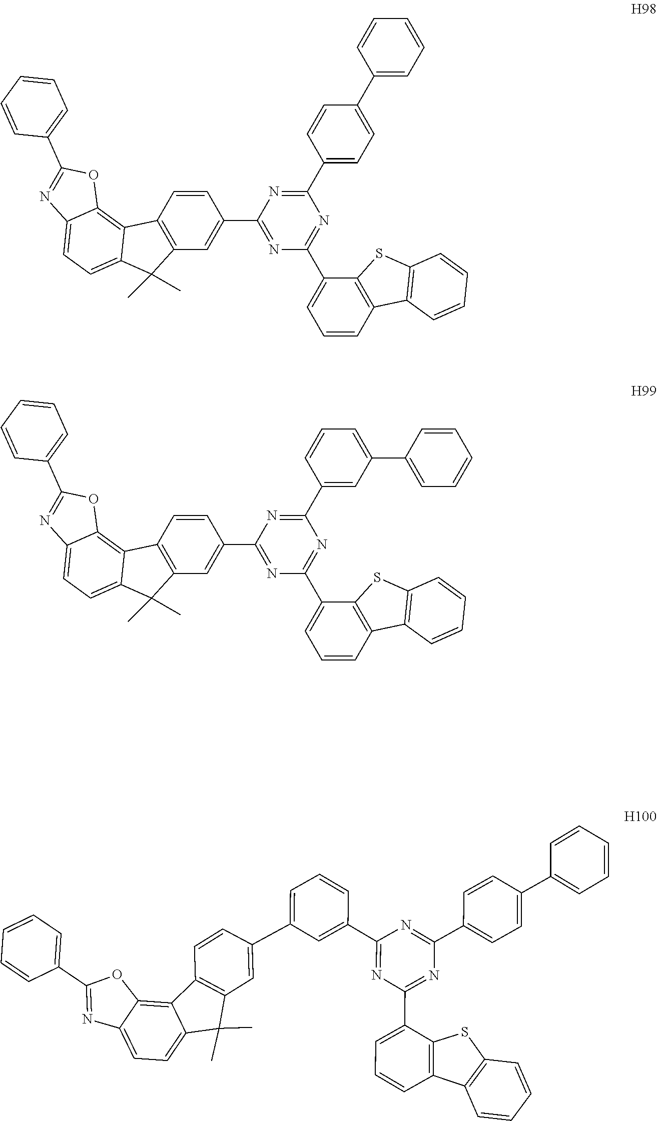 [SMILES: CC1(C)c2cc(-c3nc(-c4ccc(-c5ccccc5)cc4)nc(-c4cccc5c4sc4ccccc45)n3)ccc2-c2c1ccc1nc(-c3ccccc3)oc21 ; CC1(C)c2cc(-c3nc(-c4cccc(-c5ccccc5)c4)nc(-c4cccc5c4sc4ccccc45)n3)ccc2-c2c1ccc1nc(-c3ccccc3)oc21 ; CC1(C)c2cc(-c3cccc(-c4nc(-c5ccc(-c6ccccc6)cc5)nc(-c5cccc6c5sc5ccccc56)n4)c3)ccc2-c2c1ccc1nc(-c3ccccc3)oc21]

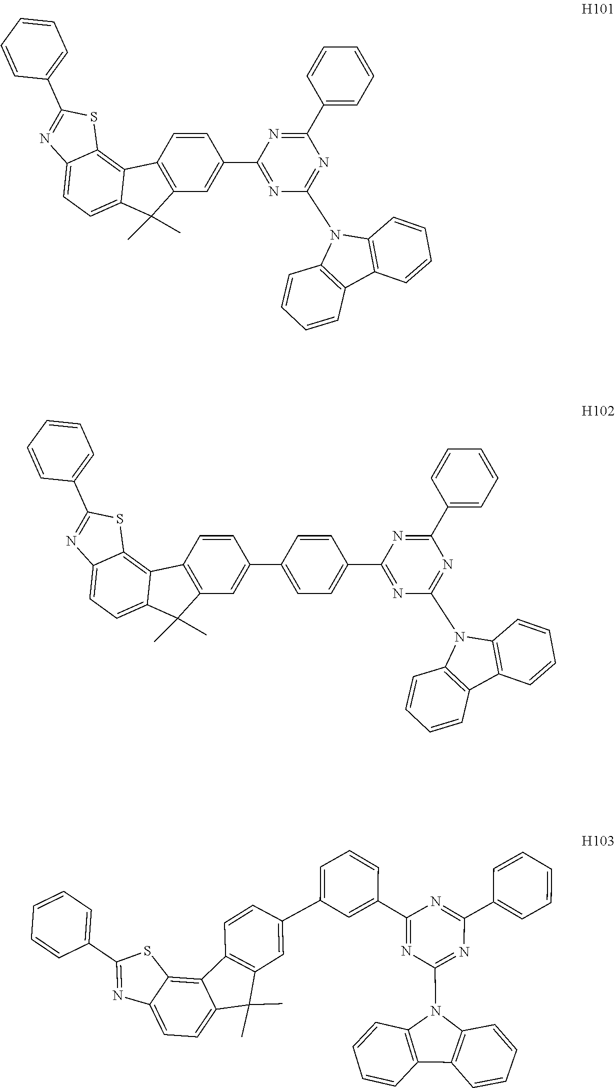 [SMILES: CC1(C)c2cc(-c3nc(-c4ccccc4)nc(-n4c5ccccc5c5ccccc54)n3)ccc2-c2c1ccc1nc(-c3ccccc3)sc21 ; CC1(C)c2cc(-c3ccc(-c4nc(-c5ccccc5)nc(-n5c6ccccc6c6ccccc65)n4)cc3)ccc2-c2c1ccc1nc(-c3ccccc3)sc21 ; CC1(C)c2cc(-c3cccc(-c4nc(-c5ccccc5)nc(-n5c6ccccc6c6ccccc65)n4)c3)ccc2-c2c1ccc1nc(-c3ccccc3)sc21]

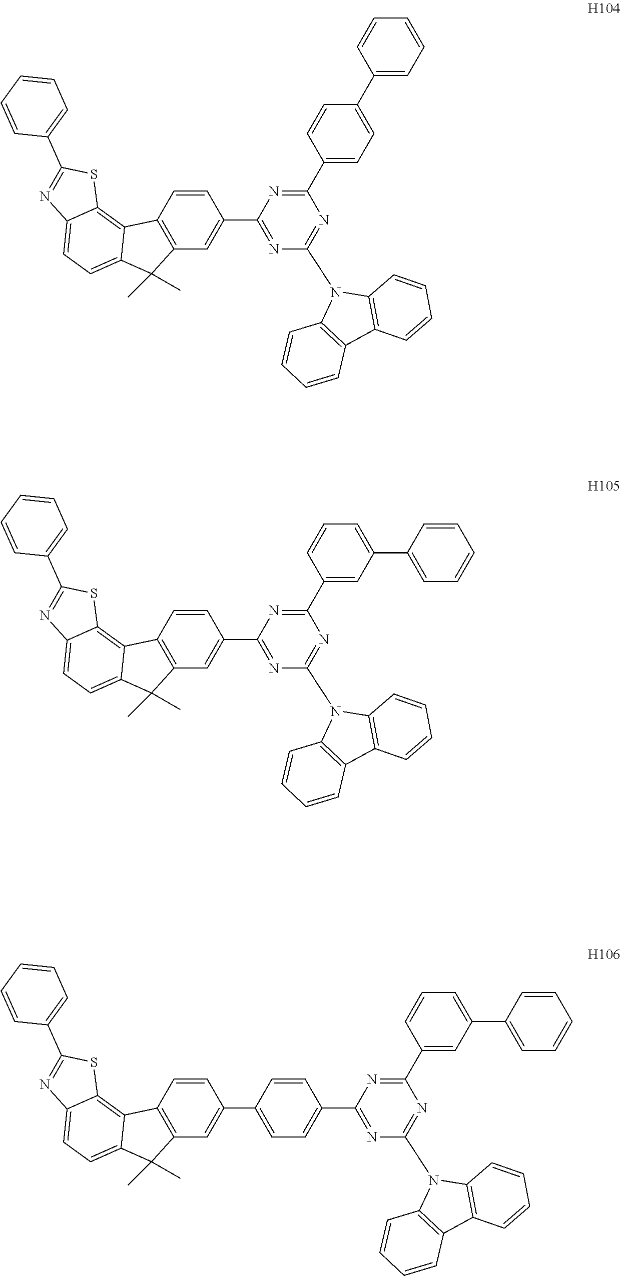 [SMILES: CC1(C)c2cc(-c3nc(-c4ccc(-c5ccccc5)cc4)nc(-n4c5ccccc5c5ccccc54)n3)ccc2-c2c1ccc1nc(-c3ccccc3)sc21 ; CC1(C)c2cc(-c3nc(-c4cccc(-c5ccccc5)c4)nc(-n4c5ccccc5c5ccccc54)n3)ccc2-c2c1ccc1nc(-c3ccccc3)sc21 ; CC1(C)c2cc(-c3ccc(-c4nc(-c5cccc(-c6ccccc6)c5)nc(-n5c6ccccc6c6ccccc65)n4)cc3)ccc2-c2c1ccc1nc(-c3ccccc3)sc21]

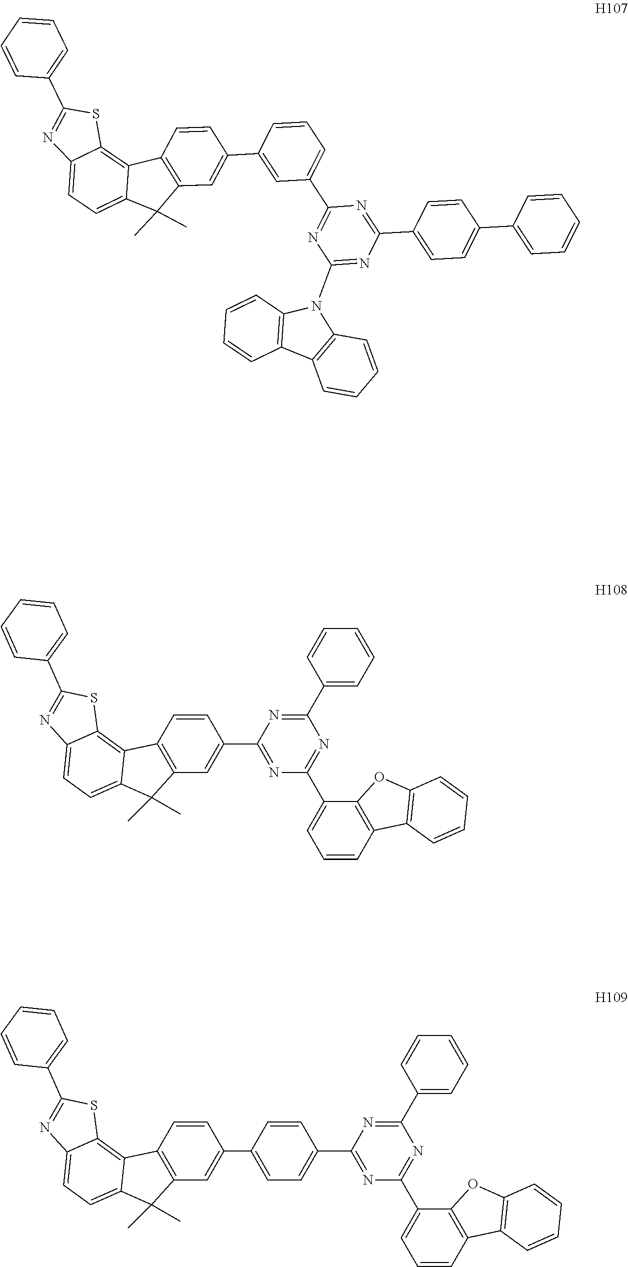 [SMILES: CC1(C)c2cc(-c3cccc(-c4nc(-c5ccc(-c6ccccc6)cc5)nc(-n5c6ccccc6c6ccccc65)n4)c3)ccc2-c2c1ccc1nc(-c3ccccc3)sc21 ; CC1(C)c2cc(-c3nc(-c4ccccc4)nc(-c4cccc5c4oc4ccccc45)n3)ccc2-c2c1ccc1nc(-c3ccccc3)sc21 ; CC1(C)c2cc(-c3ccc(-c4nc(-c5ccccc5)nc(-c5cccc6c5oc5ccccc56)n4)cc3)ccc2-c2c1ccc1nc(-c3ccccc3)sc21]

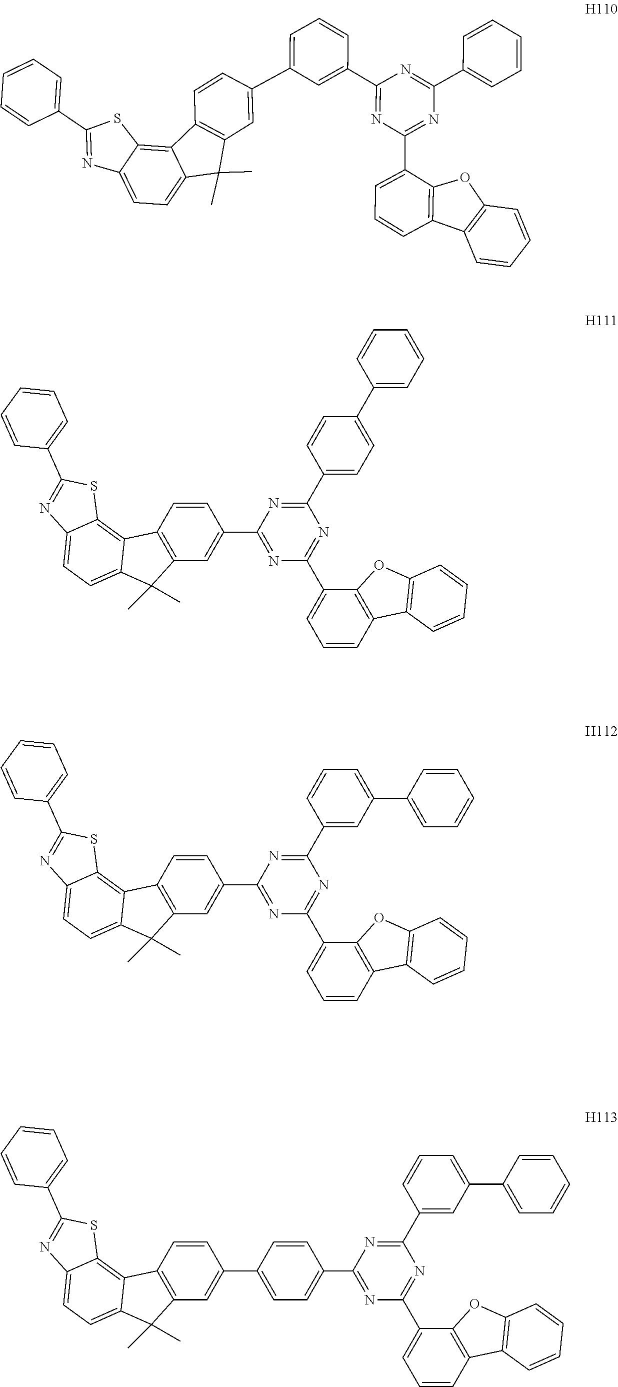 [SMILES: CC1(C)c2cc(-c3cccc(-c4nc(-c5ccccc5)nc(-c5cccc6c5oc5ccccc56)n4)c3)ccc2-c2c1ccc1nc(-c3ccccc3)sc21 ; CC1(C)c2cc(-c3nc(-c4ccc(-c5ccccc5)cc4)nc(-c4cccc5c4oc4ccccc45)n3)ccc2-c2c1ccc1nc(-c3ccccc3)sc21 ; CC1(C)c2cc(-c3nc(-c4cccc(-c5ccccc5)c4)nc(-c4cccc5c4oc4ccccc45)n3)ccc2-c2c1ccc1nc(-c3ccccc3)sc21 ; CC1(C)c2cc(-c3ccc(-c4nc(-c5cccc(-c6ccccc6)c5)nc(-c5cccc6c5oc5ccccc56)n4)cc3)ccc2-c2c1ccc1nc(-c3ccccc3)sc21]

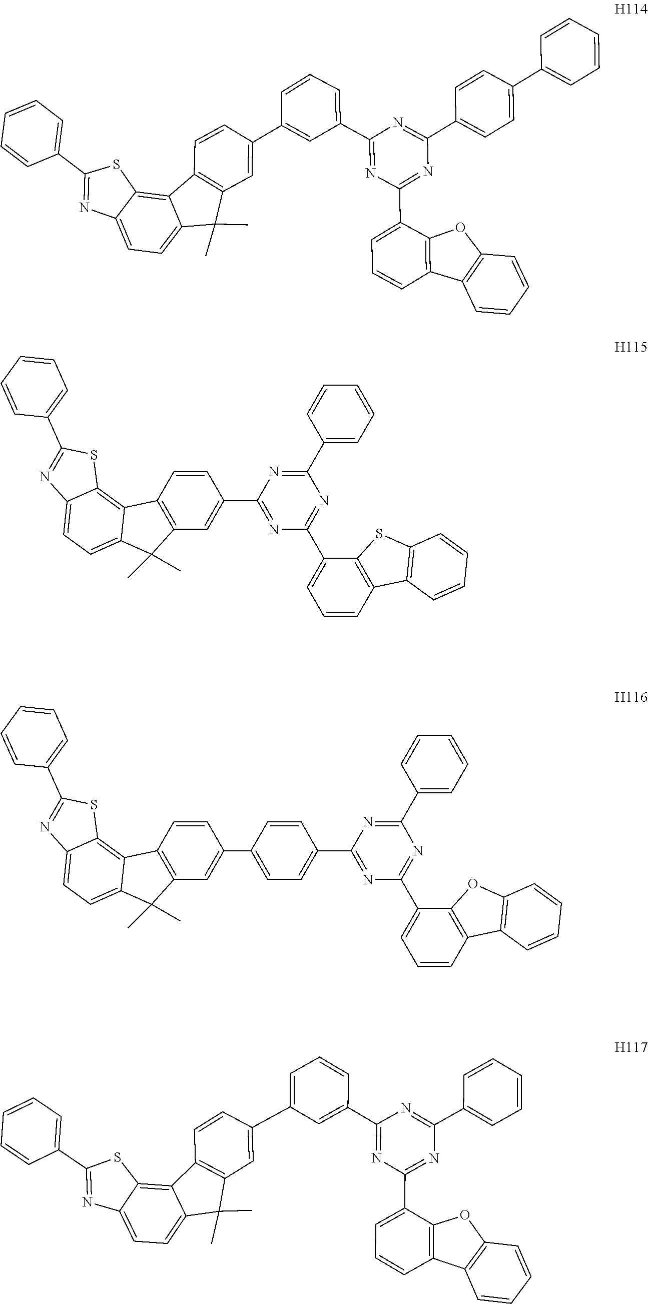 [SMILES: CC1(C)c2cc(-c3cccc(-c4nc(-c5ccc(-c6ccccc6)cc5)nc(-c5cccc6c5oc5ccccc56)n4)c3)ccc2-c2c1ccc1nc(-c3ccccc3)sc21 ; CC1(C)c2cc(-c3nc(-c4ccccc4)nc(-c4cccc5c4sc4ccccc45)n3)ccc2-c2c1ccc1nc(-c3ccccc3)sc21 ; CC1(C)c2cc(-c3ccc(-c4nc(-c5ccccc5)nc(-c5cccc6c5oc5ccccc56)n4)cc3)ccc2-c2c1ccc1nc(-c3ccccc3)sc21 ; CC1(C)c2cc(-c3cccc(-c4nc(-c5ccccc5)nc(-c5cccc6c5oc5ccccc56)n4)c3)ccc2-c2c1ccc1nc(-c3ccccc3)sc21]

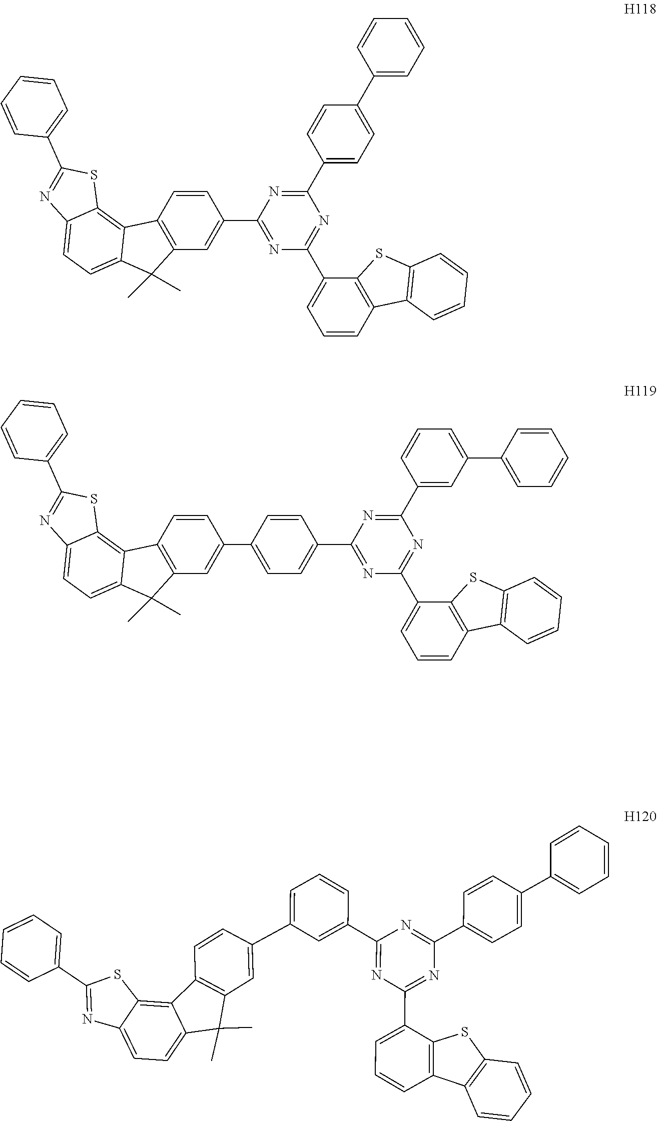 [SMILES: CC1(C)c2cc(-c3nc(-c4ccc(-c5ccccc5)cc4)nc(-c4cccc5c4sc4ccccc45)n3)ccc2-c2c1ccc1nc(-c3ccccc3)sc21 ; CC1(C)c2cc(-c3ccc(-c4nc(-c5cccc(-c6ccccc6)c5)nc(-c5cccc6c5sc5ccccc56)n4)cc3)ccc2-c2c1ccc1nc(-c3ccccc3)sc21 ; CC1(C)c2cc(-c3cccc(-c4nc(-c5ccc(-c6ccccc6)cc5)nc(-c5cccc6c5sc5ccccc56)n4)c3)ccc2-c2c1ccc1nc(-c3ccccc3)sc21]

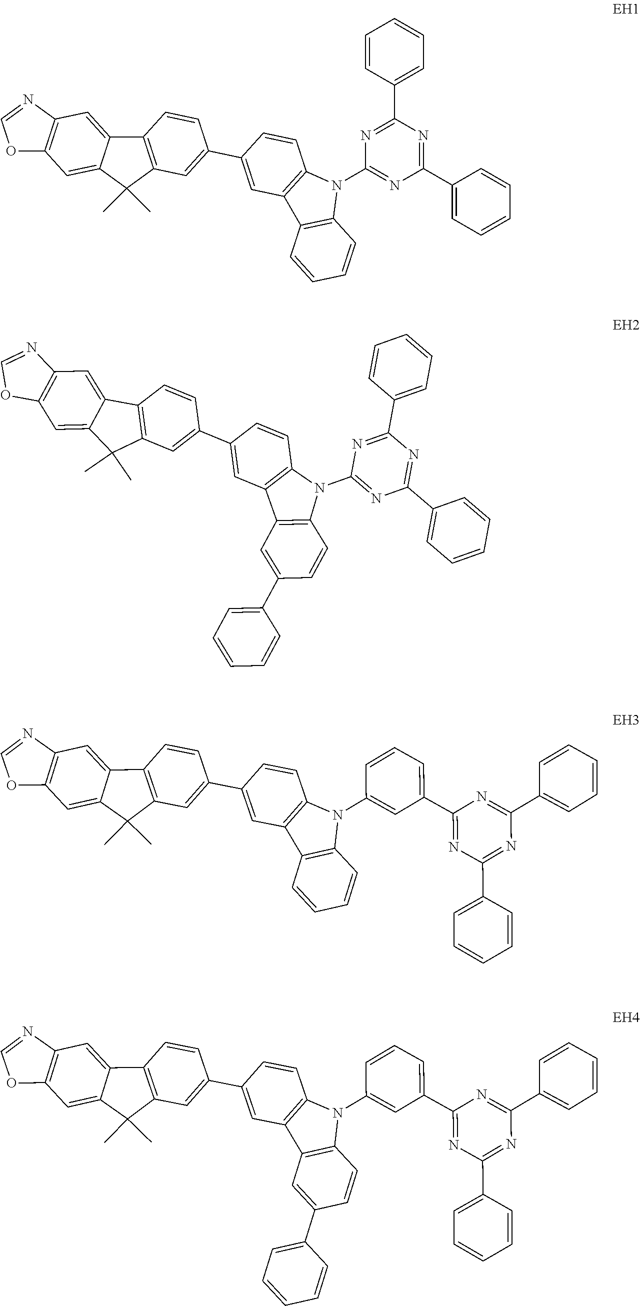 [SMILES: CC1(C)c2cc(-c3ccc4c(c3)c3ccccc3n4-c3nc(-c4ccccc4)nc(-c4ccccc4)n3)ccc2-c2cc3ncoc3cc21 ; CC1(C)c2cc(-c3ccc4c(c3)c3cc(-c5ccccc5)ccc3n4-c3nc(-c4ccccc4)nc(-c4ccccc4)n3)ccc2-c2cc3ncoc3cc21 ; CC1(C)c2cc(-c3ccc4c(c3)c3ccccc3n4-c3cccc(-c4nc(-c5ccccc5)nc(-c5ccccc5)n4)c3)ccc2-c2cc3ncoc3cc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2cc3ncoc3cc21]

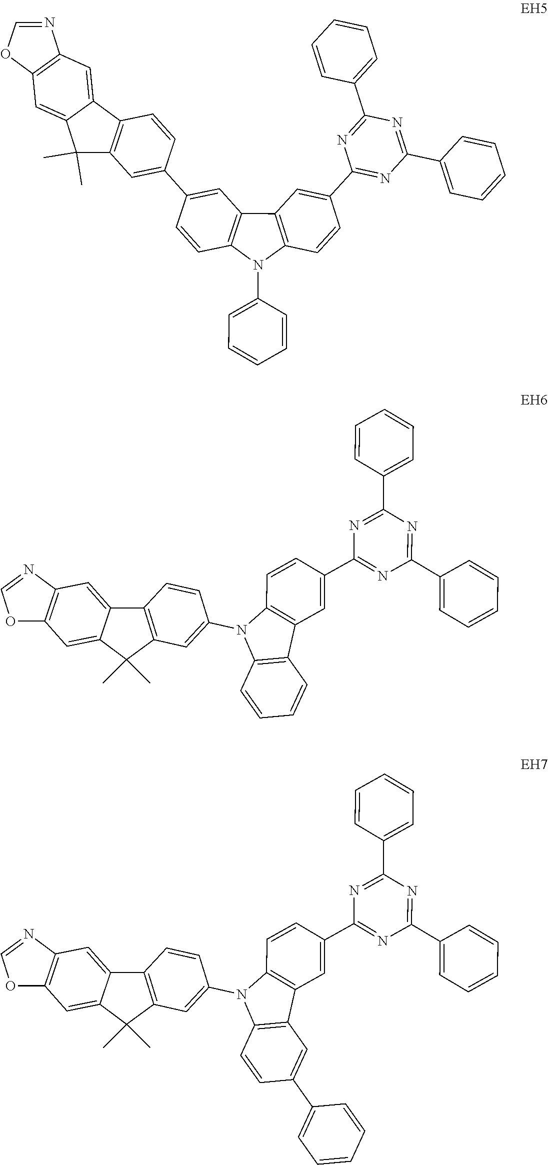 [SMILES: CC1(C)c2cc(-c3ccc4c(c3)c3cc(-c5nc(-c6ccccc6)nc(-c6ccccc6)n5)ccc3n4-c3ccccc3)ccc2-c2cc3ncoc3cc21 ; CC1(C)c2cc(-n3c4ccccc4c4cc(-c5nc(-c6ccccc6)nc(-c6ccccc6)n5)ccc43)ccc2-c2cc3ncoc3cc21 ; CC1(C)c2cc(-n3c4ccc(-c5ccccc5)cc4c4cc(-c5nc(-c6ccccc6)nc(-c6ccccc6)n5)ccc43)ccc2-c2cc3ncoc3cc21]

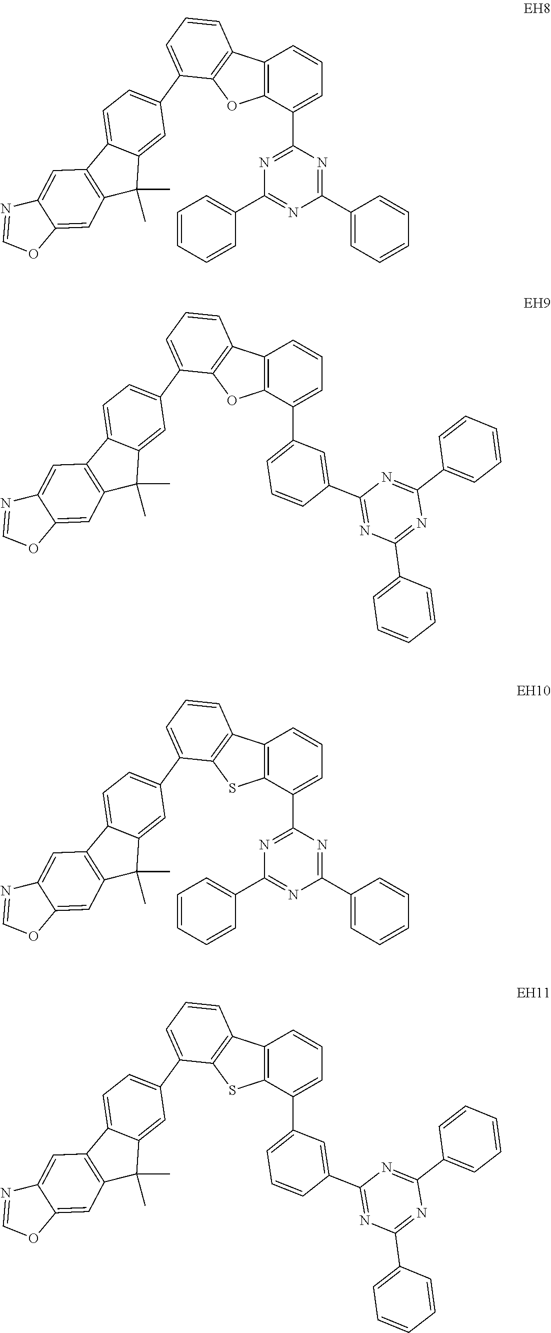 [SMILES: CC1(C)c2cc(-c3cccc4c3oc3c(-c5nc(-c6ccccc6)nc(-c6ccccc6)n5)cccc34)ccc2-c2cc3ncoc3cc21 ; CC1(C)c2cc(-c3cccc4c3oc3c(-c5cccc(-c6nc(-c7ccccc7)nc(-c7ccccc7)n6)c5)cccc34)ccc2-c2cc3ncoc3cc21 ; CC1(C)c2cc(-c3cccc4c3sc3c(-c5nc(-c6ccccc6)nc(-c6ccccc6)n5)cccc34)ccc2-c2cc3ncoc3cc21 ; CC1(C)c2cc(-c3cccc4c3sc3c(-c5cccc(-c6nc(-c7ccccc7)nc(-c7ccccc7)n6)c5)cccc34)ccc2-c2cc3ncoc3cc21]

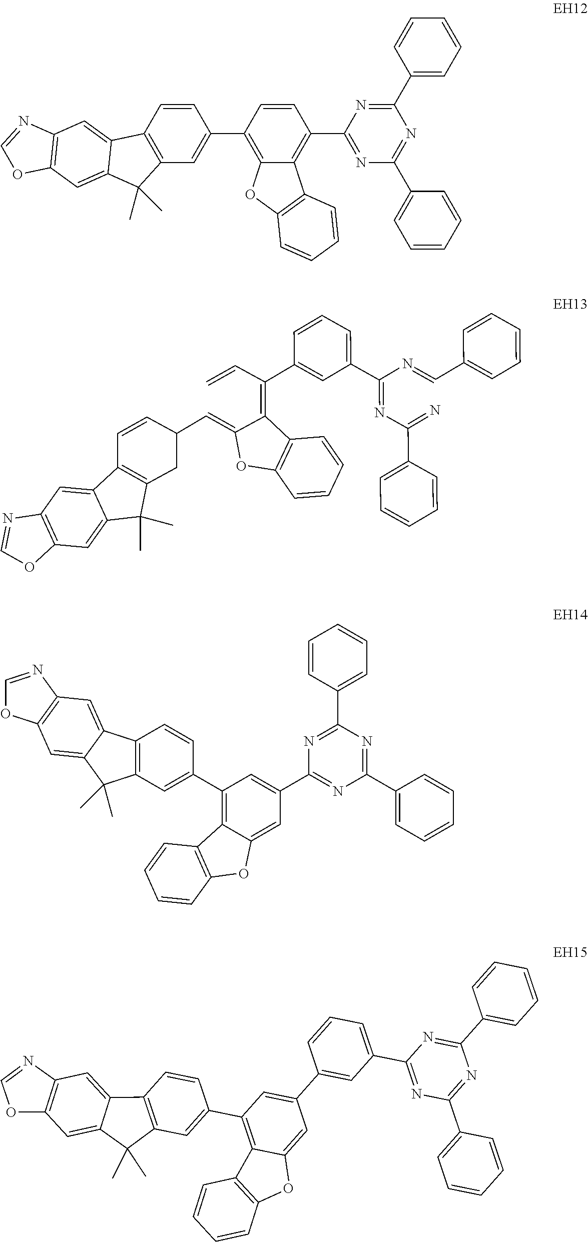 [SMILES: CC1(C)c2cc(-c3ccc(-c4nc(-c5ccccc5)nc(-c5ccccc5)n4)c4c3oc3ccccc34)ccc2-c2cc3ncoc3cc21 ; C=C/C(c1cccc(C(=N/C(=N)c2ccccc2)/N=C/c2ccccc2)c1)=c1\c(=C\C2C=CC3=C(C2)C(C)(C)c2cc4ocnc4cc23)oc2ccccc12 ; CC1(C)c2cc(-c3cc(-c4nc(-c5ccccc5)nc(-c5ccccc5)n4)cc4oc5ccccc5c34)ccc2-c2cc3ncoc3cc21 ; CC1(C)c2cc(-c3cc(-c4cccc(-c5nc(-c6ccccc6)nc(-c6ccccc6)n5)c4)cc4oc5ccccc5c34)ccc2-c2cc3ncoc3cc21]

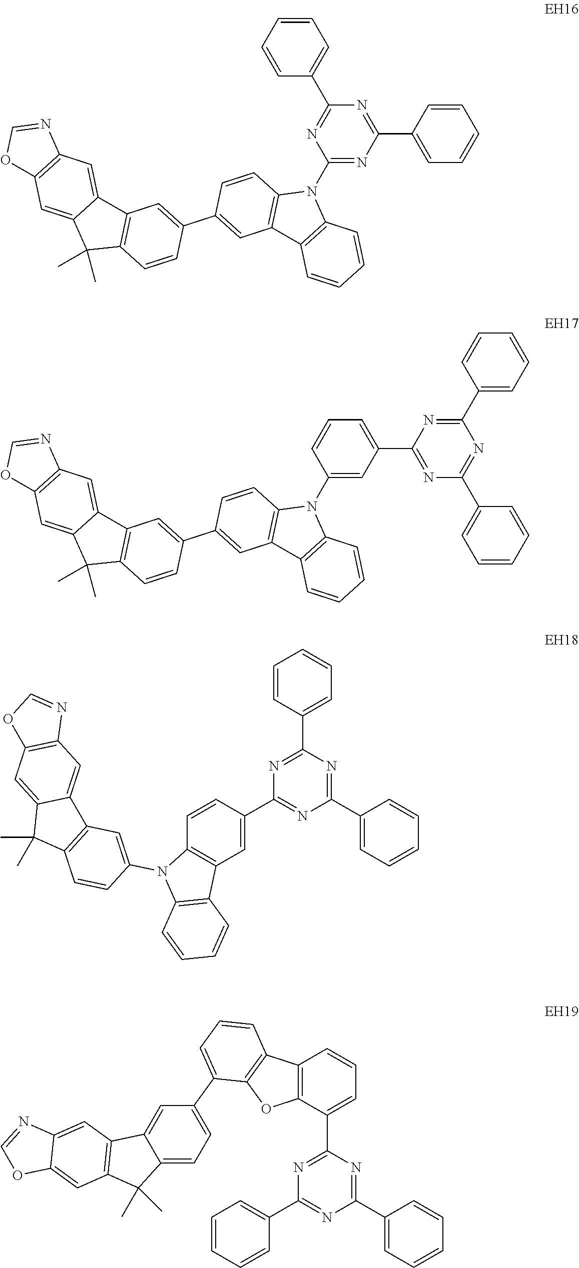 [SMILES: CC1(C)c2ccc(-c3ccc4c(c3)c3ccccc3n4-c3nc(-c4ccccc4)nc(-c4ccccc4)n3)cc2-c2cc3ncoc3cc21 ; CC1(C)c2ccc(-c3ccc4c(c3)c3ccccc3n4-c3cccc(-c4nc(-c5ccccc5)nc(-c5ccccc5)n4)c3)cc2-c2cc3ncoc3cc21 ; CC1(C)c2ccc(-n3c4ccccc4c4cc(-c5nc(-c6ccccc6)nc(-c6ccccc6)n5)ccc43)cc2-c2cc3ncoc3cc21 ; CC1(C)c2ccc(-c3cccc4c3oc3c(-c5nc(-c6ccccc6)nc(-c6ccccc6)n5)cccc34)cc2-c2cc3ncoc3cc21]

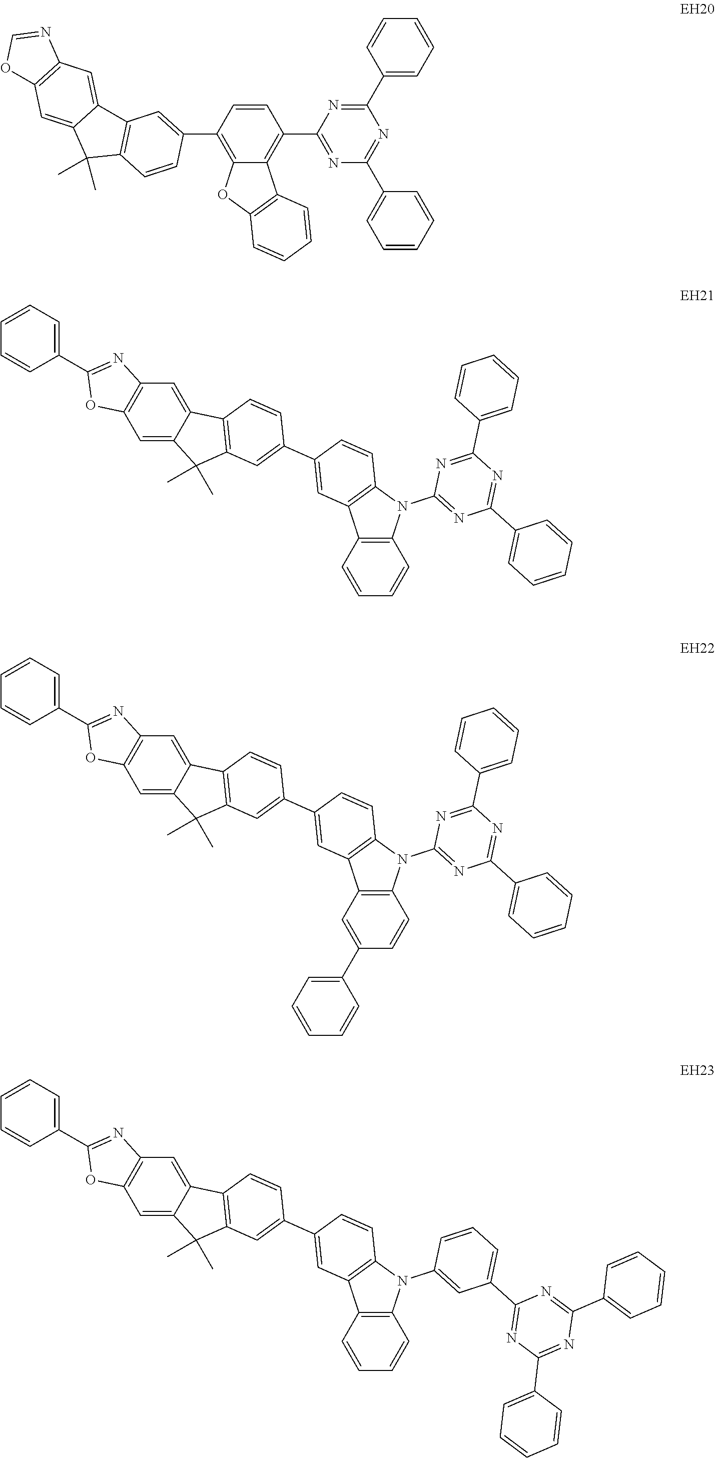 [SMILES: CC1(C)c2ccc(-c3ccc(-c4nc(-c5ccccc5)nc(-c5ccccc5)n4)c4c3oc3ccccc34)cc2-c2cc3ncoc3cc21 ; CC1(C)c2cc(-c3ccc4c(c3)c3ccccc3n4-c3nc(-c4ccccc4)nc(-c4ccccc4)n3)ccc2-c2cc3nc(-c4ccccc4)oc3cc21 ; CC1(C)c2cc(-c3ccc4c(c3)c3cc(-c5ccccc5)ccc3n4-c3nc(-c4ccccc4)nc(-c4ccccc4)n3)ccc2-c2cc3nc(-c4ccccc4)oc3cc21 ; CC1(C)c2cc(-c3ccc4c(c3)c3ccccc3n4-c3cccc(-c4nc(-c5ccccc5)nc(-c5ccccc5)n4)c3)ccc2-c2cc3nc(-c4ccccc4)oc3cc21]

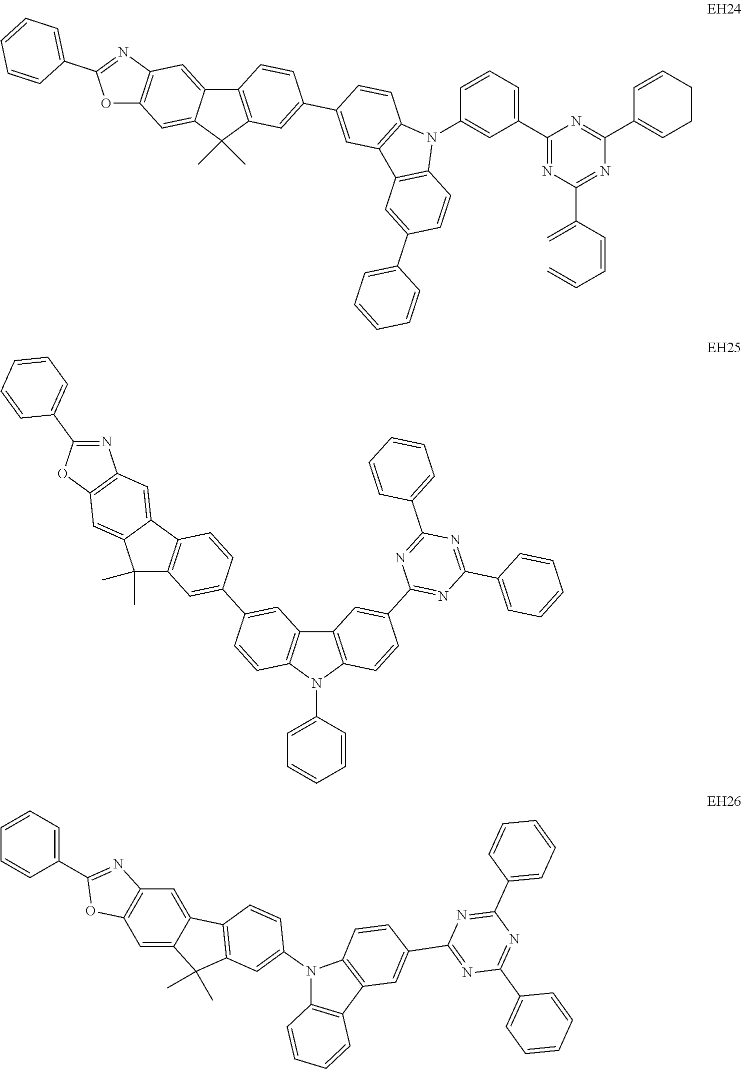 [SMILES: C=C/C=C\C(=C)c1nc(C2=CCCC=C2)nc(-c2cccc(-n3c4ccc(-c5ccccc5)cc4c4cc(-c5ccc6c(c5)C(C)(C)c5cc7oc(-c8ccccc8)nc7cc5-6)ccc43)c2)n1 ; CC1(C)c2cc(-c3ccc4c(c3)c3cc(-c5nc(-c6ccccc6)nc(-c6ccccc6)n5)ccc3n4-c3ccccc3)ccc2-c2cc3nc(-c4ccccc4)oc3cc21 ; CC1(C)c2cc(-n3c4ccccc4c4cc(-c5nc(-c6ccccc6)nc(-c6ccccc6)n5)ccc43)ccc2-c2cc3nc(-c4ccccc4)oc3cc21]

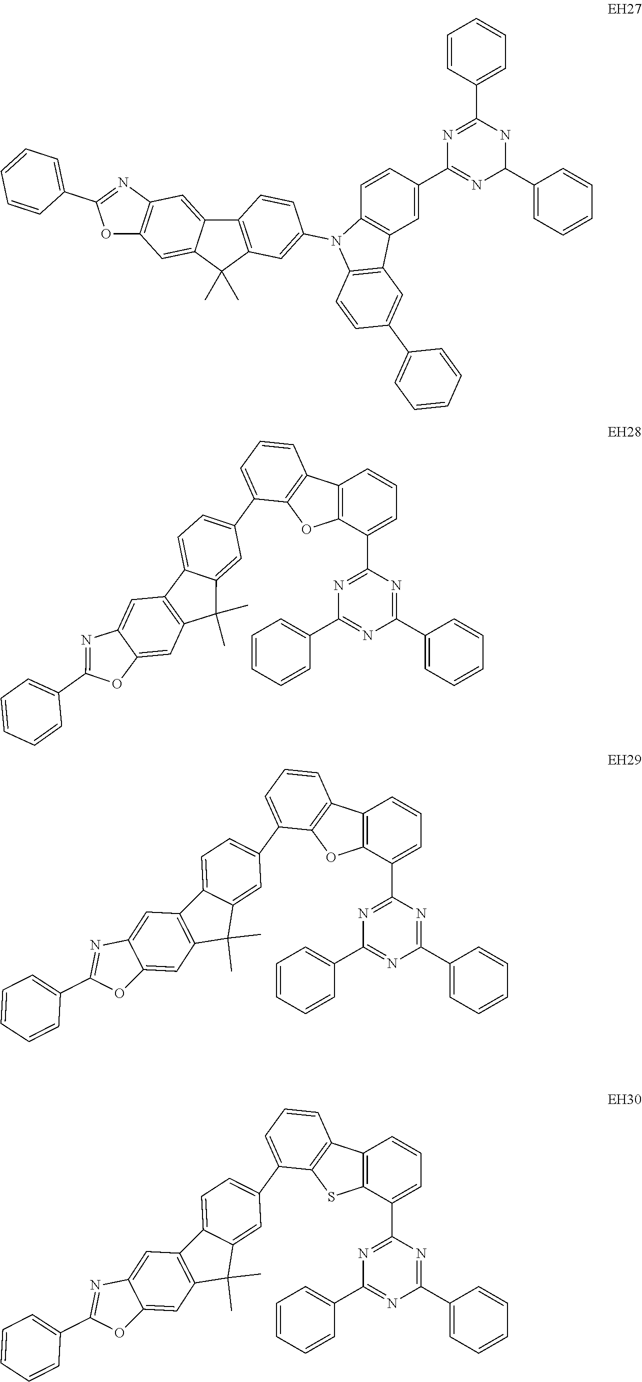 [SMILES: CC1(C)c2cc(-n3c4ccc(C5=NC(c6ccccc6)NC(c6ccccc6)=N5)cc4c4cc(-c5ccccc5)ccc43)ccc2-c2cc3nc(-c4ccccc4)oc3cc21 ; CC1(C)c2cc(-c3cccc4c3oc3c(-c5nc(-c6ccccc6)nc(-c6ccccc6)n5)cccc34)ccc2-c2cc3nc(-c4ccccc4)oc3cc21 ; CC1(C)c2cc(-c3cccc4c3oc3c(-c5nc(-c6ccccc6)nc(-c6ccccc6)n5)cccc34)ccc2-c2cc3nc(-c4ccccc4)oc3cc21 ; CC1(C)c2cc(-c3cccc4c3sc3c(-c5nc(-c6ccccc6)nc(-c6ccccc6)n5)cccc34)ccc2-c2cc3nc(-c4ccccc4)oc3cc21]

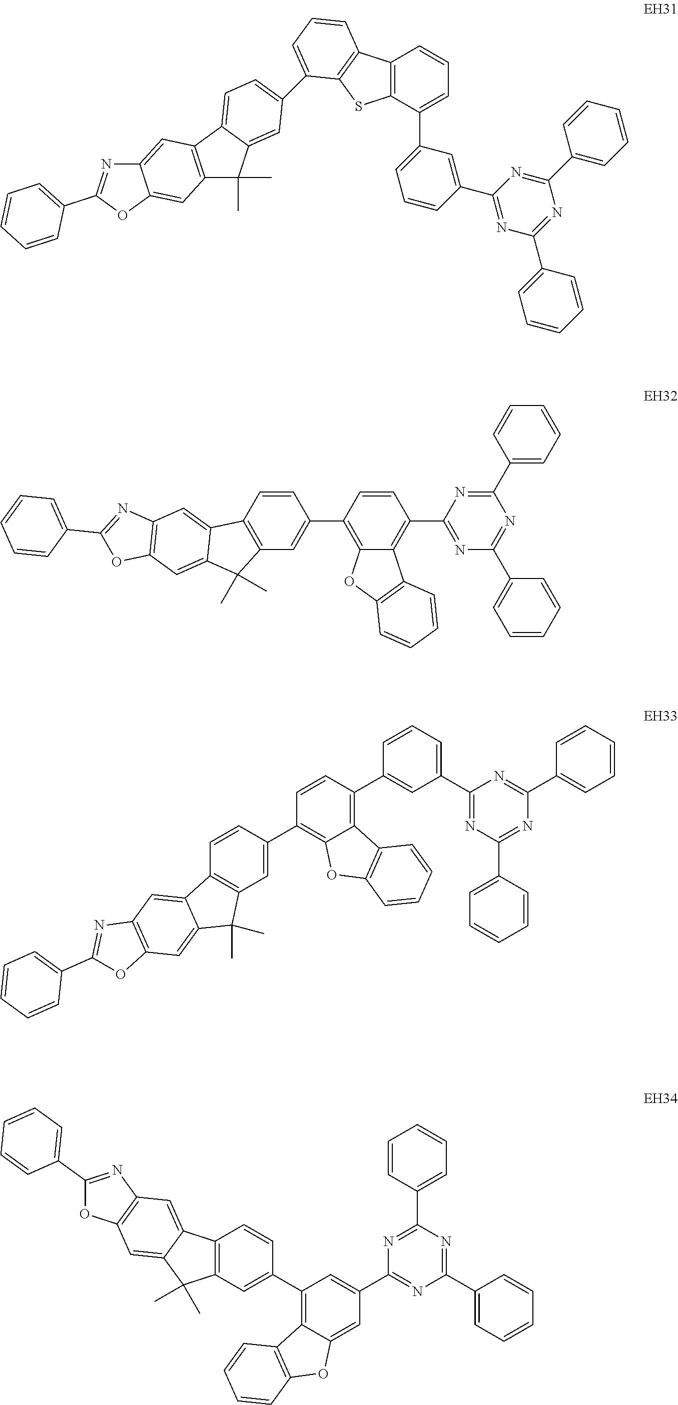 [SMILES: CC1(C)c2cc(-c3cccc4c3sc3c(-c5cccc(-c6nc(-c7ccccc7)nc(-c7ccccc7)n6)c5)cccc34)ccc2-c2cc3nc(-c4ccccc4)oc3cc21 ; CC1(C)c2cc(-c3ccc(-c4nc(-c5ccccc5)nc(-c5ccccc5)n4)c4c3oc3ccccc34)ccc2-c2cc3nc(-c4ccccc4)oc3cc21 ; CC1(C)c2cc(-c3ccc(-c4cccc(-c5nc(-c6ccccc6)nc(-c6ccccc6)n5)c4)c4c3oc3ccccc34)ccc2-c2cc3nc(-c4ccccc4)oc3cc21 ; CC1(C)c2cc(-c3cc(-c4nc(-c5ccccc5)nc(-c5ccccc5)n4)cc4oc5ccccc5c34)ccc2-c2cc3nc(-c4ccccc4)oc3cc21]

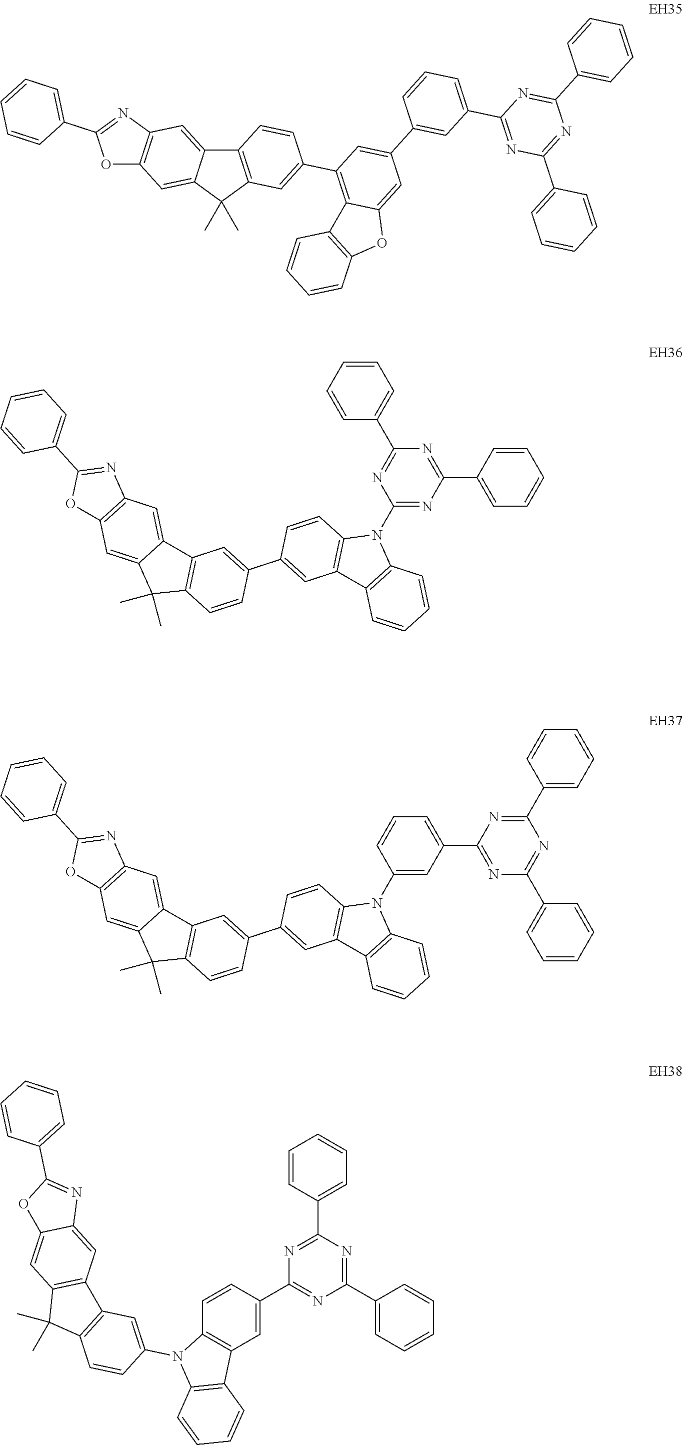 [SMILES: CC1(C)c2cc(-c3cc(-c4cccc(-c5nc(-c6ccccc6)nc(-c6ccccc6)n5)c4)cc4oc5ccccc5c34)ccc2-c2cc3nc(-c4ccccc4)oc3cc21 ; CC1(C)c2ccc(-c3ccc4c(c3)c3ccccc3n4-c3nc(-c4ccccc4)nc(-c4ccccc4)n3)cc2-c2cc3nc(-c4ccccc4)oc3cc21 ; CC1(C)c2ccc(-c3ccc4c(c3)c3ccccc3n4-c3cccc(-c4nc(-c5ccccc5)nc(-c5ccccc5)n4)c3)cc2-c2cc3nc(-c4ccccc4)oc3cc21 ; CC1(C)c2ccc(-n3c4ccccc4c4cc(-c5nc(-c6ccccc6)nc(-c6ccccc6)n5)ccc43)cc2-c2cc3nc(-c4ccccc4)oc3cc21]

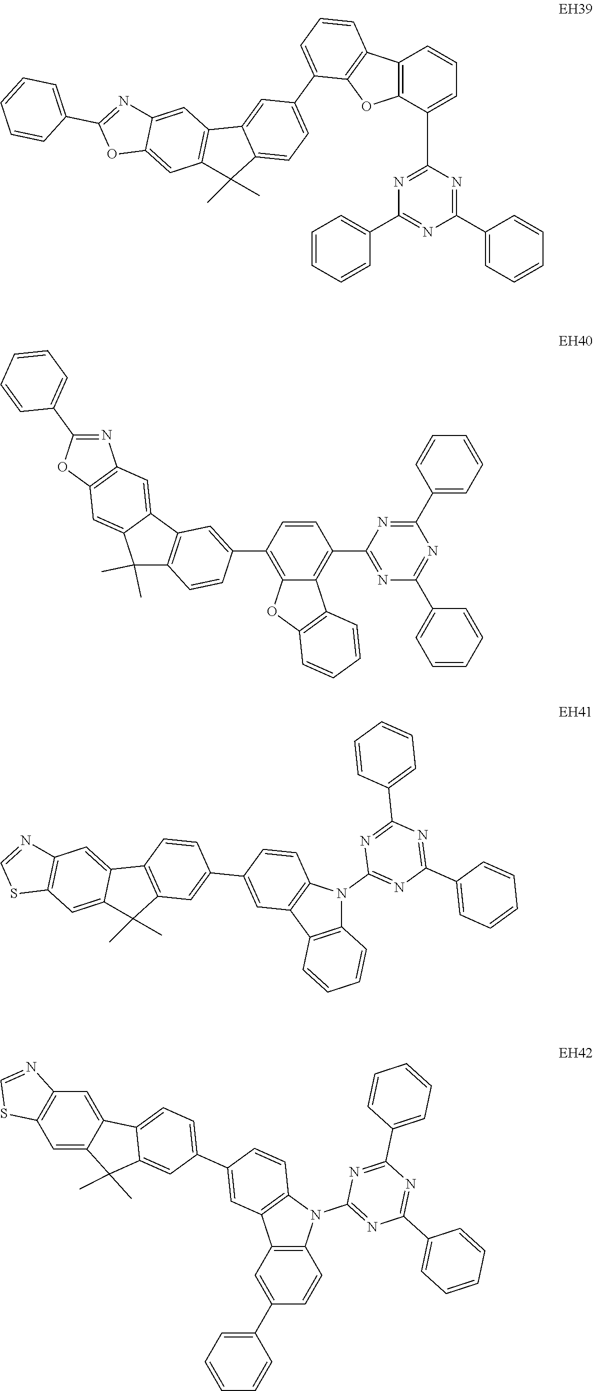 [SMILES: CC1(C)c2ccc(-c3cccc4c3oc3c(-c5nc(-c6ccccc6)nc(-c6ccccc6)n5)cccc34)cc2-c2cc3nc(-c4ccccc4)oc3cc21 ; CC1(C)c2ccc(-c3ccc(-c4nc(-c5ccccc5)nc(-c5ccccc5)n4)c4c3oc3ccccc34)cc2-c2cc3nc(-c4ccccc4)oc3cc21 ; CC1(C)c2cc(-c3ccc4c(c3)c3ccccc3n4-c3nc(-c4ccccc4)nc(-c4ccccc4)n3)ccc2-c2cc3ncsc3cc21 ; CC1(C)c2cc(-c3ccc4c(c3)c3cc(-c5ccccc5)ccc3n4-c3nc(-c4ccccc4)nc(-c4ccccc4)n3)ccc2-c2cc3ncsc3cc21]

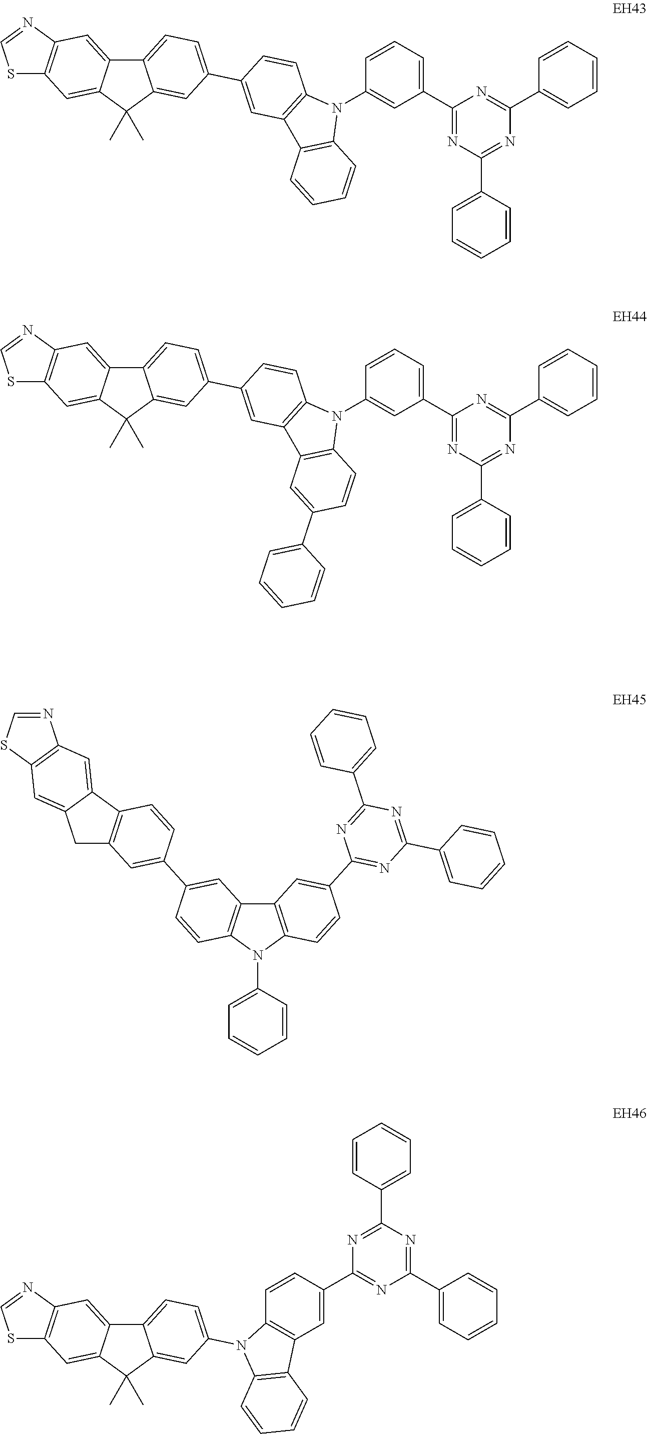 [SMILES: CC1(C)c2cc(-c3ccc4c(c3)c3ccccc3n4-c3cccc(-c4nc(-c5ccccc5)nc(-c5ccccc5)n4)c3)ccc2-c2cc3ncsc3cc21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2cc3ncsc3cc21 ; c1ccc(-c2nc(-c3ccccc3)nc(-c3ccc4c(c3)c3cc(-c5ccc6c(c5)Cc5cc7scnc7cc5-6)ccc3n4-c3ccccc3)n2)cc1 ; CC1(C)c2cc(-n3c4ccccc4c4cc(-c5nc(-c6ccccc6)nc(-c6ccccc6)n5)ccc43)ccc2-c2cc3ncsc3cc21]

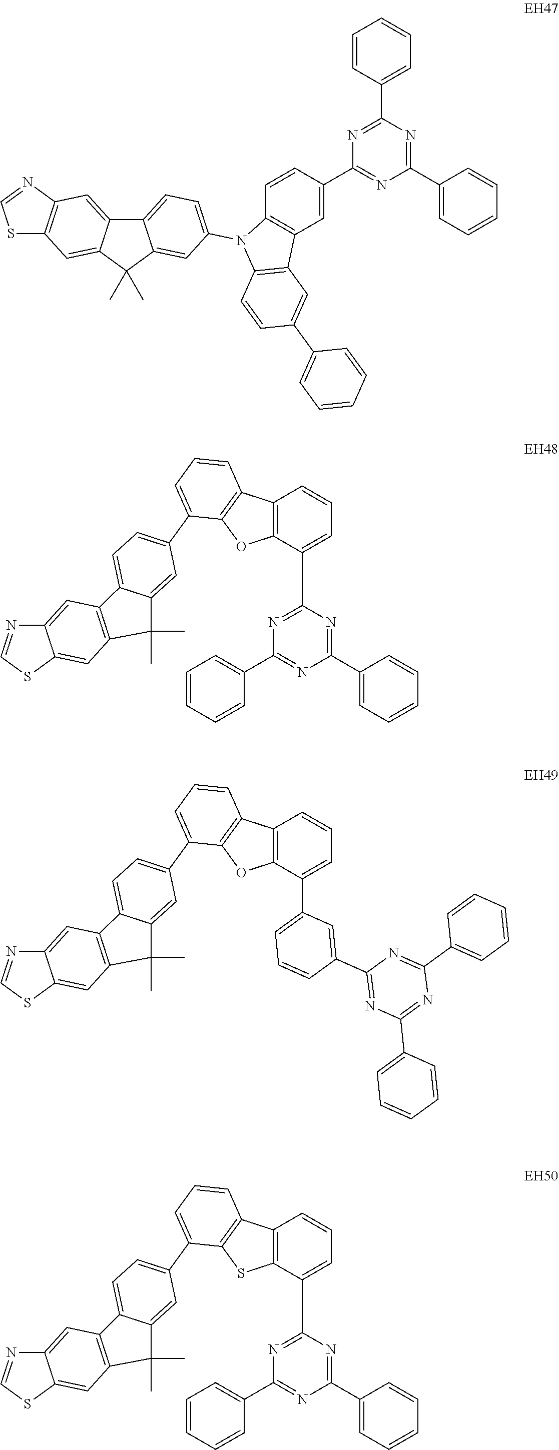 [SMILES: CC1(C)c2cc(-n3c4ccc(-c5ccccc5)cc4c4cc(-c5nc(-c6ccccc6)nc(-c6ccccc6)n5)ccc43)ccc2-c2cc3ncsc3cc21 ; CC1(C)c2cc(-c3cccc4c3oc3c(-c5nc(-c6ccccc6)nc(-c6ccccc6)n5)cccc34)ccc2-c2cc3ncsc3cc21 ; CC1(C)c2cc(-c3cccc4c3oc3c(-c5cccc(-c6nc(-c7ccccc7)nc(-c7ccccc7)n6)c5)cccc34)ccc2-c2cc3ncsc3cc21 ; CC1(C)c2cc(-c3cccc4c3sc3c(-c5nc(-c6ccccc6)nc(-c6ccccc6)n5)cccc34)ccc2-c2cc3ncsc3cc21]

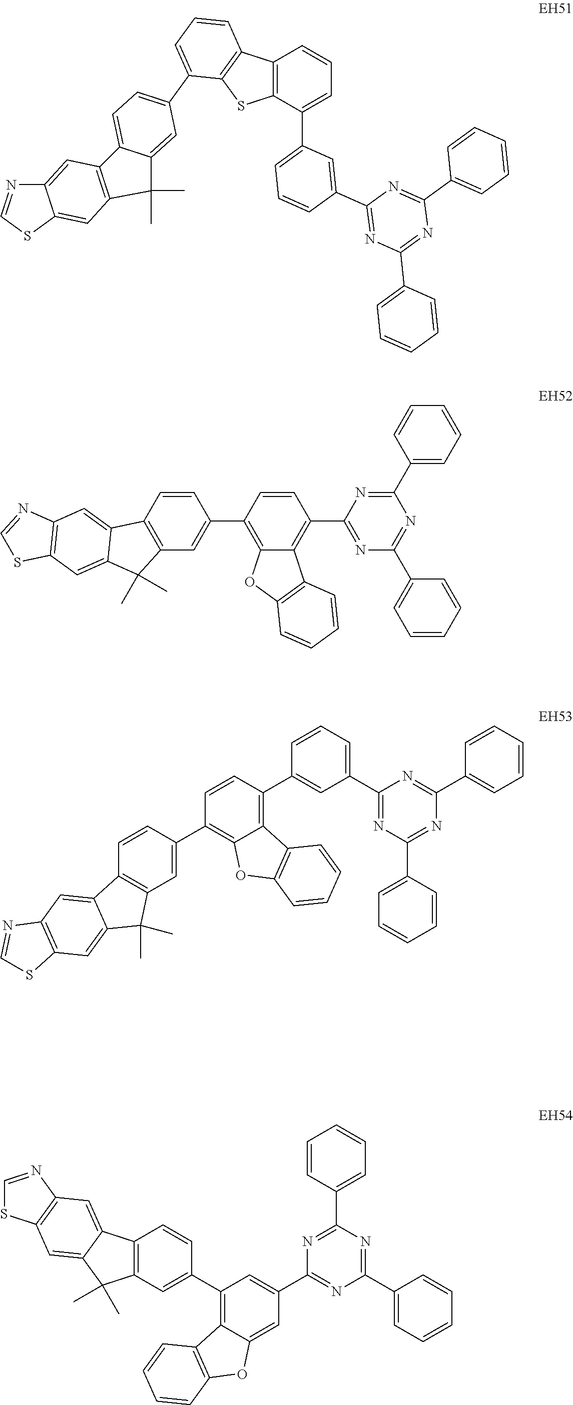 [SMILES: CC1(C)c2cc(-c3cccc4c3sc3c(-c5cccc(-c6nc(-c7ccccc7)nc(-c7ccccc7)n6)c5)cccc34)ccc2-c2cc3ncsc3cc21 ; CC1(C)c2cc(-c3ccc(-c4nc(-c5ccccc5)nc(-c5ccccc5)n4)c4c3oc3ccccc34)ccc2-c2cc3ncsc3cc21 ; CC1(C)c2cc(-c3ccc(-c4cccc(-c5nc(-c6ccccc6)nc(-c6ccccc6)n5)c4)c4c3oc3ccccc34)ccc2-c2cc3ncsc3cc21 ; CC1(C)c2cc(-c3cc(-c4nc(-c5ccccc5)nc(-c5ccccc5)n4)cc4oc5ccccc5c34)ccc2-c2cc3ncsc3cc21]

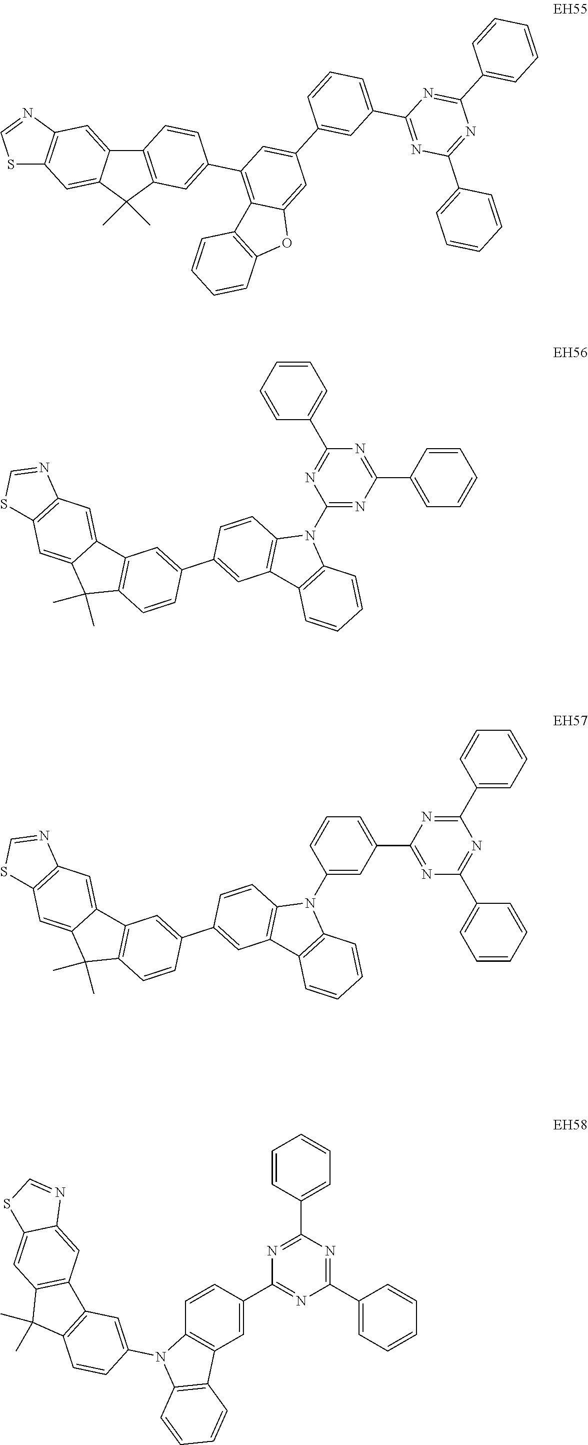 [SMILES: CC1(C)c2cc(-c3cc(-c4cccc(-c5nc(-c6ccccc6)nc(-c6ccccc6)n5)c4)cc4oc5ccccc5c34)ccc2-c2cc3ncsc3cc21 ; CC1(C)c2ccc(-c3ccc4c(c3)c3ccccc3n4-c3nc(-c4ccccc4)nc(-c4ccccc4)n3)cc2-c2cc3ncsc3cc21 ; CC1(C)c2ccc(-c3ccc4c(c3)c3ccccc3n4-c3cccc(-c4nc(-c5ccccc5)nc(-c5ccccc5)n4)c3)cc2-c2cc3ncsc3cc21 ; CC1(C)c2ccc(-n3c4ccccc4c4cc(-c5nc(-c6ccccc6)nc(-c6ccccc6)n5)ccc43)cc2-c2cc3ncsc3cc21]

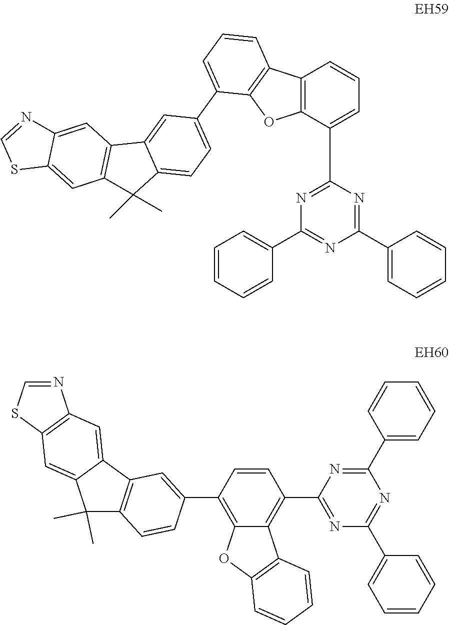 [SMILES: CC1(C)c2ccc(-c3cccc4c3oc3c(-c5nc(-c6ccccc6)nc(-c6ccccc6)n5)cccc34)cc2-c2cc3ncsc3cc21 ; CC1(C)c2ccc(-c3ccc(-c4nc(-c5ccccc5)nc(-c5ccccc5)n4)c4c3oc3ccccc34)cc2-c2cc3ncsc3cc21]

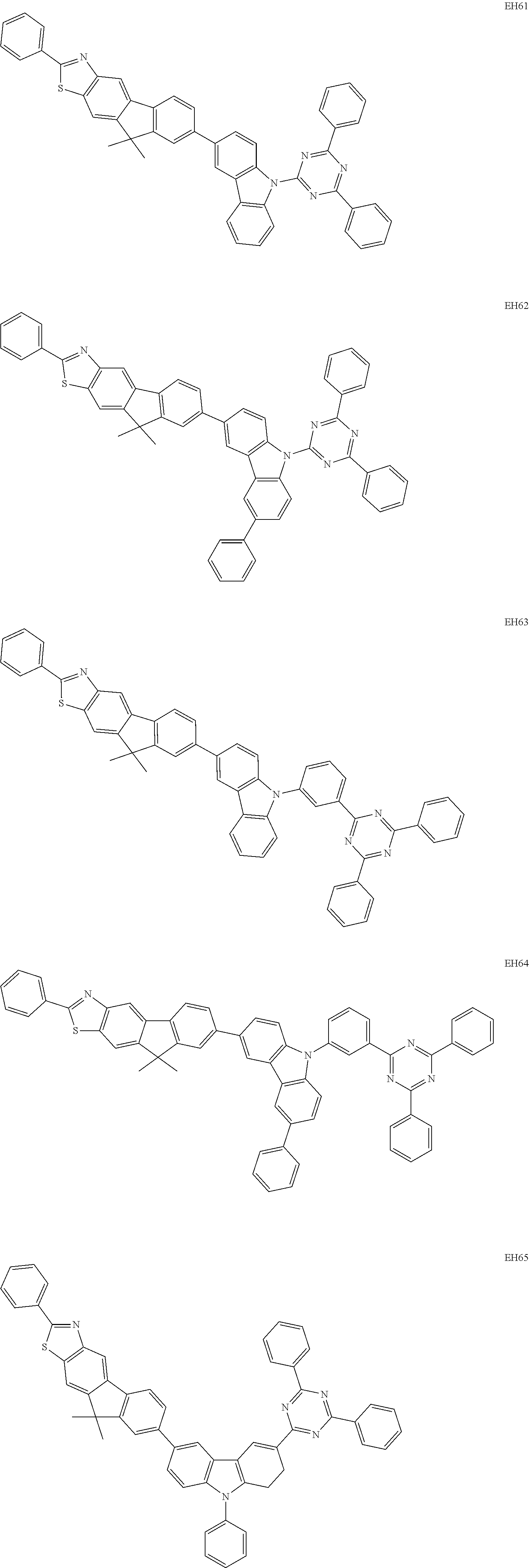

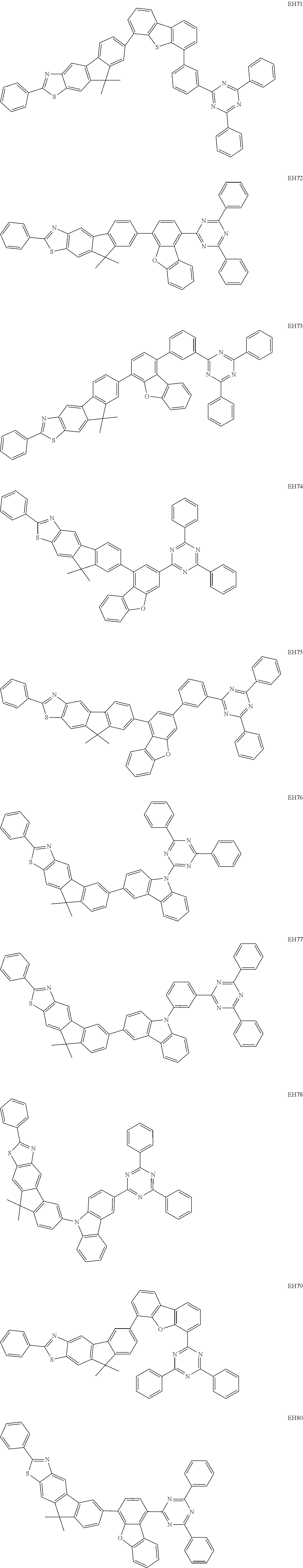

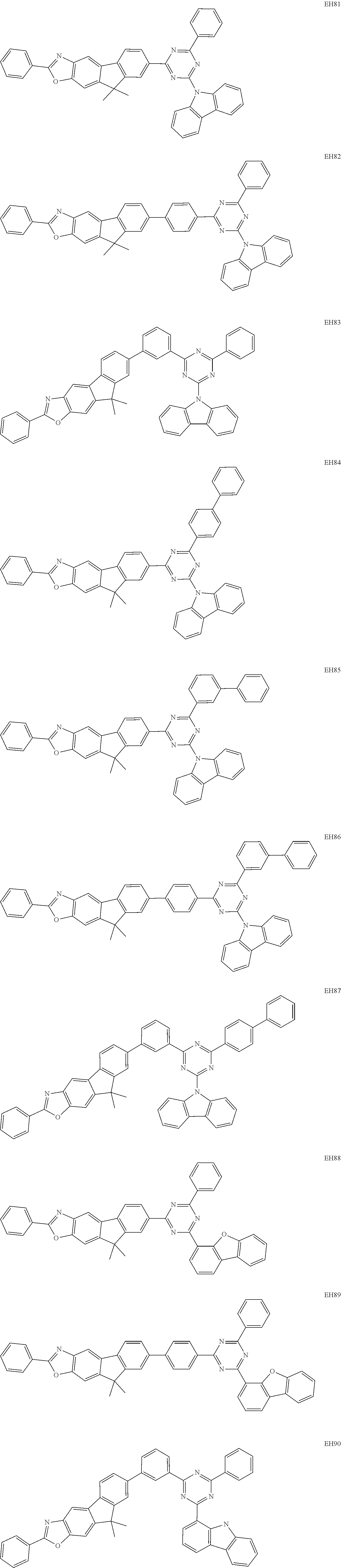

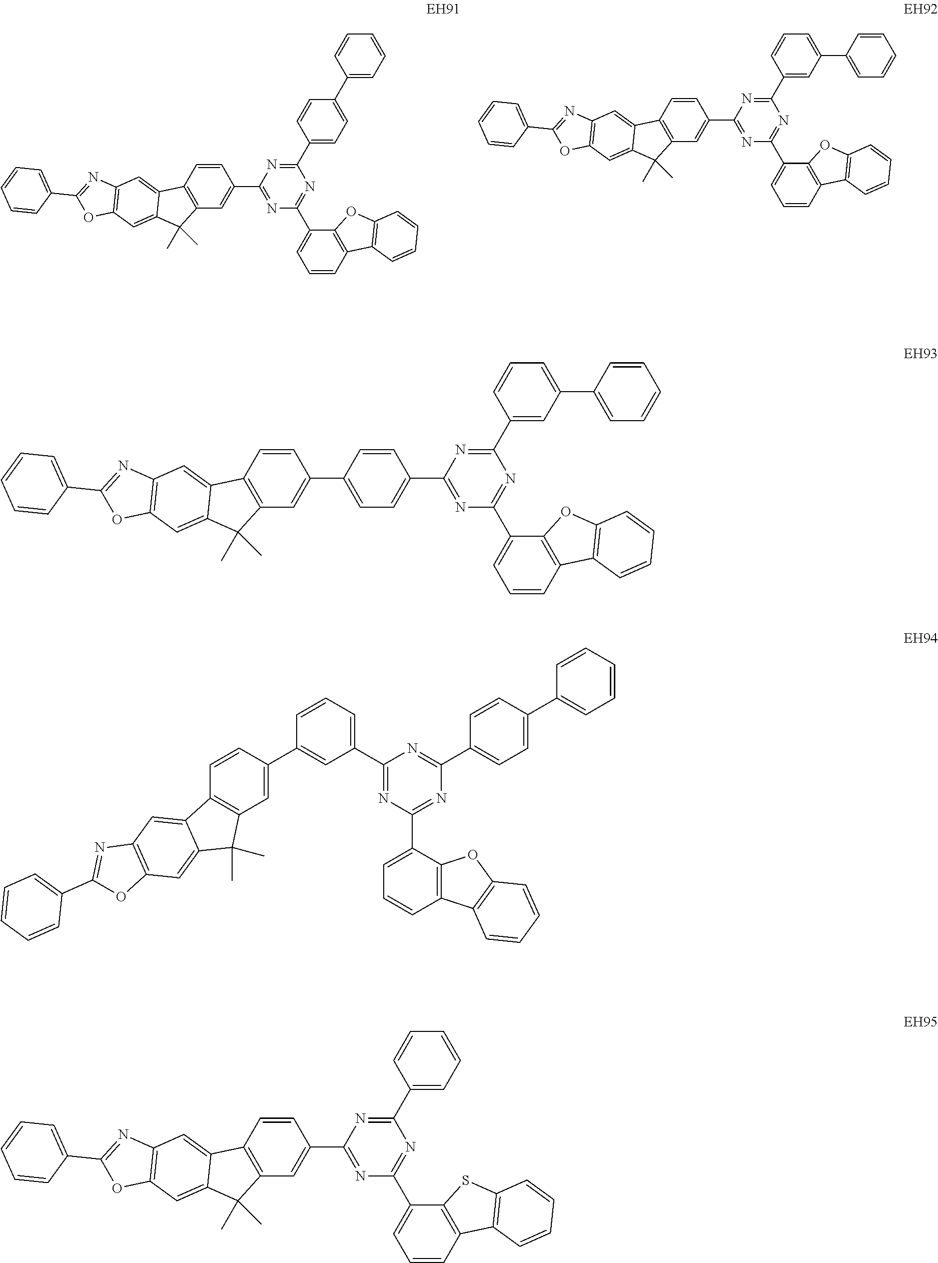 [SMILES: CC1(C)c2cc(-c3nc(-c4ccc(-c5ccccc5)cc4)nc(-c4cccc5c4oc4ccccc45)n3)ccc2-c2cc3nc(-c4ccccc4)oc3cc21 ; CC1(C)c2cc(-c3nc(-c4cccc(-c5ccccc5)c4)nc(-c4cccc5c4oc4ccccc45)n3)ccc2-c2cc3nc(-c4ccccc4)oc3cc21 ; CC1(C)c2cc(-c3ccc(-c4nc(-c5cccc(-c6ccccc6)c5)nc(-c5cccc6c5oc5ccccc56)n4)cc3)ccc2-c2cc3nc(-c4ccccc4)oc3cc21 ; CC1(C)c2cc(-c3cccc(-c4nc(-c5ccc(-c6ccccc6)cc5)nc(-c5cccc6c5oc5ccccc56)n4)c3)ccc2-c2cc3nc(-c4ccccc4)oc3cc21 ; CC1(C)c2cc(-c3nc(-c4ccccc4)nc(-c4cccc5c4sc4ccccc45)n3)ccc2-c2cc3nc(-c4ccccc4)oc3cc21]

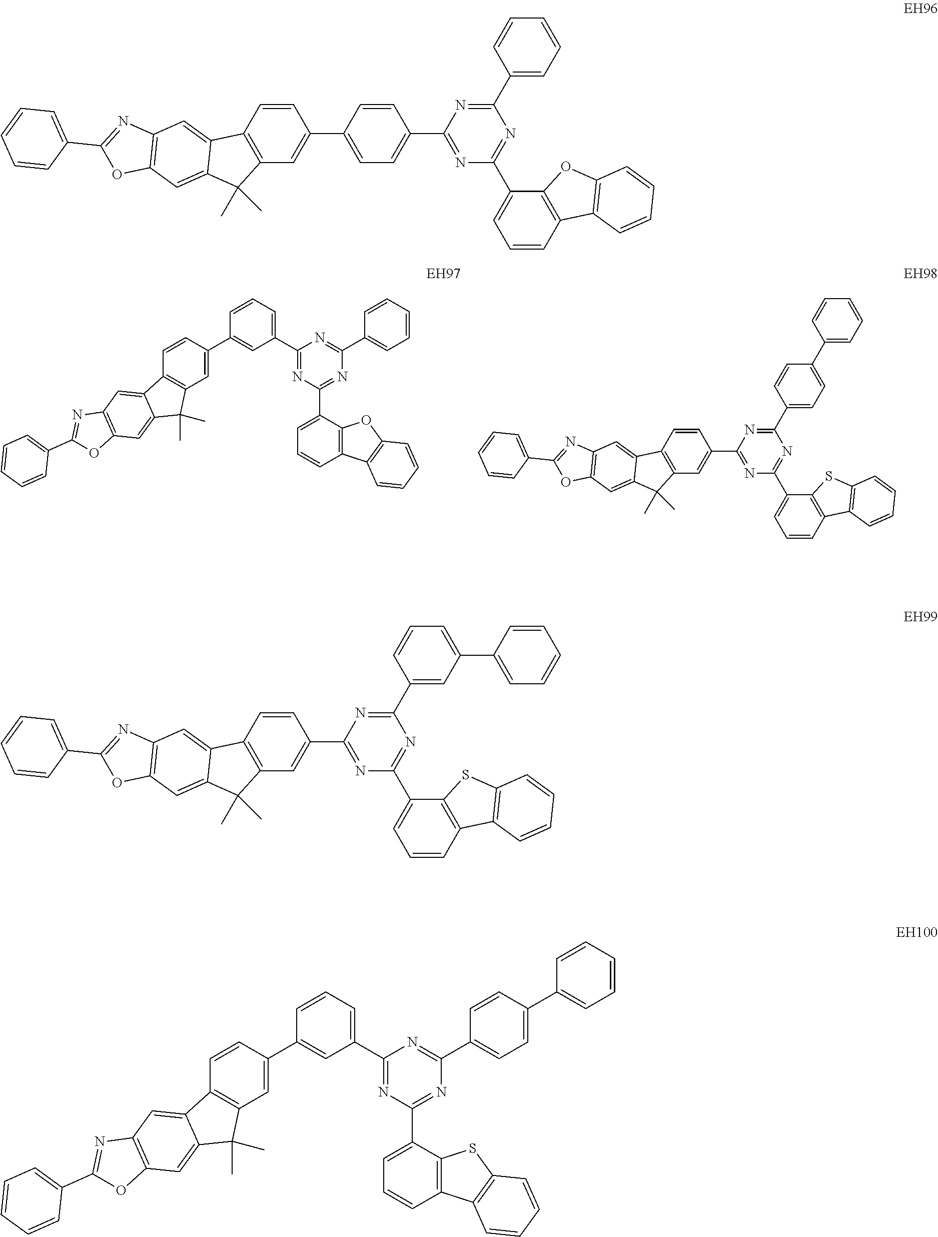 [SMILES: CC1(C)c2cc(-c3ccc(-c4nc(-c5ccccc5)nc(-c5cccc6c5oc5ccccc56)n4)cc3)ccc2-c2cc3nc(-c4ccccc4)oc3cc21 ; CC1(C)c2cc(-c3cccc(-c4nc(-c5ccccc5)nc(-c5cccc6c5oc5ccccc56)n4)c3)ccc2-c2cc3nc(-c4ccccc4)oc3cc21 ; CC1(C)c2cc(-c3nc(-c4ccc(-c5ccccc5)cc4)nc(-c4cccc5c4sc4ccccc45)n3)ccc2-c2cc3nc(-c4ccccc4)oc3cc21 ; CC1(C)c2cc(-c3nc(-c4cccc(-c5ccccc5)c4)nc(-c4cccc5c4sc4ccccc45)n3)ccc2-c2cc3nc(-c4ccccc4)oc3cc21 ; CC1(C)c2cc(-c3cccc(-c4nc(-c5ccc(-c6ccccc6)cc5)nc(-c5cccc6c5sc5ccccc56)n4)c3)ccc2-c2cc3nc(-c4ccccc4)oc3cc21]

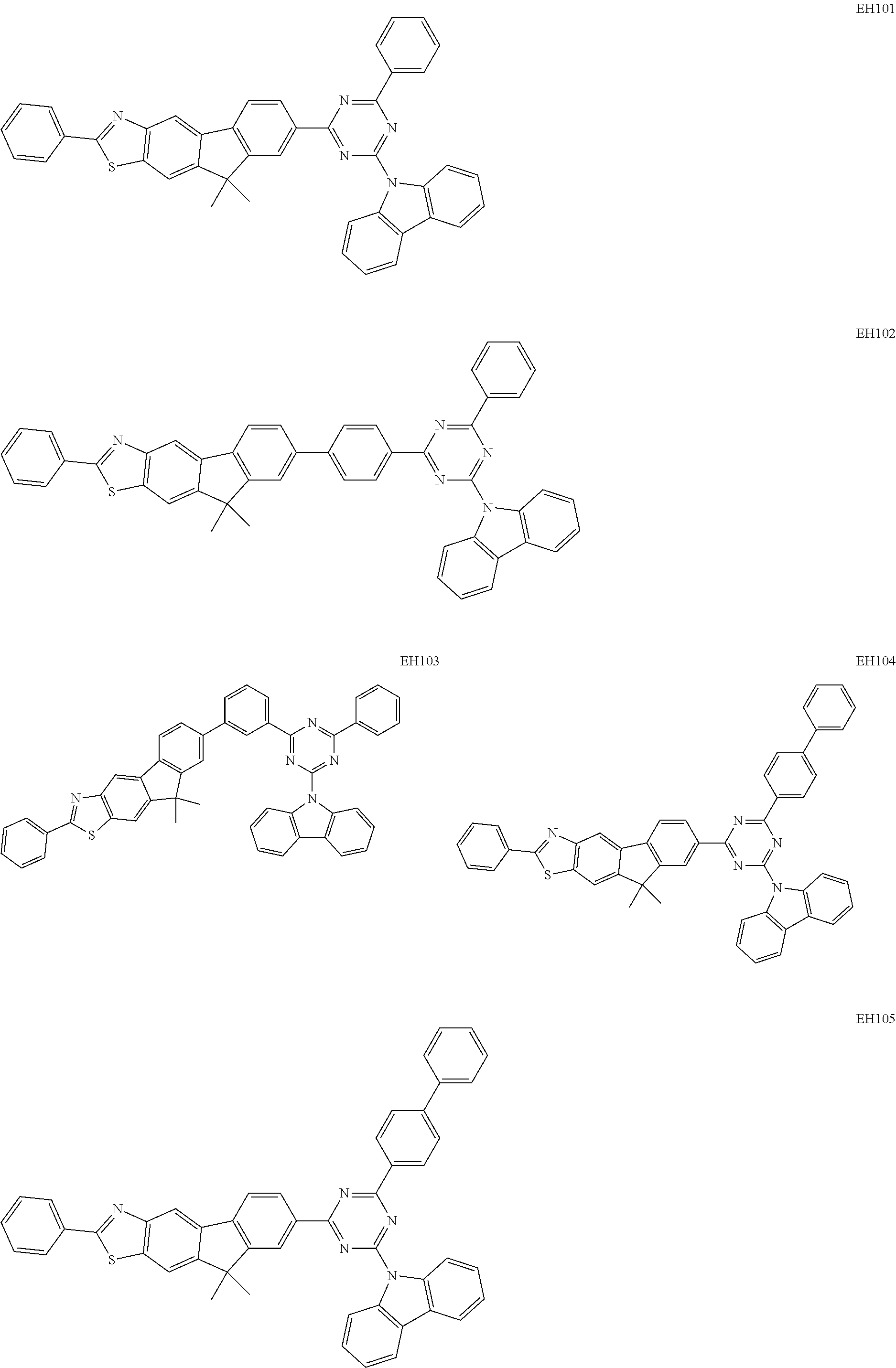 [SMILES: CC1(C)c2cc(-c3nc(-c4ccccc4)nc(-n4c5ccccc5c5ccccc54)n3)ccc2-c2cc3nc(-c4ccccc4)sc3cc21 ; CC1(C)c2cc(-c3ccc(-c4nc(-c5ccccc5)nc(-n5c6ccccc6c6ccccc65)n4)cc3)ccc2-c2cc3nc(-c4ccccc4)sc3cc21 ; CC1(C)c2cc(-c3cccc(-c4nc(-c5ccccc5)nc(-n5c6ccccc6c6ccccc65)n4)c3)ccc2-c2cc3nc(-c4ccccc4)sc3cc21 ; CC1(C)c2cc(-c3nc(-c4ccc(-c5ccccc5)cc4)nc(-n4c5ccccc5c5ccccc54)n3)ccc2-c2cc3nc(-c4ccccc4)sc3cc21 ; CC1(C)c2cc(-c3nc(-c4ccc(-c5ccccc5)cc4)nc(-n4c5ccccc5c5ccccc54)n3)ccc2-c2cc3nc(-c4ccccc4)sc3cc21]

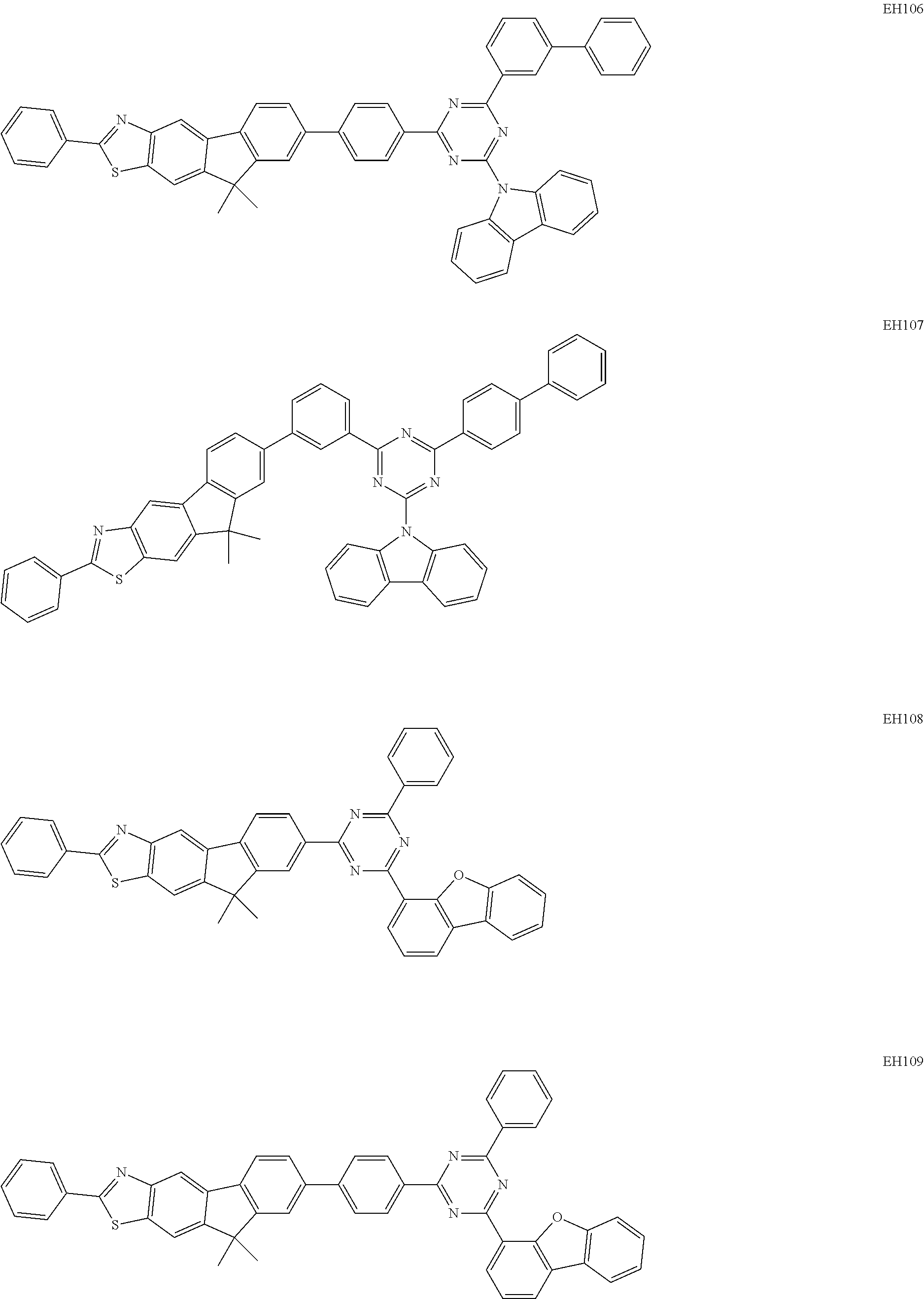 [SMILES: CC1(C)c2cc(-c3ccc(-c4nc(-c5cccc(-c6ccccc6)c5)nc(-n5c6ccccc6c6ccccc65)n4)cc3)ccc2-c2cc3nc(-c4ccccc4)sc3cc21 ; CC1(C)c2cc(-c3cccc(-c4nc(-c5ccc(-c6ccccc6)cc5)nc(-n5c6ccccc6c6ccccc65)n4)c3)ccc2-c2cc3nc(-c4ccccc4)sc3cc21 ; CC1(C)c2cc(-c3nc(-c4ccccc4)nc(-c4cccc5c4oc4ccccc45)n3)ccc2-c2cc3nc(-c4ccccc4)sc3cc21 ; CC1(C)c2cc(-c3ccc(-c4nc(-c5ccccc5)nc(-c5cccc6c5oc5ccccc56)n4)cc3)ccc2-c2cc3nc(-c4ccccc4)sc3cc21]

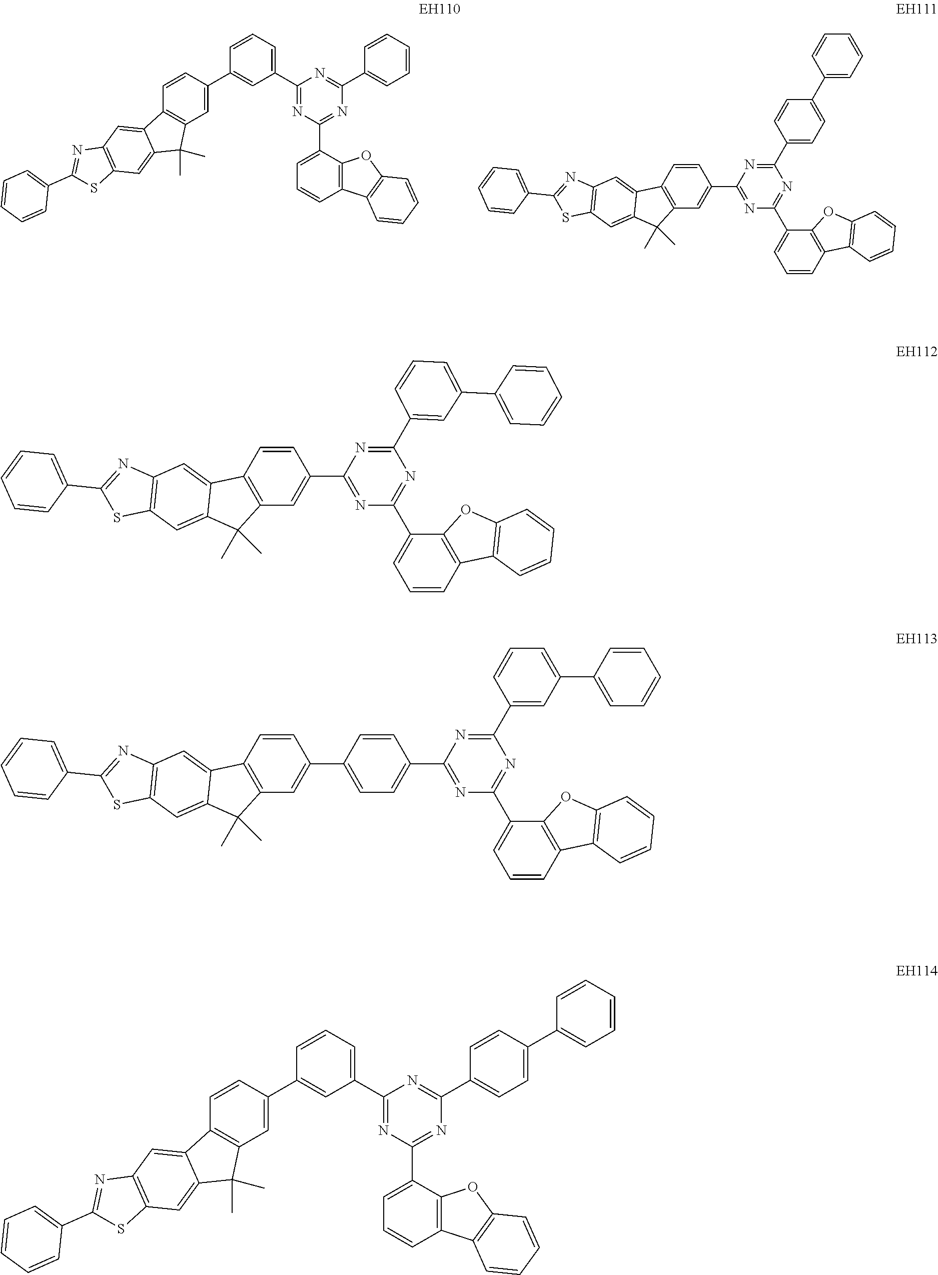

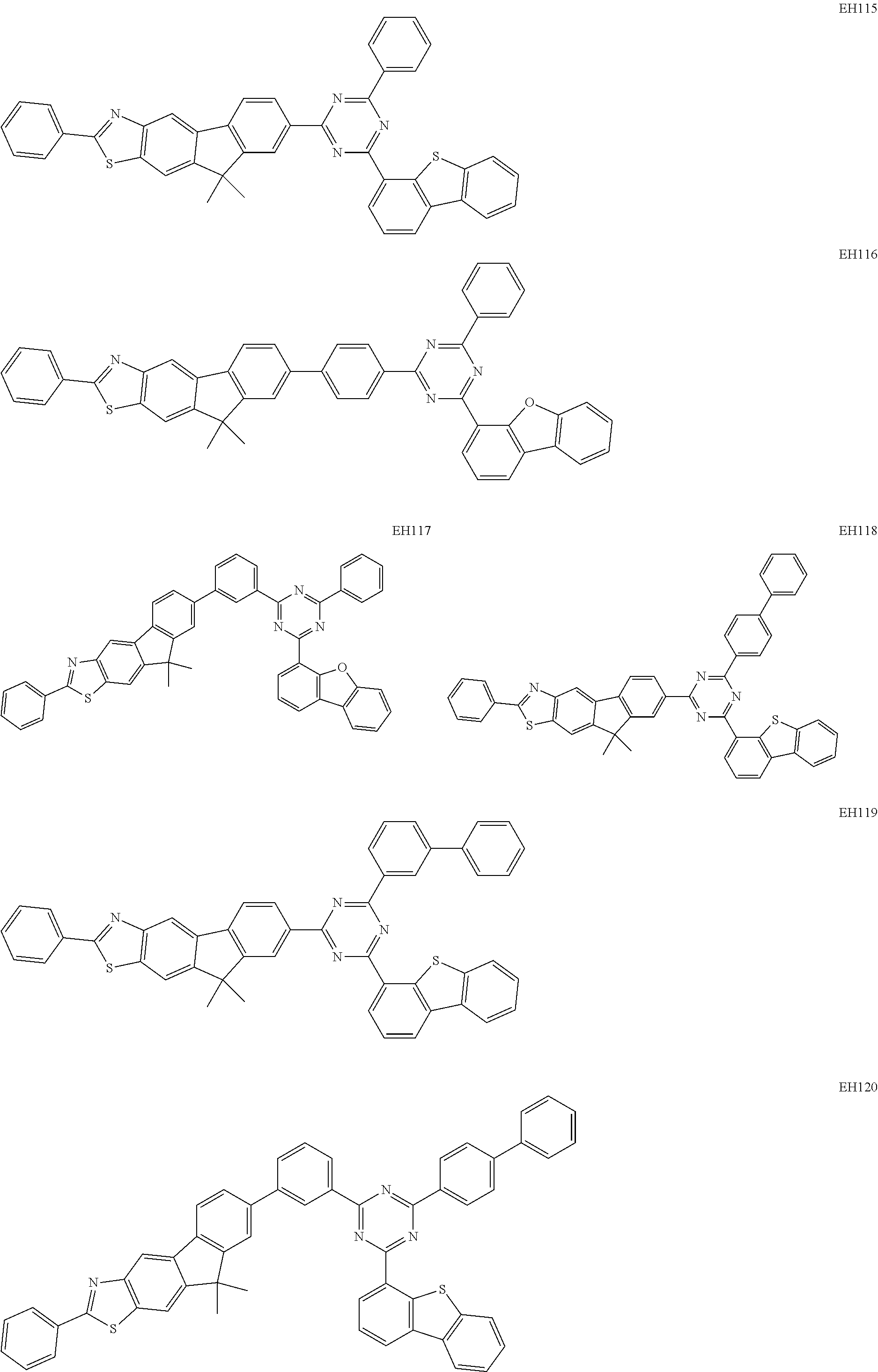

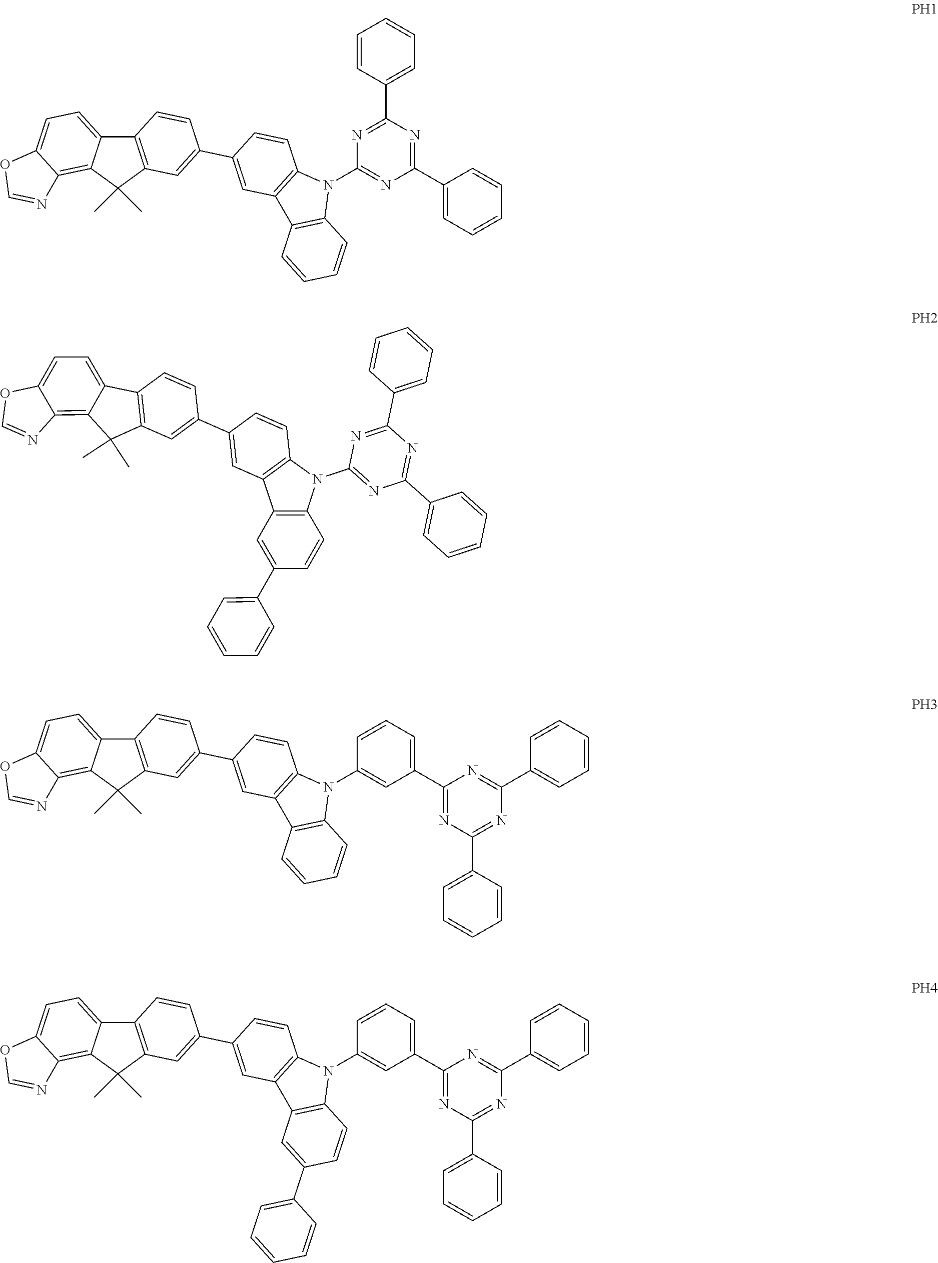 [SMILES: CC1(C)c2cc(-c3ccc4c(c3)c3ccccc3n4-c3nc(-c4ccccc4)nc(-c4ccccc4)n3)ccc2-c2ccc3ocnc3c21 ; CC1(C)c2cc(-c3ccc4c(c3)c3cc(-c5ccccc5)ccc3n4-c3nc(-c4ccccc4)nc(-c4ccccc4)n3)ccc2-c2ccc3ocnc3c21 ; CC1(C)c2cc(-c3ccc4c(c3)c3ccccc3n4-c3cccc(-c4nc(-c5ccccc5)nc(-c5ccccc5)n4)c3)ccc2-c2ccc3ocnc3c21 ; CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2ccc3ocnc3c21]

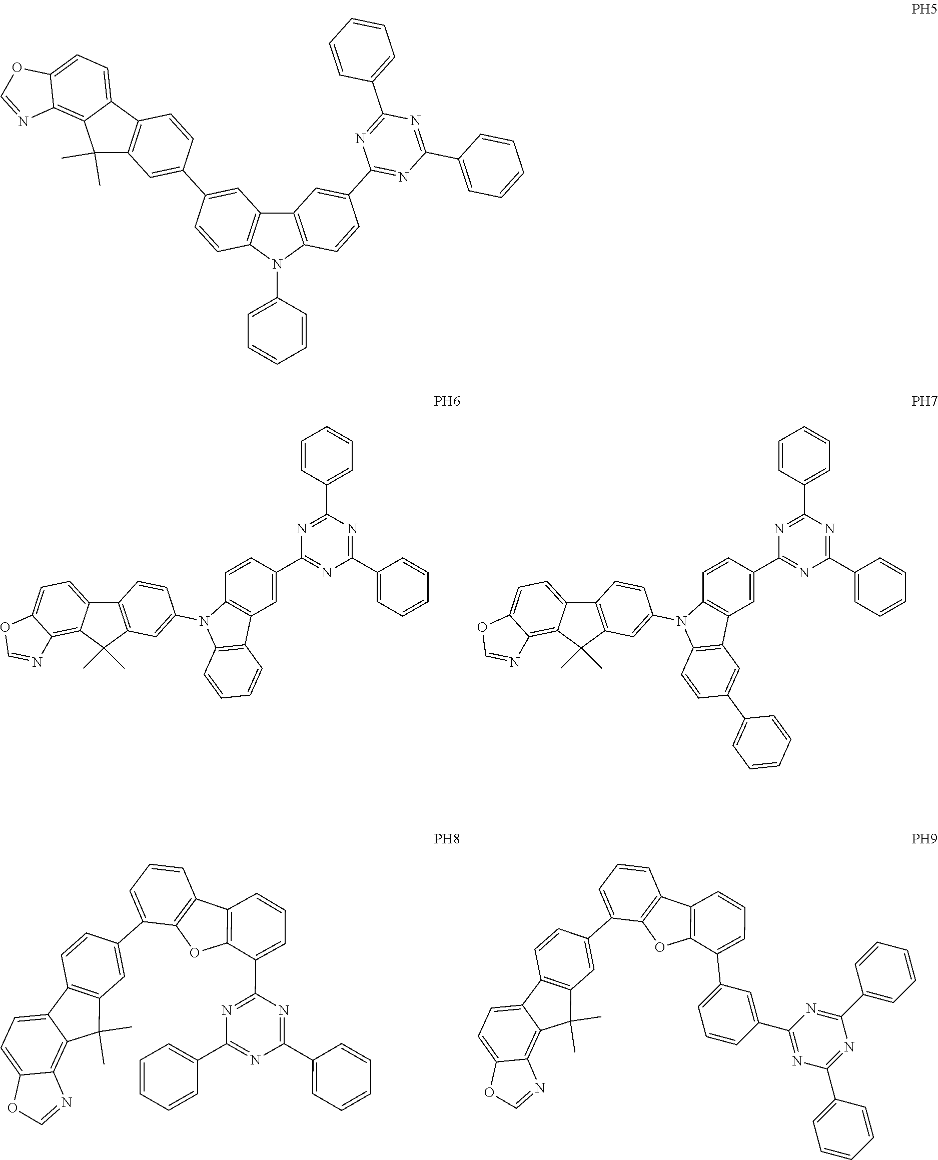 [SMILES: CC1(C)c2cc(-c3ccc4c(c3)c3cc(-c5nc(-c6ccccc6)nc(-c6ccccc6)n5)ccc3n4-c3ccccc3)ccc2-c2ccc3ocnc3c21 ; CC1(C)c2cc(-n3c4ccccc4c4cc(-c5nc(-c6ccccc6)nc(-c6ccccc6)n5)ccc43)ccc2-c2ccc3ocnc3c21 ; CC1(C)c2cc(-n3c4ccc(-c5ccccc5)cc4c4cc(-c5nc(-c6ccccc6)nc(-c6ccccc6)n5)ccc43)ccc2-c2ccc3ocnc3c21 ; CC1(C)c2cc(-c3cccc4c3oc3c(-c5nc(-c6ccccc6)nc(-c6ccccc6)n5)cccc34)ccc2-c2ccc3ocnc3c21 ; CC1(C)c2cc(-c3cccc4c3oc3c(-c5cccc(-c6nc(-c7ccccc7)nc(-c7ccccc7)n6)c5)cccc34)ccc2-c2ccc3ocnc3c21]

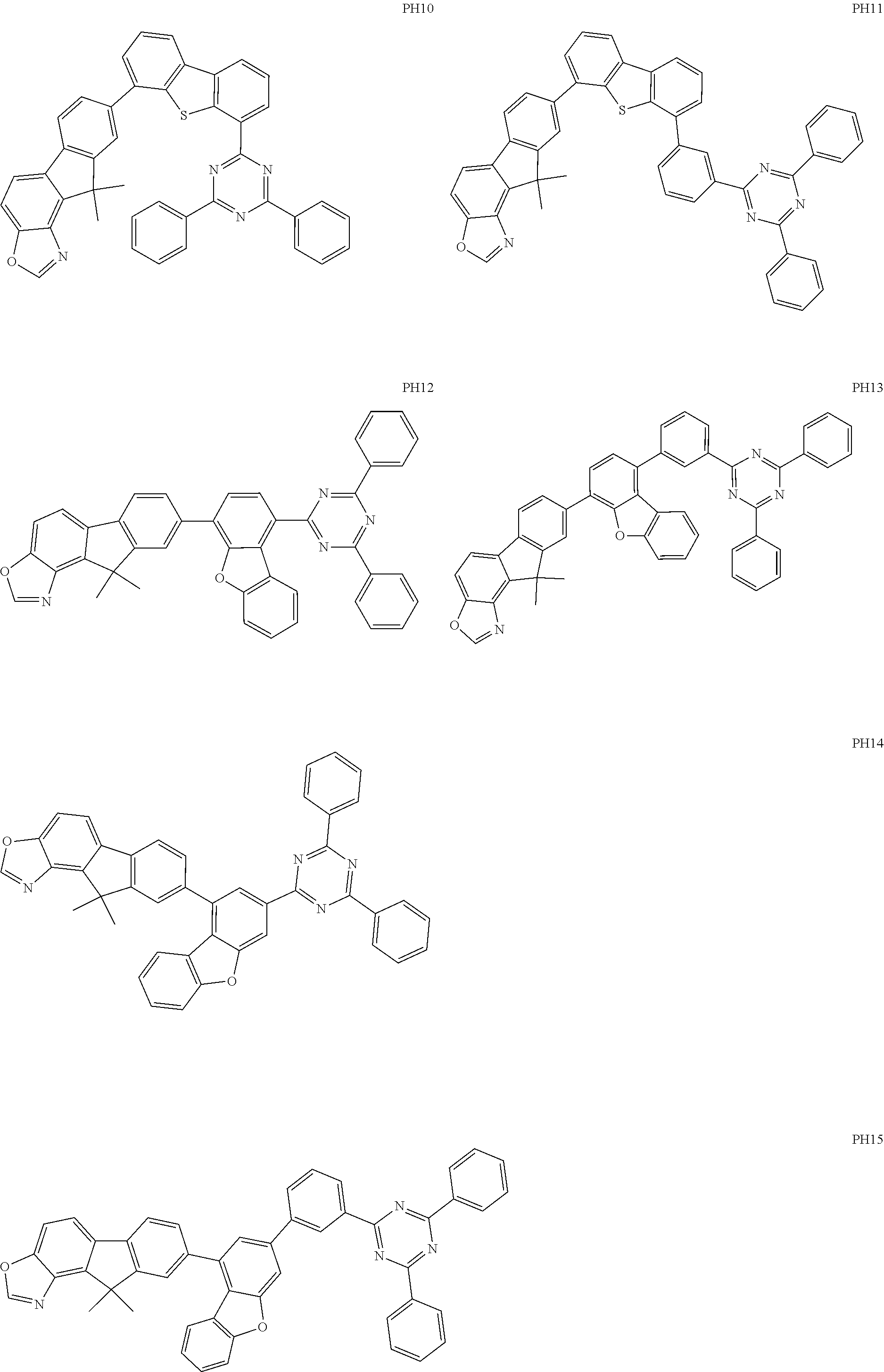

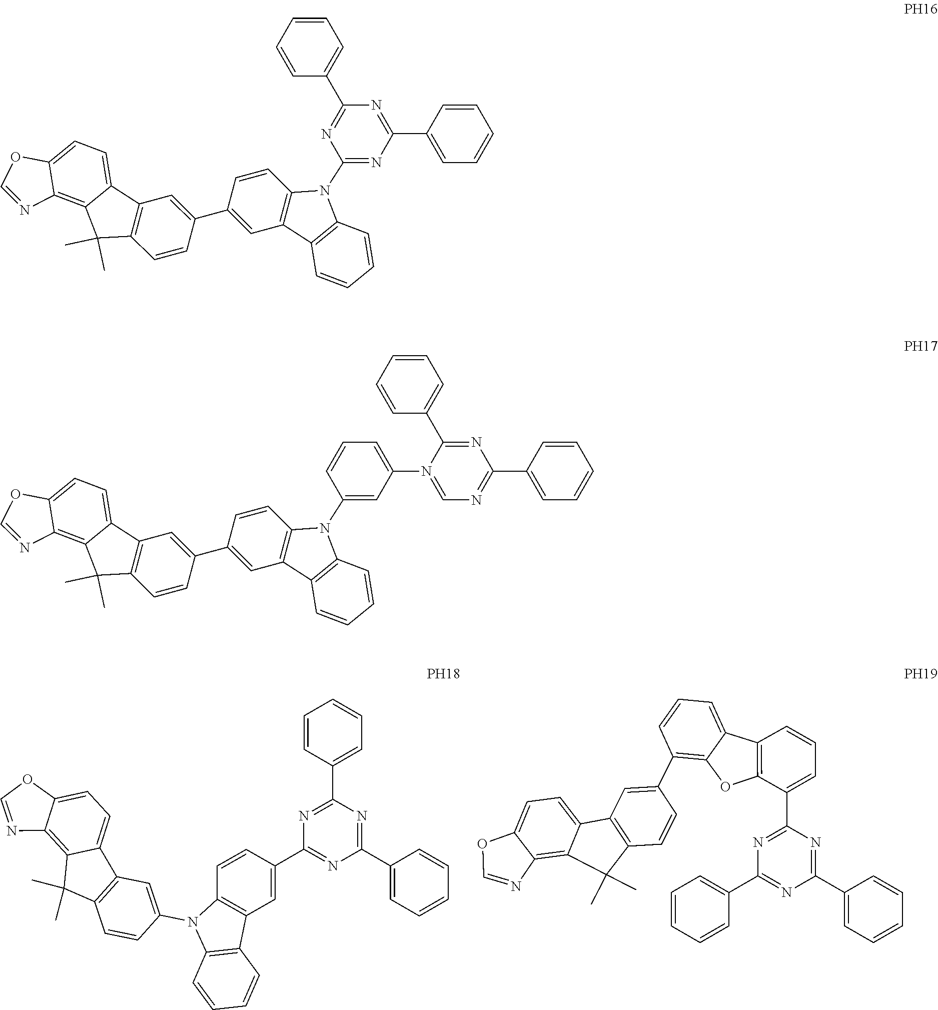

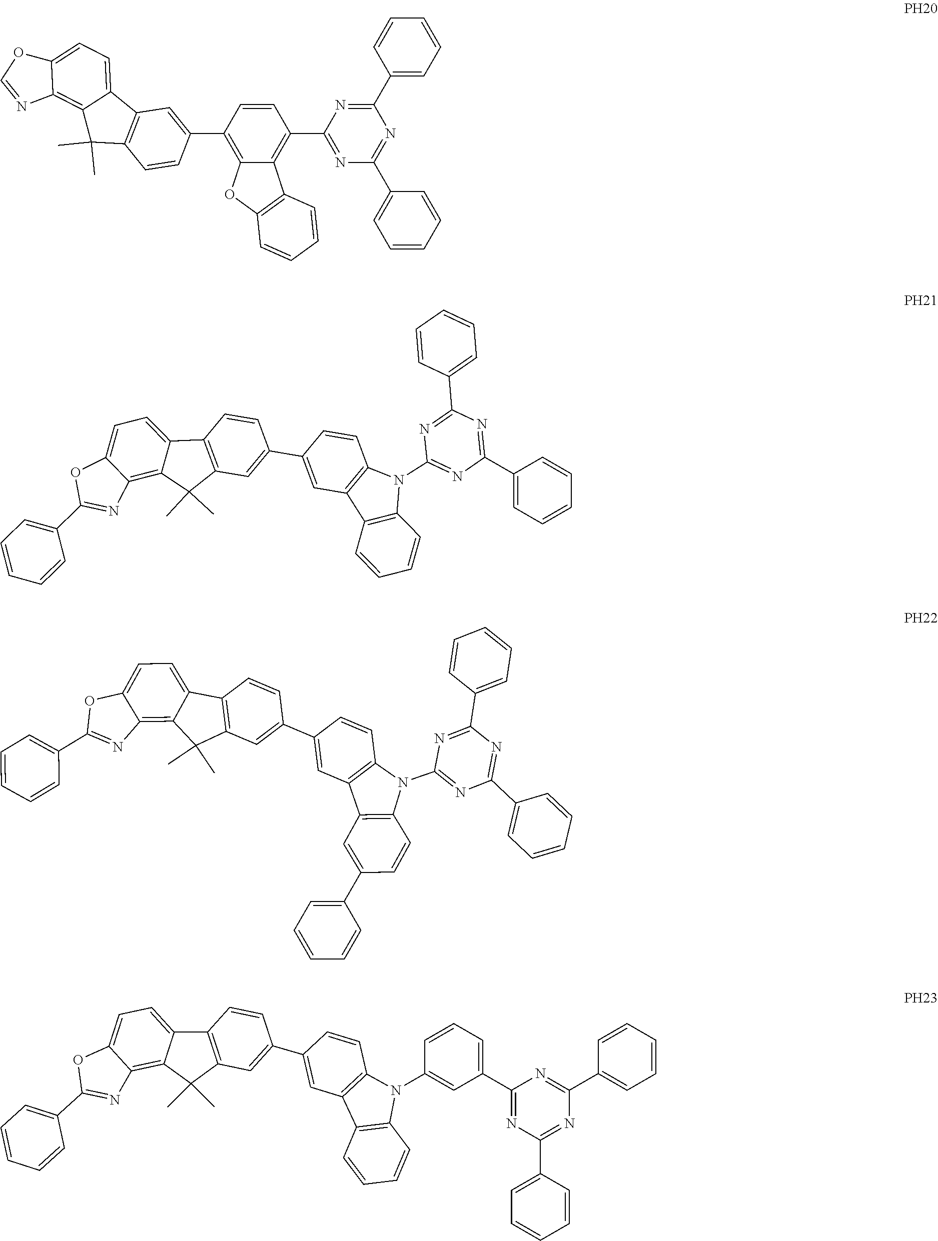 [SMILES: CC1(C)c2ccc(-c3ccc(-c4nc(-c5ccccc5)nc(-c5ccccc5)n4)c4c3oc3ccccc34)cc2-c2ccc3ocnc3c21 ; CC1(C)c2cc(-c3ccc4c(c3)c3ccccc3n4-c3nc(-c4ccccc4)nc(-c4ccccc4)n3)ccc2-c2ccc3oc(-c4ccccc4)nc3c21 ; CC1(C)c2cc(-c3ccc4c(c3)c3cc(-c5ccccc5)ccc3n4-c3nc(-c4ccccc4)nc(-c4ccccc4)n3)ccc2-c2ccc3oc(-c4ccccc4)nc3c21 ; CC1(C)c2cc(-c3ccc4c(c3)c3ccccc3n4-c3cccc(-c4nc(-c5ccccc5)nc(-c5ccccc5)n4)c3)ccc2-c2ccc3oc(-c4ccccc4)nc3c21]

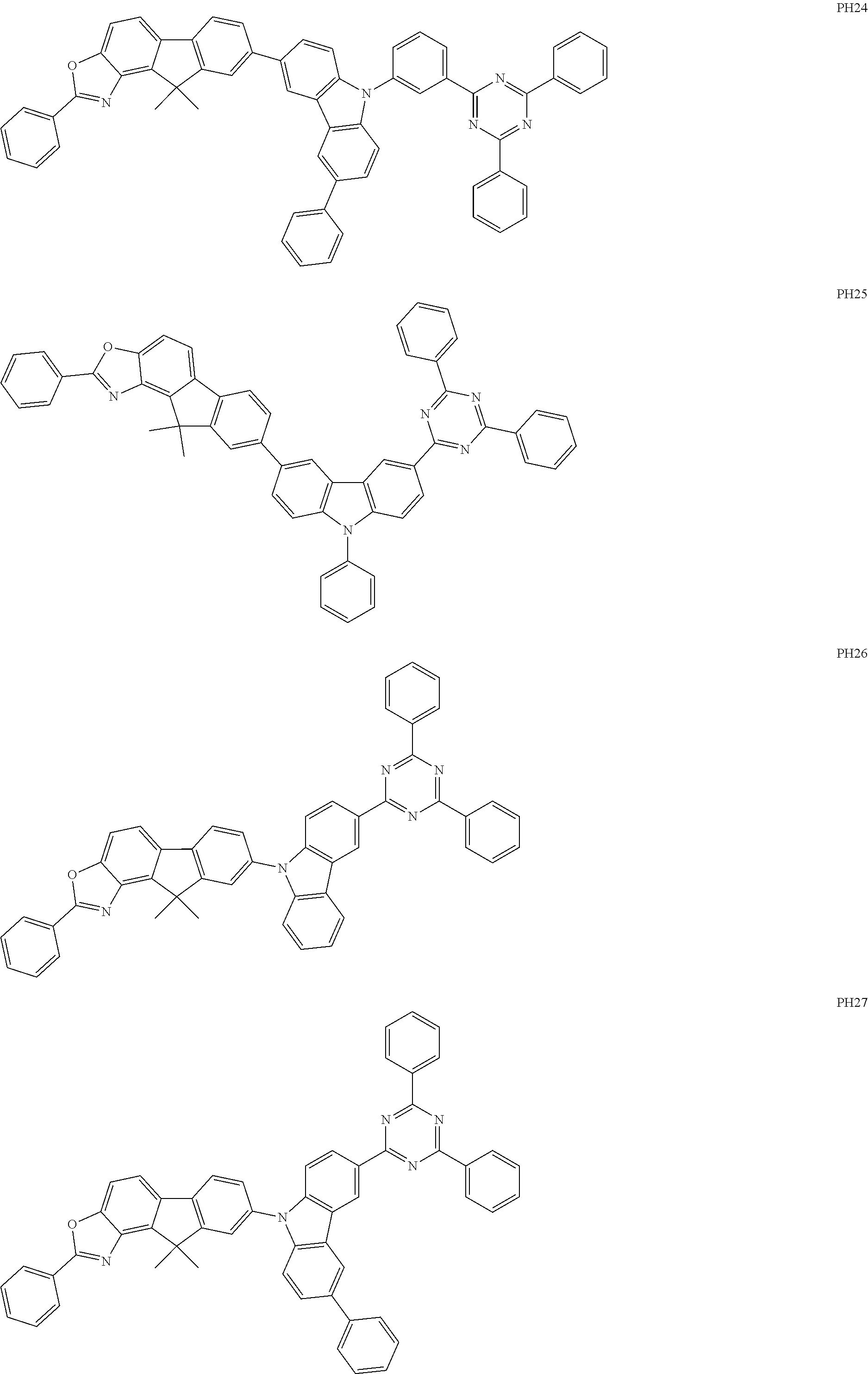 [SMILES: CC1(C)c2cc(-c3ccc4c(c3)c3cc(-c5ccccc5)ccc3n4-c3cccc(-c4nc(-c5ccccc5)nc(-c5ccccc5)n4)c3)ccc2-c2ccc3oc(-c4ccccc4)nc3c21 ; CC1(C)c2cc(-c3ccc4c(c3)c3cc(-c5nc(-c6ccccc6)nc(-c6ccccc6)n5)ccc3n4-c3ccccc3)ccc2-c2ccc3oc(-c4ccccc4)nc3c21 ; CC1(C)c2cc(-n3c4ccccc4c4cc(-c5nc(-c6ccccc6)nc(-c6ccccc6)n5)ccc43)ccc2-c2ccc3oc(-c4ccccc4)nc3c21 ; CC1(C)c2cc(-n3c4ccc(-c5ccccc5)cc4c4cc(-c5nc(-c6ccccc6)nc(-c6ccccc6)n5)ccc43)ccc2-c2ccc3oc(-c4ccccc4)nc3c21]

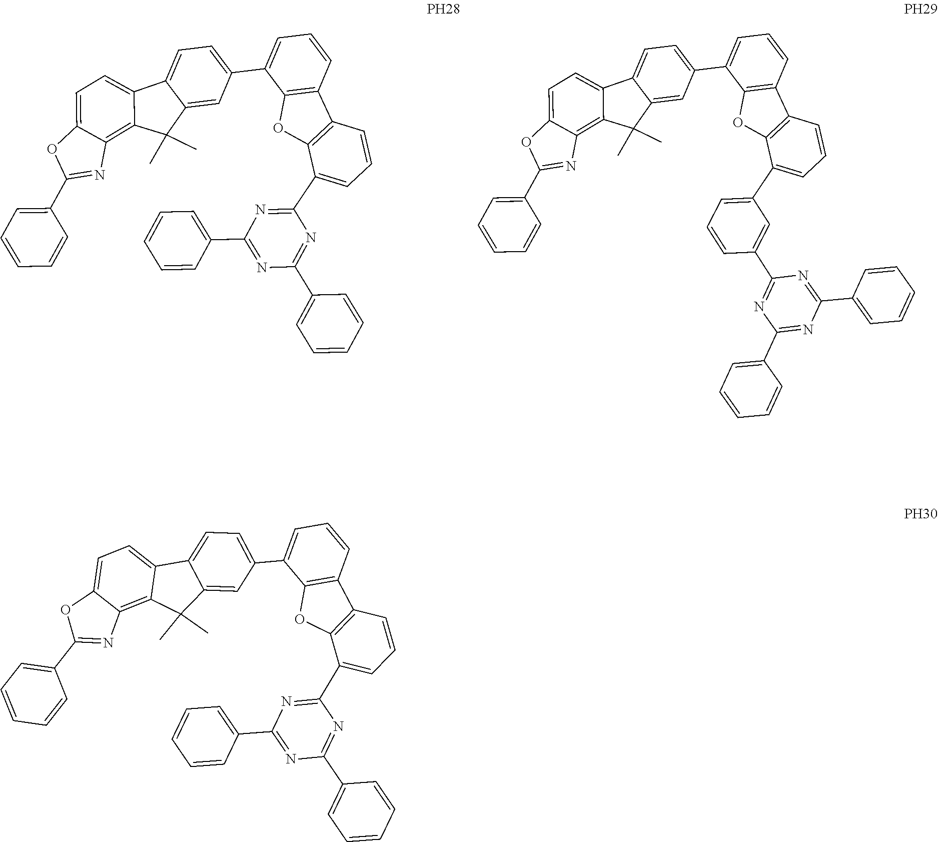 [SMILES: CC1(C)c2cc(-c3cccc4c3oc3c(-c5nc(-c6ccccc6)nc(-c6ccccc6)n5)cccc34)ccc2-c2ccc3oc(-c4ccccc4)nc3c21 ; CC1(C)c2cc(-c3cccc4c3oc3c(-c5cccc(-c6nc(-c7ccccc7)nc(-c7ccccc7)n6)c5)cccc34)ccc2-c2ccc3oc(-c4ccccc4)nc3c21 ; CC1(C)c2cc(-c3cccc4c3oc3c(-c5nc(-c6ccccc6)nc(-c6ccccc6)n5)cccc34)ccc2-c2ccc3oc(-c4ccccc4)nc3c21]

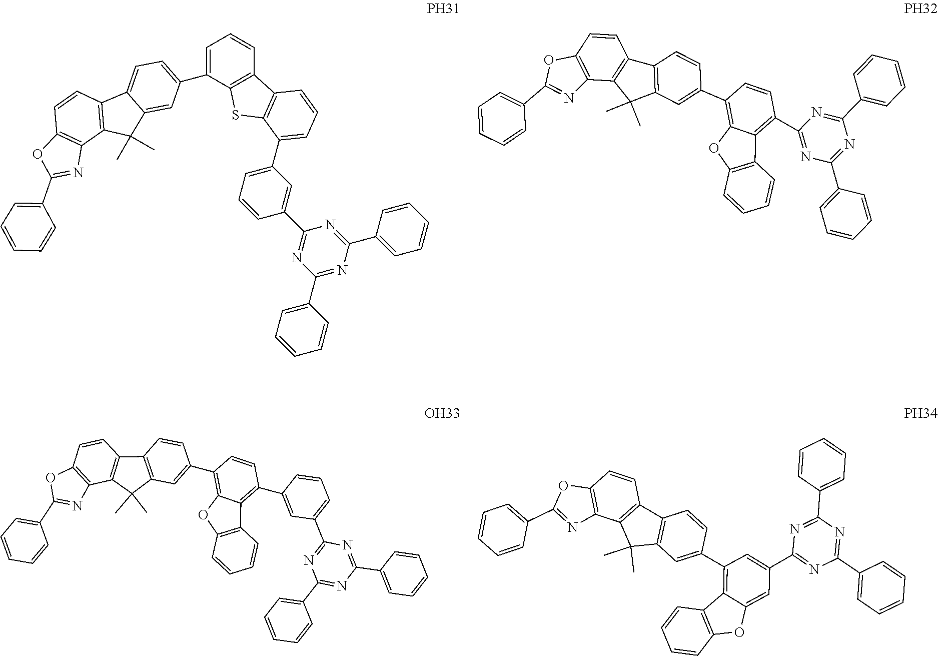 [SMILES: CC1(C)c2cc(-c3cccc4c3sc3c(-c5cccc(-c6nc(-c7ccccc7)nc(-c7ccccc7)n6)c5)cccc34)ccc2-c2ccc3oc(-c4ccccc4)nc3c21 ; CC1(C)c2cc(-c3ccc(-c4nc(-c5ccccc5)nc(-c5ccccc5)n4)c4c3oc3ccccc34)ccc2-c2ccc3oc(-c4ccccc4)nc3c21 ; CC1(C)c2cc(-c3ccc(-c4cccc(-c5nc(-c6ccccc6)nc(-c6ccccc6)n5)c4)c4c3oc3ccccc34)ccc2-c2ccc3oc(-c4ccccc4)nc3c21 ; CC1(C)c2cc(-c3cc(-c4nc(-c5ccccc5)nc(-c5ccccc5)n4)cc4oc5ccccc5c34)ccc2-c2ccc3oc(-c4ccccc4)nc3c21]

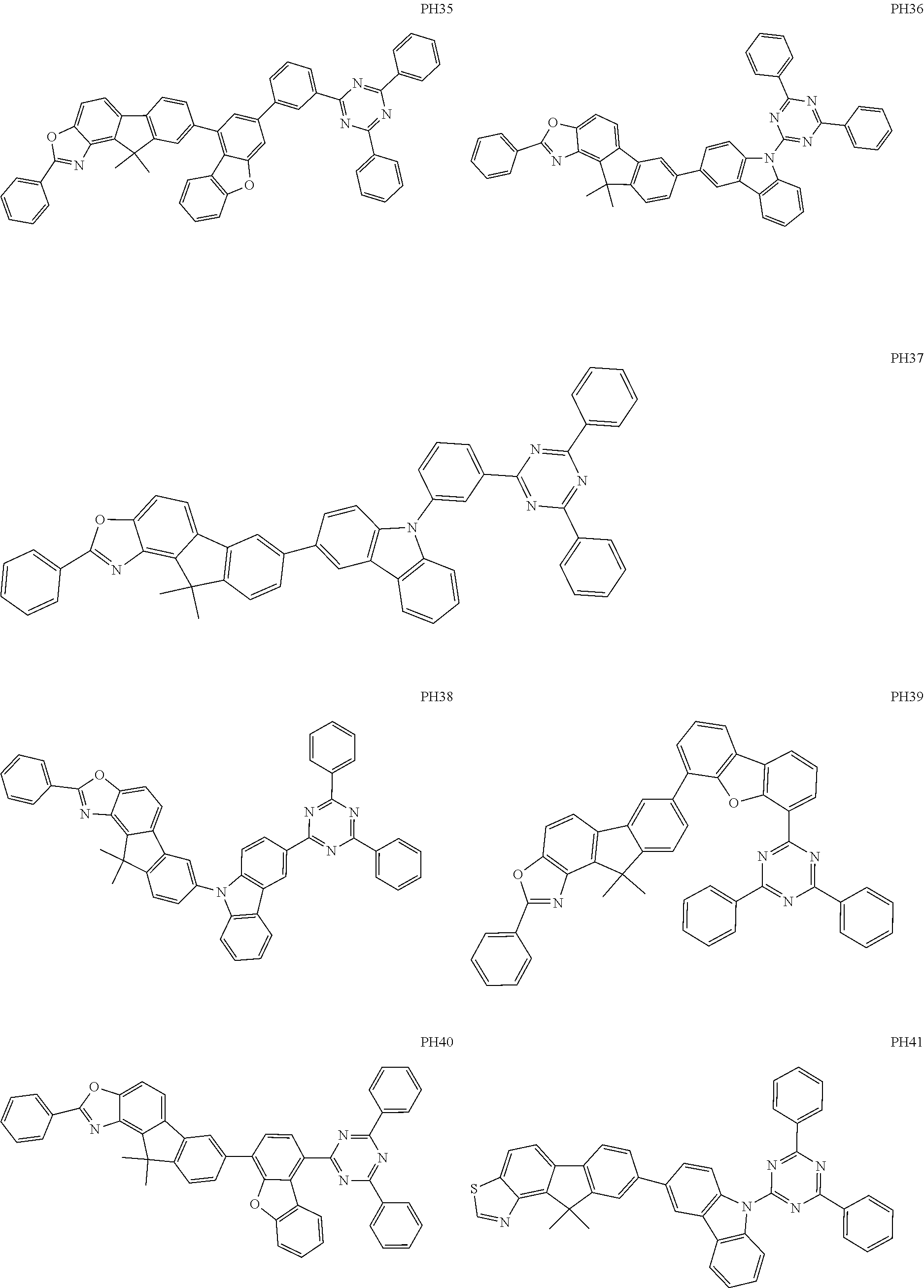

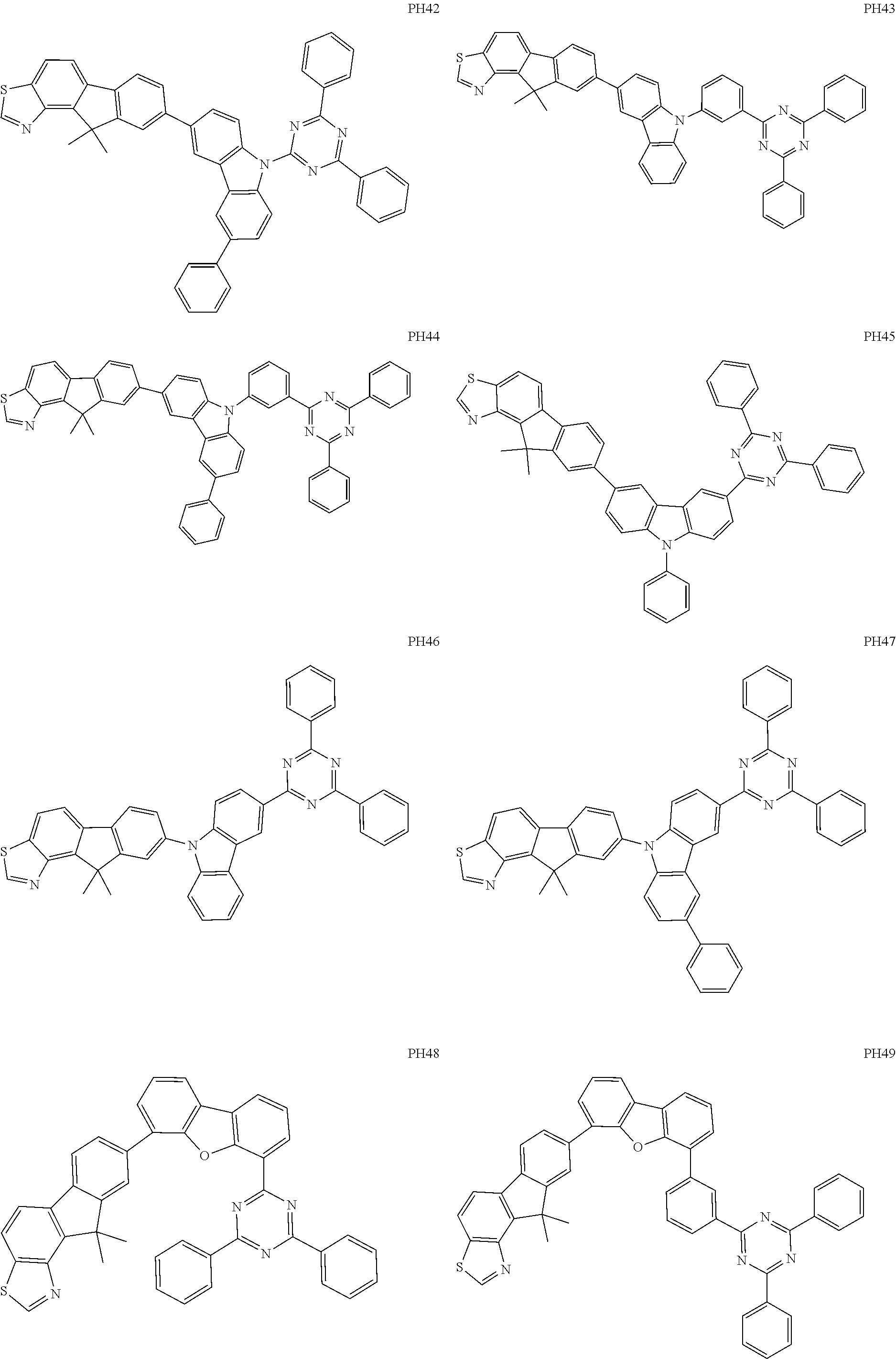

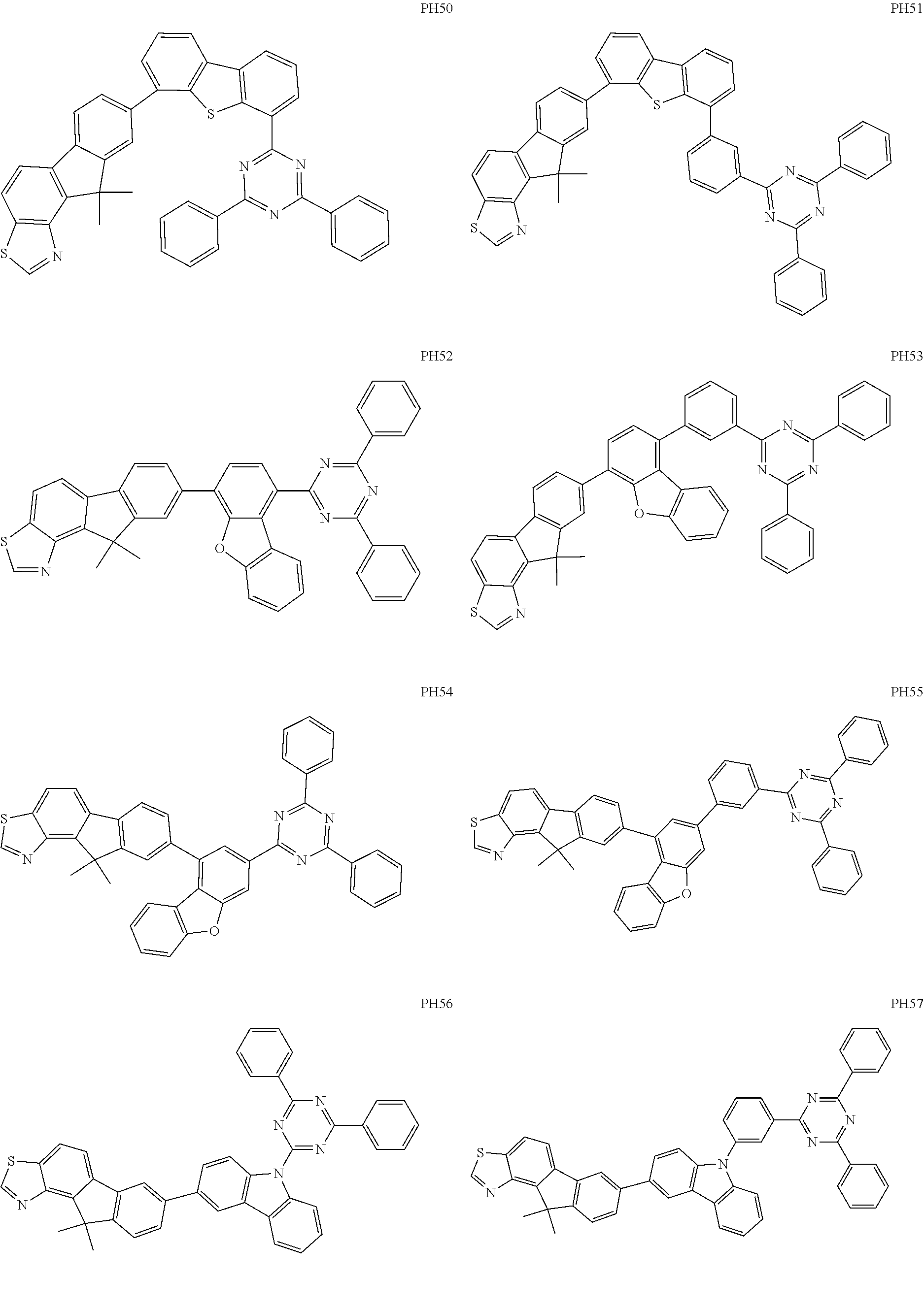

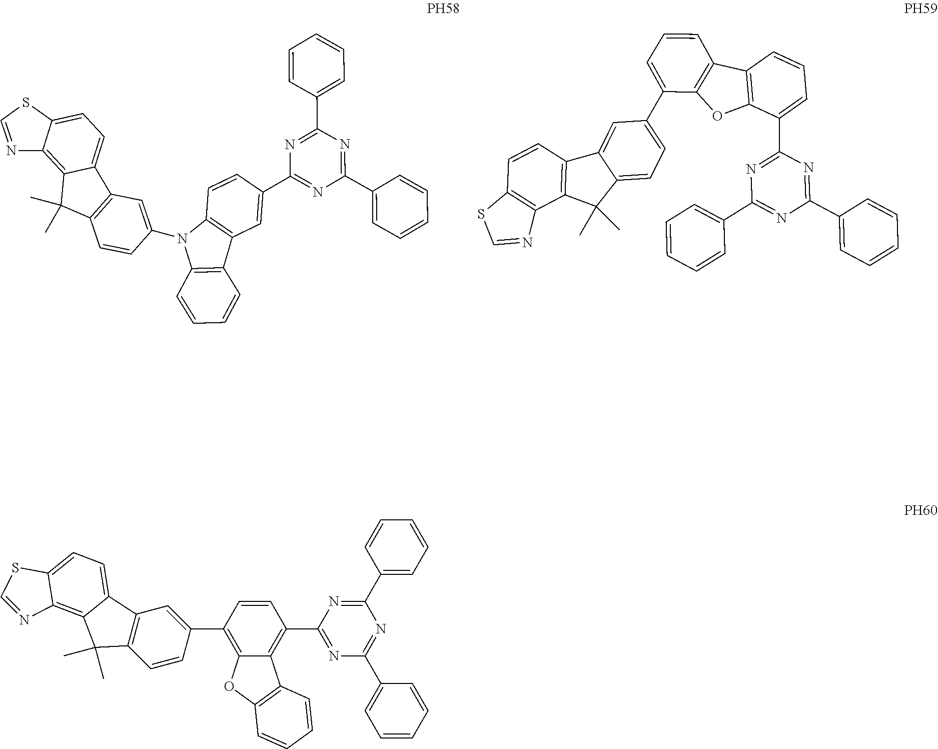 [SMILES: CC1(C)c2ccc(-n3c4ccccc4c4cc(-c5nc(-c6ccccc6)nc(-c6ccccc6)n5)ccc43)cc2-c2ccc3scnc3c21 ; CC1(C)c2ccc(-c3cccc4c3oc3c(-c5nc(-c6ccccc6)nc(-c6ccccc6)n5)cccc34)cc2-c2ccc3scnc3c21 ; CC1(C)c2ccc(-c3ccc(-c4nc(-c5ccccc5)nc(-c5ccccc5)n4)c4c3oc3ccccc34)cc2-c2ccc3scnc3c21]

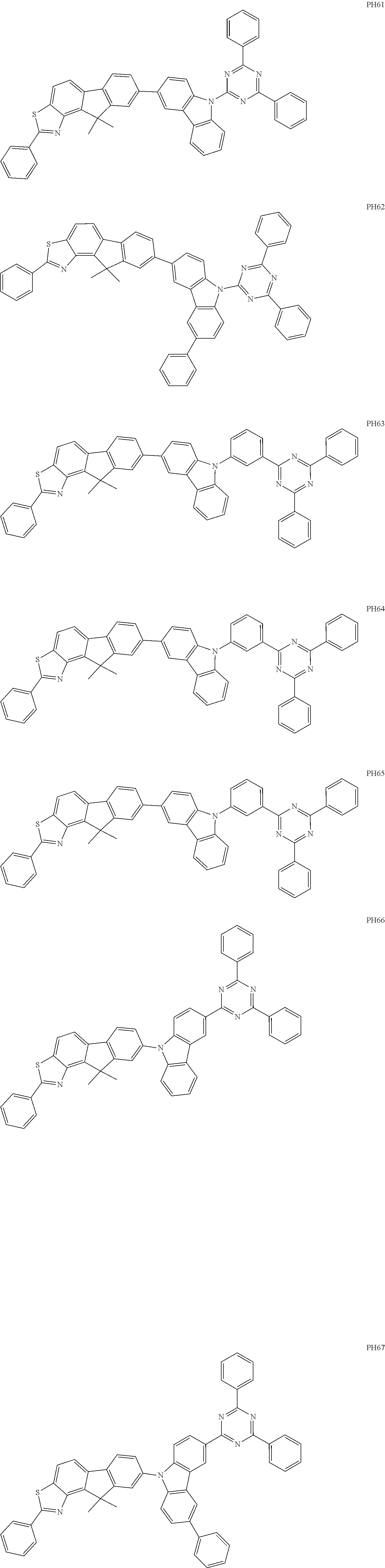

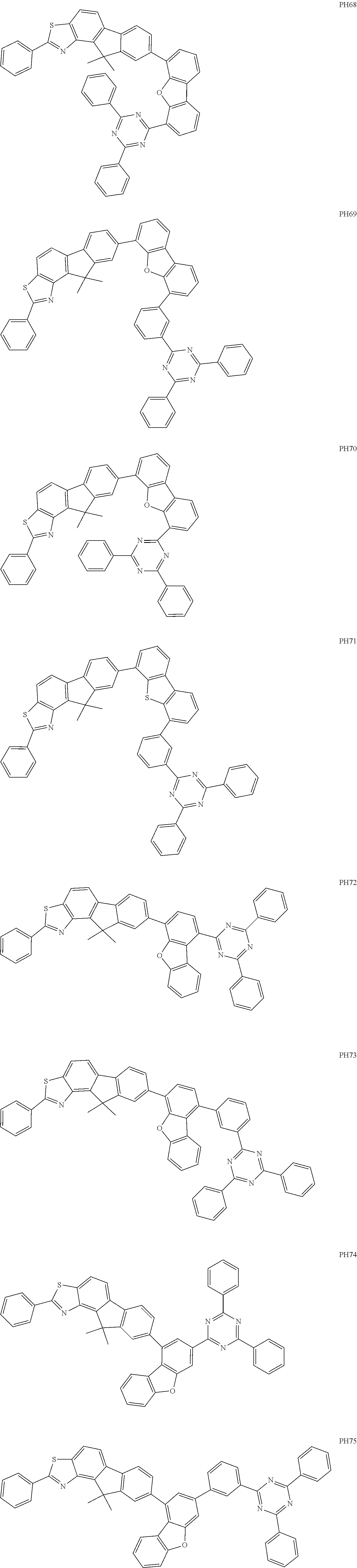

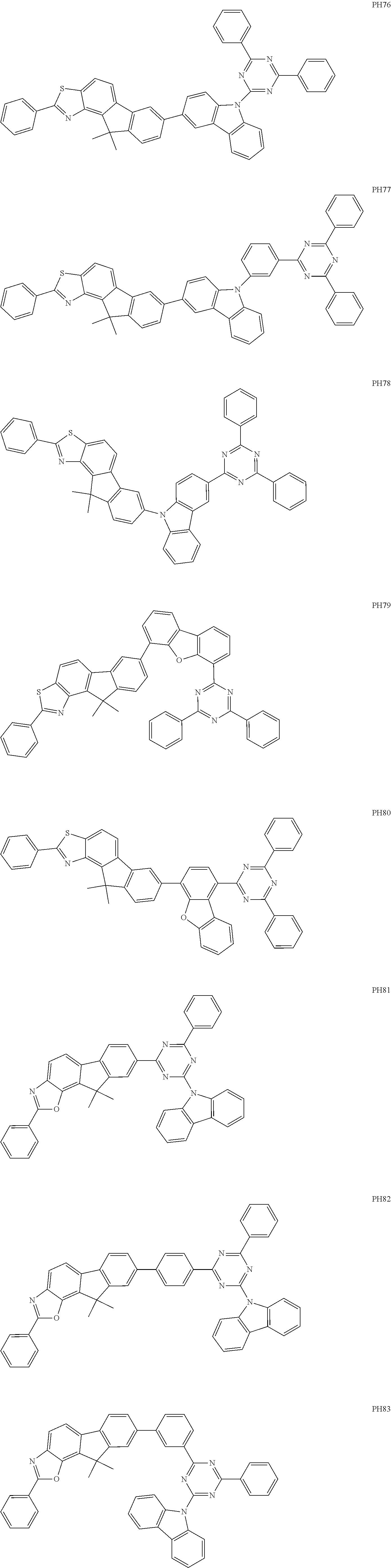

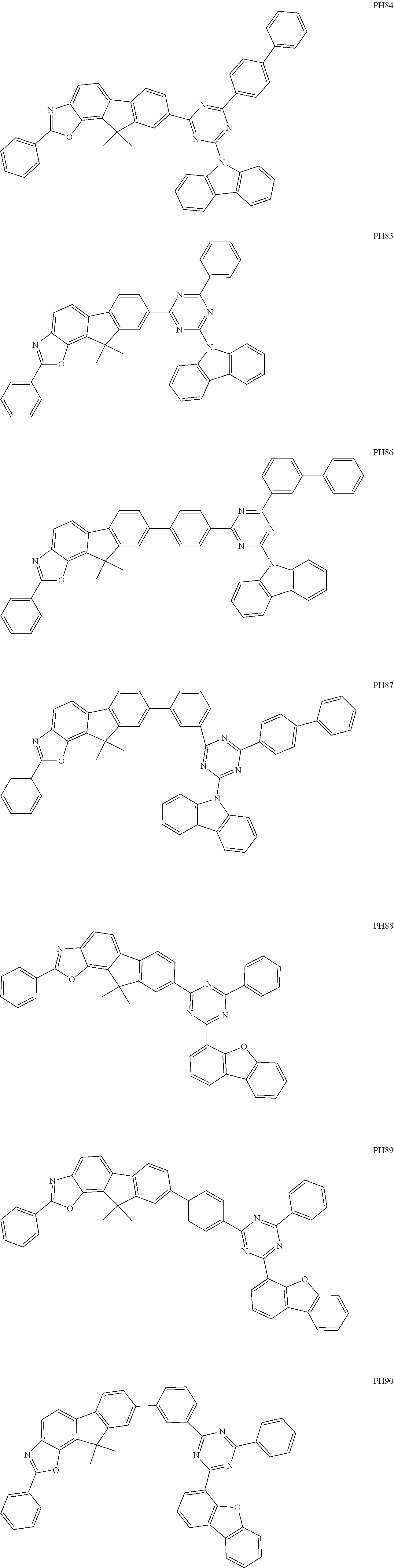

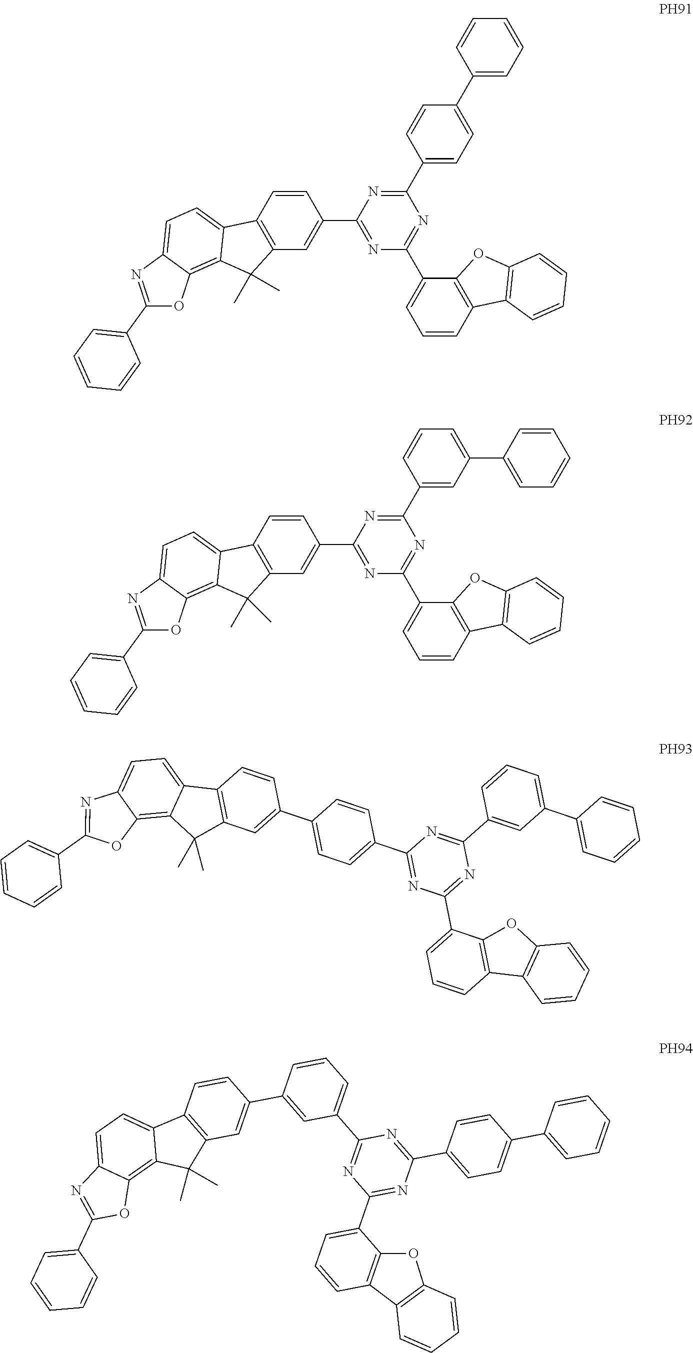 [SMILES: CC1(C)c2cc(-c3nc(-c4ccc(-c5ccccc5)cc4)nc(-c4cccc5c4oc4ccccc45)n3)ccc2-c2ccc3nc(-c4ccccc4)oc3c21 ; CC1(C)c2cc(-c3nc(-c4cccc(-c5ccccc5)c4)nc(-c4cccc5c4oc4ccccc45)n3)ccc2-c2ccc3nc(-c4ccccc4)oc3c21 ; CC1(C)c2cc(-c3ccc(-c4nc(-c5cccc(-c6ccccc6)c5)nc(-c5cccc6c5oc5ccccc56)n4)cc3)ccc2-c2ccc3nc(-c4ccccc4)oc3c21 ; CC1(C)c2cc(-c3cccc(-c4nc(-c5ccc(-c6ccccc6)cc5)nc(-c5cccc6c5oc5ccccc56)n4)c3)ccc2-c2ccc3nc(-c4ccccc4)oc3c21]

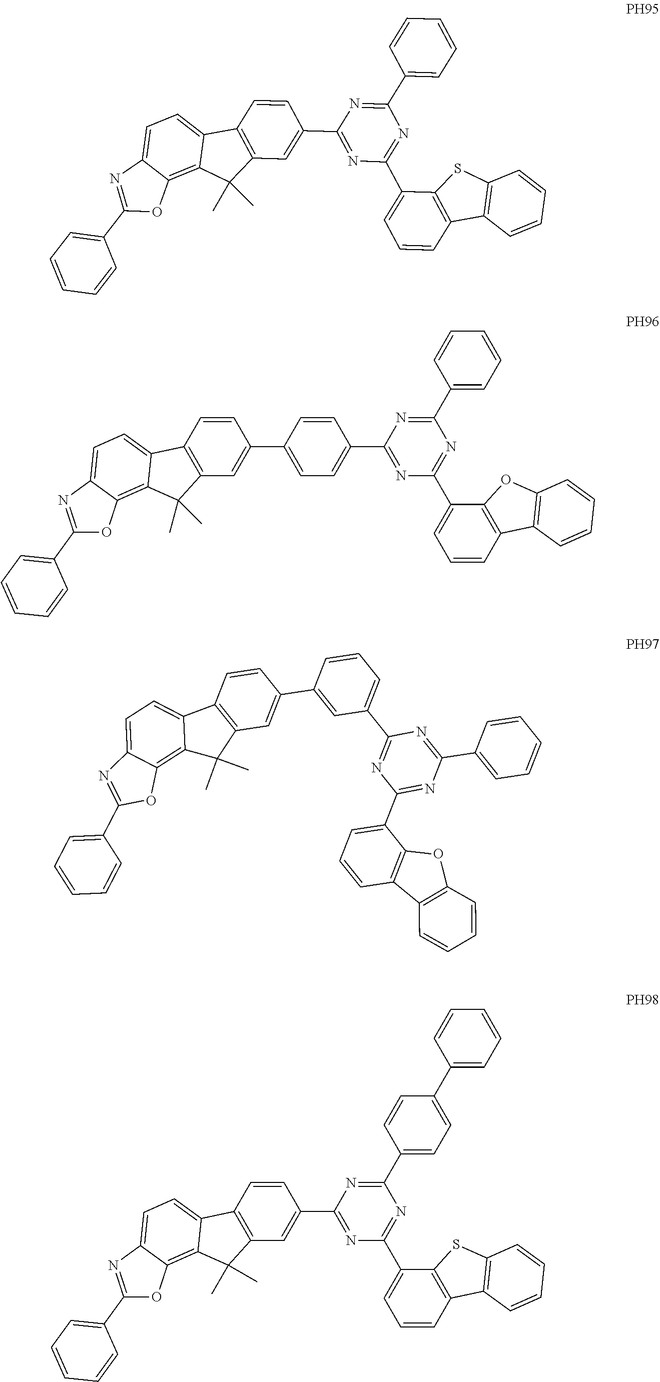 [SMILES: CC1(C)c2cc(-c3nc(-c4ccccc4)nc(-c4cccc5c4sc4ccccc45)n3)ccc2-c2ccc3nc(-c4ccccc4)oc3c21 ; CC1(C)c2cc(-c3ccc(-c4nc(-c5ccccc5)nc(-c5cccc6c5oc5ccccc56)n4)cc3)ccc2-c2ccc3nc(-c4ccccc4)oc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)oc3c21 ; CC1(C)c2cc(-c3nc(-c4ccc(-c5ccccc5)cc4)nc(-c4cccc5c4sc4ccccc45)n3)ccc2-c2ccc3nc(-c4ccccc4)oc3c21]

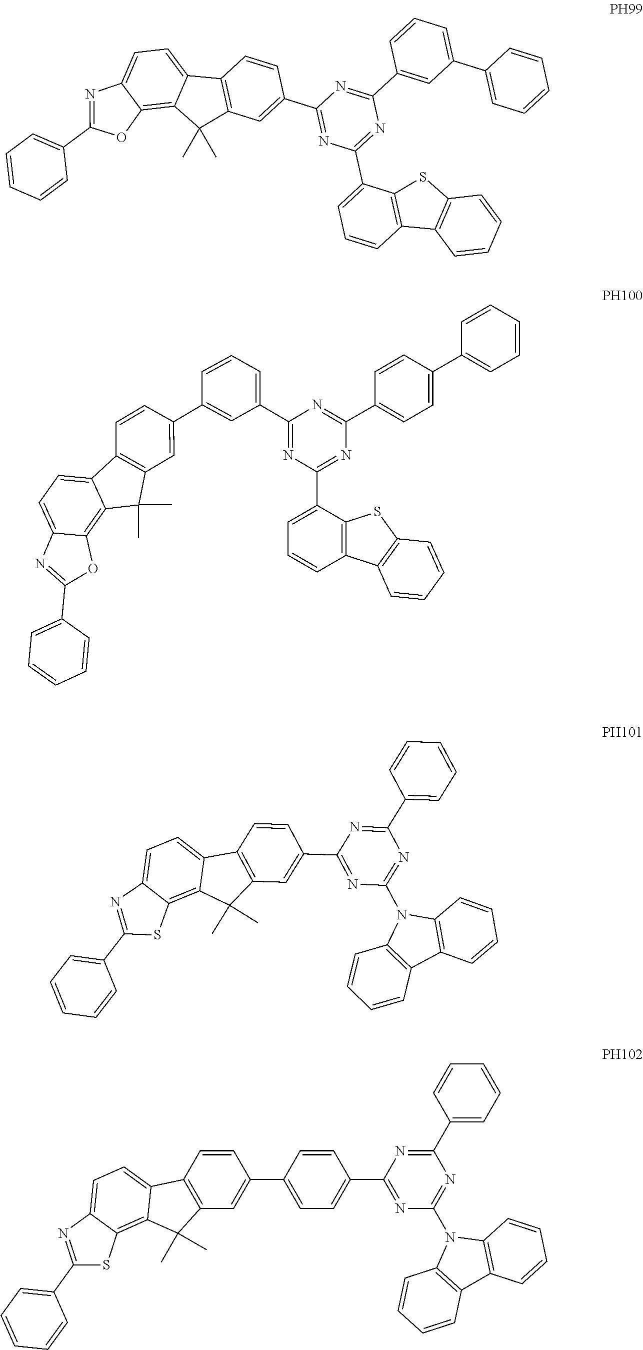 [SMILES: CC1(C)c2cc(-c3nc(-c4cccc(-c5ccccc5)c4)nc(-c4cccc5c4sc4ccccc45)n3)ccc2-c2ccc3nc(-c4ccccc4)oc3c21 ; CC1(C)c2cc(-c3cccc(-c4nc(-c5ccc(-c6ccccc6)cc5)nc(-c5cccc6c5sc5ccccc56)n4)c3)ccc2-c2ccc3nc(-c4ccccc4)oc3c21 ; CC1(C)c2cc(-c3nc(-c4ccccc4)nc(-n4c5ccccc5c5ccccc54)n3)ccc2-c2ccc3nc(-c4ccccc4)sc3c21 ; CC1(C)c2cc(-c3ccc(-c4nc(-c5ccccc5)nc(-n5c6ccccc6c6ccccc65)n4)cc3)ccc2-c2ccc3nc(-c4ccccc4)sc3c21]

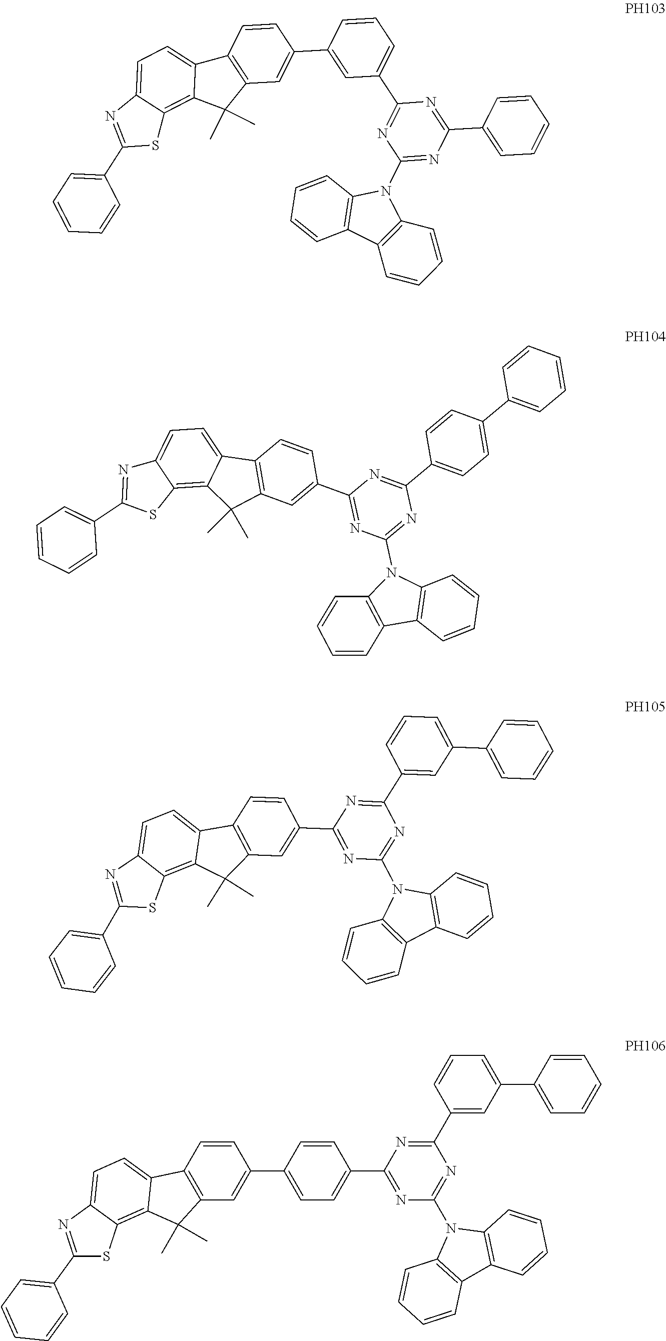 [SMILES: CC1(C)c2cc(-c3cccc(-c4nc(-c5ccccc5)nc(-n5c6ccccc6c6ccccc65)n4)c3)ccc2-c2ccc3nc(-c4ccccc4)sc3c21 ; CC1(C)c2cc(-c3nc(-c4ccc(-c5ccccc5)cc4)nc(-n4c5ccccc5c5ccccc54)n3)ccc2-c2ccc3nc(-c4ccccc4)sc3c21 ; CC1(C)c2cc(-c3nc(-c4cccc(-c5ccccc5)c4)nc(-n4c5ccccc5c5ccccc54)n3)ccc2-c2ccc3nc(-c4ccccc4)sc3c21 ; CC1(C)c2cc(-c3ccc(-c4nc(-c5cccc(-c6ccccc6)c5)nc(-n5c6ccccc6c6ccccc65)n4)cc3)ccc2-c2ccc3nc(-c4ccccc4)sc3c21]

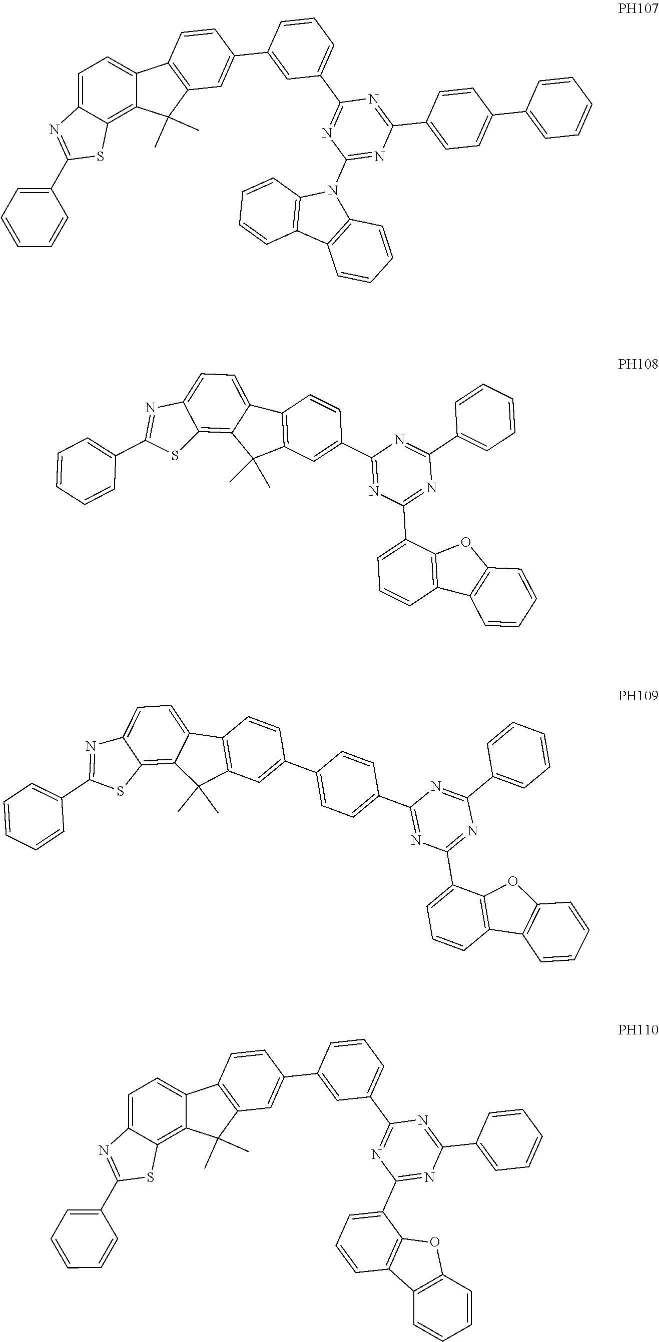 [SMILES: CC1(C)c2cc(-c3cccc(-c4nc(-c5ccc(-c6ccccc6)cc5)nc(-n5c6ccccc6c6ccccc65)n4)c3)ccc2-c2ccc3nc(-c4ccccc4)sc3c21 ; CC1(C)c2cc(-c3nc(-c4ccccc4)nc(-c4cccc5c4oc4ccccc45)n3)ccc2-c2ccc3nc(-c4ccccc4)sc3c21 ; CC1(C)c2cc(-c3ccc(-c4nc(-c5ccccc5)nc(-c5cccc6c5oc5ccccc56)n4)cc3)ccc2-c2ccc3nc(-c4ccccc4)sc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)sc3c21]

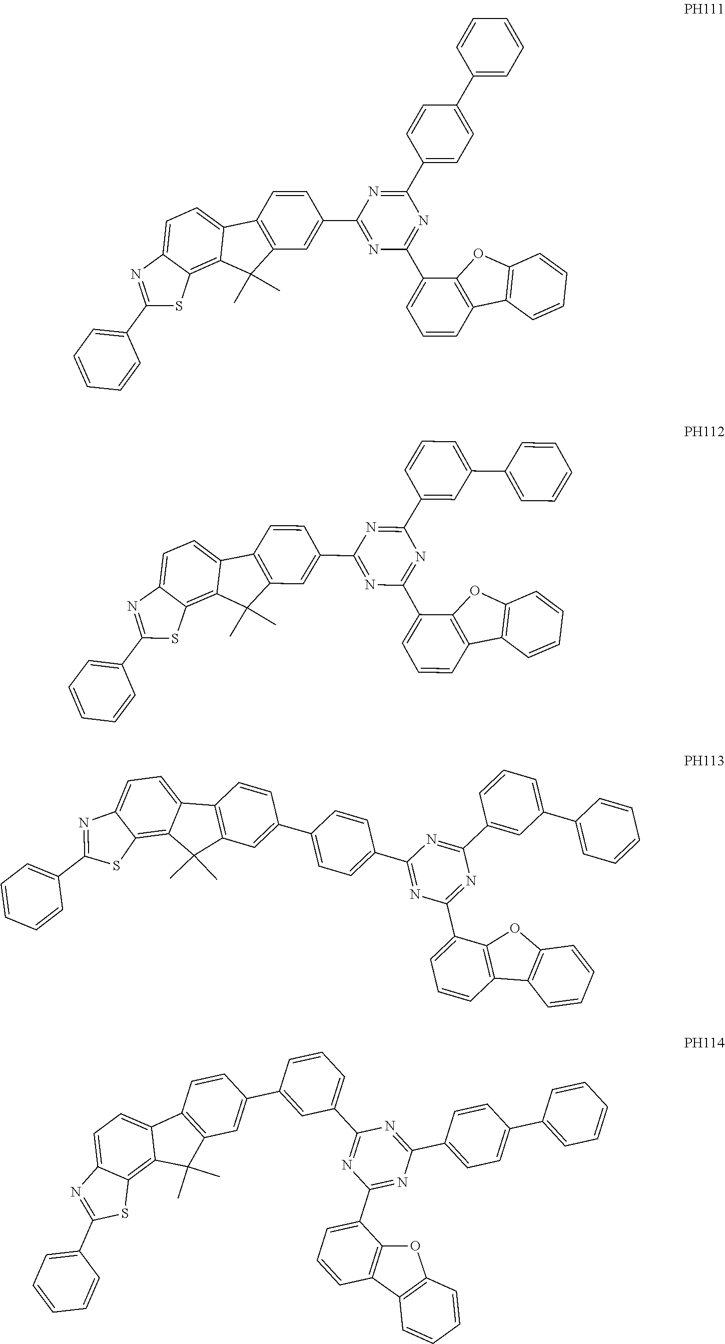 [SMILES: CC1(C)c2cc(-c3nc(-c4ccc(-c5ccccc5)cc4)nc(-c4cccc5c4oc4ccccc45)n3)ccc2-c2ccc3nc(-c4ccccc4)sc3c21 ; CC1(C)c2cc(-c3nc(-c4cccc(-c5ccccc5)c4)nc(-c4cccc5c4oc4ccccc45)n3)ccc2-c2ccc3nc(-c4ccccc4)sc3c21 ; CC1(C)c2cc(-c3ccc(-c4nc(-c5cccc(-c6ccccc6)c5)nc(-c5cccc6c5oc5ccccc56)n4)cc3)ccc2-c2ccc3nc(-c4ccccc4)sc3c21 ; CC1(C)c2cc(-c3cccc(-c4nc(-c5ccc(-c6ccccc6)cc5)nc(-c5cccc6c5oc5ccccc56)n4)c3)ccc2-c2ccc3nc(-c4ccccc4)sc3c21]

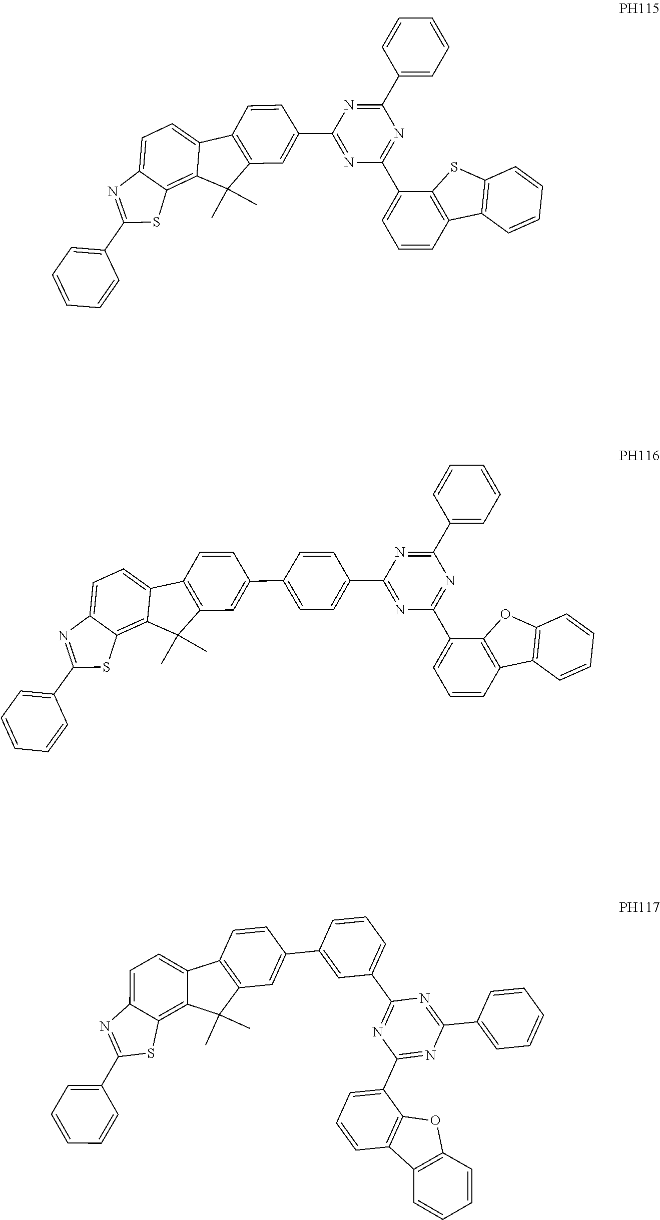 [SMILES: CC1(C)c2cc(-c3nc(-c4ccccc4)nc(-c4cccc5c4sc4ccccc45)n3)ccc2-c2ccc3nc(-c4ccccc4)sc3c21 ; CC1(C)c2cc(-c3ccc(-c4nc(-c5ccccc5)nc(-c5cccc6c5oc5ccccc56)n4)cc3)ccc2-c2ccc3nc(-c4ccccc4)sc3c21 ; CC1(C)c2cc(-c3cccc(-c4nc(-c5ccccc5)nc(-c5cccc6c5oc5ccccc56)n4)c3)ccc2-c2ccc3nc(-c4ccccc4)sc3c21]

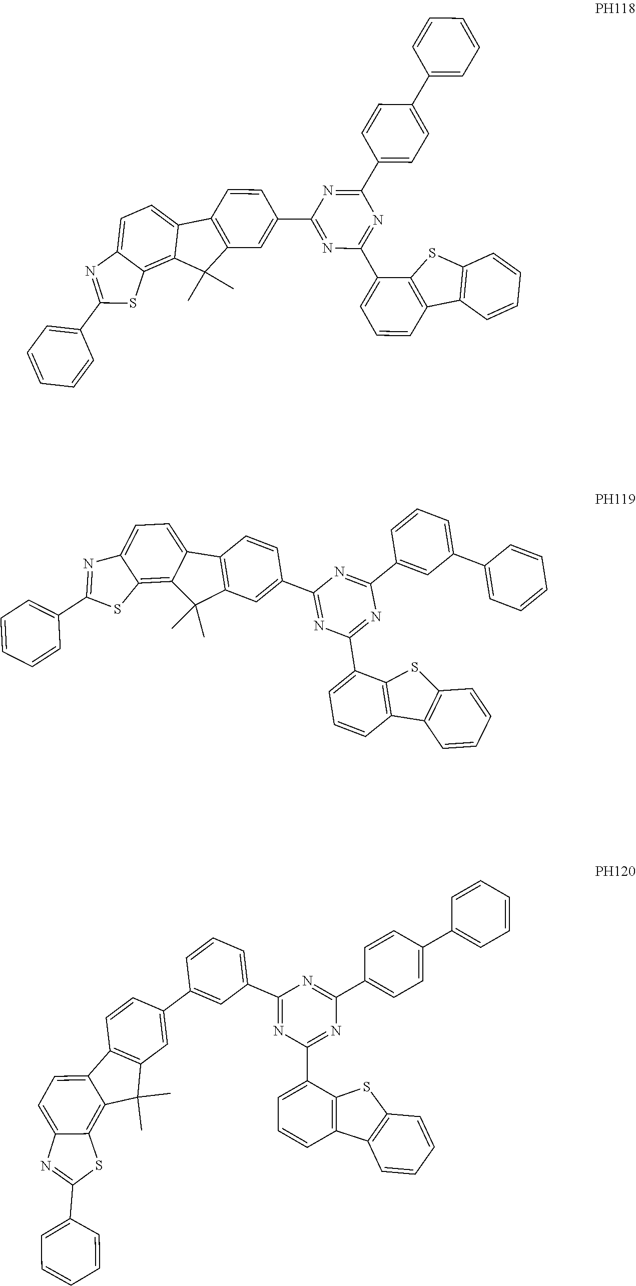 [SMILES: CC1(C)c2cc(-c3nc(-c4ccc(-c5ccccc5)cc4)nc(-c4cccc5c4sc4ccccc45)n3)ccc2-c2ccc3nc(-c4ccccc4)sc3c21 ; CC1(C)c2cc(-c3nc(-c4cccc(-c5ccccc5)c4)nc(-c4cccc5c4sc4ccccc45)n3)ccc2-c2ccc3nc(-c4ccccc4)sc3c21 ; CC1(C)c2cc(-c3cccc(-c4nc(-c5ccc(-c6ccccc6)cc5)nc(-c5cccc6c5sc5ccccc56)n4)c3)ccc2-c2ccc3nc(-c4ccccc4)sc3c21]

4. The organic light emitting element of claim 1, wherein the organic material layer includes a light emitting layer, and wherein the light emitting layer includes the compound.

5. The organic light emitting element of claim 4, wherein the organic material layer further includes at least one of a hole injection layer, a hole transport layer, an electron transport layer, and an electron injection layer.

6. The organic light emitting element of claim 4, wherein the compound is a host compound of the light emitting layer.

7. The organic light emitting element of claim 6, wherein the light emitting layer further includes a host compound different from the compound.

8. The organic light emitting element of claim 1, wherein the organic material layer includes a first stack including a first light emitting layer and a second stack including a second light emitting layer.

9. The organic light emitting element of claim 8, wherein the first light emitting layer includes the compound.

10. The organic light emitting element of claim 9, wherein the compound is a host compound of the first light emitting layer.

11. The organic light emitting element of claim 10, wherein the first light emitting layer further includes a host compound different from the compound.
